(19) United States
(12) Patent Application Publication
(10) Pub. No.: US 2024/0192591 A1
(43) Pub. Date: Jun. 13, 2024

(54) RESIST COMPOSITION AND PATTERN FORMING PROCESS

(71) Applicant: Shin-Etsu Chemical Co., Ltd., Tokyo (JP)

(72) Inventors: Jun Hatakeyama, Joetsu-shi (JP); Takayuki Fujiwara, Joetsu-shi (JP)

(73) Assignee: Shin-Etsu Chemical Co., Ltd., Tokyo (JP)

(21) Appl. No.: 18/380,970

(22) Filed: Oct. 17, 2023

(30) Foreign Application Priority Data
Oct. 24, 2022 (JP) 2022-169784

(51) Int. Cl. G03F 7/004; C08F 216/02; C08F 220/18; C08F 220/22; C08F 220/38; G03F 7/039; G03F 7/20

(52) U.S. Cl. CPC G03F 7/0045; C08F 216/02; C08F 220/1806; C08F 220/22; C08F 220/38; G03F 7/0048; G03F 7/0397; G03F 7/2004; G03F 7/2053; G03F 7/2059

(57) ABSTRACT

A resist composition comprising an acid generator containing a sulfonium salt containing a sulfonic acid anion having a carbon atom to which an iodine atom is bonded and a sulfonium cation having formula (1).

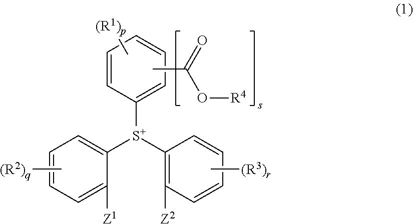

### CROSS-REFERENCE TO RELATED APPLICATIONS

This non-provisional application claims priority under 35 U.S.C. § 119(a) on Patent Application No. 2022-169784 filed in Japan on Oct. 24, 2022, the entire contents of which are hereby incorporated by reference.

### TECHNICAL FIELD

The present invention relates to a resist composition and a pattern forming process.

### BACKGROUND ART

To meet the demand for higher integration density and higher operating speed of LSIs, the effort to reduce the pattern rule is in rapid progress. As the use of 5G high-speed communications and artificial intelligence (AI) is widely spreading, high-performance devices are needed for their processing. As the most advanced miniaturization technology, mass production of microelectronic devices at the 5-nm node by the lithography using extreme ultraviolet (EUV) having a wavelength of 13.5 nm has been implemented. Studies are made on the application of EUV lithography to 3-nm node devices of the next generation and 2-nm node devices of the next-but-one generation. IMEC in Belgium announced its successful development of 1-nm and 0.7-nm node devices.

As the feature size reduces, image blurs due to acid diffusion become a problem. To ensure resolution for fine patterns of sub-45-nm size, not only an improvement in dissolution contrast is important as previously reported, but also the control of acid diffusion is important as reported in Non-Patent Document 1. Since chemically amplified resist compositions are designed such that sensitivity and contrast are enhanced by acid diffusion, an attempt to minimize acid diffusion by reducing the temperature and/or time of post exposure bake (PEB) fails, resulting in drastic reductions of sensitivity and contrast.

A triangular tradeoff relationship among sensitivity, resolution, and edge roughness (LWR) has been pointed out. Specifically, a resolution improvement requires to reduce acid diffusion whereas a short acid diffusion distance leads to a decline of sensitivity.

The addition of an acid generator capable of generating a bulky acid is an effective means for reducing acid diffusion. It was then proposed to incorporate repeat units derived from an onium salt having a polymerizable unsaturated bond in a polymer. Since this polymer functions as an acid generator, it is referred to as polymer-bound acid generator. Patent Document 1 discloses a sulfonium or iodonium salt having a polymerizable unsaturated bond and capable of generating a specific sulfonic acid. Patent Document 2 discloses a sulfonium salt having a sulfonic acid directly bonded to the backbone.

A resist composition has been proposed which has a triphenylsulfonium cation in which the 3-position of a phenyl group is substituted with an electron withdrawing group selected from a halogen atom, a halogenated alkyl group, an acyloxy group, an acyl group, a cyano group, a nitro group, and a sulfonyl group, and to which an acid generator that generates fluorosulphonic acid is added (Patent Document 3). In addition, a salt has been proposed which contains a triphenylsulfonium cation in which a phenyl group is substituted with an alkoxycarbonyl group, and a weak acid anion such as a carboxylic acid anion (Patent Document 4), and a salt has been proposed which contains a triphenylsulfonium cation in which a phenyl group is substituted with an alkoxycarbonyl group bonded to an aromatic group substituted with an iodine atom, and a strong acid anion such as a fluorosulphonic acid anion (Patent Document 5).

A resist composition containing an onium salt having an iodine atom in an anion has been proposed (Patent Documents 6 to 10). Iodine atoms strongly absorb EUV, and thus improve the acid generation efficiency and contrast. An improvement in the acid generation efficiency and contrast enables formation of a resist pattern having high sensitivity, high resolution, and good critical dimension uniformity (CDU). The present application has led to successive proposals for iodine atom-containing acid generators (Patent Documents 11 to 16).

### CITATION LIST

Patent Document 1: JP-A 2006-045311
Patent Document 2: JP-A 2006-178317
Patent Document 3: JP 6244109
Patent Document 4: JP-A 2022-068394
Patent Document 5: JP-A 2020-046661
Patent Document 6: JP-A 2018-005224
Patent Document 7: JP-A 2018-025789
Patent Document 8: JP-A 2018-155902
Patent Document 9: JP-A 2018-155908
Patent Document 10: JP-A 2018-159744
Patent Document 11: JP-A 2019-094323
Patent Document 12: JP-A: 2020-181064
Patent Document 13: JP-A 2021-187843
Patent Document 14: JP-A 2020-187844
Patent Document 15: JP-A 2022-075556
Patent Document 16: JP-A 2022-077892
Non-Patent Document 1: SPIE Vol. 6520 65203L-1 (2007)

### SUMMARY OF THE INVENTION

It is desired to develop a resist composition that has higher sensitivity than previous resist compositions and is capable of improving the LWR of line patterns and the CDU of hole patterns.

The present invention has been made in view of the above circumstances, and an object of the present invention is to provide a resist composition which exhibits higher sensitivity and improved LWR and CDU regardless of whether it is of positive or negative tone, and a pattern forming process using the resist composition.

As a result of intensive studies to achieve the above object, the present inventors have found that a resist composition having high sensitivity, improved LWR and CDU, high contrast, excellent resolution, and a wide process margin can be obtained by adding a sulfonium salt containing a sulfonic acid anion having a carbon atom to which an iodine atom is bonded and a triphenylsulfonium cation in which at least one phenyl group is substituted with a predetermined hydrocarbyloxycarbonyl group, and have completed the present invention.

That is, the present invention provides the following resist composition and pattern forming process.

1. A resist composition comprising an acid generator containing a sulfonium salt containing a sulfonic acid anion having a carbon atom to which an iodine atom is bonded and a sulfonium cation having formula (1):

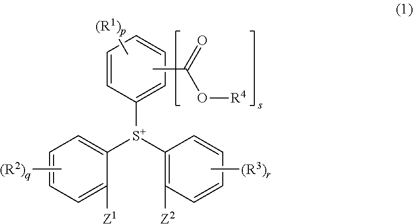

wherein p, q, and r are each independently an integer of 0 to 3, and s is 1 or 2, provided that 1≤r+s≤3,
R¹ is a halogen atom, a trifluoromethyl group, a trifluoromethoxy group, a trifluoromethylthio group, a nitro group, a cyano group, —C(═O)—R⁵, —O—C(═O)—R⁵, or —O—R⁵,
R² and R³ are each independently a halogen atom, a trifluoromethyl group, a trifluoromethoxy group, a trifluoromethylthio group, a nitro group, a cyano group, —C(═O)—O—R⁴, —C(═O)—R⁵, —O—C(═O)—R⁵, —O—C(═O)—O—R⁵, or —O—R⁵,
R⁴ is a C₁-C₁₀ aliphatic hydrocarbyl group, a C₆-C₁₂ aryl group, or a C₄-C₁₂ heteroaryl group, some or all of hydrogen atoms of these groups may be substituted with a halogen atom other than an iodine atom, a hydroxy group, a cyano group, a nitro group, a halogenated alkyl group, a halogenated alkoxy group, or a halogenated alkylthio group, and some of —CH₂— of these groups may be substituted with an ether bond, an ester bond, a carbonyl group, or a sulfonic ester bond, provided that R⁴ is not an acid labile group,
R⁵ is a C₁-C₁₀ hydrocarbyl group, and
Z¹ and Z² are each independently a hydrogen atom, a halogen atom, a trifluoromethyl group, a trifluoromethoxy group, a trifluoromethylthio group, a nitro group, a cyano group, —C(═O)—O—R⁴, —C(═O)—R⁵, —O—C(═O)—R⁵, —O—C(═O)—O—R⁵, or —O—R⁵, and Z¹ and Z² may together form a single bond, an ether bond, a carbonyl group, —N(R^{N})—, a sulfide bond, or a sulfonyl group, wherein R^{N} is a hydrogen atom or a C₁-C₆ saturated hydrocarbyl group.

2. The resist composition of item 1, wherein the sulfonic acid anion having a carbon atom to which an iodine atom is bonded has formula (2)-1:

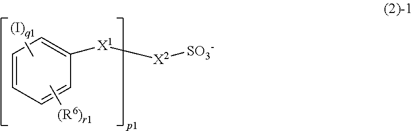

wherein p1 is an integer of 1 to 3, q1 is an integer of 1 to 5, and r1 is an integer of 0 to 4, provided that 1≤q1+r1≤5,
R⁶ is a hydroxy group, a carboxy group, a halogen atom other than an iodine atom, an amino group, or a C₁-C₂₀ hydrocarbyl group, a C₁-C₂₀ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a halogen atom, a hydroxy group, an amino group, or an ether bond, —N(R^{6A})(R^{6B}), —N(R^{6C})—C(═O)—R^{6D}, or —N(R^{6C})—C(═O)—O—R^{6D}, wherein R^{6A} and R^{6B} are each independently a hydrogen atom or a C₁-C₆ saturated hydrocarbyl group, R^{6C} is a hydrogen atom or a C₁-C₆ saturated hydrocarbyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group, R^{6D} is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group,
X¹ is a single bond, an ether bond, an amide bond, a urethane bond, an ester bond, or a C₁-C₆ saturated hydrocarbylene group which may contain an ether bond or an ester bond, and
X² is a single bond or a C₁-C₂₂ divalent linking group when p1 is 1, and a C₁-C₂₂ (p1+1)-valent linking group which may contain an oxygen atom, a sulfur atom, a nitrogen atom, or a halogen atom when p1 is 2 or 3.

3. The resist composition of item 1, wherein the sulfonic acid anion having a carbon atom to which an iodine atom is bonded has formula (2)-2:

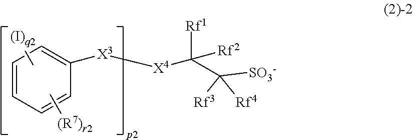

wherein p2 is an integer of 1 to 3, q2 is an integer of 1 to 5, and r2 is an integer of 0 to 4, provided that 1≤q2+r2≤5,
R⁷ is a hydroxy group, a carboxy group, a halogen atom other than an iodine atom, an amino group, or a C₁-C₂₀ hydrocarbyl group, a C₁-C₂₀ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a halogen atom, a hydroxy group, an amino group, or an ether bond, —N(R^{7A})(R^{7B}), —N(R^{7C})—C(═O)—R^{7D}, or —N(R^{7C})—C(═O)—O—R^{7D}, wherein R^{7A} and R^{7B} are each independently a hydrogen atom or a C₁-C₆ saturated hydrocarbyl group, R^{7C} is a hydrogen atom or a C₁-C₆ saturated hydrocarbyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group, R^{7D} is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group,
X³ is a single bond, an ether bond, an amide bond, a urethane bond, an ester bond, or a C₁-C₆ saturated hydrocarbylene group which may contain an ether bond or an ester bond,
X⁴ is a single bond or a C₁-C₂₀ divalent linking group when p2 is 1, and a C₁-C₂₀ (p2+1)-valent linking group which may contain an oxygen atom, a sulfur atom, or a nitrogen atom when p2 is 2 or 3, and
Rf¹ to Rf⁴ are each independently a hydrogen atom, a fluorine atom, or a trifluoromethyl group, at least one of Rf¹ to Rf⁴ is a fluorine atom or a trifluoromethyl group, and Rf¹ and Rf² may together form a carbonyl group.

4. The resist composition of any one of items 1 to 3, further comprising a base polymer.

5. The resist composition of item 4, wherein the base polymer further contains repeat units having formula (a1) or (a2):

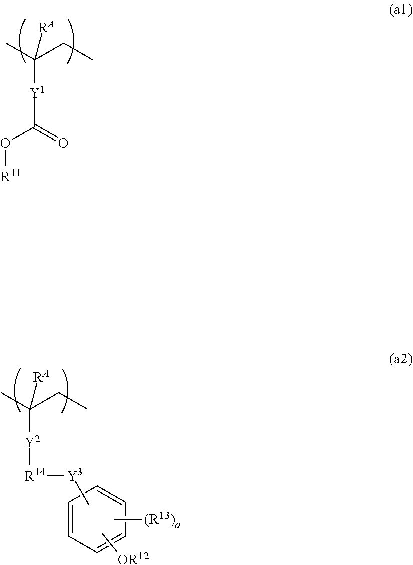

wherein R^{A} is each independently a hydrogen atom or a methyl group,
Y¹ is a single bond, a phenylene group, a naphthylene group, or a C₁-C₁₂ linking group containing at least one moiety selected from an ester bond, an ether bond, and a lactone ring,
Y² is a single bond or an ester bond,
Y³ is a single bond, an ether bond, or an ester bond,
R¹¹ and R¹² are each independently an acid labile group,
R¹³ is a C₁-C₄ saturated hydrocarbyl group, a halogen atom, a C₂-C₅ saturated hydrocarbylcarbonyl group, a cyano group, or a C₂-C₅ saturated hydrocarbyloxycarbonyl group,
R¹⁴ is a single bond or a C₁-C₆ alkanediyl group which may contain an ether bond or an ester bond, and
a is an integer of 0 to 4.

6. The resist composition of item 5, which is a chemically amplified positive resist composition.

7. The resist composition of item 4, wherein the base polymer is free of an acid labile group.

8. The resist composition of item 7, which is a chemically amplified negative resist composition.

9. The resist composition of any one of items 1 to 8, further comprising an organic solvent.

10. The resist composition of any one of items 1 to 9, further comprising a quencher.

11. The resist composition of any one of items 1 to 10, further comprising a surfactant.

12. A pattern forming process comprising the steps of:
applying the resist composition of any one of items 1 to 11 onto a substrate to form a resist film thereon,
exposing the resist film to high-energy radiation, and
developing the exposed resist film in a developer.

13. The pattern forming process of item 12, wherein the high-energy radiation is ArF excimer laser having a wavelength of 193 nm, KrF excimer laser having a wavelength of 248 nm, electron beam, or extreme ultraviolet having a wavelength of 3 to 15 nm.

### Advantageous Effects of the Invention

In a resist film comprising, as an acid generator, a sulfonium salt containing a sulfonic acid anion having a carbon atom to which an iodine atom is bonded and a sulfonium cation having formula (1), the cation decomposition efficiency during exposure is high due to the electron withdrawing effect of the hydrocarbyloxycarbonyl group, and the hydrocarbyloxycarbonyl group also has a high acid diffusion controlling effect. In addition, the acid generator has an increased absorption capability due to an iodine atom that strongly absorbs EUV in the anion, and this also improves the decomposition efficiency in exposure, and the variation in the number of photons is reduced by an increase of the number of absorbed photons, so that the absorption contrast is improved. This makes it possible to prevent a reduction of resolution due to blur by acid diffusion and to improve the LWR and CDU. The effect of improving the LWR and CDU by the acid generator is exerted in both positive pattern formation and negative pattern formation by alkaline aqueous solution development and negative pattern formation by organic solvent development.

### DETAILED DESCRIPTION OF THE INVENTION

Resist Composition

The resist composition of the present invention comprises, as an acid generator, a sulfonium salt containing a sulfonic acid anion having a carbon atom to which an iodine atom is bonded and a triphenylsulfonium cation in which at least one phenyl group is substituted with a predetermined hydrocarbyloxycarbonyl group.

Acid Generator

The sulfonium cation has formula (1).

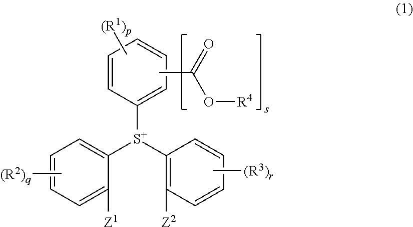

In formula (1), p, q, and r are each independently an integer of 0 to 3, and s is 1 or 2, provided that 1≤r+s≤3.

In formula (1), R¹ is a halogen atom, a trifluoromethyl group, a trifluoromethoxy group, a trifluoromethylthio group, a nitro group, a cyano group, —C(═O)—R⁵, —O—C(═O)—R⁵, or —O—R⁵.

In formula (1), R² and R³ are each independently a halogen atom, a trifluoromethyl group, a trifluoromethoxy group, a trifluoromethylthio group, a nitro group, a cyano group, —C(═O)—O—R⁴, —C(═O)—R⁵, —O—C(═O)—R⁵, —O—C(═O)—O—R⁵, or —O—R⁵.

In formula (1), R⁴ is a C₁-C₁₀ aliphatic hydrocarbyl group, a C₆-C₁₂ aryl group, or a C₄-C₁₂ heteroaryl group, some or all of hydrogen atoms of these groups may be substituted with a halogen atom other than an iodine atom, a hydroxy group, a cyano group, a nitro group, a halogenated alkyl group, a halogenated alkoxy group, or a halogenated alkylthio group, and some of —CH₂— of these groups may be substituted with an ether bond, an ester bond, a carbonyl group, or a sulfonic ester bond.

The C₁-C₁₀ aliphatic hydrocarbyl group represented by R⁴ may be saturated or unsaturated, and may be straight, branched, or cyclic. Examples thereof include C₁-C₁₀ alkyl groups such as a methyl group, an ethyl group, a n-propyl group, an isopropyl group, a n-butyl group, an isobutyl group, a sec-butyl group, a n-pentyl group, an isopentyl group, a sec-pentyl group, a 3-pentyl group, a neopentyl group, a n-hexyl group, a n-octyl group, a n-nonyl group, and a n-decyl group; C₃-C₁₀ cyclic saturated hydrocarbyl groups such as a cyclopropyl group, a cyclobutyl group, a cyclopentyl group, a cyclohexyl group, an adamantyl group, a norbornyl group, a cyclopropylmethyl group, a cyclopropylethyl group, a cyclobutylmethyl group, a cyclobutylethyl group, a cyclopentylmethyl group, a cyclopentylethyl group, a cyclohexylmethyl group, a cyclohexylethyl group, a methylcyclopropyl group, a methylcyclobutyl group, a methylcyclopentyl group, a methylcyclohexyl group, an ethylcyclopropyl group, an ethylcyclobutyl group, an ethylcyclopentyl group, and an ethylcyclohexyl group; C₂-C₁₀ alkenyl groups such as a vinyl group, a 1-propenyl group, a 2-propenyl group, a butenyl group, a pentenyl group, a hexenyl group, a heptenyl group, a nonenyl group, and a decenyl group; C₂-C₁₀ alkynyl groups such as an ethynyl group, a propynyl group, a butynyl group, a pentynyl group, a hexynyl group, a heptynyl group, an octynyl group, a nonynyl group, and a decynyl group; C₃-C₁₀ cyclic unsaturated aliphatic hydrocarbyl groups such as a cyclopentenyl group, a cyclohexenyl group, a methylcyclopentenyl group, a methylcyclohexenyl group, an ethylcyclopentenyl group, an ethylcyclohexenyl group, and a norbornenyl group; and groups obtained by combining the foregoing.

Examples of the C₆-C₁₂ aryl group represented by R⁴ include a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, an indanyl group, and a tetralinyl group. Examples of the C₄-C₁₂ heteroaryl group represented by R⁴ include a furyl group and a thienyl group.

R⁴ is not an acid labile group. For example, the following 1) to 3) correspond to the case where R⁴ is an acid labile group.

1) The carbon atom bonded to the oxygen atom of the ester bond is a tertiary carbon atom, and the alkyl group bonded to the tertiary carbon atom does not contain a halogen atom, a cyano group, or a nitro group.

2) The carbon atom bonded to the oxygen atom of the ester bond is a secondary carbon atom, and R⁴ has a cyclic structure containing the secondary carbon atom, does not contain a heteroatom such as an oxygen atom, a sulfur atom, a nitrogen atom, or a halogen atom, and has a double bond, a triple bond, or an aromatic group on a carbon atom other than the carbon atom bonded to the oxygen atom of the ester bond.

3) R⁴ is an acetal group having an ether bond next to the carbon atom bonded to the oxygen atom of the ester bond.

R⁵ is a C₁-C₁₀ hydrocarbyl group. The hydrocarbyl group may be saturated or unsaturated, and may be straight, branched, or cyclic. Examples thereof include C₁-C₁₀ alkyl groups such as a methyl group, an ethyl group, a n-propyl group, an isopropyl group, a n-butyl group, an isobutyl group, a sec-butyl group, a tert-butyl group, a n-pentyl group, an isopentyl group, a sec-pentyl group, a 3-pentyl group, a tert-pentyl group, a neopentyl group, a n-hexyl group, a n-octyl group, a n-nonyl group, and a n-decyl group; C₃-C₁₀ cyclic saturated hydrocarbyl groups such as a cyclopropyl group, a cyclobutyl group, a cyclopentyl group, a cyclohexyl group, an adamantyl group, a norbornyl group, a cyclopropylmethyl group, a cyclopropylethyl group, a cyclobutylmethyl group, a cyclobutylethyl group, a cyclopentylmethyl group, a cyclopentylethyl group, a cyclohexylmethyl group, a cyclohexylethyl group, a methylcyclopropyl group, a methylcyclobutyl group, a methylcyclopentyl group, a methylcyclohexyl group, an ethylcyclopropyl group, an ethylcyclobutyl group, an ethylcyclopentyl group, and an ethylcyclohexyl group; C₂-C₁₀ alkenyl groups such as a vinyl group, a 1-propenyl group, a 2-propenyl group, a butenyl group, a pentenyl group, a hexenyl group, a heptenyl group, a nonenyl group, and a decenyl group; C₂-C₁₀ alkynyl groups such as an ethynyl group, a propynyl group, a butynyl group, a pentynyl group, a hexynyl group, a heptynyl group, an octynyl group, a nonynyl group, and a decynyl group; C₃-C₁₀ cyclic unsaturated aliphatic hydrocarbyl groups such as a cyclopentenyl group, a cyclohexenyl group, a methylcyclopentenyl group, a methylcyclohexenyl group, an ethylcyclopentenyl group, an ethylcyclohexenyl group, and a norbornenyl group; C₆-C₁₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, and a naphthyl group; C₇-C₁₀ aralkyl groups such as a benzyl group, a phenethyl group, a phenylpropyl group, and a phenylbutyl group; and groups obtained by combining the foregoing.

In formula (1), Z¹ and Z² are each independently a hydrogen atom, a halogen atom, a trifluoromethyl group, a trifluoromethoxy group, a trifluoromethylthio group, a nitro group, a cyano group, —C(═O)—O—R⁴, —C(═O)—R⁵, —O—C(═O)—R⁵, —O—C(═O)—O—R⁵, or —O—R⁵. Z¹ and Z² may together form a single bond, an ether bond, a carbonyl group, —N(R^{N})—, a sulfide bond, or a sulfonyl group. R^{N} is a hydrogen atom or a C₁-C₆ saturated hydrocarbyl group.

Examples of the structure formed by Z¹ and Z² together in the sulfonium cation having formula (1) include those shown below.

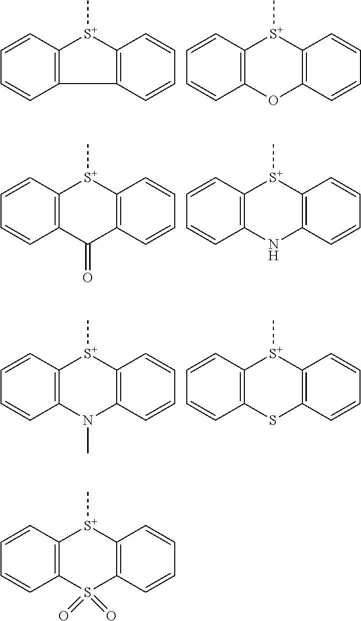

In the formulae, a broken line designates a bond.

Examples of the sulfonium cation having formula (1) include those shown below, but are not limited thereto.

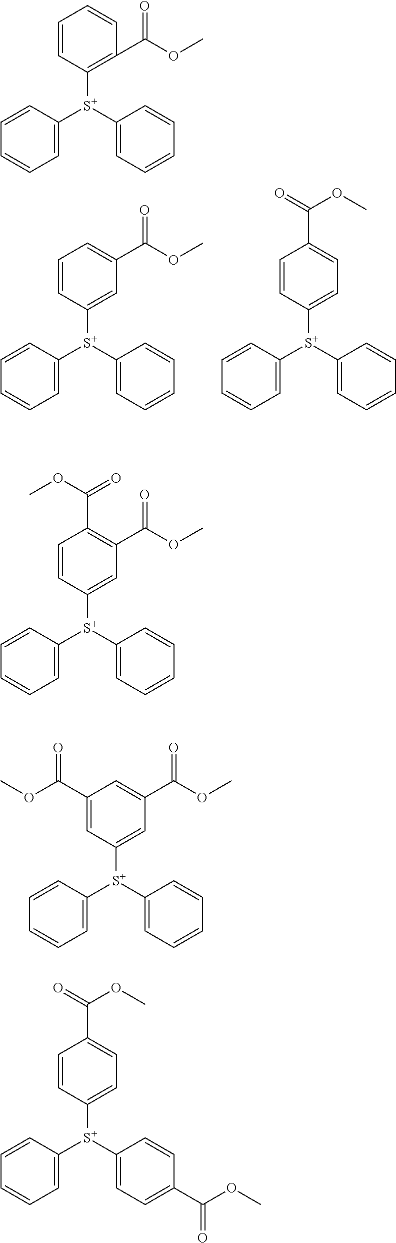

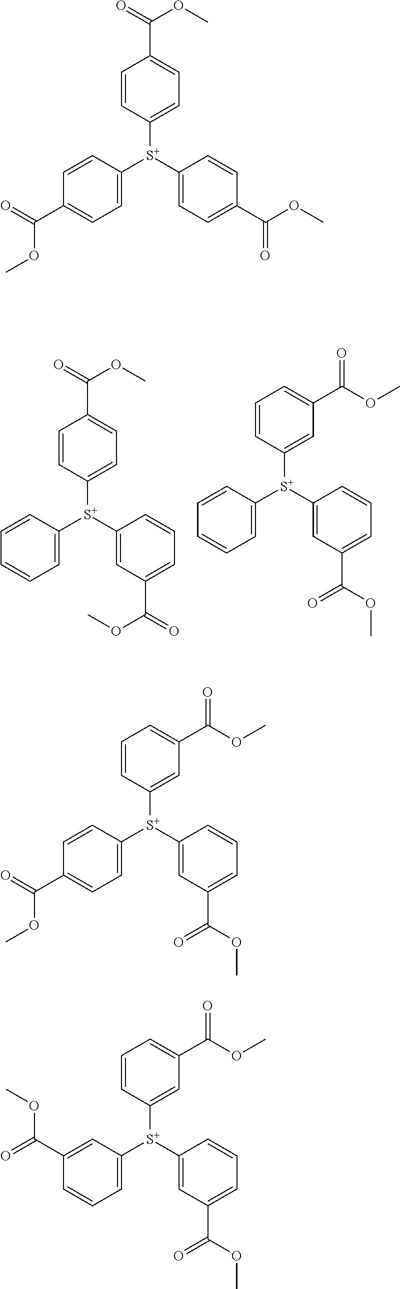 [SMILES: COC(=O)c1ccc([S+](c2ccc(C(=O)OC)cc2)c2ccc(C(=O)OC)cc2)cc1 ; COC(=O)c1ccc([S+](c2ccccc2)c2cccc(C(=O)OC)c2)cc1 ; COC(=O)c1cccc([S+](c2ccccc2)c2cccc(C(=O)OC)c2)c1 ; COC(=O)c1ccc([S+](c2cccc(C(=O)OC)c2)c2cccc(C(=O)OC)c2)cc1 ; COC(=O)c1cccc([S+](c2cccc(C(=O)OC)c2)c2cccc(C(=O)OC)c2)c1]

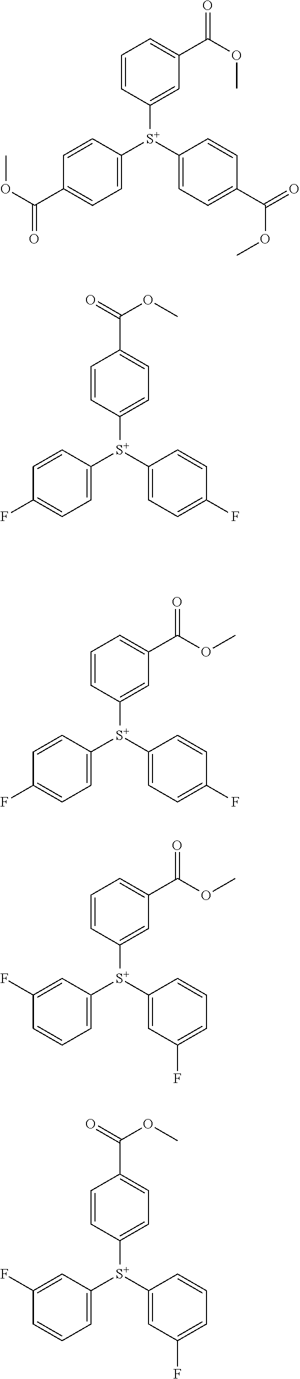 [SMILES: COC(=O)c1ccc([S+](c2ccc(C(=O)OC)cc2)c2cccc(C(=O)OC)c2)cc1 ; COC(=O)c1ccc([S+](c2ccc(F)cc2)c2ccc(F)cc2)cc1 ; COC(=O)c1cccc([S+](c2ccc(F)cc2)c2ccc(F)cc2)c1 ; COC(=O)c1cccc([S+](c2cccc(F)c2)c2cccc(F)c2)c1 ; COC(=O)c1ccc([S+](c2cccc(F)c2)c2cccc(F)c2)cc1]

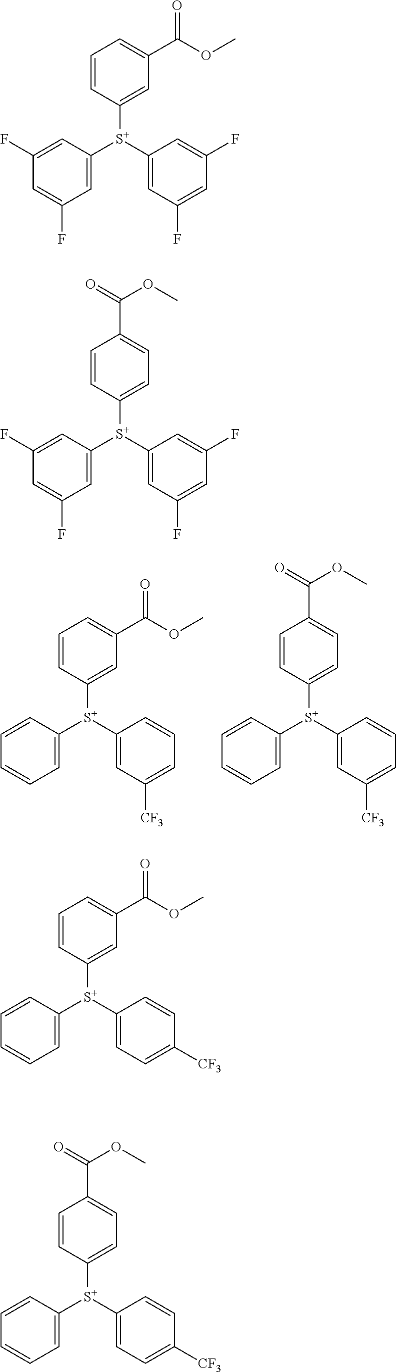 [SMILES: COC(=O)c1cccc([S+](c2cc(F)cc(F)c2)c2cc(F)cc(F)c2)c1 ; COC(=O)c1ccc([S+](c2cc(F)cc(F)c2)c2cc(F)cc(F)c2)cc1 ; COC(=O)c1cccc([S+](c2ccccc2)c2cccc(C(F)(F)F)c2)c1 ; COC(=O)c1ccc([S+](c2ccccc2)c2cccc(C(F)(F)F)c2)cc1 ; COC(=O)c1cccc([S+](c2ccccc2)c2ccc(C(F)(F)F)cc2)c1 ; COC(=O)c1ccc([S+](c2ccccc2)c2ccc(C(F)(F)F)cc2)cc1]

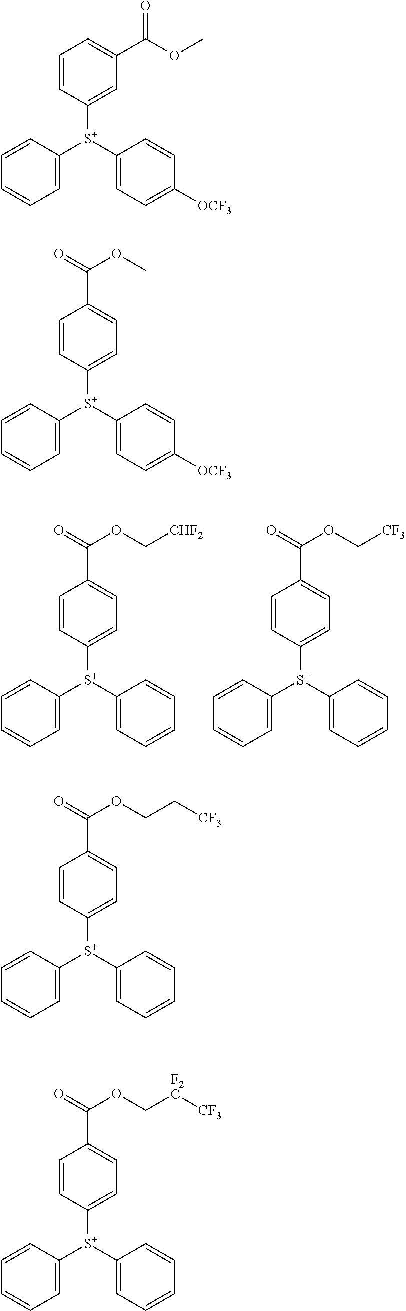 [SMILES: COC(=O)c1cccc([S+](c2ccccc2)c2ccc(OC(F)(F)F)cc2)c1 ; COC(=O)c1ccc([S+](c2ccccc2)c2ccc(OC(F)(F)F)cc2)cc1 ; O=C(OCC(F)F)c1ccc([S+](c2ccccc2)c2ccccc2)cc1 ; O=C(OCC(F)(F)F)c1ccc([S+](c2ccccc2)c2ccccc2)cc1 ; O=C(OCCC(F)(F)F)c1ccc([S+](c2ccccc2)c2ccccc2)cc1 ; O=C(OCC(F)(F)C(F)(F)F)c1ccc([S+](c2ccccc2)c2ccccc2)cc1]

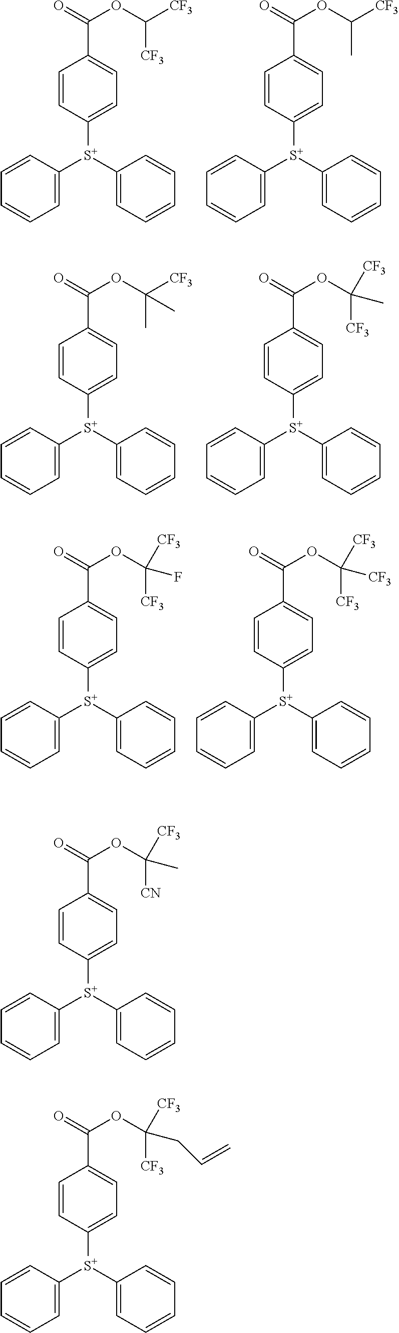

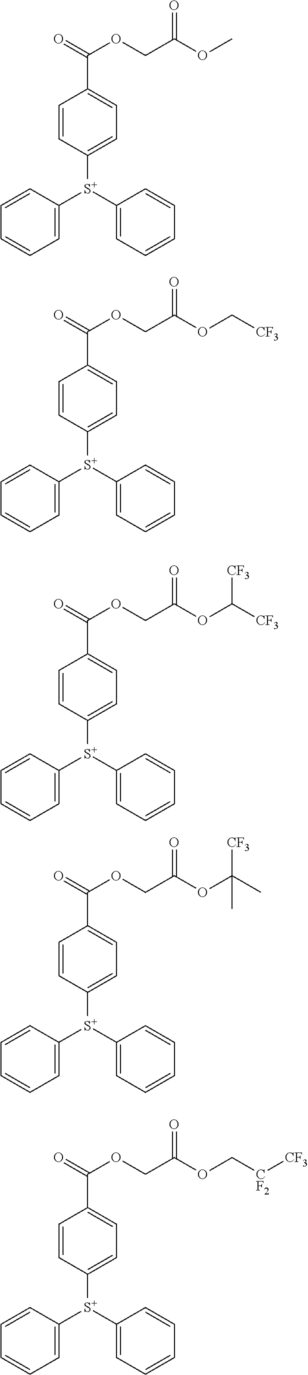 [SMILES: COC(=O)COC(=O)c1ccc([S+](c2ccccc2)c2ccccc2)cc1 ; O=C(COC(=O)c1ccc([S+](c2ccccc2)c2ccccc2)cc1)OCC(F)(F)F ; O=C(COC(=O)c1ccc([S+](c2ccccc2)c2ccccc2)cc1)OC(C(F)(F)F)C(F)(F)F ; CC(C)(OC(=O)COC(=O)c1ccc([S+](c2ccccc2)c2ccccc2)cc1)C(F)(F)F ; O=C(COC(=O)c1ccc([S+](c2ccccc2)c2ccccc2)cc1)OCC(F)(F)C(F)(F)F]

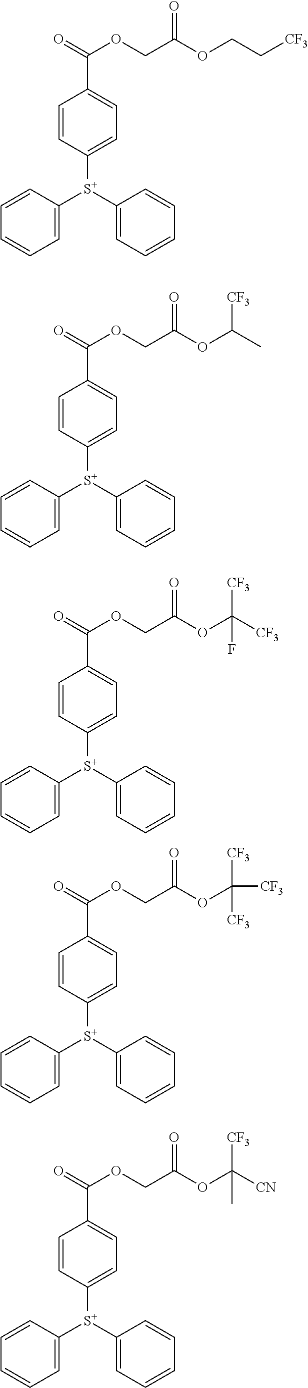 [SMILES: O=C(COC(=O)c1ccc([S+](c2ccccc2)c2ccccc2)cc1)OCCC(F)(F)F ; CC(OC(=O)COC(=O)c1ccc([S+](c2ccccc2)c2ccccc2)cc1)C(F)(F)F ; O=C(COC(=O)c1ccc([S+](c2ccccc2)c2ccccc2)cc1)OC(F)(C(F)(F)F)C(F)(F)F ; O=C(COC(=O)c1ccc([S+](c2ccccc2)c2ccccc2)cc1)OC(C(F)(F)F)(C(F)(F)F)C(F)(F)F ; CC(C#N)(OC(=O)COC(=O)c1ccc([S+](c2ccccc2)c2ccccc2)cc1)C(F)(F)F]

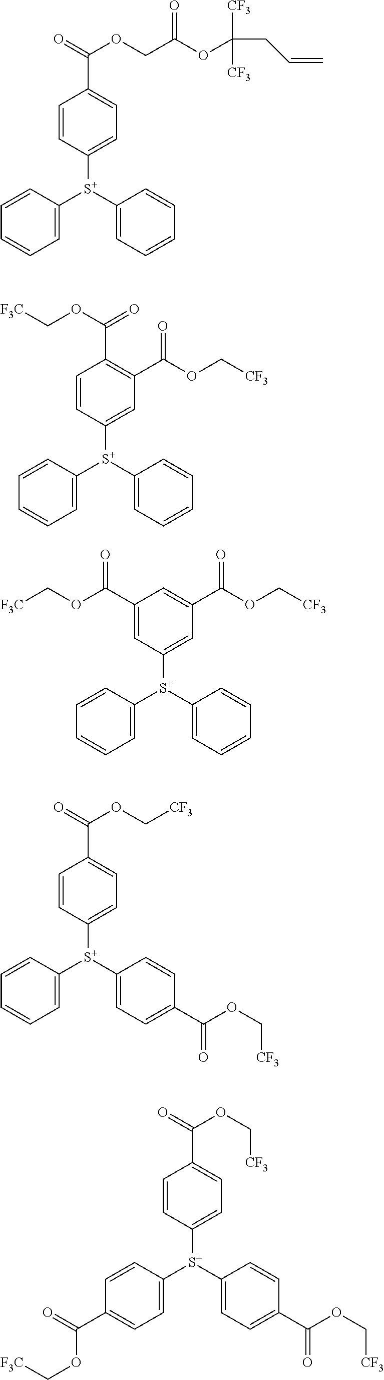 [SMILES: C=CCC(OC(=O)COC(=O)c1ccc([S+](c2ccccc2)c2ccccc2)cc1)(C(F)(F)F)C(F)(F)F ; O=C(OCC(F)(F)F)c1ccc([S+](c2ccccc2)c2ccccc2)cc1C(=O)OCC(F)(F)F ; O=C(OCC(F)(F)F)c1cc(C(=O)OCC(F)(F)F)cc([S+](c2ccccc2)c2ccccc2)c1 ; O=C(OCC(F)(F)F)c1ccc([S+](c2ccccc2)c2ccc(C(=O)OCC(F)(F)F)cc2)cc1 ; O=C(OCC(F)(F)F)c1ccc([S+](c2ccc(C(=O)OCC(F)(F)F)cc2)c2ccc(C(=O)OCC(F)(F)F)cc2)cc1]

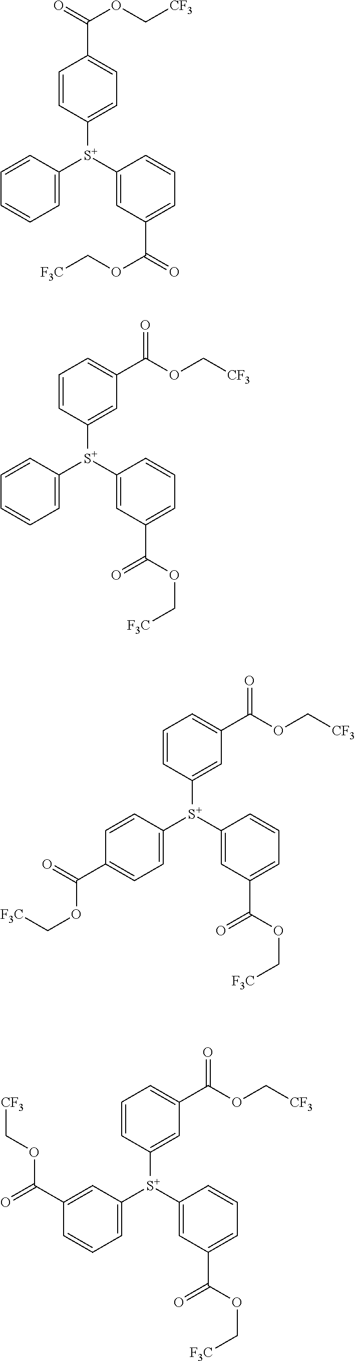 [SMILES: O=C(OCC(F)(F)F)c1ccc([S+](c2ccccc2)c2cccc(C(=O)OCC(F)(F)F)c2)cc1 ; O=C(OCC(F)(F)F)c1cccc([S+](c2ccccc2)c2cccc(C(=O)OCC(F)(F)F)c2)c1 ; O=C(OCC(F)(F)F)c1ccc([S+](c2cccc(C(=O)OCC(F)(F)F)c2)c2cccc(C(=O)OCC(F)(F)F)c2)cc1 ; O=C(OCC(F)(F)F)c1cccc([S+](c2cccc(C(=O)OCC(F)(F)F)c2)c2cccc(C(=O)OCC(F)(F)F)c2)c1]

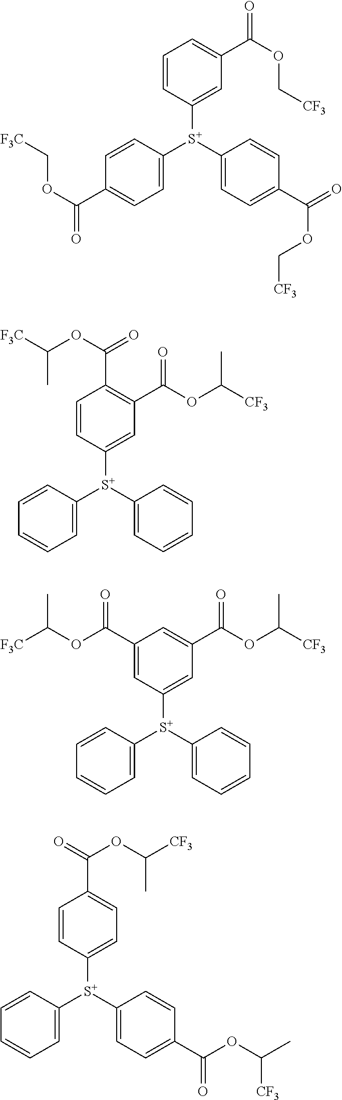 [SMILES: O=C(OCC(F)(F)F)c1ccc([S+](c2ccc(C(=O)OCC(F)(F)F)cc2)c2cccc(C(=O)OCC(F)(F)F)c2)cc1 ; CC(OC(=O)c1ccc([S+](c2ccccc2)c2ccccc2)cc1C(=O)OC(C)C(F)(F)F)C(F)(F)F ; CC(OC(=O)c1cc(C(=O)OC(C)C(F)(F)F)cc([S+](c2ccccc2)c2ccccc2)c1)C(F)(F)F ; CC(OC(=O)c1ccc([S+](c2ccccc2)c2ccc(C(=O)OC(C)C(F)(F)F)cc2)cc1)C(F)(F)F]

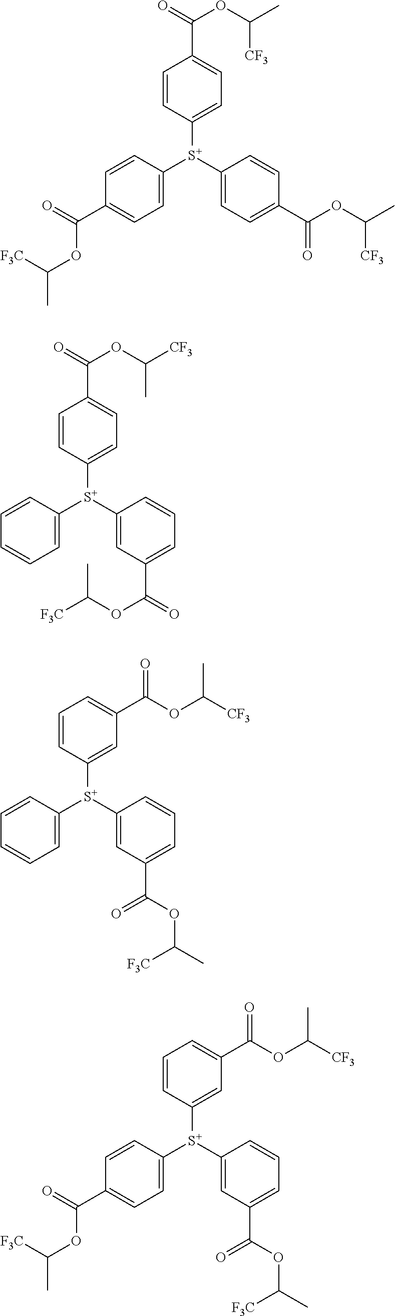 [SMILES: CC(OC(=O)c1ccc([S+](c2ccc(C(=O)OC(C)C(F)(F)F)cc2)c2ccc(C(=O)OC(C)C(F)(F)F)cc2)cc1)C(F)(F)F ; CC(OC(=O)c1ccc([S+](c2ccccc2)c2cccc(C(=O)OC(C)C(F)(F)F)c2)cc1)C(F)(F)F ; CC(OC(=O)c1cccc([S+](c2ccccc2)c2cccc(C(=O)OC(C)C(F)(F)F)c2)c1)C(F)(F)F ; CC(OC(=O)c1ccc([S+](c2cccc(C(=O)OC(C)C(F)(F)F)c2)c2cccc(C(=O)OC(C)C(F)(F)F)c2)cc1)C(F)(F)F]

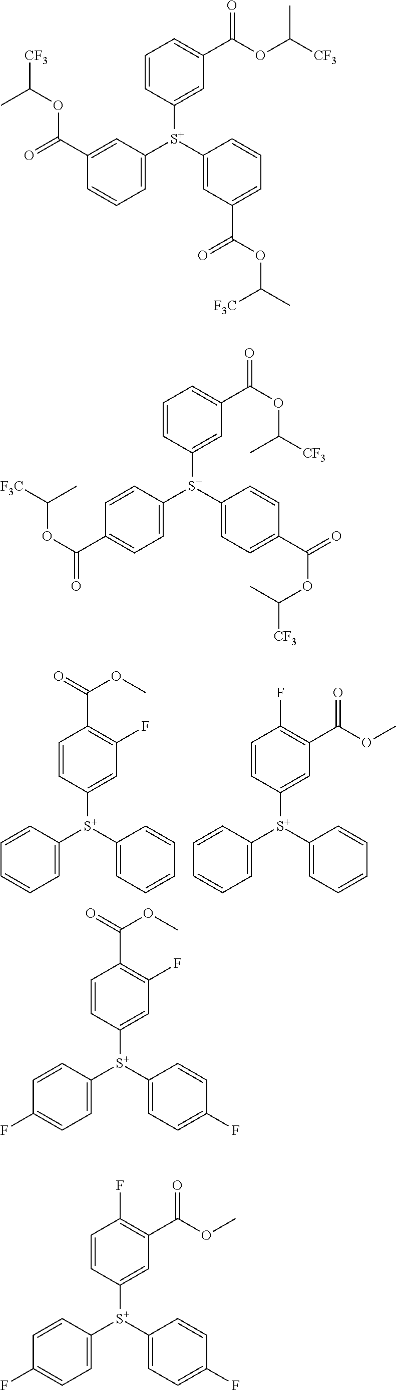 [SMILES: CC(OC(=O)c1cccc([S+](c2cccc(C(=O)OC(C)C(F)(F)F)c2)c2cccc(C(=O)OC(C)C(F)(F)F)c2)c1)C(F)(F)F ; CC(OC(=O)c1ccc([S+](c2ccc(C(=O)OC(C)C(F)(F)F)cc2)c2cccc(C(=O)OC(C)C(F)(F)F)c2)cc1)C(F)(F)F ; COC(=O)c1ccc([S+](c2ccccc2)c2ccccc2)cc1F ; COC(=O)c1cc([S+](c2ccccc2)c2ccccc2)ccc1F ; COC(=O)c1ccc([S+](c2ccc(F)cc2)c2ccc(F)cc2)cc1F ; COC(=O)c1cc([S+](c2ccc(F)cc2)c2ccc(F)cc2)ccc1F]

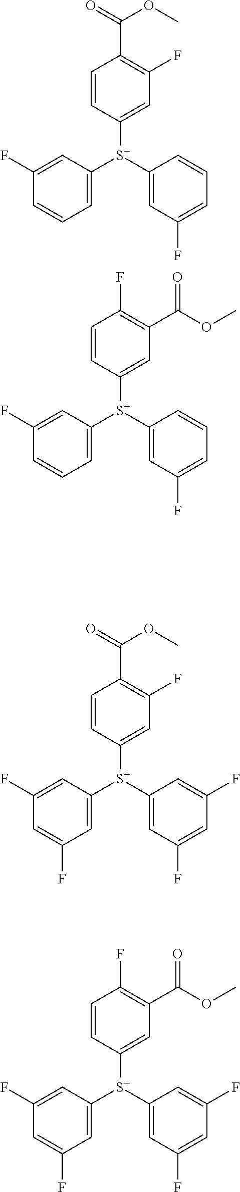 [SMILES: COC(=O)c1ccc([S+](c2cccc(F)c2)c2cccc(F)c2)cc1F ; COC(=O)c1cc([S+](c2cccc(F)c2)c2cccc(F)c2)ccc1F ; COC(=O)c1ccc([S+](c2cc(F)cc(F)c2)c2cc(F)cc(F)c2)cc1F ; COC(=O)c1cc([S+](c2cc(F)cc(F)c2)c2cc(F)cc(F)c2)ccc1F]

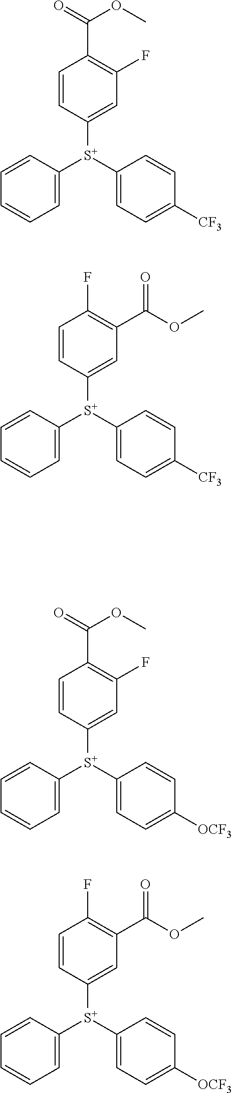 [SMILES: COC(=O)c1ccc([S+](c2ccccc2)c2ccc(C(F)(F)F)cc2)cc1F ; COC(=O)c1cc([S+](c2ccccc2)c2ccc(C(F)(F)F)cc2)ccc1F ; COC(=O)c1ccc([S+](c2ccccc2)c2ccc(OC(F)(F)F)cc2)cc1F ; COC(=O)c1cc([S+](c2ccccc2)c2ccc(OC(F)(F)F)cc2)ccc1F]

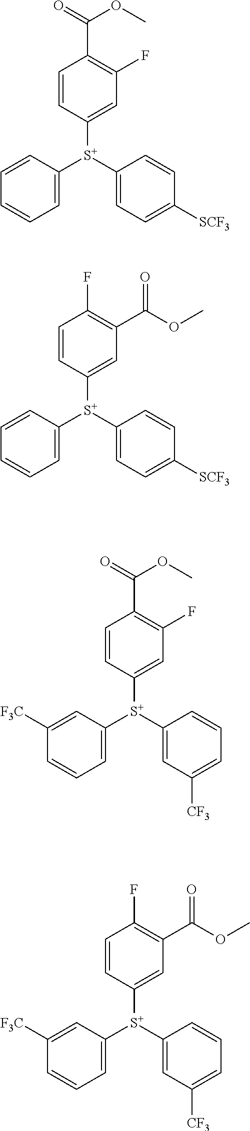

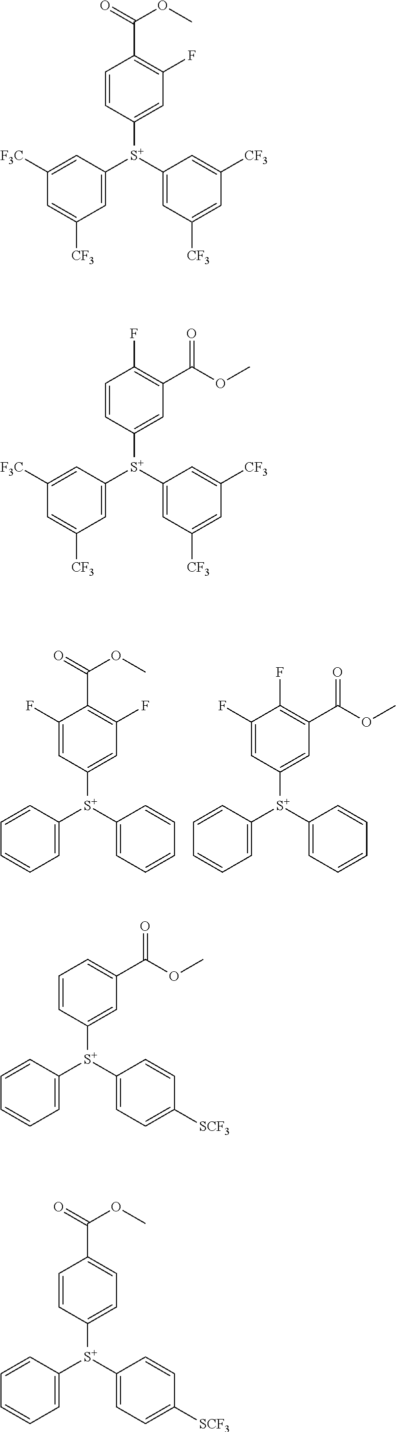

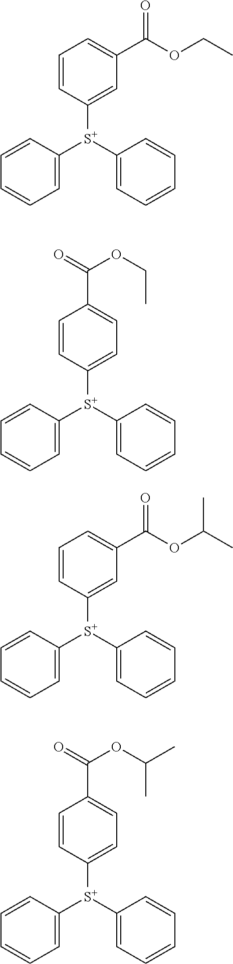 [SMILES: CCOC(=O)c1cccc([S+](c2ccccc2)c2ccccc2)c1 ; CCOC(=O)c1ccc([S+](c2ccccc2)c2ccccc2)cc1 ; CC(C)OC(=O)c1cccc([S+](c2ccccc2)c2ccccc2)c1 ; CC(C)OC(=O)c1ccc([S+](c2ccccc2)c2ccccc2)cc1]

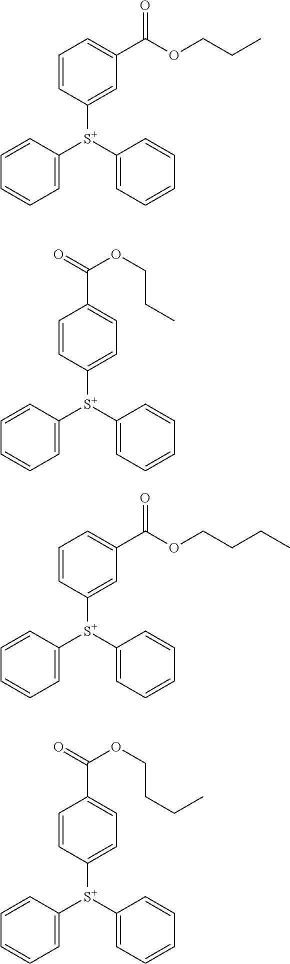 [SMILES: CCCOC(=O)c1cccc([S+](c2ccccc2)c2ccccc2)c1 ; CCCOC(=O)c1ccc([S+](c2ccccc2)c2ccccc2)cc1 ; CCCCOC(=O)c1cccc([S+](c2ccccc2)c2ccccc2)c1 ; CCCCOC(=O)c1ccc([S+](c2ccccc2)c2ccccc2)cc1]

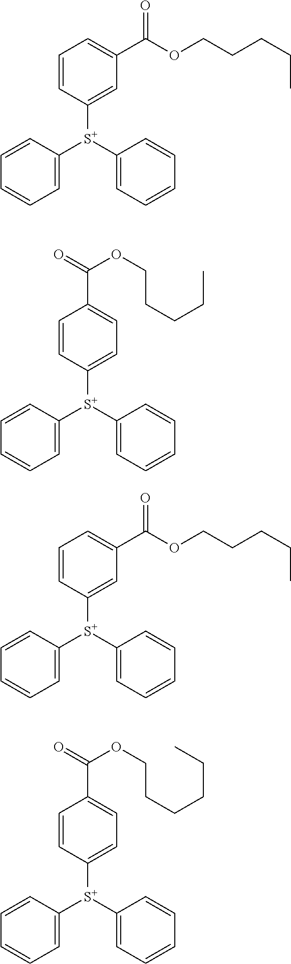 [SMILES: CCCCCOC(=O)c1cccc([S+](c2ccccc2)c2ccccc2)c1 ; CCCCCOC(=O)c1ccc([S+](c2ccccc2)c2ccccc2)cc1 ; CCCCCOC(=O)c1cccc([S+](c2ccccc2)c2ccccc2)c1 ; CCCCCCOC(=O)c1ccc([S+](c2ccccc2)c2ccccc2)cc1]

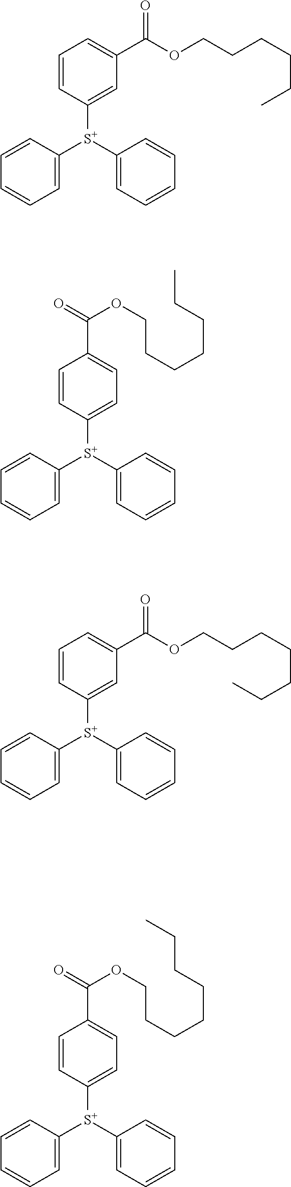 [SMILES: CCCCCCOC(=O)c1cccc([S+](c2ccccc2)c2ccccc2)c1 ; CCCCCCCOC(=O)c1ccc([S+](c2ccccc2)c2ccccc2)cc1 ; CCCCCCCOC(=O)c1cccc([S+](c2ccccc2)c2ccccc2)c1 ; CCCCCCCCOC(=O)c1ccc([S+](c2ccccc2)c2ccccc2)cc1]

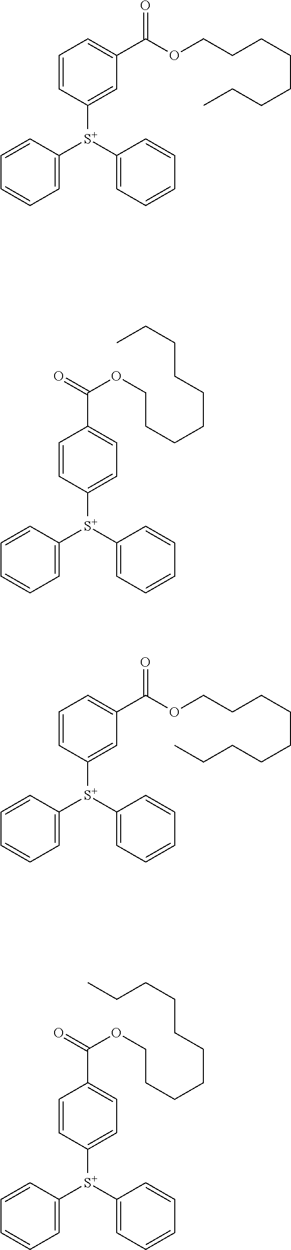 [SMILES: CCCCCCCCOC(=O)c1cccc([S+](c2ccccc2)c2ccccc2)c1 ; CCCCCCCCCOC(=O)c1ccc([S+](c2ccccc2)c2ccccc2)cc1 ; CCCCCCCCCOC(=O)c1cccc([S+](c2ccccc2)c2ccccc2)c1 ; CCCCCCCCCCOC(=O)c1ccc([S+](c2ccccc2)c2ccccc2)cc1]

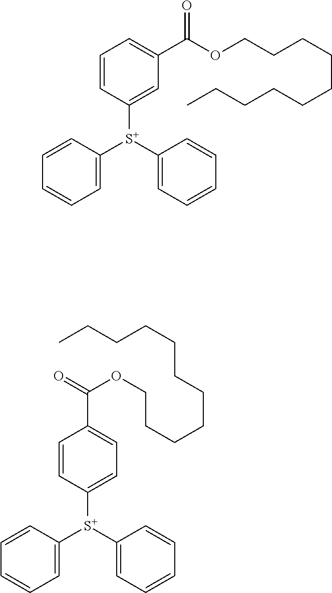 [SMILES: CCCCCCCCCCOC(=O)c1cccc([S+](c2ccccc2)c2ccccc2)c1 ; CCCCCCCCCCCOC(=O)c1ccc([S+](c2ccccc2)c2ccccc2)cc1]

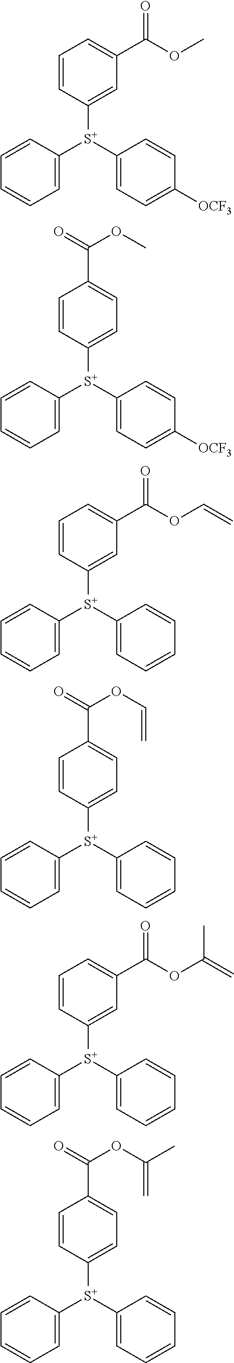 [SMILES: COC(=O)c1cccc([S+](c2ccccc2)c2ccc(OC(F)(F)F)cc2)c1 ; COC(=O)c1ccc([S+](c2ccccc2)c2ccc(OC(F)(F)F)cc2)cc1 ; C=COC(=O)c1cccc([S+](c2ccccc2)c2ccccc2)c1 ; C=COC(=O)c1ccc([S+](c2ccccc2)c2ccccc2)cc1 ; C=C(C)OC(=O)c1cccc([S+](c2ccccc2)c2ccccc2)c1 ; C=C(C)OC(=O)c1ccc([S+](c2ccccc2)c2ccccc2)cc1]

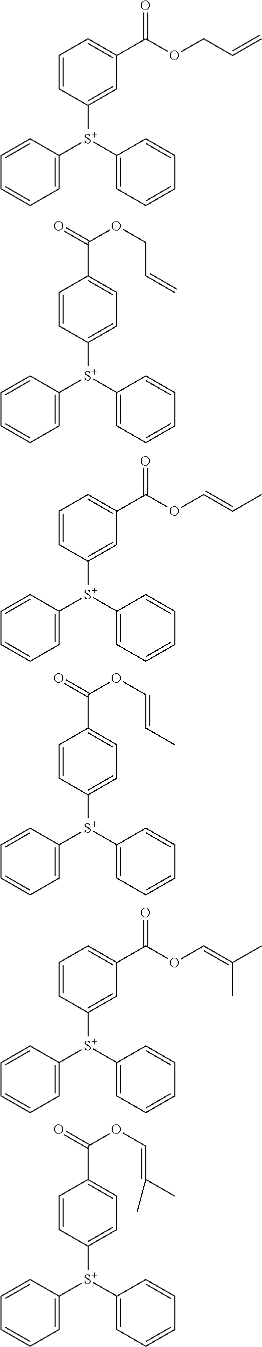 [SMILES: C=CCOC(=O)c1cccc([S+](c2ccccc2)c2ccccc2)c1 ; C=CCOC(=O)c1ccc([S+](c2ccccc2)c2ccccc2)cc1 ; C/C=C/OC(=O)c1cccc([S+](c2ccccc2)c2ccccc2)c1 ; C/C=C/OC(=O)c1ccc([S+](c2ccccc2)c2ccccc2)cc1 ; CC(C)=COC(=O)c1cccc([S+](c2ccccc2)c2ccccc2)c1 ; CC(C)=COC(=O)c1ccc([S+](c2ccccc2)c2ccccc2)cc1]

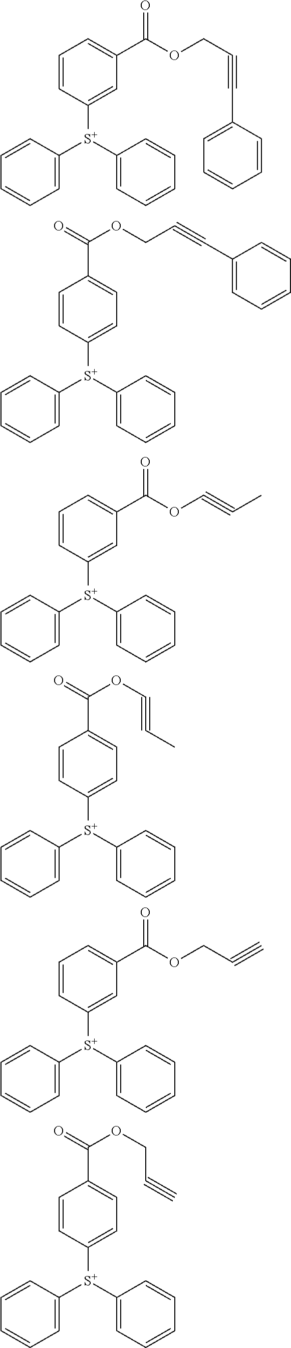 [SMILES: O=C(OCC#Cc1ccccc1)c1cccc([S+](c2ccccc2)c2ccccc2)c1 ; O=C(OCC#Cc1ccccc1)c1ccc([S+](c2ccccc2)c2ccccc2)cc1 ; CC#COC(=O)c1cccc([S+](c2ccccc2)c2ccccc2)c1 ; CC#COC(=O)c1ccc([S+](c2ccccc2)c2ccccc2)cc1 ; C#CCOC(=O)c1cccc([S+](c2ccccc2)c2ccccc2)c1 ; C#CCOC(=O)c1ccc([S+](c2ccccc2)c2ccccc2)cc1]

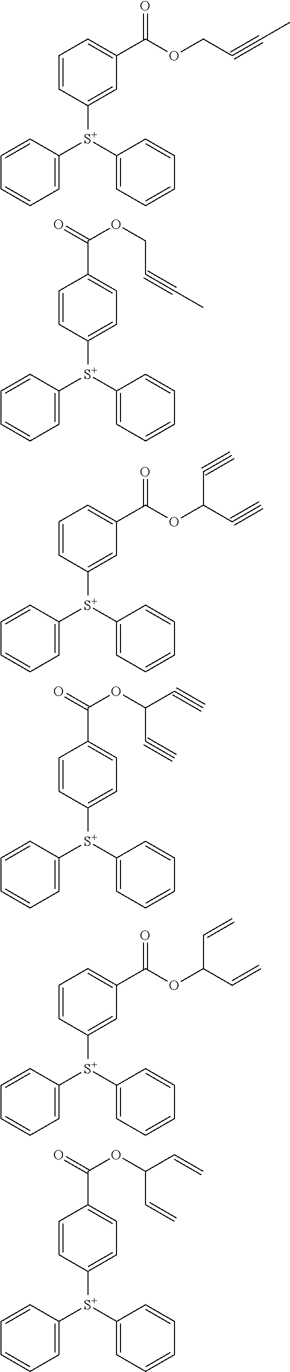 [SMILES: CC#CCOC(=O)c1cccc([S+](c2ccccc2)c2ccccc2)c1 ; CC#CCOC(=O)c1ccc([S+](c2ccccc2)c2ccccc2)cc1 ; C#CC(C#C)OC(=O)c1cccc([S+](c2ccccc2)c2ccccc2)c1 ; C#CC(C#C)OC(=O)c1ccc([S+](c2ccccc2)c2ccccc2)cc1 ; C=CC(C=C)OC(=O)c1cccc([S+](c2ccccc2)c2ccccc2)c1 ; C=CC(C=C)OC(=O)c1ccc([S+](c2ccccc2)c2ccccc2)cc1]

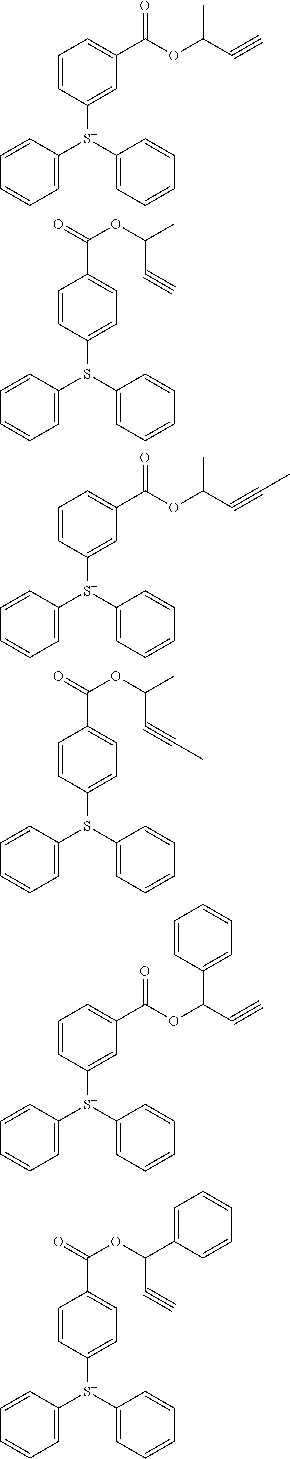 [SMILES: C#CC(C)OC(=O)c1cccc([S+](c2ccccc2)c2ccccc2)c1 ; C#CC(C)OC(=O)c1ccc([S+](c2ccccc2)c2ccccc2)cc1 ; CC#CC(C)OC(=O)c1cccc([S+](c2ccccc2)c2ccccc2)c1 ; CC#CC(C)OC(=O)c1ccc([S+](c2ccccc2)c2ccccc2)cc1 ; C#CC(OC(=O)c1cccc([S+](c2ccccc2)c2ccccc2)c1)c1ccccc1 ; C#CC(OC(=O)c1ccc([S+](c2ccccc2)c2ccccc2)cc1)c1ccccc1]

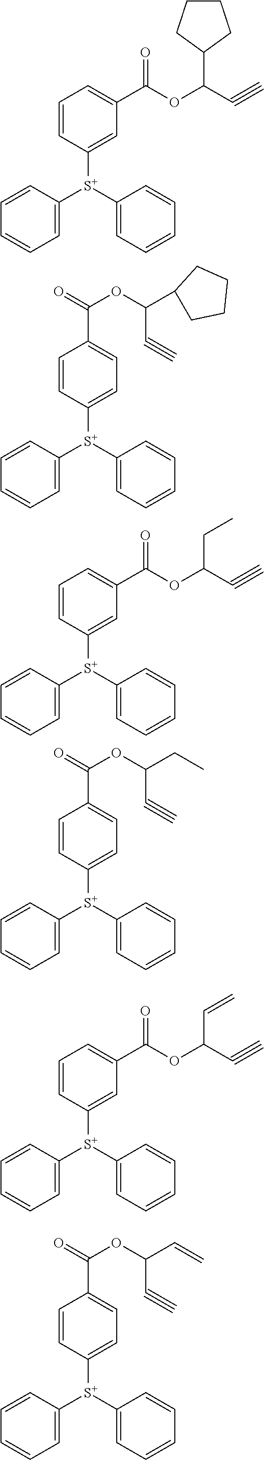 [SMILES: C#CC(OC(=O)c1cccc([S+](c2ccccc2)c2ccccc2)c1)C1CCCC1 ; C#CC(OC(=O)c1ccc([S+](c2ccccc2)c2ccccc2)cc1)C1CCCC1 ; C#CC(CC)OC(=O)c1cccc([S+](c2ccccc2)c2ccccc2)c1 ; C#CC(CC)OC(=O)c1ccc([S+](c2ccccc2)c2ccccc2)cc1 ; C#CC(C=C)OC(=O)c1cccc([S+](c2ccccc2)c2ccccc2)c1 ; C#CC(C=C)OC(=O)c1ccc([S+](c2ccccc2)c2ccccc2)cc1]

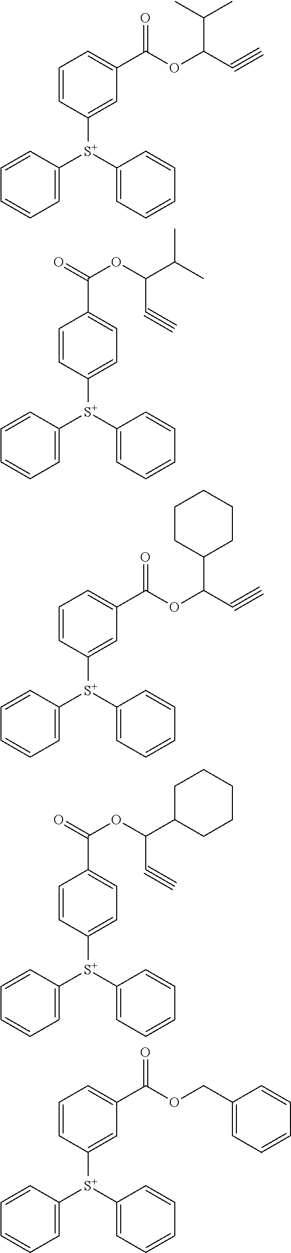 [SMILES: C#CC(OC(=O)c1cccc([S+](c2ccccc2)c2ccccc2)c1)C(C)C ; C#CC(OC(=O)c1ccc([S+](c2ccccc2)c2ccccc2)cc1)C(C)C ; C#CC(OC(=O)c1cccc([S+](c2ccccc2)c2ccccc2)c1)C1CCCCC1 ; C#CC(OC(=O)c1ccc([S+](c2ccccc2)c2ccccc2)cc1)C1CCCCC1 ; O=C(OCc1ccccc1)c1cccc([S+](c2ccccc2)c2ccccc2)c1]

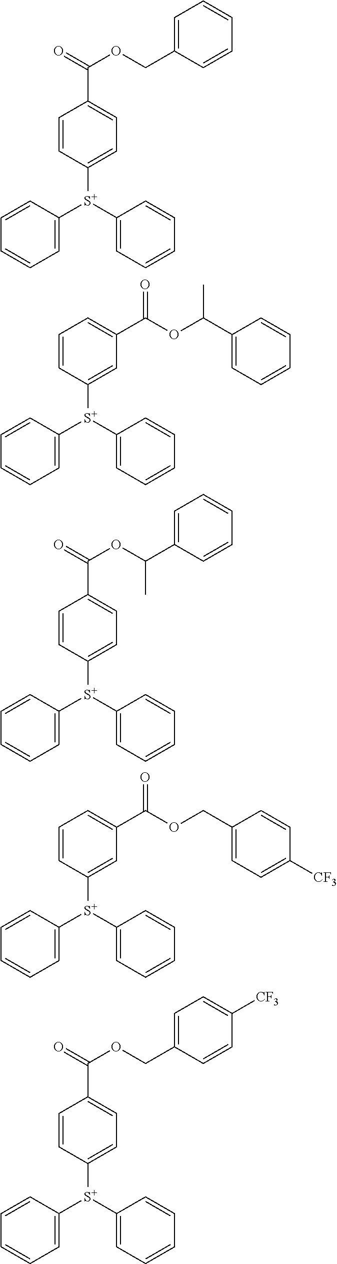 [SMILES: O=C(OCc1ccccc1)c1ccc([S+](c2ccccc2)c2ccccc2)cc1 ; CC(OC(=O)c1cccc([S+](c2ccccc2)c2ccccc2)c1)c1ccccc1 ; CC(OC(=O)c1ccc([S+](c2ccccc2)c2ccccc2)cc1)c1ccccc1 ; O=C(OCc1ccc(C(F)(F)F)cc1)c1cccc([S+](c2ccccc2)c2ccccc2)c1 ; O=C(OCc1ccc(C(F)(F)F)cc1)c1ccc([S+](c2ccccc2)c2ccccc2)cc1]

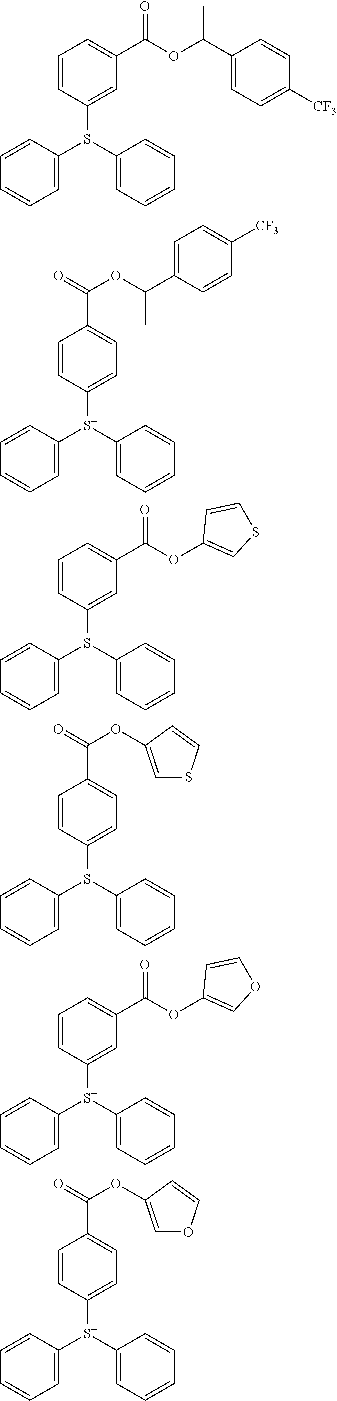 [SMILES: CC(OC(=O)c1cccc([S+](c2ccccc2)c2ccccc2)c1)c1ccc(C(F)(F)F)cc1 ; CC(OC(=O)c1ccc([S+](c2ccccc2)c2ccccc2)cc1)c1ccc(C(F)(F)F)cc1 ; O=C(Oc1ccsc1)c1cccc([S+](c2ccccc2)c2ccccc2)c1 ; O=C(Oc1ccsc1)c1ccc([S+](c2ccccc2)c2ccccc2)cc1 ; O=C(Oc1ccoc1)c1cccc([S+](c2ccccc2)c2ccccc2)c1 ; O=C(Oc1ccoc1)c1ccc([S+](c2ccccc2)c2ccccc2)cc1]

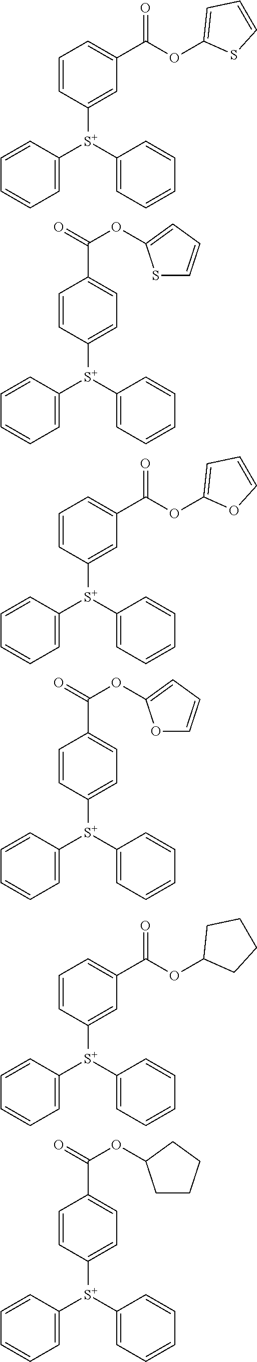 [SMILES: O=C(Oc1cccs1)c1cccc([S+](c2ccccc2)c2ccccc2)c1 ; O=C(Oc1cccs1)c1ccc([S+](c2ccccc2)c2ccccc2)cc1 ; O=C(Oc1ccco1)c1cccc([S+](c2ccccc2)c2ccccc2)c1 ; O=C(Oc1ccco1)c1ccc([S+](c2ccccc2)c2ccccc2)cc1 ; O=C(OC1CCCC1)c1cccc([S+](c2ccccc2)c2ccccc2)c1 ; O=C(OC1CCCC1)c1ccc([S+](c2ccccc2)c2ccccc2)cc1]

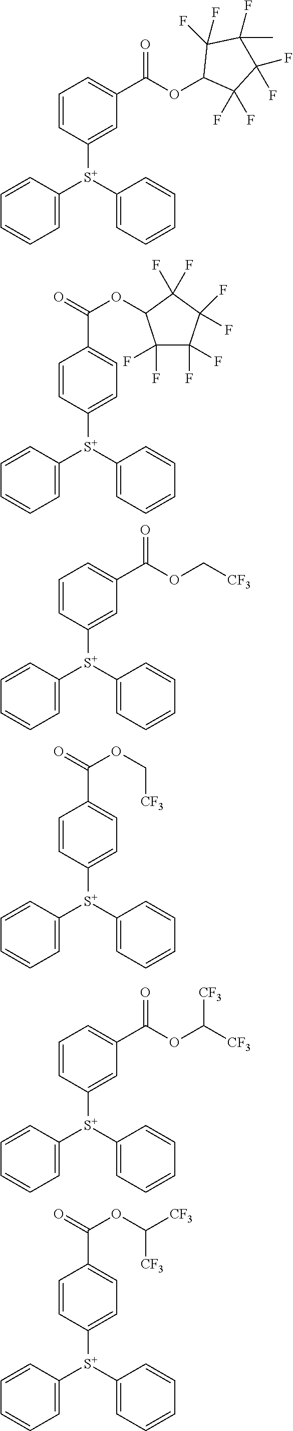 [SMILES: CC1(F)C(F)(F)C(OC(=O)c2cccc([S+](c3ccccc3)c3ccccc3)c2)C(F)(F)C1(F)F ; O=C(OC1C(F)(F)C(F)(F)C(F)(F)C1(F)F)c1ccc([S+](c2ccccc2)c2ccccc2)cc1 ; O=C(OCC(F)(F)F)c1cccc([S+](c2ccccc2)c2ccccc2)c1 ; O=C(OCC(F)(F)F)c1ccc([S+](c2ccccc2)c2ccccc2)cc1 ; O=C(OC(C(F)(F)F)C(F)(F)F)c1cccc([S+](c2ccccc2)c2ccccc2)c1 ; O=C(OC(C(F)(F)F)C(F)(F)F)c1ccc([S+](c2ccccc2)c2ccccc2)cc1]

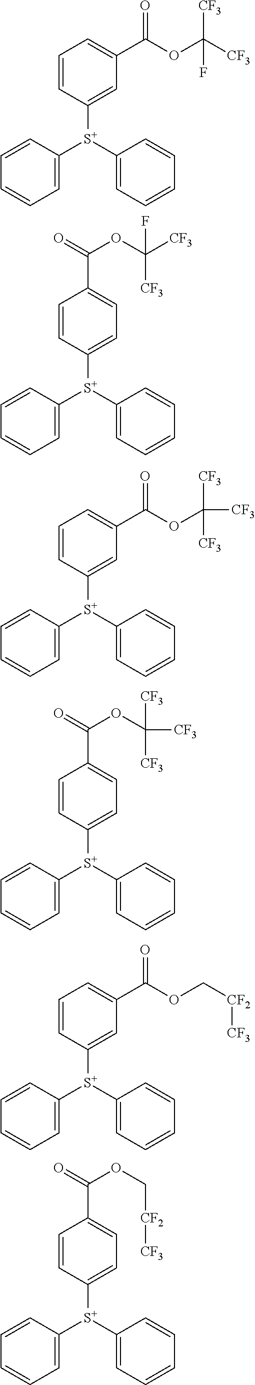 [SMILES: O=C(OC(F)(C(F)(F)F)C(F)(F)F)c1cccc([S+](c2ccccc2)c2ccccc2)c1 ; O=C(OC(F)(C(F)(F)F)C(F)(F)F)c1ccc([S+](c2ccccc2)c2ccccc2)cc1 ; O=C(OC(C(F)(F)F)(C(F)(F)F)C(F)(F)F)c1cccc([S+](c2ccccc2)c2ccccc2)c1 ; O=C(OC(C(F)(F)F)(C(F)(F)F)C(F)(F)F)c1ccc([S+](c2ccccc2)c2ccccc2)cc1 ; O=C(OCC(F)(F)C(F)(F)F)c1cccc([S+](c2ccccc2)c2ccccc2)c1 ; O=C(OCC(F)(F)C(F)(F)F)c1ccc([S+](c2ccccc2)c2ccccc2)cc1]

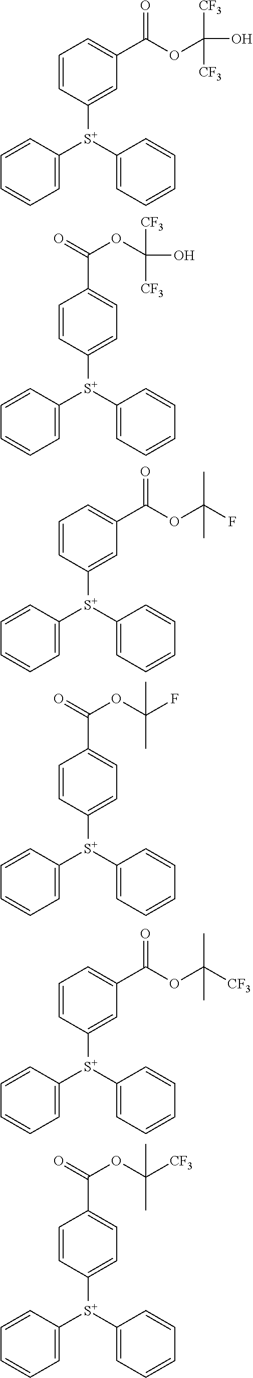 [SMILES: O=C(OC(O)(C(F)(F)F)C(F)(F)F)c1cccc([S+](c2ccccc2)c2ccccc2)c1 ; O=C(OC(O)(C(F)(F)F)C(F)(F)F)c1ccc([S+](c2ccccc2)c2ccccc2)cc1 ; CC(C)(F)OC(=O)c1cccc([S+](c2ccccc2)c2ccccc2)c1 ; CC(C)(F)OC(=O)c1ccc([S+](c2ccccc2)c2ccccc2)cc1 ; CC(C)(OC(=O)c1cccc([S+](c2ccccc2)c2ccccc2)c1)C(F)(F)F ; CC(C)(OC(=O)c1ccc([S+](c2ccccc2)c2ccccc2)cc1)C(F)(F)F]

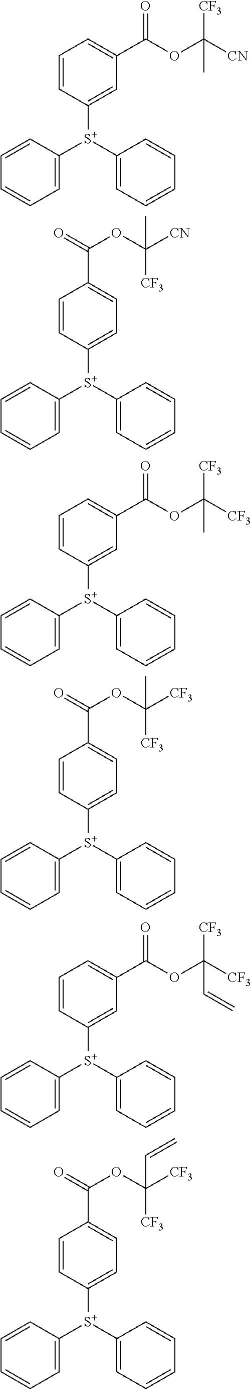 [SMILES: CC(C#N)(OC(=O)c1cccc([S+](c2ccccc2)c2ccccc2)c1)C(F)(F)F ; CC(C#N)(OC(=O)c1ccc([S+](c2ccccc2)c2ccccc2)cc1)C(F)(F)F ; CC(OC(=O)c1cccc([S+](c2ccccc2)c2ccccc2)c1)(C(F)(F)F)C(F)(F)F ; CC(OC(=O)c1ccc([S+](c2ccccc2)c2ccccc2)cc1)(C(F)(F)F)C(F)(F)F ; C=CC(OC(=O)c1cccc([S+](c2ccccc2)c2ccccc2)c1)(C(F)(F)F)C(F)(F)F ; C=CC(OC(=O)c1ccc([S+](c2ccccc2)c2ccccc2)cc1)(C(F)(F)F)C(F)(F)F]

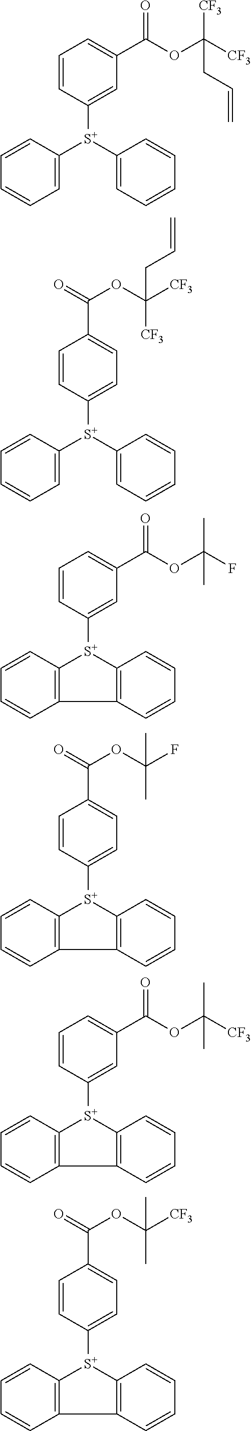 [SMILES: C=CCC(OC(=O)c1cccc([S+](c2ccccc2)c2ccccc2)c1)(C(F)(F)F)C(F)(F)F ; C=CCC(OC(=O)c1ccc([S+](c2ccccc2)c2ccccc2)cc1)(C(F)(F)F)C(F)(F)F ; CC(C)(F)OC(=O)c1cccc(-[s+]2c3ccccc3c3ccccc32)c1 ; CC(C)(F)OC(=O)c1ccc(-[s+]2c3ccccc3c3ccccc32)cc1 ; CC(C)(OC(=O)c1cccc(-[s+]2c3ccccc3c3ccccc32)c1)C(F)(F)F ; CC(C)(OC(=O)c1ccc(-[s+]2c3ccccc3c3ccccc32)cc1)C(F)(F)F]

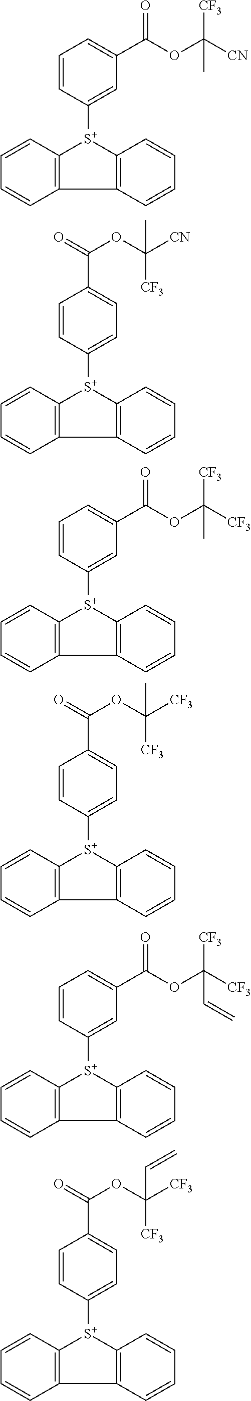 [SMILES: CC(C#N)(OC(=O)c1cccc(-[s+]2c3ccccc3c3ccccc32)c1)C(F)(F)F ; CC(C#N)(OC(=O)c1ccc(-[s+]2c3ccccc3c3ccccc32)cc1)C(F)(F)F ; CC(OC(=O)c1cccc(-[s+]2c3ccccc3c3ccccc32)c1)(C(F)(F)F)C(F)(F)F ; CC(OC(=O)c1ccc(-[s+]2c3ccccc3c3ccccc32)cc1)(C(F)(F)F)C(F)(F)F ; C=CC(OC(=O)c1cccc(-[s+]2c3ccccc3c3ccccc32)c1)(C(F)(F)F)C(F)(F)F ; C=CC(OC(=O)c1ccc(-[s+]2c3ccccc3c3ccccc32)cc1)(C(F)(F)F)C(F)(F)F]

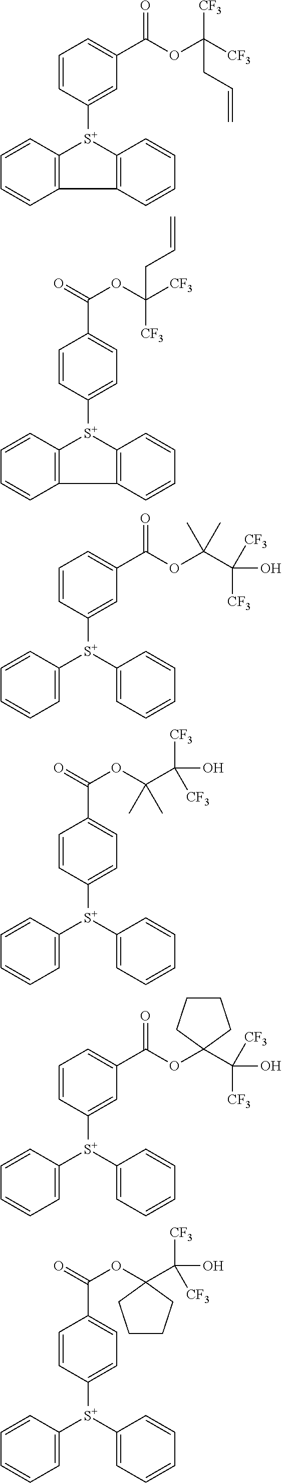 [SMILES: C=CCC(OC(=O)c1cccc(-[s+]2c3ccccc3c3ccccc32)c1)(C(F)(F)F)C(F)(F)F ; C=CCC(OC(=O)c1ccc(-[s+]2c3ccccc3c3ccccc32)cc1)(C(F)(F)F)C(F)(F)F ; CC(C)(OC(=O)c1cccc([S+](c2ccccc2)c2ccccc2)c1)C(O)(C(F)(F)F)C(F)(F)F ; CC(C)(OC(=O)c1ccc([S+](c2ccccc2)c2ccccc2)cc1)C(O)(C(F)(F)F)C(F)(F)F ; O=C(OC1(C(O)(C(F)(F)F)C(F)(F)F)CCCC1)c1cccc([S+](c2ccccc2)c2ccccc2)c1 ; O=C(OC1(C(O)(C(F)(F)F)C(F)(F)F)CCCC1)c1ccc([S+](c2ccccc2)c2ccccc2)cc1]

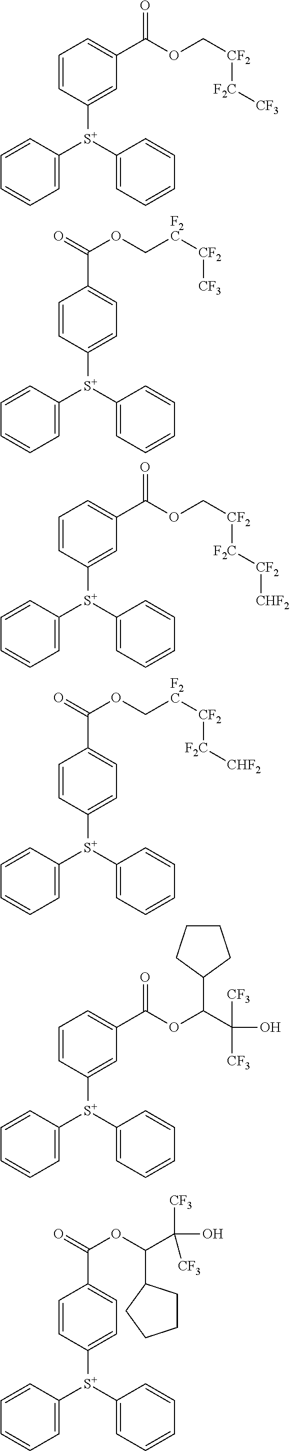 [SMILES: O=C(OCC(F)(F)C(F)(F)C(F)(F)F)c1cccc([S+](c2ccccc2)c2ccccc2)c1 ; O=C(OCC(F)(F)C(F)(F)C(F)(F)F)c1ccc([S+](c2ccccc2)c2ccccc2)cc1 ; O=C(OCC(F)(F)C(F)(F)C(F)(F)C(F)F)c1cccc([S+](c2ccccc2)c2ccccc2)c1 ; O=C(OCC(F)(F)C(F)(F)C(F)(F)C(F)F)c1ccc([S+](c2ccccc2)c2ccccc2)cc1 ; O=C(OC(C1CCCC1)C(O)(C(F)(F)F)C(F)(F)F)c1cccc([S+](c2ccccc2)c2ccccc2)c1 ; O=C(OC(C1CCCC1)C(O)(C(F)(F)F)C(F)(F)F)c1ccc([S+](c2ccccc2)c2ccccc2)cc1]

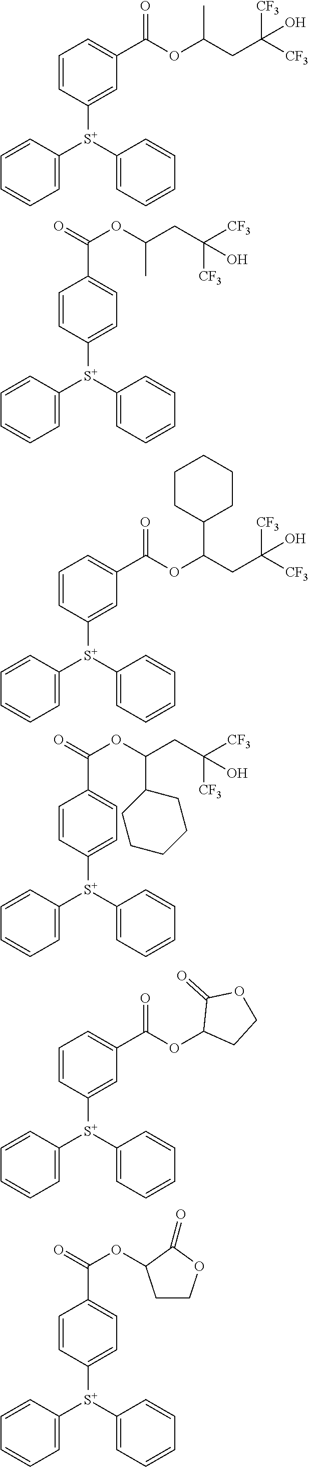 [SMILES: CC(CC(O)(C(F)(F)F)C(F)(F)F)OC(=O)c1cccc([S+](c2ccccc2)c2ccccc2)c1 ; CC(CC(O)(C(F)(F)F)C(F)(F)F)OC(=O)c1ccc([S+](c2ccccc2)c2ccccc2)cc1 ; O=C(OC(CC(O)(C(F)(F)F)C(F)(F)F)C1CCCCC1)c1cccc([S+](c2ccccc2)c2ccccc2)c1 ; O=C(OC(CC(O)(C(F)(F)F)C(F)(F)F)C1CCCCC1)c1ccc([S+](c2ccccc2)c2ccccc2)cc1 ; O=C(OC1CCOC1=O)c1cccc([S+](c2ccccc2)c2ccccc2)c1 ; O=C(OC1CCOC1=O)c1ccc([S+](c2ccccc2)c2ccccc2)cc1]

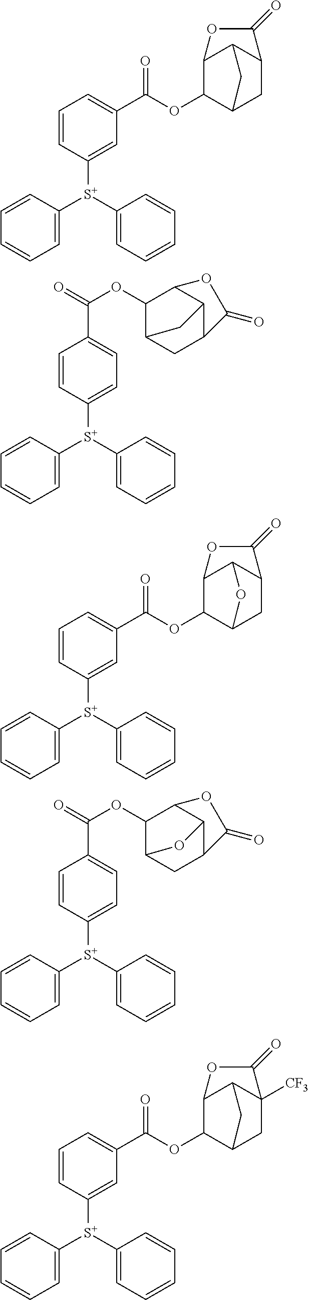 [SMILES: O=C(OC1C2CC3C(=O)OC1C3C2)c1cccc([S+](c2ccccc2)c2ccccc2)c1 ; O=C(OC1C2CC3C(=O)OC1C3C2)c1ccc([S+](c2ccccc2)c2ccccc2)cc1 ; O=C(OC1C2CC3C(=O)OC1C3O2)c1cccc([S+](c2ccccc2)c2ccccc2)c1 ; O=C(OC1C2CC3C(=O)OC1C3O2)c1ccc([S+](c2ccccc2)c2ccccc2)cc1 ; O=C(OC1C2CC3C1OC(=O)C3(C(F)(F)F)C2)c1cccc([S+](c2ccccc2)c2ccccc2)c1]

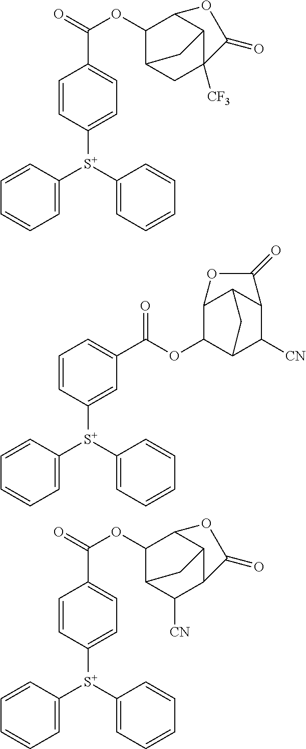 [SMILES: O=C(OC1C2CC3C1OC(=O)C3(C(F)(F)F)C2)c1ccc([S+](c2ccccc2)c2ccccc2)cc1 ; N#CC1C2CC3C(OC(=O)C13)C2OC(=O)c1cccc([S+](c2ccccc2)c2ccccc2)c1 ; N#CC1C2CC3C(OC(=O)C13)C2OC(=O)c1ccc([S+](c2ccccc2)c2ccccc2)cc1]

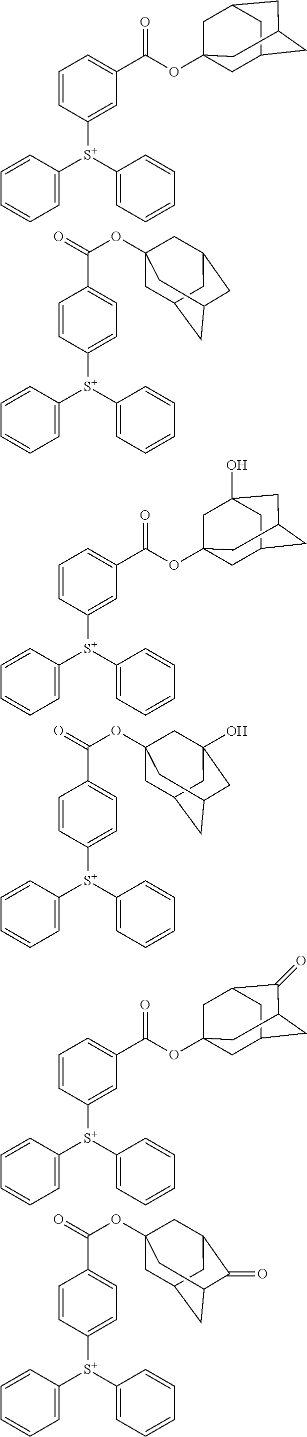 [SMILES: O=C(OC12CC3CC(CC(C3)C1)C2)c1cccc([S+](c2ccccc2)c2ccccc2)c1 ; O=C(OC12CC3CC(CC(C3)C1)C2)c1ccc([S+](c2ccccc2)c2ccccc2)cc1 ; O=C(OC12CC3CC(CC(O)(C3)C1)C2)c1cccc([S+](c2ccccc2)c2ccccc2)c1 ; O=C(OC12CC3CC(CC(O)(C3)C1)C2)c1ccc([S+](c2ccccc2)c2ccccc2)cc1 ; O=C(OC12CC3CC(C1)C(=O)C(C3)C2)c1cccc([S+](c2ccccc2)c2ccccc2)c1 ; O=C(OC12CC3CC(C1)C(=O)C(C3)C2)c1ccc([S+](c2ccccc2)c2ccccc2)cc1]

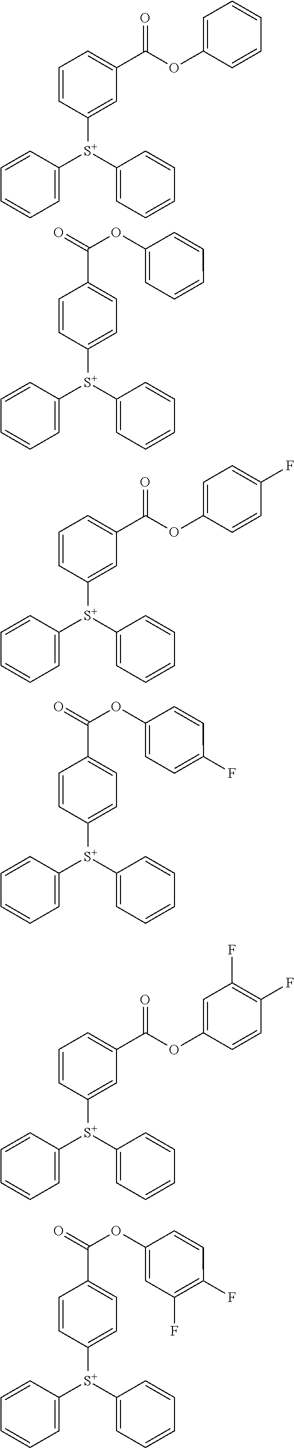 [SMILES: O=C(Oc1ccccc1)c1cccc([S+](c2ccccc2)c2ccccc2)c1 ; O=C(Oc1ccccc1)c1ccc([S+](c2ccccc2)c2ccccc2)cc1 ; O=C(Oc1ccc(F)cc1)c1cccc([S+](c2ccccc2)c2ccccc2)c1 ; O=C(Oc1ccc(F)cc1)c1ccc([S+](c2ccccc2)c2ccccc2)cc1 ; O=C(Oc1ccc(F)c(F)c1)c1cccc([S+](c2ccccc2)c2ccccc2)c1 ; O=C(Oc1ccc(F)c(F)c1)c1ccc([S+](c2ccccc2)c2ccccc2)cc1]

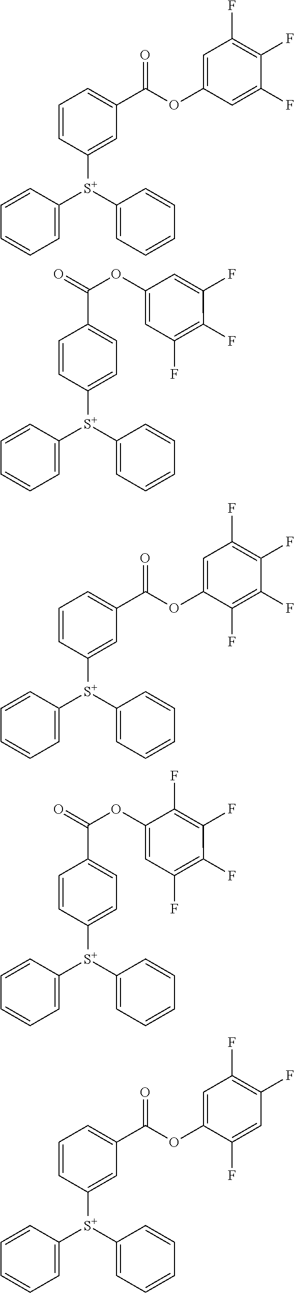 [SMILES: O=C(Oc1cc(F)c(F)c(F)c1)c1cccc([S+](c2ccccc2)c2ccccc2)c1 ; O=C(Oc1cc(F)c(F)c(F)c1)c1ccc([S+](c2ccccc2)c2ccccc2)cc1 ; O=C(Oc1cc(F)c(F)c(F)c1F)c1cccc([S+](c2ccccc2)c2ccccc2)c1 ; O=C(Oc1cc(F)c(F)c(F)c1F)c1ccc([S+](c2ccccc2)c2ccccc2)cc1 ; O=C(Oc1cc(F)c(F)cc1F)c1cccc([S+](c2ccccc2)c2ccccc2)c1]

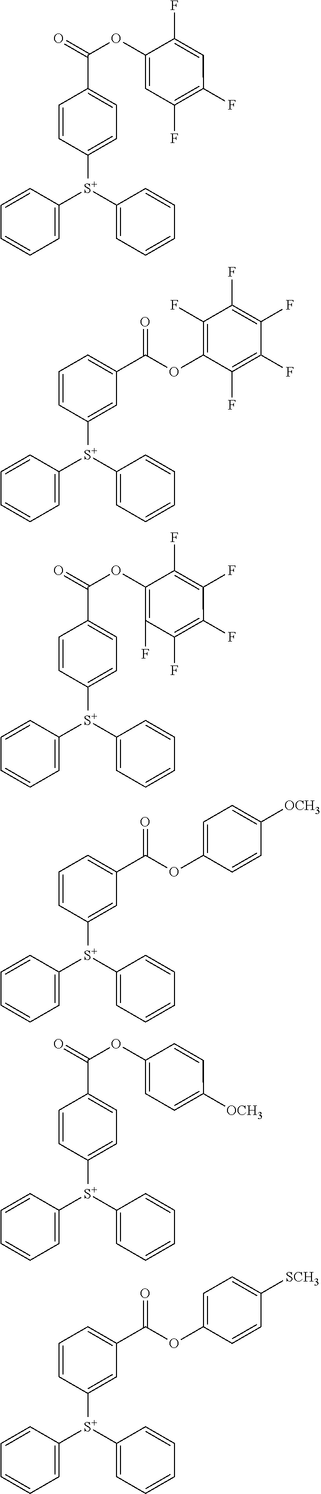 [SMILES: O=C(Oc1cc(F)c(F)cc1F)c1ccc([S+](c2ccccc2)c2ccccc2)cc1 ; O=C(Oc1c(F)c(F)c(F)c(F)c1F)c1cccc([S+](c2ccccc2)c2ccccc2)c1 ; O=C(Oc1c(F)c(F)c(F)c(F)c1F)c1ccc([S+](c2ccccc2)c2ccccc2)cc1 ; COc1ccc(OC(=O)c2cccc([S+](c3ccccc3)c3ccccc3)c2)cc1 ; COc1ccc(OC(=O)c2ccc([S+](c3ccccc3)c3ccccc3)cc2)cc1 ; CSc1ccc(OC(=O)c2cccc([S+](c3ccccc3)c3ccccc3)c2)cc1]

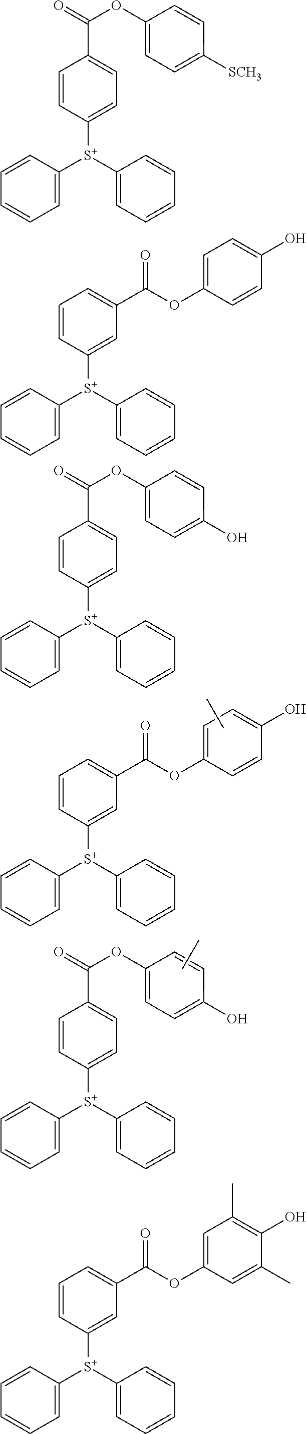

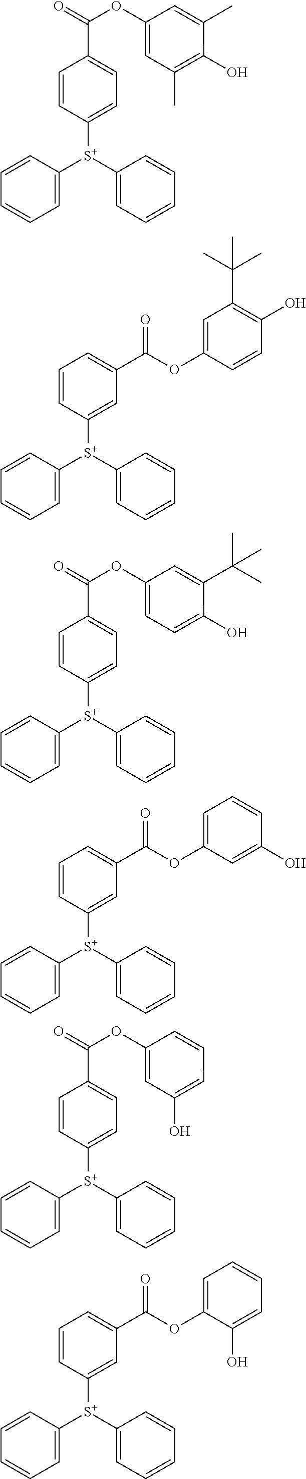 [SMILES: Cc1cc(OC(=O)c2ccc([S+](c3ccccc3)c3ccccc3)cc2)cc(C)c1O ; CC(C)(C)c1cc(OC(=O)c2cccc([S+](c3ccccc3)c3ccccc3)c2)ccc1O ; CC(C)(C)c1cc(OC(=O)c2ccc([S+](c3ccccc3)c3ccccc3)cc2)ccc1O ; O=C(Oc1cccc(O)c1)c1cccc([S+](c2ccccc2)c2ccccc2)c1 ; O=C(Oc1cccc(O)c1)c1ccc([S+](c2ccccc2)c2ccccc2)cc1 ; O=C(Oc1ccccc1O)c1cccc([S+](c2ccccc2)c2ccccc2)c1]

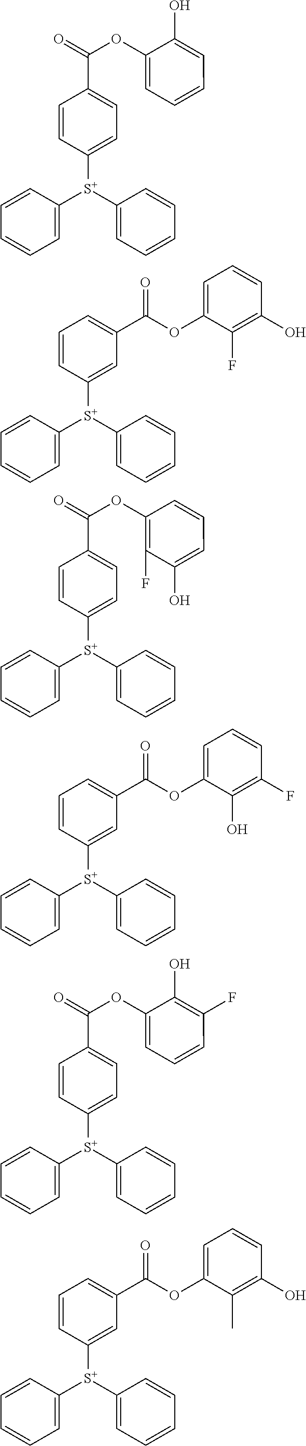 [SMILES: O=C(Oc1ccccc1O)c1ccc([S+](c2ccccc2)c2ccccc2)cc1 ; O=C(Oc1cccc(O)c1F)c1cccc([S+](c2ccccc2)c2ccccc2)c1 ; O=C(Oc1cccc(O)c1F)c1ccc([S+](c2ccccc2)c2ccccc2)cc1 ; O=C(Oc1cccc(F)c1O)c1cccc([S+](c2ccccc2)c2ccccc2)c1 ; O=C(Oc1cccc(F)c1O)c1ccc([S+](c2ccccc2)c2ccccc2)cc1 ; Cc1c(O)cccc1OC(=O)c1cccc([S+](c2ccccc2)c2ccccc2)c1]

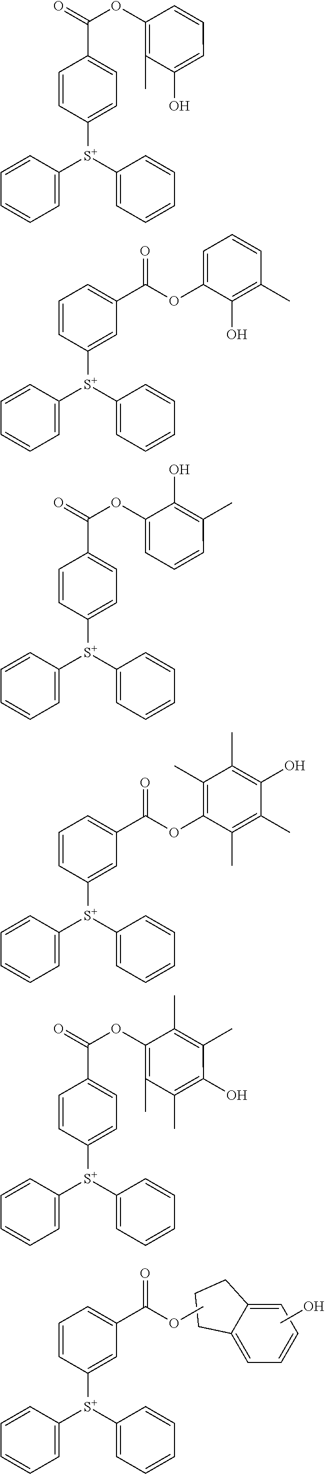

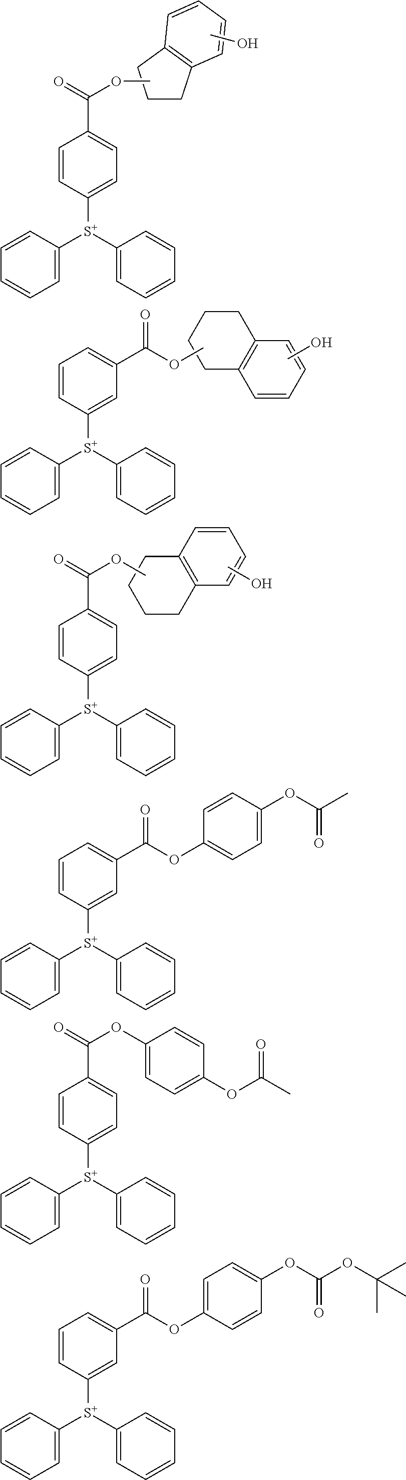

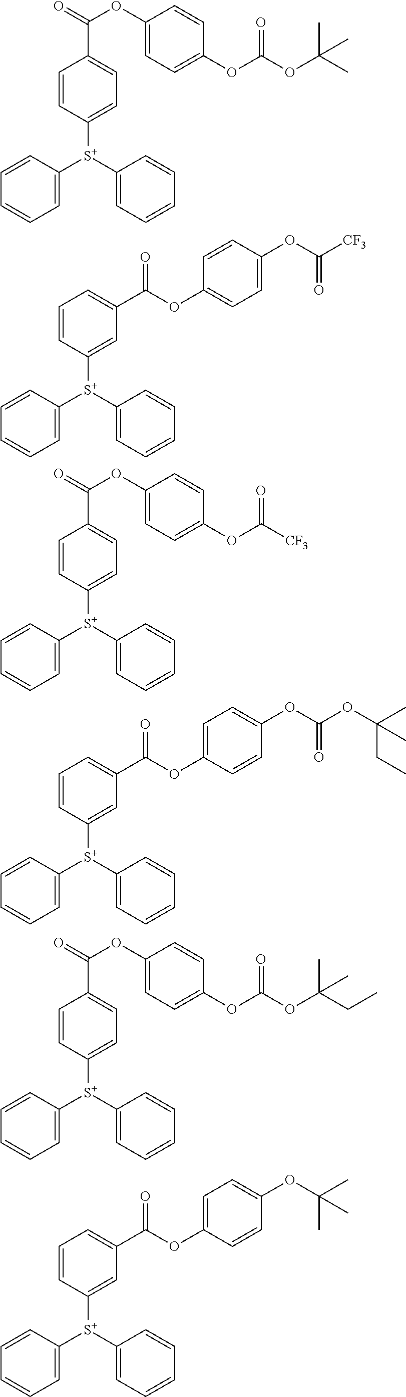 [SMILES: CC(C)(C)OC(=O)Oc1ccc(OC(=O)c2ccc([S+](c3ccccc3)c3ccccc3)cc2)cc1 ; O=C(Oc1ccc(OC(=O)C(F)(F)F)cc1)c1cccc([S+](c2ccccc2)c2ccccc2)c1 ; O=C(Oc1ccc(OC(=O)C(F)(F)F)cc1)c1ccc([S+](c2ccccc2)c2ccccc2)cc1 ; CCC(C)(C)OC(=O)Oc1ccc(OC(=O)c2cccc([S+](c3ccccc3)c3ccccc3)c2)cc1 ; CCC(C)(C)OC(=O)Oc1ccc(OC(=O)c2ccc([S+](c3ccccc3)c3ccccc3)cc2)cc1 ; CC(C)(C)Oc1ccc(OC(=O)c2cccc([S+](c3ccccc3)c3ccccc3)c2)cc1]

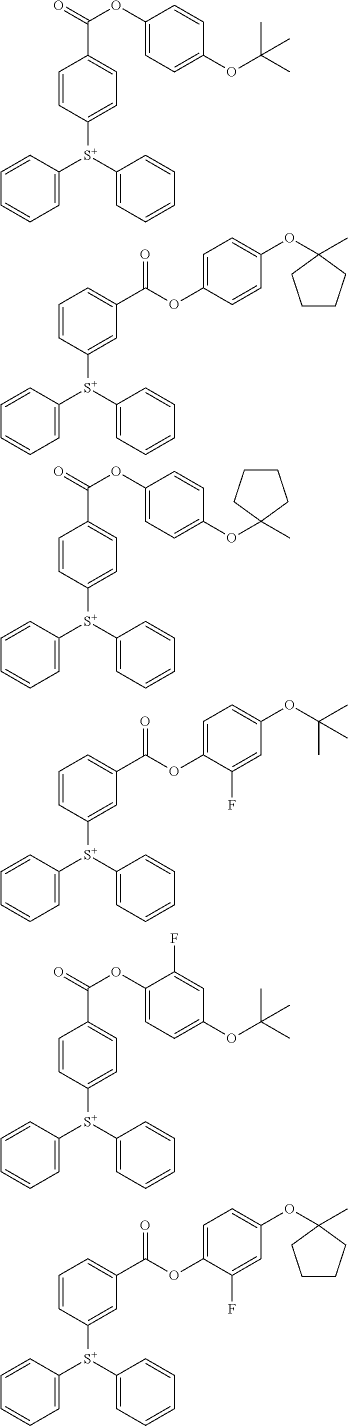 [SMILES: CC(C)(C)Oc1ccc(OC(=O)c2ccc([S+](c3ccccc3)c3ccccc3)cc2)cc1 ; CC1(Oc2ccc(OC(=O)c3cccc([S+](c4ccccc4)c4ccccc4)c3)cc2)CCCC1 ; CC1(Oc2ccc(OC(=O)c3ccc([S+](c4ccccc4)c4ccccc4)cc3)cc2)CCCC1 ; CC(C)(C)Oc1ccc(OC(=O)c2cccc([S+](c3ccccc3)c3ccccc3)c2)c(F)c1 ; CC(C)(C)Oc1ccc(OC(=O)c2ccc([S+](c3ccccc3)c3ccccc3)cc2)c(F)c1 ; CC1(Oc2ccc(OC(=O)c3cccc([S+](c4ccccc4)c4ccccc4)c3)c(F)c2)CCCC1]

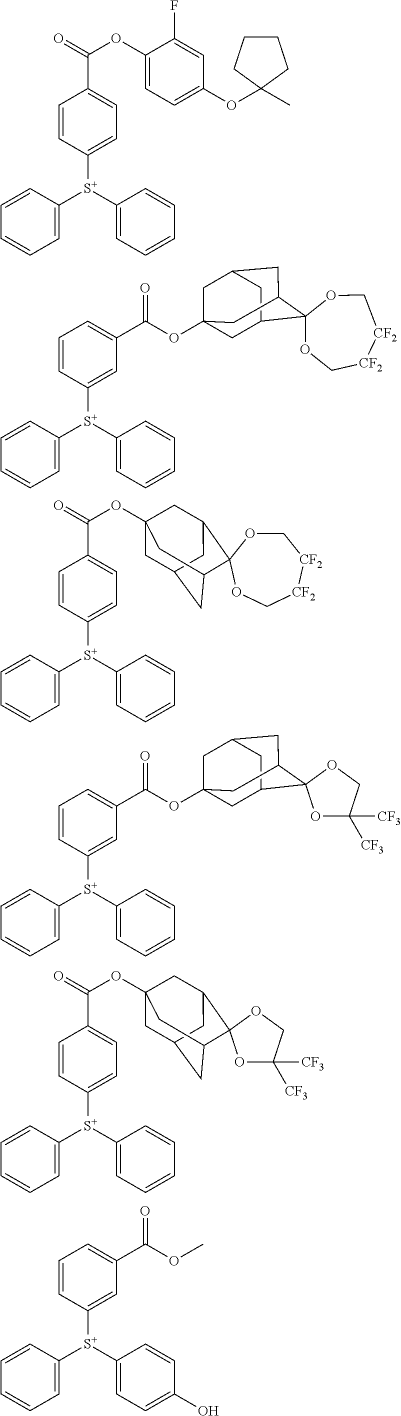 [SMILES: CC1(Oc2ccc(OC(=O)c3ccc([S+](c4ccccc4)c4ccccc4)cc3)c(F)c2)CCCC1 ; O=C(OC12CC3CC(C1)C1(OCC(F)(F)C(F)(F)CO1)C(C3)C2)c1cccc([S+](c2ccccc2)c2ccccc2)c1 ; O=C(OC12CC3CC(C1)C1(OCC(F)(F)C(F)(F)CO1)C(C3)C2)c1ccc([S+](c2ccccc2)c2ccccc2)cc1 ; O=C(OC12CC3CC(C1)C1(OCC(C(F)(F)F)(C(F)(F)F)O1)C(C3)C2)c1cccc([S+](c2ccccc2)c2ccccc2)c1 ; O=C(OC12CC3CC(C1)C1(OCC(C(F)(F)F)(C(F)(F)F)O1)C(C3)C2)c1ccc([S+](c2ccccc2)c2ccccc2)cc1 ; COC(=O)c1cccc([S+](c2ccccc2)c2ccc(O)cc2)c1]

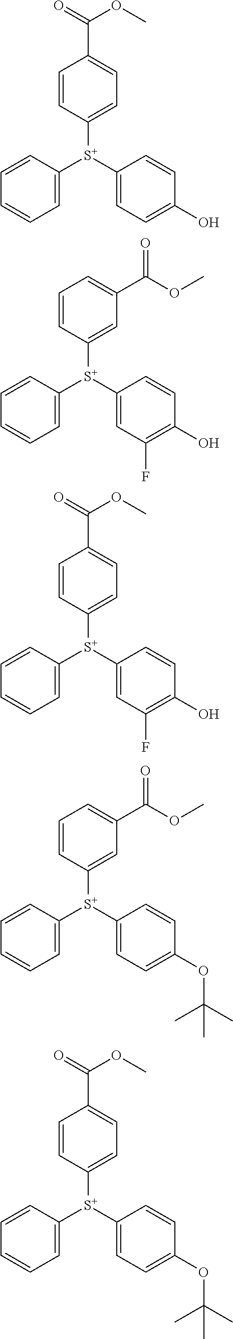 [SMILES: COC(=O)c1ccc([S+](c2ccccc2)c2ccc(O)cc2)cc1 ; COC(=O)c1cccc([S+](c2ccccc2)c2ccc(O)c(F)c2)c1 ; COC(=O)c1ccc([S+](c2ccccc2)c2ccc(O)c(F)c2)cc1 ; COC(=O)c1cccc([S+](c2ccccc2)c2ccc(OC(C)(C)C)cc2)c1 ; COC(=O)c1ccc([S+](c2ccccc2)c2ccc(OC(C)(C)C)cc2)cc1]

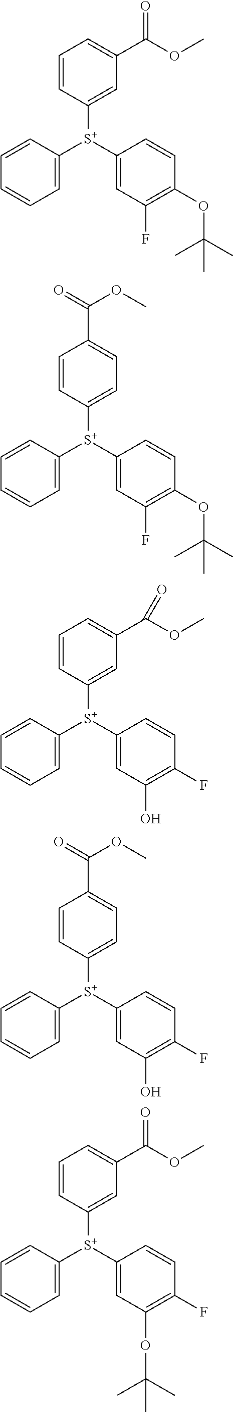 [SMILES: COC(=O)c1cccc([S+](c2ccccc2)c2ccc(OC(C)(C)C)c(F)c2)c1 ; COC(=O)c1ccc([S+](c2ccccc2)c2ccc(OC(C)(C)C)c(F)c2)cc1 ; COC(=O)c1cccc([S+](c2ccccc2)c2ccc(F)c(O)c2)c1 ; COC(=O)c1ccc([S+](c2ccccc2)c2ccc(F)c(O)c2)cc1 ; COC(=O)c1cccc([S+](c2ccccc2)c2ccc(F)c(OC(C)(C)C)c2)c1]

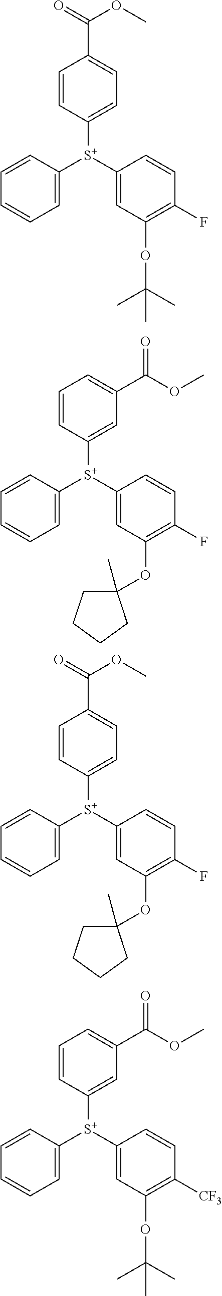 [SMILES: COC(=O)c1ccc([S+](c2ccccc2)c2ccc(F)c(OC(C)(C)C)c2)cc1 ; COC(=O)c1cccc([S+](c2ccccc2)c2ccc(F)c(OC3(C)CCCC3)c2)c1 ; COC(=O)c1ccc([S+](c2ccccc2)c2ccc(F)c(OC3(C)CCCC3)c2)cc1 ; COC(=O)c1cccc([S+](c2ccccc2)c2ccc(C(F)(F)F)c(OC(C)(C)C)c2)c1]

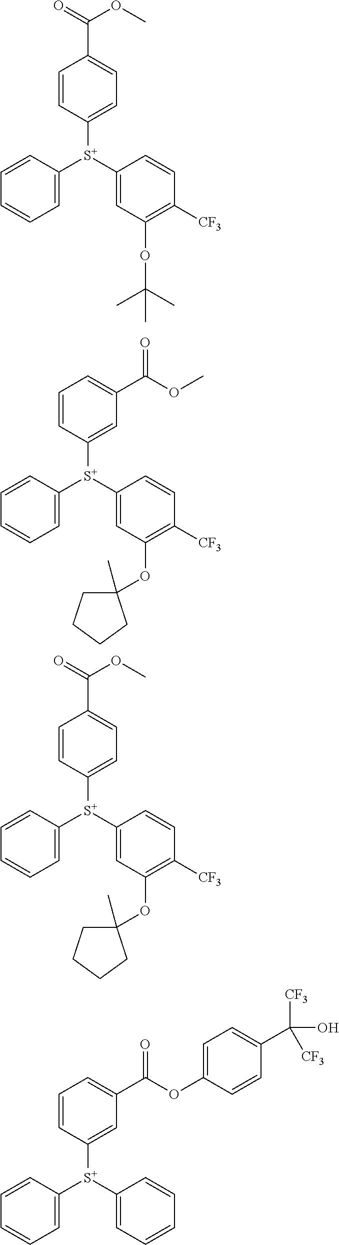 [SMILES: COC(=O)c1ccc([S+](c2ccccc2)c2ccc(C(F)(F)F)c(OC(C)(C)C)c2)cc1 ; COC(=O)c1cccc([S+](c2ccccc2)c2ccc(C(F)(F)F)c(OC3(C)CCCC3)c2)c1 ; COC(=O)c1ccc([S+](c2ccccc2)c2ccc(C(F)(F)F)c(OC3(C)CCCC3)c2)cc1 ; O=C(Oc1ccc(C(O)(C(F)(F)F)C(F)(F)F)cc1)c1cccc([S+](c2ccccc2)c2ccccc2)c1]

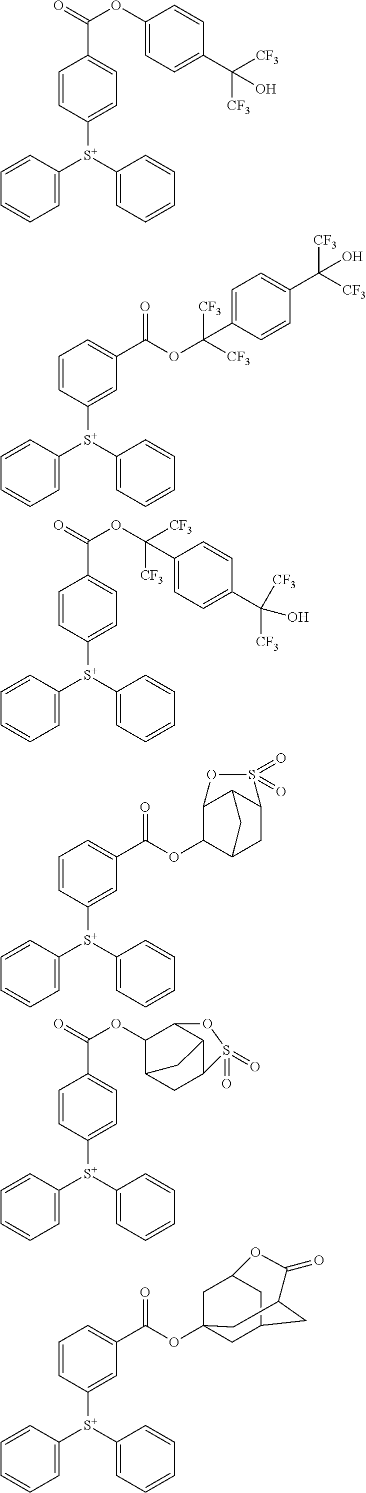 [SMILES: O=C(Oc1ccc(C(O)(C(F)(F)F)C(F)(F)F)cc1)c1ccc([S+](c2ccccc2)c2ccccc2)cc1 ; O=C(OC(c1ccc(C(O)(C(F)(F)F)C(F)(F)F)cc1)(C(F)(F)F)C(F)(F)F)c1cccc([S+](c2ccccc2)c2ccccc2)c1 ; O=C(OC(c1ccc(C(O)(C(F)(F)F)C(F)(F)F)cc1)(C(F)(F)F)C(F)(F)F)c1ccc([S+](c2ccccc2)c2ccccc2)cc1 ; O=C(OC1C2CC3C1OS(=O)(=O)C3C2)c1cccc([S+](c2ccccc2)c2ccccc2)c1 ; O=C(OC1C2CC3C1OS(=O)(=O)C3C2)c1ccc([S+](c2ccccc2)c2ccccc2)cc1 ; O=C(OC12CC3CC(C1)OC(=O)C(C3)C2)c1cccc([S+](c2ccccc2)c2ccccc2)c1]

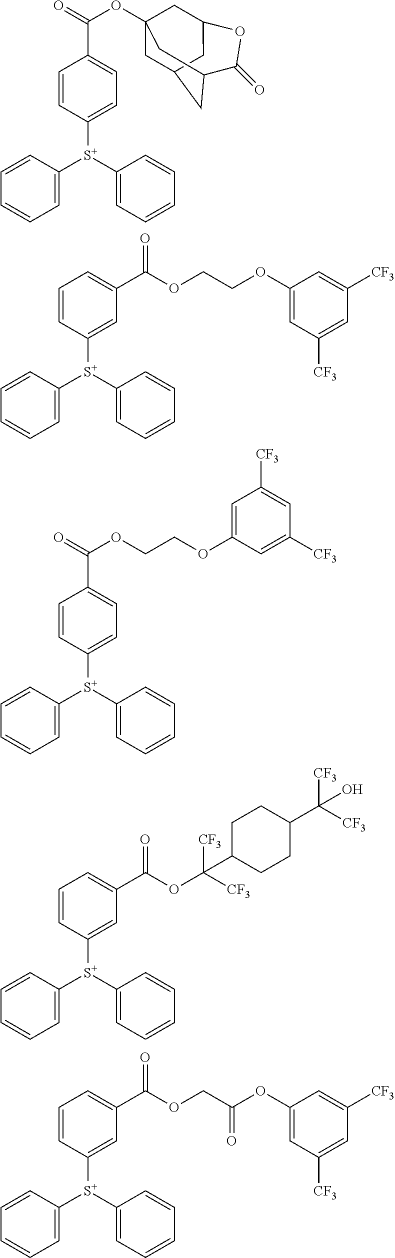 [SMILES: O=C(OC12CC3CC(C1)OC(=O)C(C3)C2)c1ccc([S+](c2ccccc2)c2ccccc2)cc1 ; O=C(OCCOc1cc(C(F)(F)F)cc(C(F)(F)F)c1)c1cccc([S+](c2ccccc2)c2ccccc2)c1 ; O=C(OCCOc1cc(C(F)(F)F)cc(C(F)(F)F)c1)c1ccc([S+](c2ccccc2)c2ccccc2)cc1 ; O=C(OC(C1CCC(C(O)(C(F)(F)F)C(F)(F)F)CC1)(C(F)(F)F)C(F)(F)F)c1cccc([S+](c2ccccc2)c2ccccc2)c1 ; O=C(COC(=O)c1cccc([S+](c2ccccc2)c2ccccc2)c1)Oc1cc(C(F)(F)F)cc(C(F)(F)F)c1]

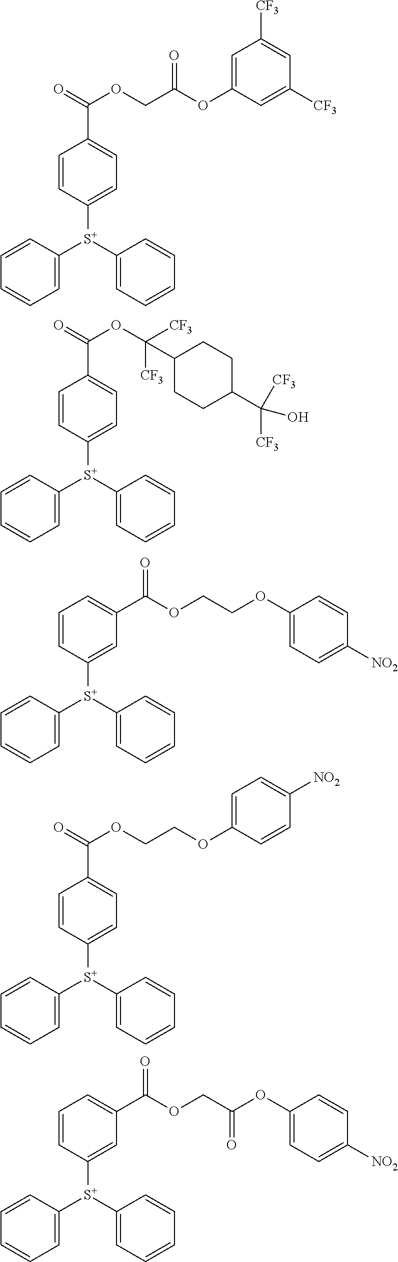 [SMILES: O=C(COC(=O)c1ccc([S+](c2ccccc2)c2ccccc2)cc1)Oc1cc(C(F)(F)F)cc(C(F)(F)F)c1 ; O=C(OC(C1CCC(C(O)(C(F)(F)F)C(F)(F)F)CC1)(C(F)(F)F)C(F)(F)F)c1ccc([S+](c2ccccc2)c2ccccc2)cc1 ; O=C(OCCOc1ccc([N+](=O)[O-])cc1)c1cccc([S+](c2ccccc2)c2ccccc2)c1 ; O=C(OCCOc1ccc([N+](=O)[O-])cc1)c1ccc([S+](c2ccccc2)c2ccccc2)cc1 ; O=C(COC(=O)c1cccc([S+](c2ccccc2)c2ccccc2)c1)Oc1ccc([N+](=O)[O-])cc1]

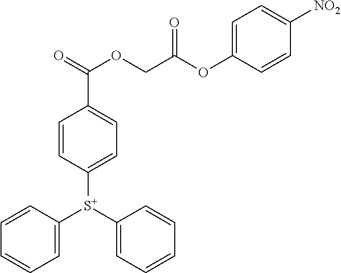 [SMILES: O=C(COC(=O)c1ccc([S+](c2ccccc2)c2ccccc2)cc1)Oc1ccc([N+](=O)[O-])cc1]

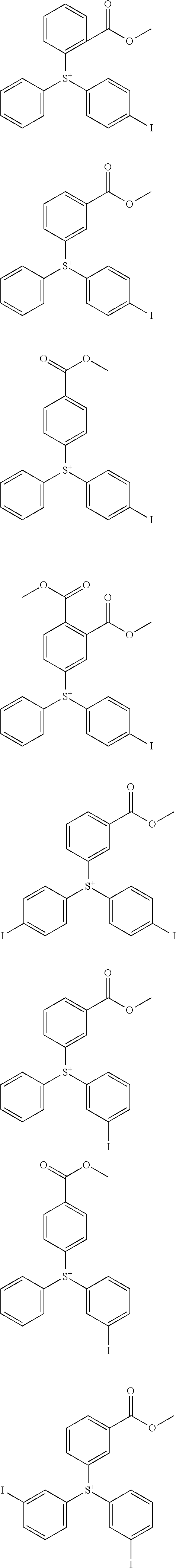

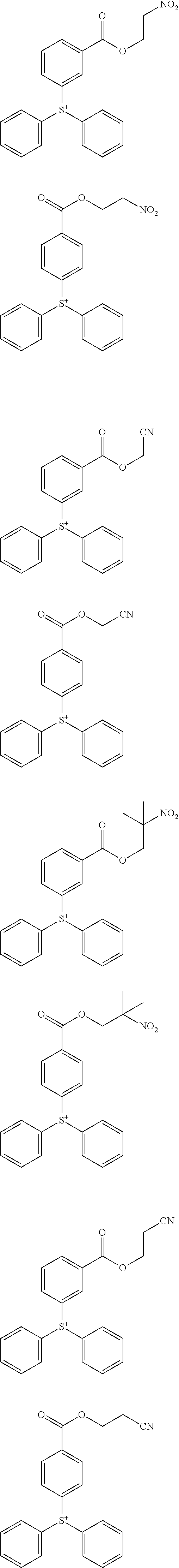

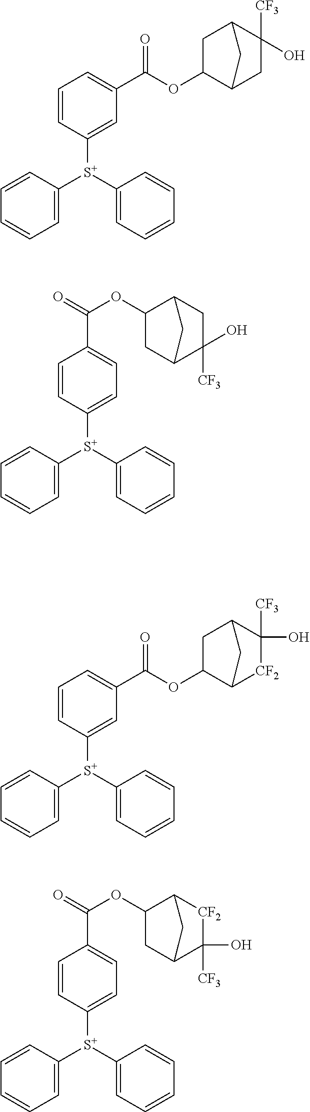 [SMILES: O=C(OC1CC2CC1CC2(O)C(F)(F)F)c1cccc([S+](c2ccccc2)c2ccccc2)c1 ; O=C(OC1CC2CC1CC2(O)C(F)(F)F)c1ccc([S+](c2ccccc2)c2ccccc2)cc1 ; O=C(OC1CC2CC1C(F)(F)C2(O)C(F)(F)F)c1cccc([S+](c2ccccc2)c2ccccc2)c1 ; O=C(OC1CC2CC1C(F)(F)C2(O)C(F)(F)F)c1ccc([S+](c2ccccc2)c2ccccc2)cc1]

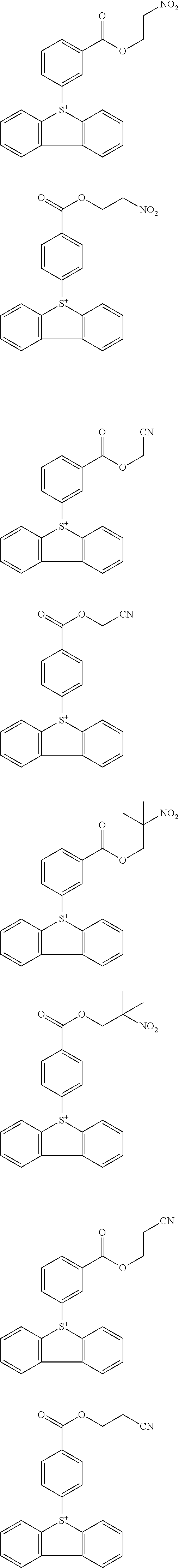

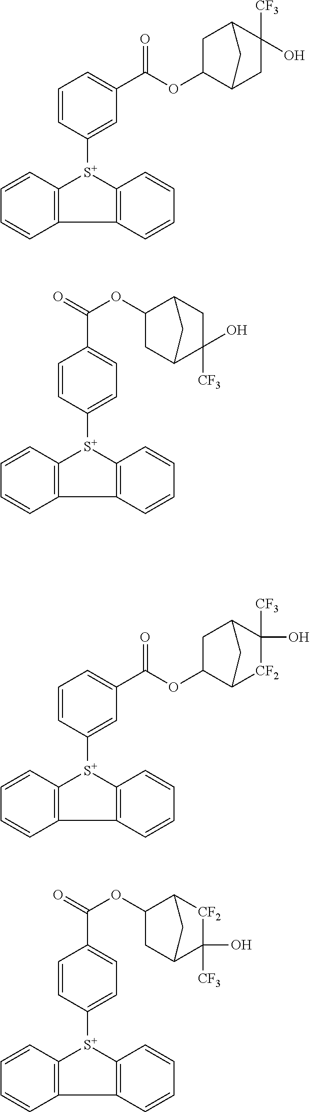 [SMILES: O=C(OC1CC2CC1CC2(O)C(F)(F)F)c1cccc(-[s+]2c3ccccc3c3ccccc32)c1 ; O=C(OC1CC2CC1CC2(O)C(F)(F)F)c1ccc(-[s+]2c3ccccc3c3ccccc32)cc1 ; O=C(OC1CC2CC1C(F)(F)C2(O)C(F)(F)F)c1cccc(-[s+]2c3ccccc3c3ccccc32)c1 ; O=C(OC1CC2CC1C(F)(F)C2(O)C(F)(F)F)c1ccc(-[s+]2c3ccccc3c3ccccc32)cc1]

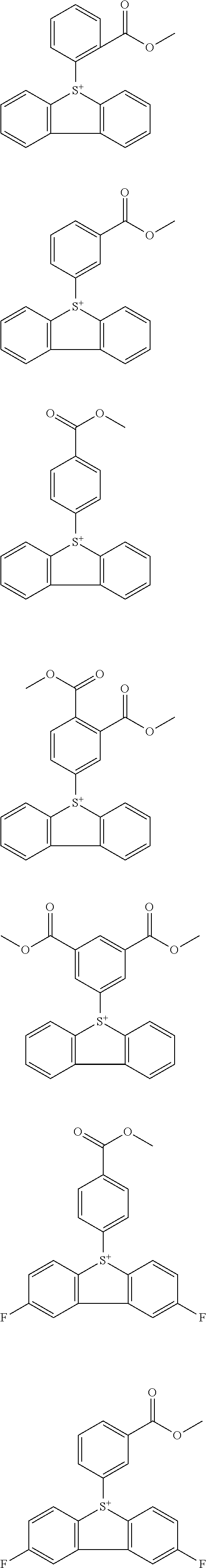

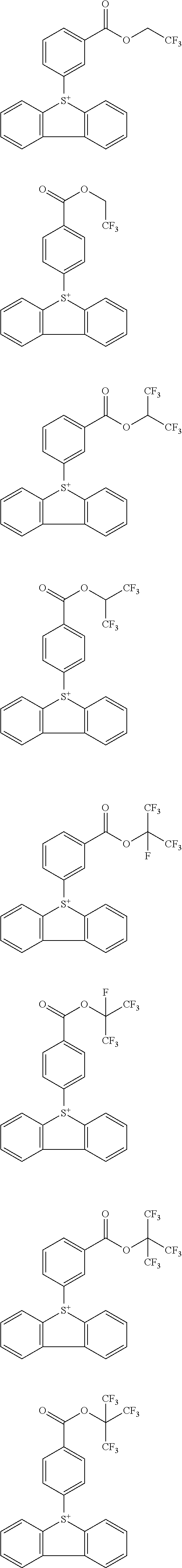

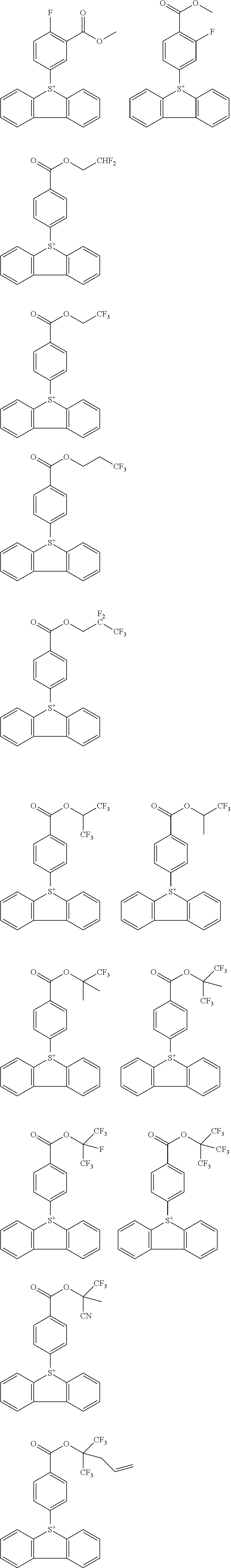

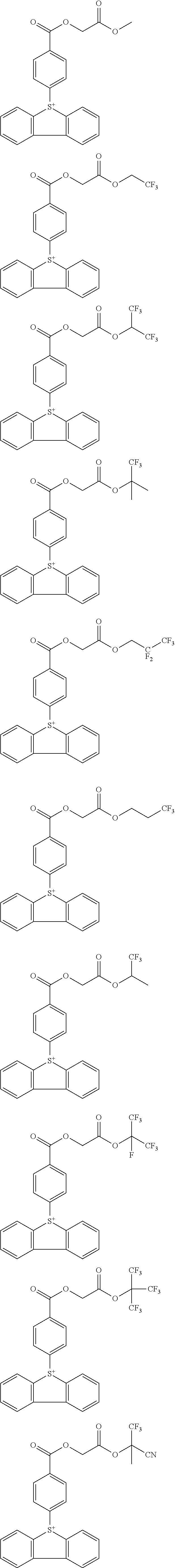

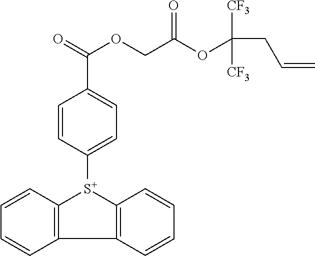 [SMILES: C=CCC(OC(=O)COC(=O)c1ccc(-[s+]2c3ccccc3c3ccccc32)cc1)(C(F)(F)F)C(F)(F)F]

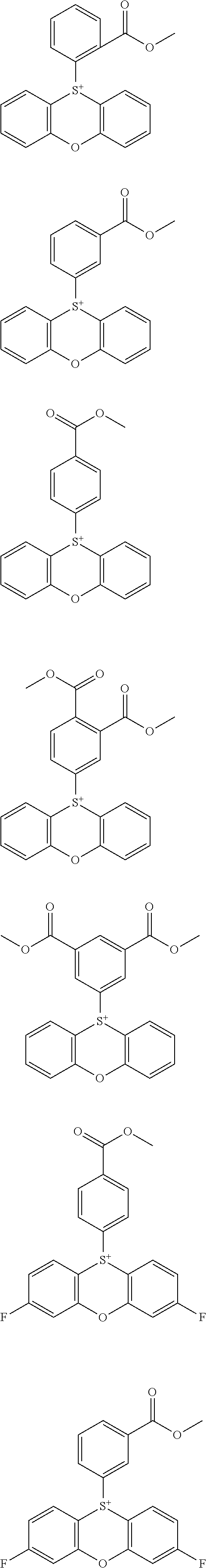

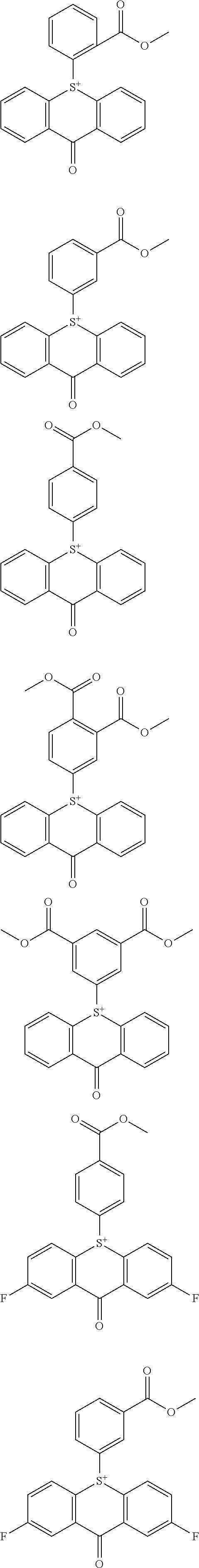

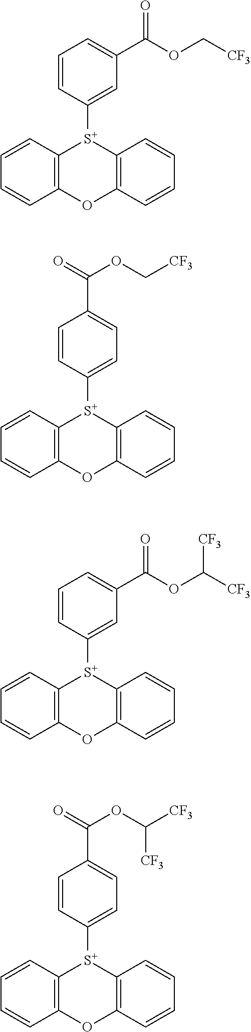 [SMILES: O=C(OCC(F)(F)F)c1cccc([S+]2c3ccccc3Oc3ccccc32)c1 ; O=C(OCC(F)(F)F)c1ccc([S+]2c3ccccc3Oc3ccccc32)cc1 ; O=C(OC(C(F)(F)F)C(F)(F)F)c1cccc([S+]2c3ccccc3Oc3ccccc32)c1 ; O=C(OC(C(F)(F)F)C(F)(F)F)c1ccc([S+]2c3ccccc3Oc3ccccc32)cc1]

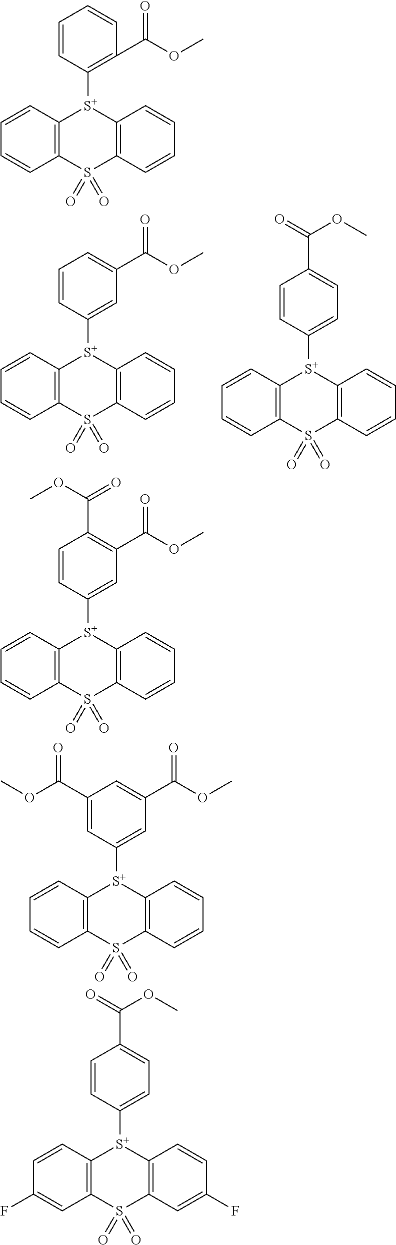

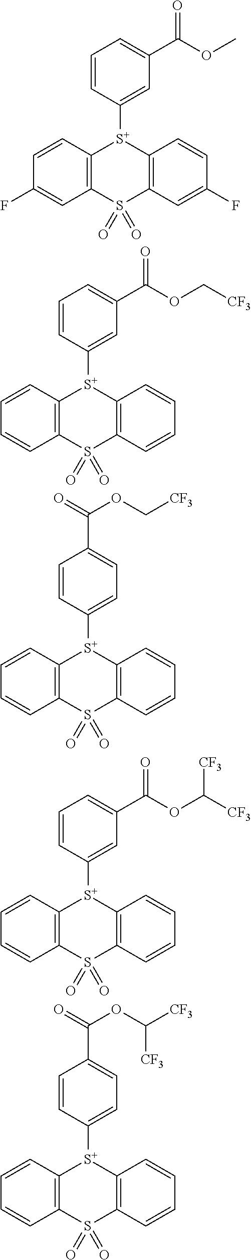 [SMILES: COC(=O)c1cccc([S+]2c3ccc(F)cc3S(=O)(=O)c3cc(F)ccc32)c1 ; O=C(OCC(F)(F)F)c1cccc([S+]2c3ccccc3S(=O)(=O)c3ccccc32)c1 ; O=C(OCC(F)(F)F)c1ccc([S+]2c3ccccc3S(=O)(=O)c3ccccc32)cc1 ; O=C(OC(C(F)(F)F)C(F)(F)F)c1cccc([S+]2c3ccccc3S(=O)(=O)c3ccccc32)c1 ; O=C(OC(C(F)(F)F)C(F)(F)F)c1ccc([S+]2c3ccccc3S(=O)(=O)c3ccccc32)cc1]

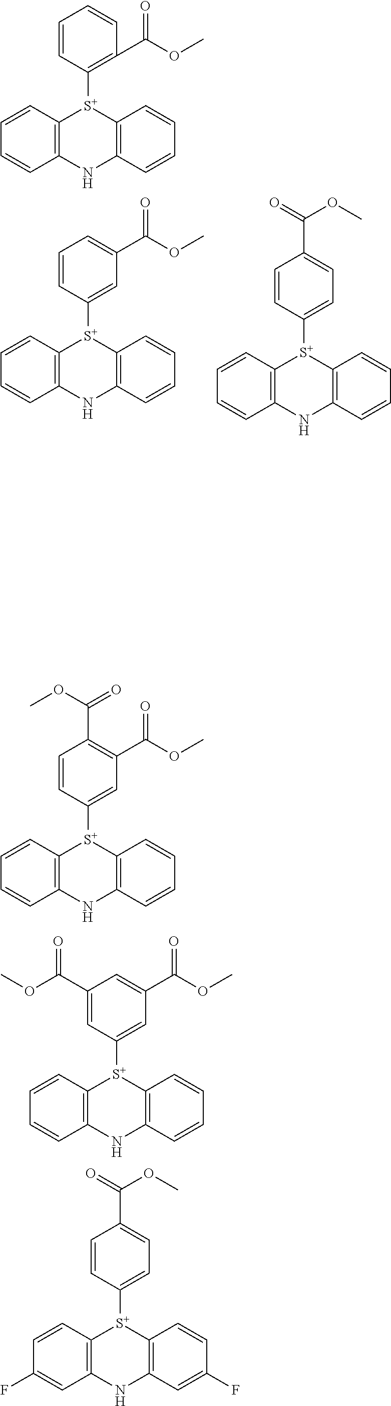

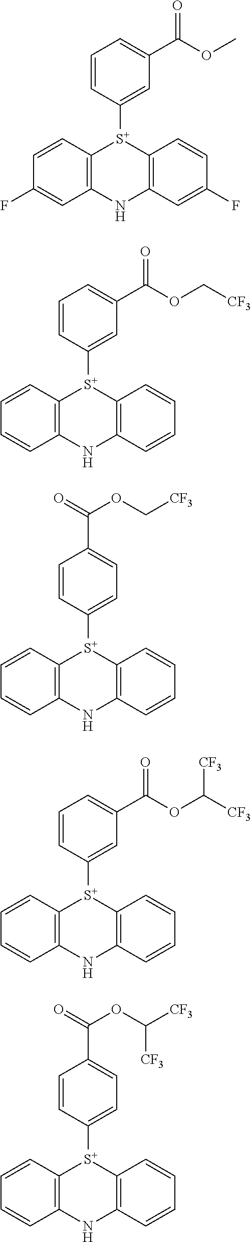 [SMILES: COC(=O)c1cccc([S+]2c3ccc(F)cc3Nc3cc(F)ccc32)c1 ; O=C(OCC(F)(F)F)c1cccc([S+]2c3ccccc3Nc3ccccc32)c1 ; O=C(OCC(F)(F)F)c1ccc([S+]2c3ccccc3Nc3ccccc32)cc1 ; O=C(OC(C(F)(F)F)C(F)(F)F)c1cccc([S+]2c3ccccc3Nc3ccccc32)c1 ; O=C(OC(C(F)(F)F)C(F)(F)F)c1ccc([S+]2c3ccccc3Nc3ccccc32)cc1]

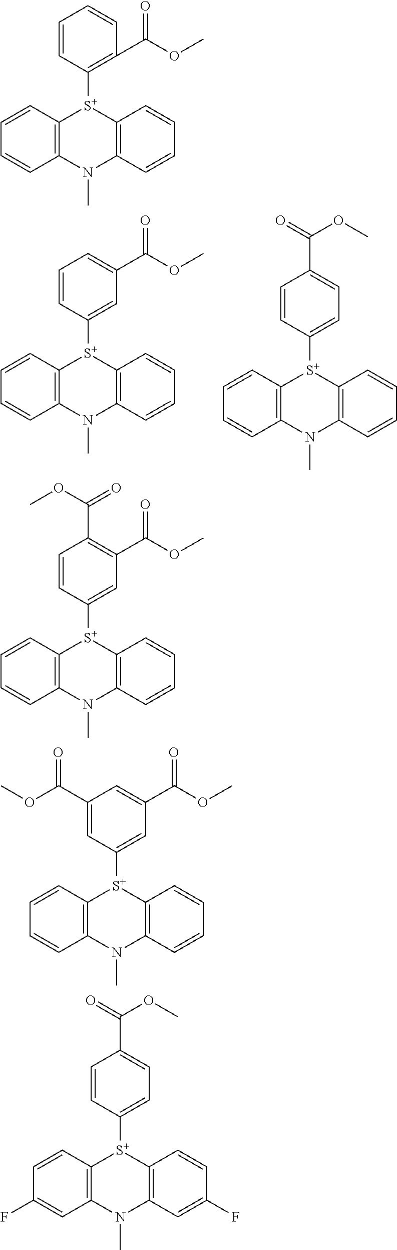

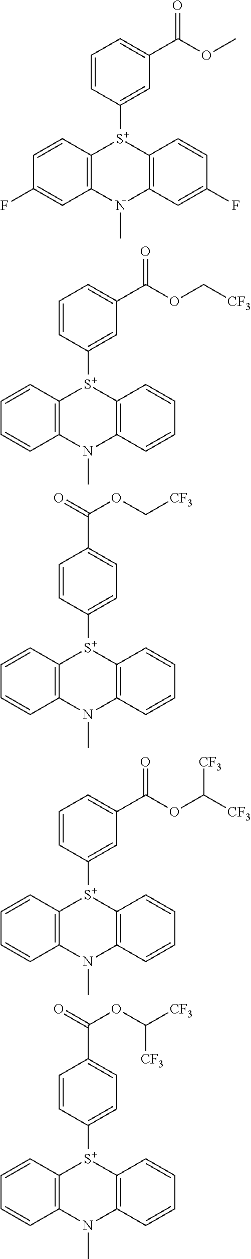 [SMILES: COC(=O)c1cccc([S+]2c3ccc(F)cc3N(C)c3cc(F)ccc32)c1 ; CN1c2ccccc2[S+](c2cccc(C(=O)OCC(F)(F)F)c2)c2ccccc21 ; CN1c2ccccc2[S+](c2ccc(C(=O)OCC(F)(F)F)cc2)c2ccccc21 ; CN1c2ccccc2[S+](c2cccc(C(=O)OC(C(F)(F)F)C(F)(F)F)c2)c2ccccc21 ; CN1c2ccccc2[S+](c2ccc(C(=O)OC(C(F)(F)F)C(F)(F)F)cc2)c2ccccc21]

Examples of the sulfonic acid anion having a carbon atom to which an iodine atom is bonded include those represented by formula (2)-1.

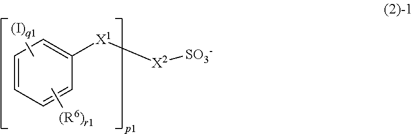

In formula (2)-1, p1 is an integer of 1 to 3, q1 is an integer of 1 to 5, and r1 is an integer of 0 to 4, provided that 1≤q1+r1≤5.

In formula (2)-1, R⁶ is a hydroxy group, a carboxy group, a halogen atom other than an iodine atom, an amino group, or a C₁-C₂₀ hydrocarbyl group, a C₁-C₂₀ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a halogen atom, a hydroxy group, an amino group, or an ether bond, —N(R^{6A})(R^{6B}), —N(R^{6C})—C(═O)—R^{6D}, or —N(R^{6C})—C(═O)O—R^{6D}. R^{6A} and R^{6B} are each independently a hydrogen atom or a C₁-C₆ saturated hydrocarbyl group. R^{6C} is a hydrogen atom or a C₁-C₆ saturated hydrocarbyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. R^{6D} is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. The aliphatic hydrocarbyl group may be saturated or unsaturated, and may be straight, branched, or cyclic. The hydrocarbyl group and the hydrocarbyl moiety in the hydrocarbyloxy group, the hydrocarbyloxycarbonyl group, the hydrocarbylcarbonyl group, and the hydrocarbylcarbonyloxy group may be saturated or unsaturated, and may be straight, branched, or cyclic. Examples thereof include those groups mentioned as the hydrocarbyl group represented by R²¹ to R²⁸ in the description of formulae (f1) to (f3) described later. Groups R⁶ may be identical or different when p1 and/or r1 is 2 or more.

In formula (2)-1, X¹ is a single bond, an ether bond, an amide bond, a urethane bond, an ester bond, or a C₁-C₆ saturated hydrocarbylene group which may contain an ether bond or an ester bond. The saturated hydrocarbylene group may be straight, branched, or cyclic.

In formula (2)-1, X² is a single bond or a C₁-C₂₂ divalent linking group when p1 is 1, and a C₁-C₂₂ (p1+1)-valent linking group which may contain an oxygen atom, a sulfur atom, a nitrogen atom, or a halogen atom when p1 is 2 or 3.

Examples of the sulfonic acid anion having a carbon atom to which an iodine atom is bonded include those represented by formula (2)-2.

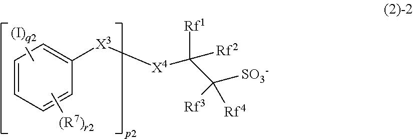

In formula (2)-2, p2 is an integer of 1 to 3, q2 is an integer of 1 to 5, and r2 is an integer of 0 to 4, provided that 1≤q2+r2≤5.

In formula (2)-2, R⁷ is a hydroxy group, a carboxy group, a halogen atom other than an iodine atom, an amino group, or a C₁-C₂₀ hydrocarbyl group, a C₁-C₂₀ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a halogen atom, a hydroxy group, an amino group, or an ether bond, —N(R^{7A})(R^{7B}), —N(R^{7C})—C(═O)—R^{7D}, or —N(R^{7C})—C(═O)—O—R^{7D}. R^{7A} and R^{7B} are each independently a hydrogen atom or a C₁-C₆ saturated hydrocarbyl group. R^{7C} is a hydrogen atom or a C₁-C₆ saturated hydrocarbyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. R^{7D} is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. The aliphatic hydrocarbyl group may be saturated or unsaturated, and may be straight, branched, or cyclic. The hydrocarbyl group and the hydrocarbyl moiety in the hydrocarbyloxy group, the hydrocarbyloxycarbonyl group, the hydrocarbylcarbonyl group, and the hydrocarbylcarbonyloxy group may be saturated or unsaturated, and may be straight, branched, or cyclic. Examples thereof include those groups mentioned as the hydrocarbyl group represented by R²¹ to R²⁸ in the description of formulae (f1) to (f3) described later. Groups R⁷ may be identical or different when p2 and/or r2 is 2 or more.

In formula (2)-2, X³ is a single bond, an ether bond, an amide bond, a urethane bond, an ester bond, or a C₁-C₆ saturated hydrocarbylene group which may contain an ether bond or an ester bond. The saturated hydrocarbylene group may be straight, branched, or cyclic.

In formula (2)-2, X⁴ is a single bond or a C₁-C₂₀ divalent linking group when p2 is 1, and a C₁-C₂₀ (p2+1)-valent linking group which may contain an oxygen atom, a sulfur atom, or a nitrogen atom when p2 is 2 or 3.

In formula (2)-2, Rf¹ to Rf⁴ are each independently a hydrogen atom, a fluorine atom, or a trifluoromethyl group, and at least one of Rf¹ to Rf⁴ is a fluorine atom or a trifluoromethyl group. Rf¹ and Rf² may together form a carbonyl group.

Examples of the anion having formula (2)-1 include those shown below, but are not limited thereto.

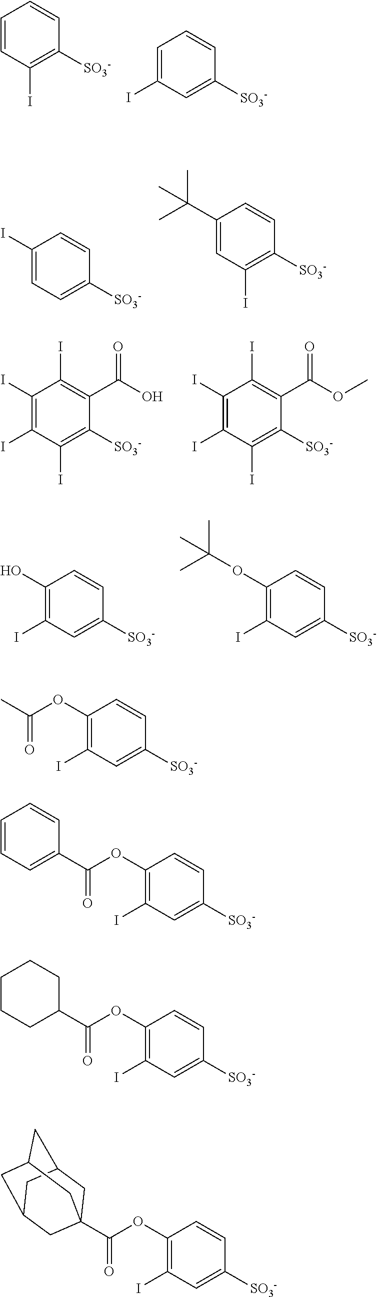

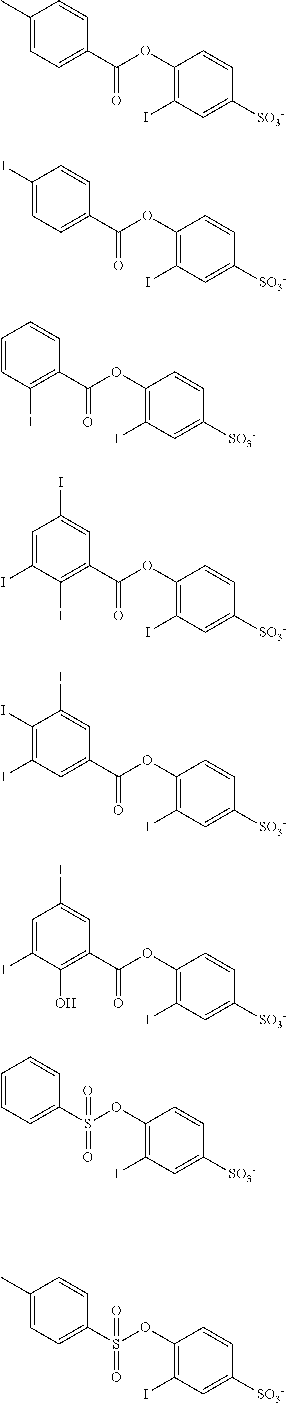

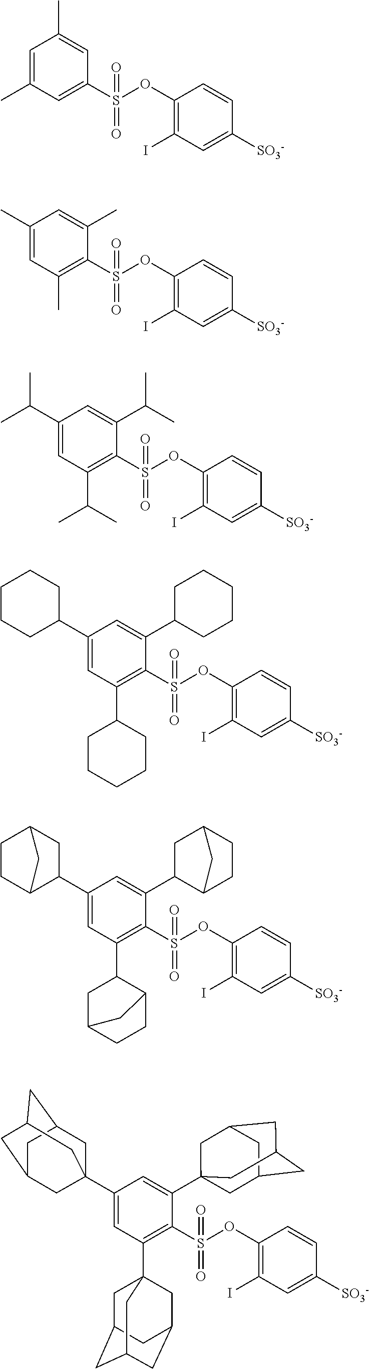

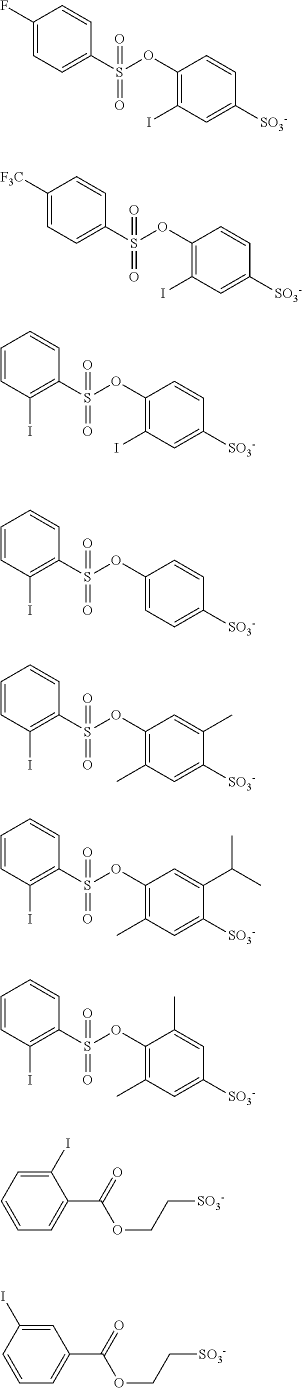

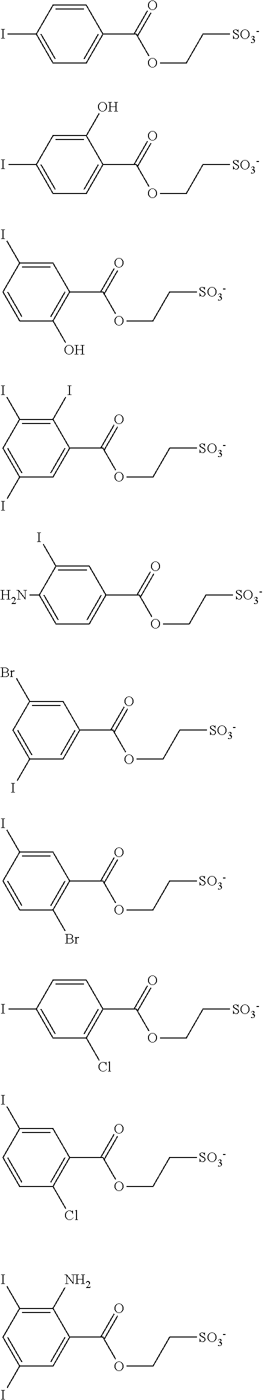

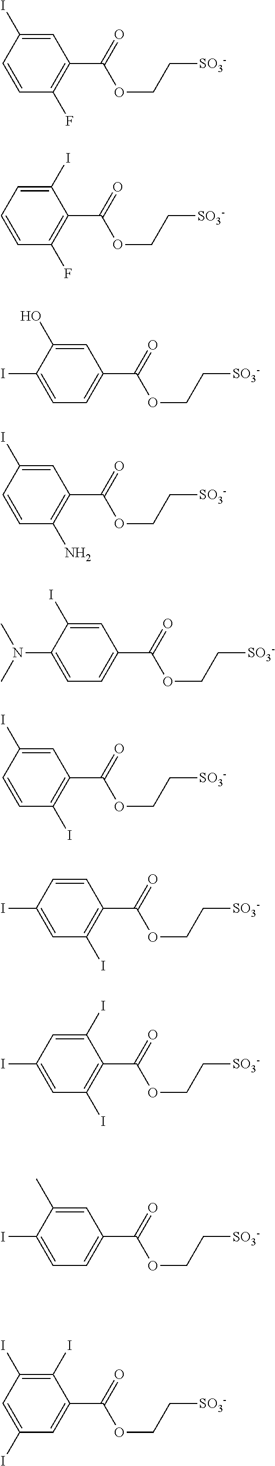

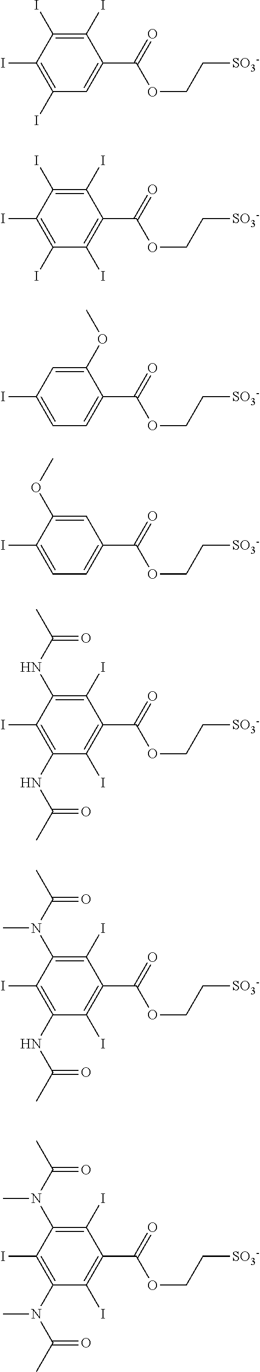

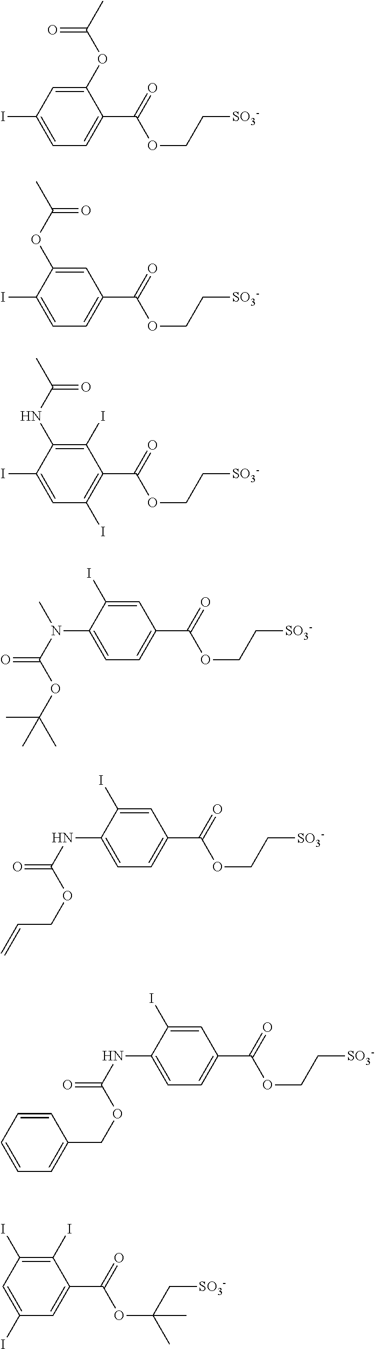

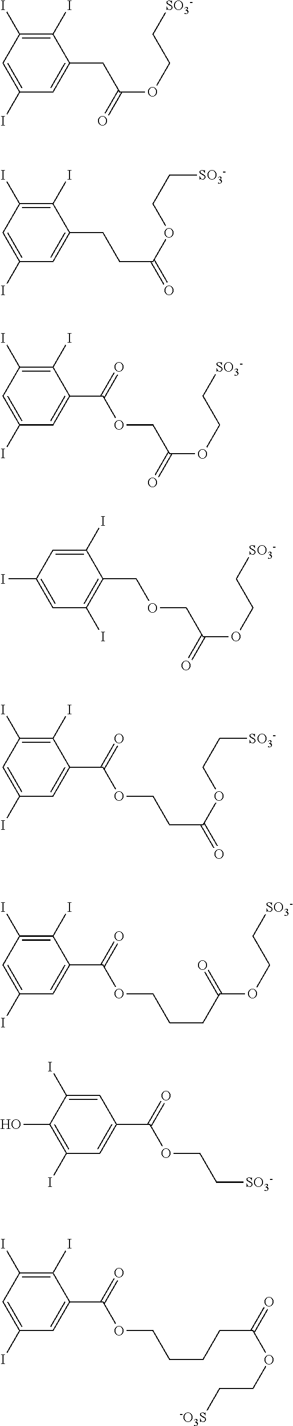

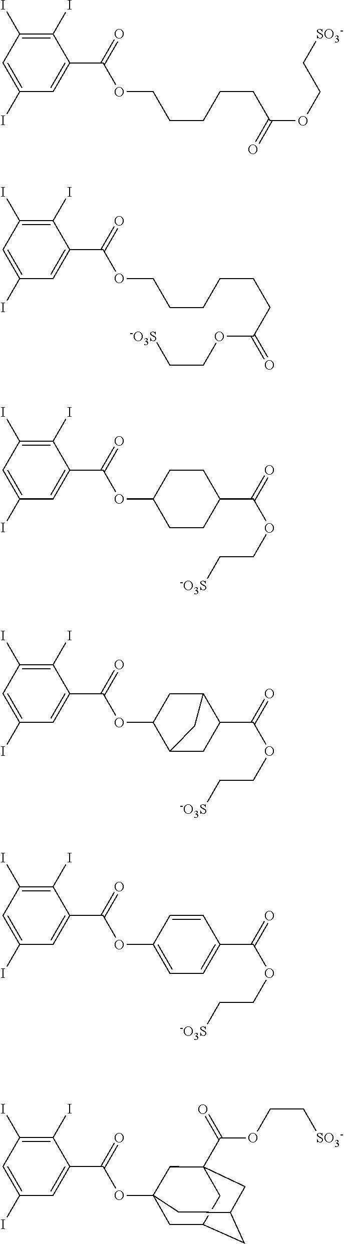

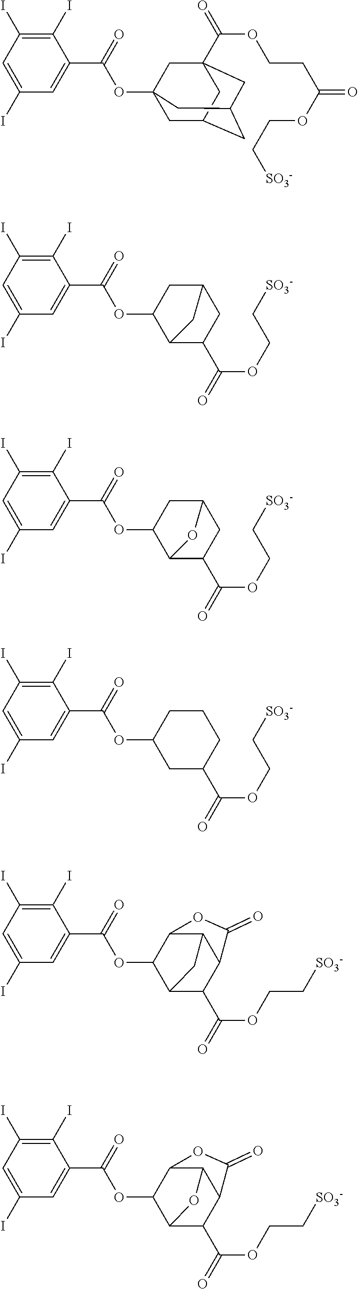

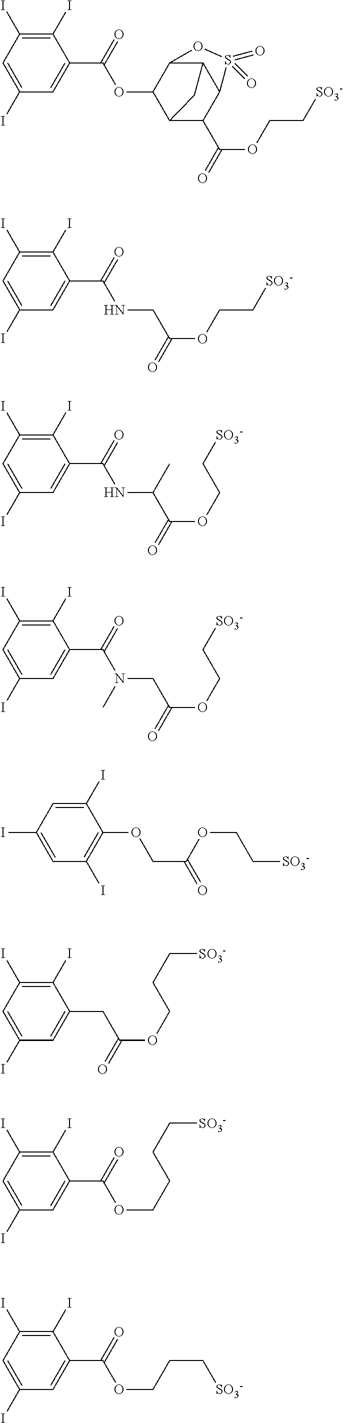

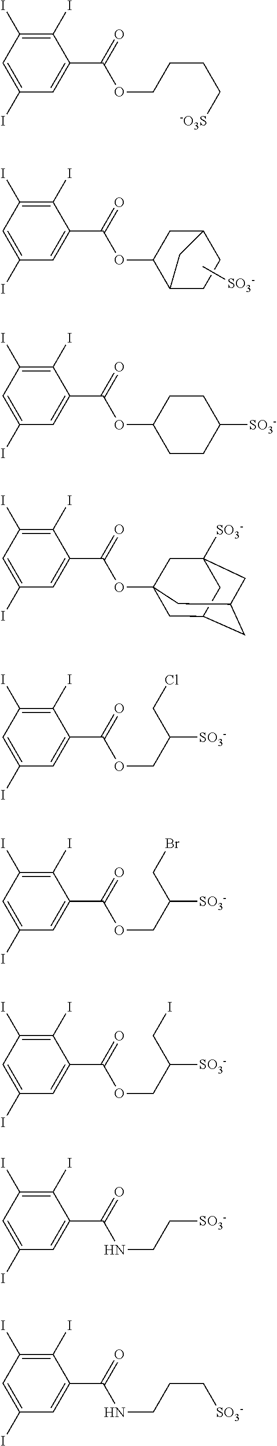

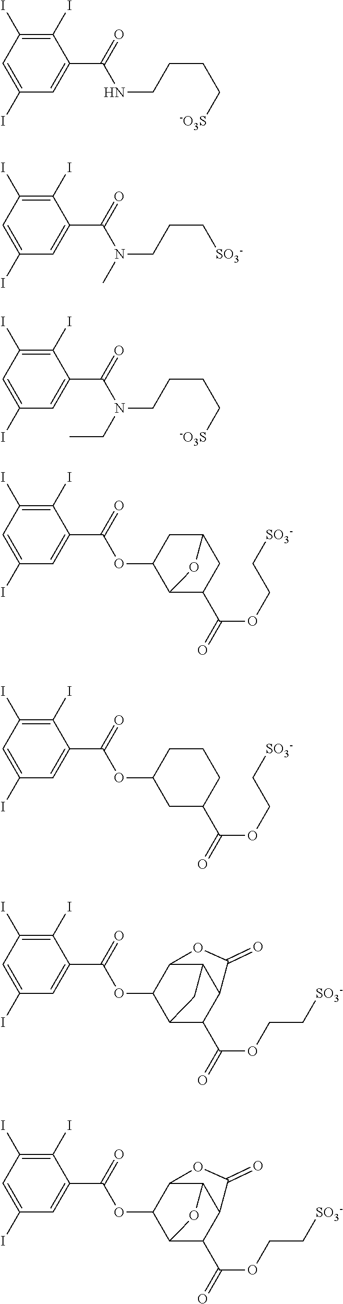

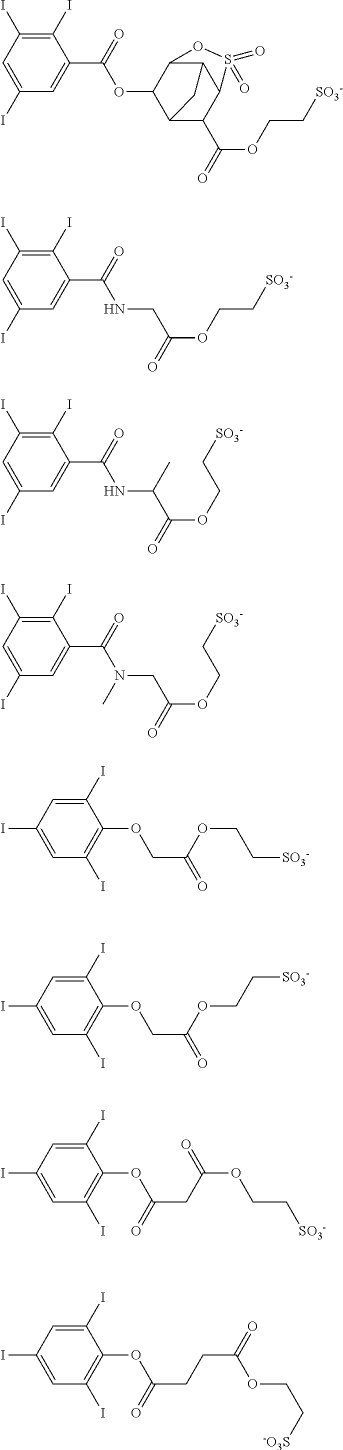

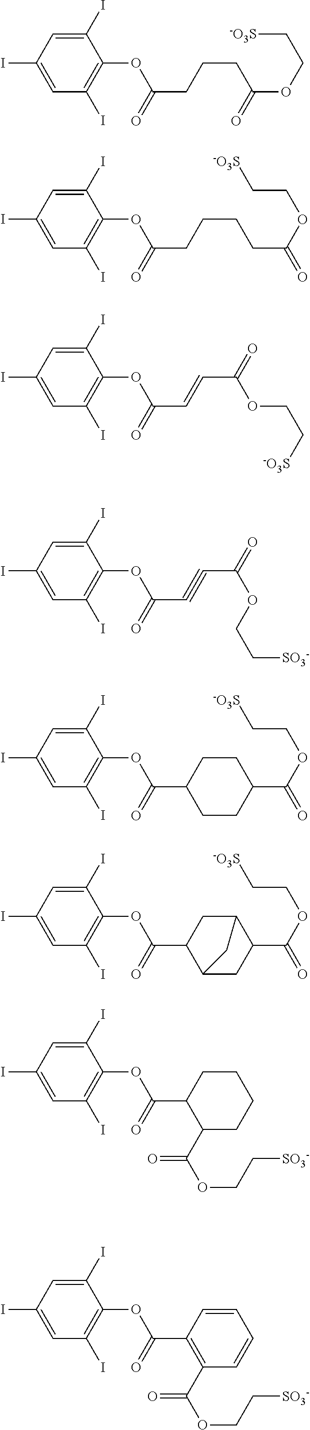

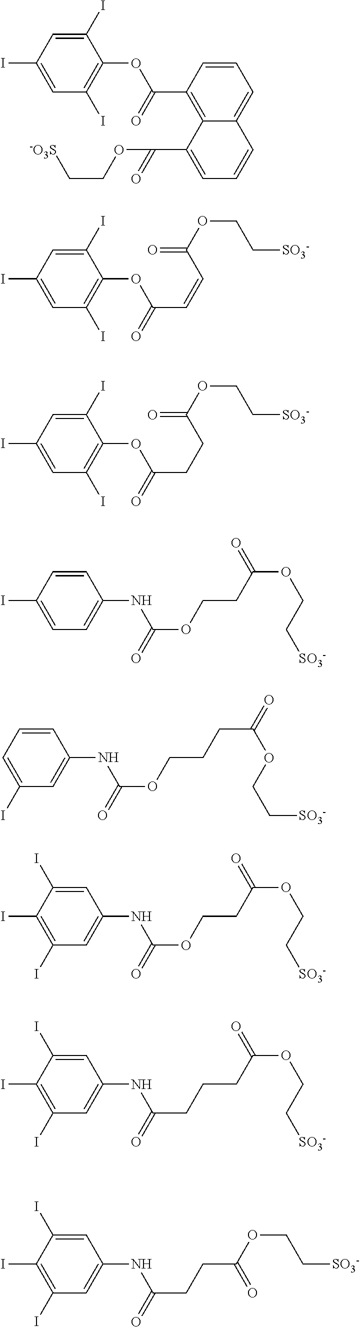

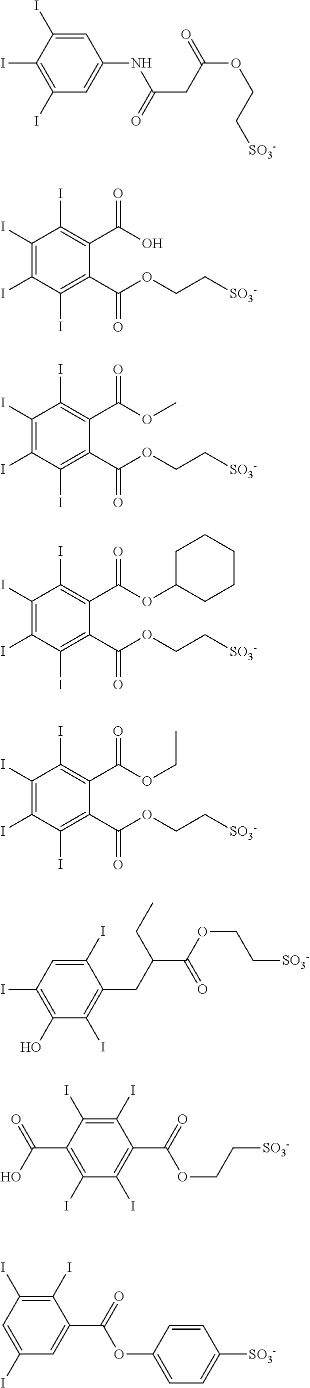

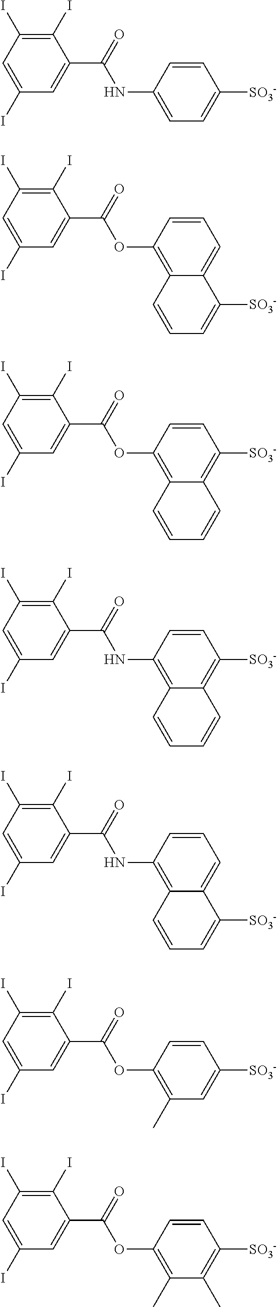

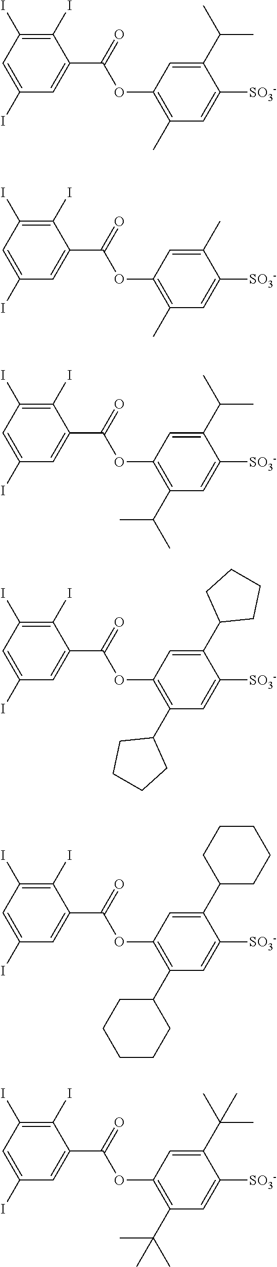

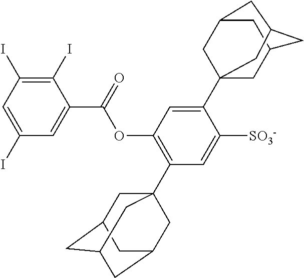

Examples of the anion having formula (2)-2 include those shown below, but are not limited thereto.

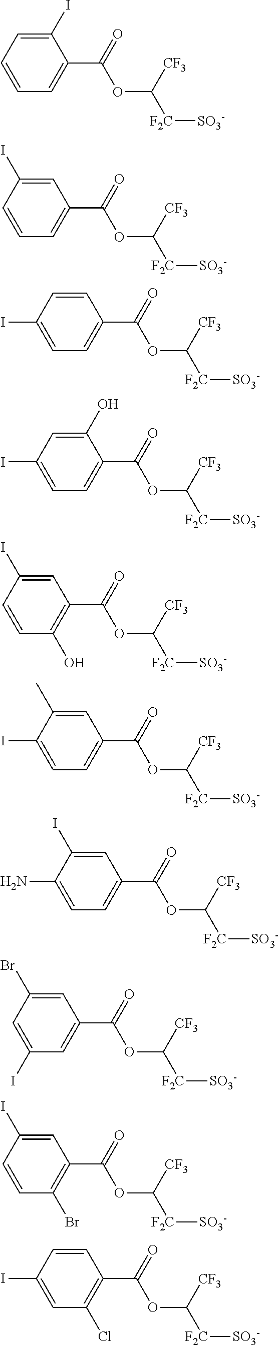

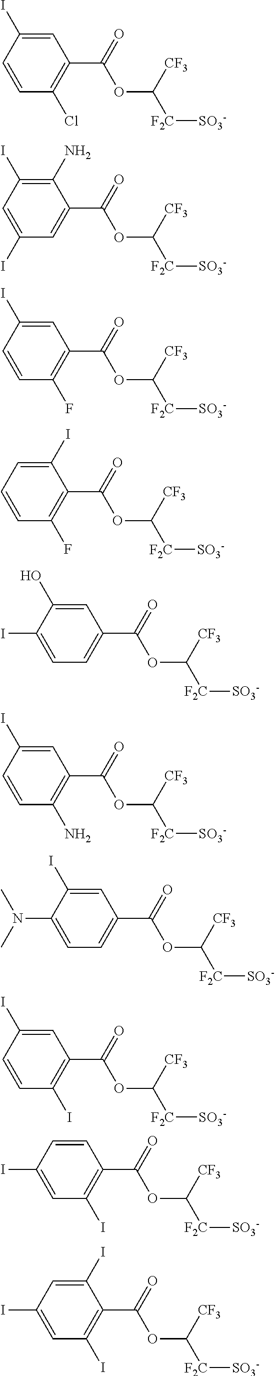

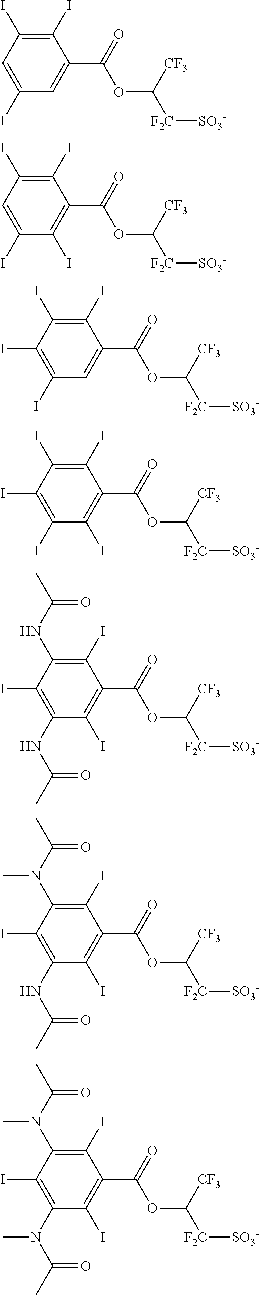

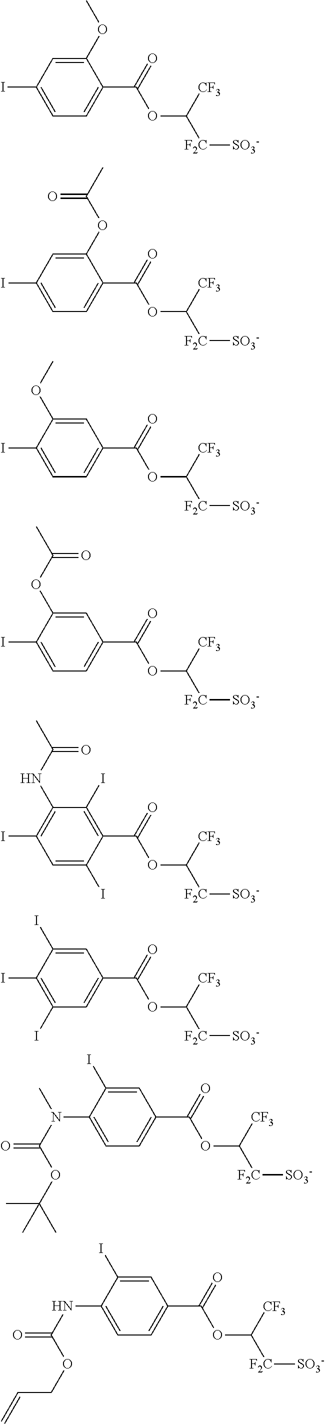

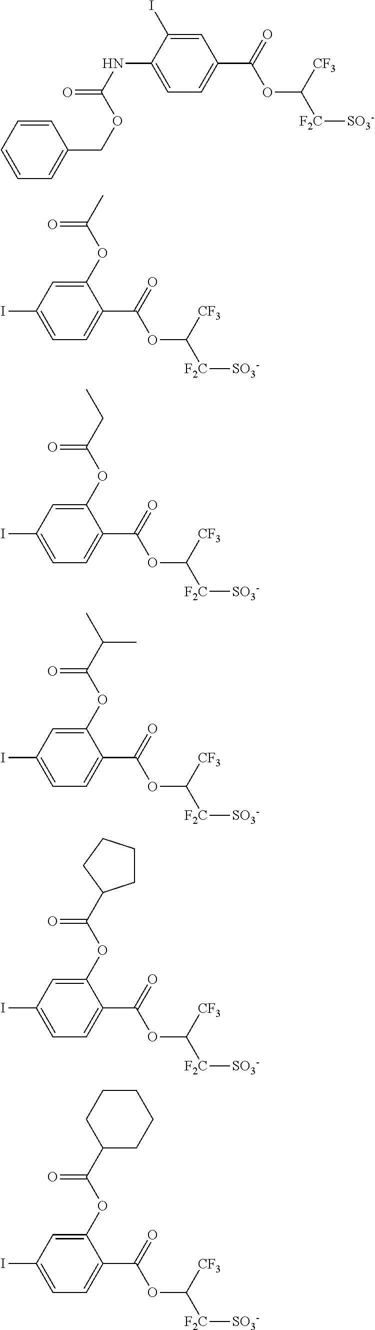

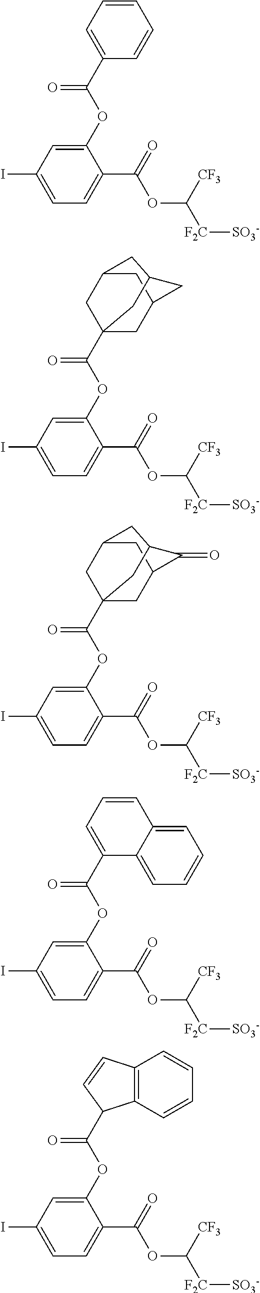

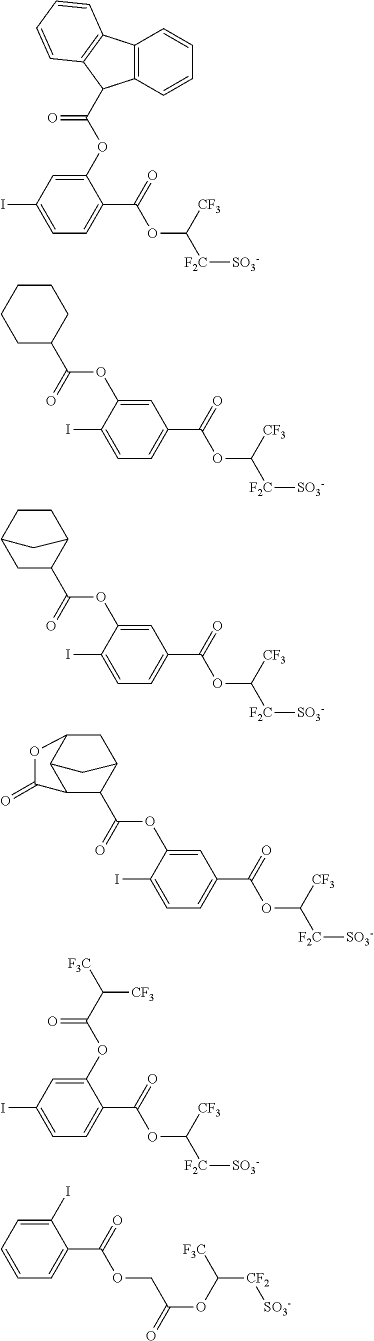

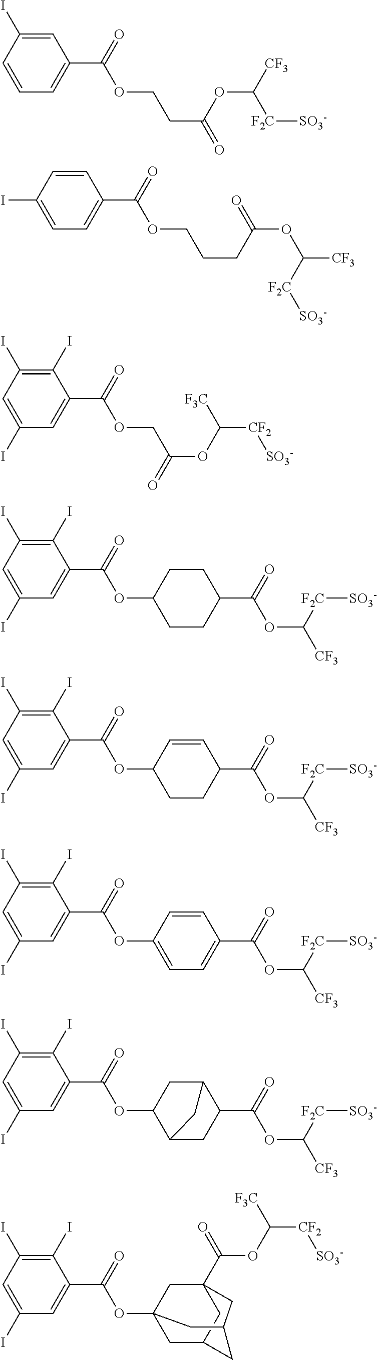

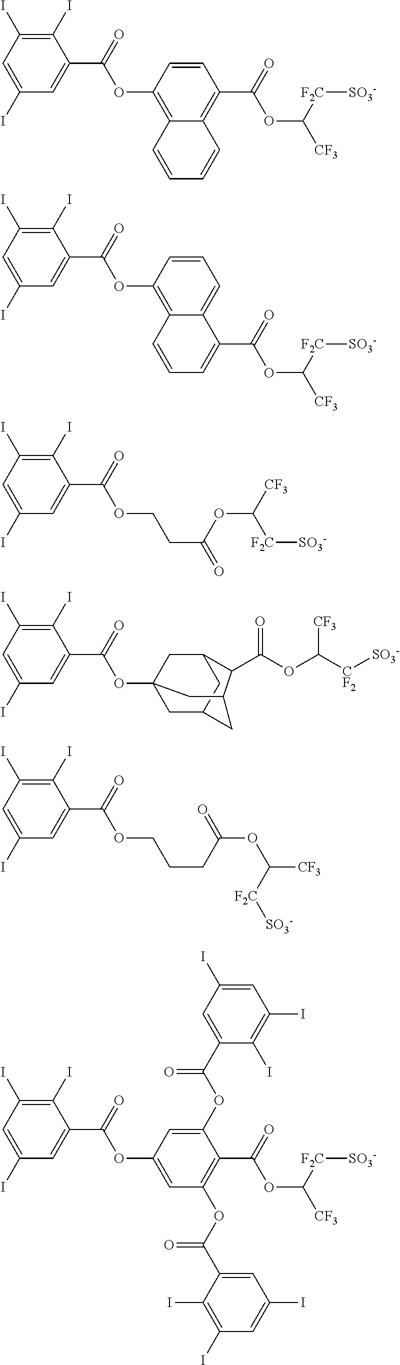

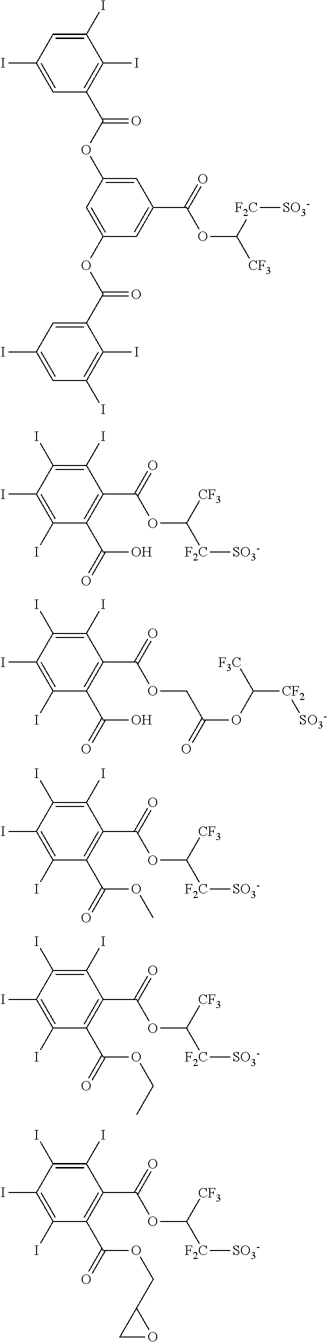

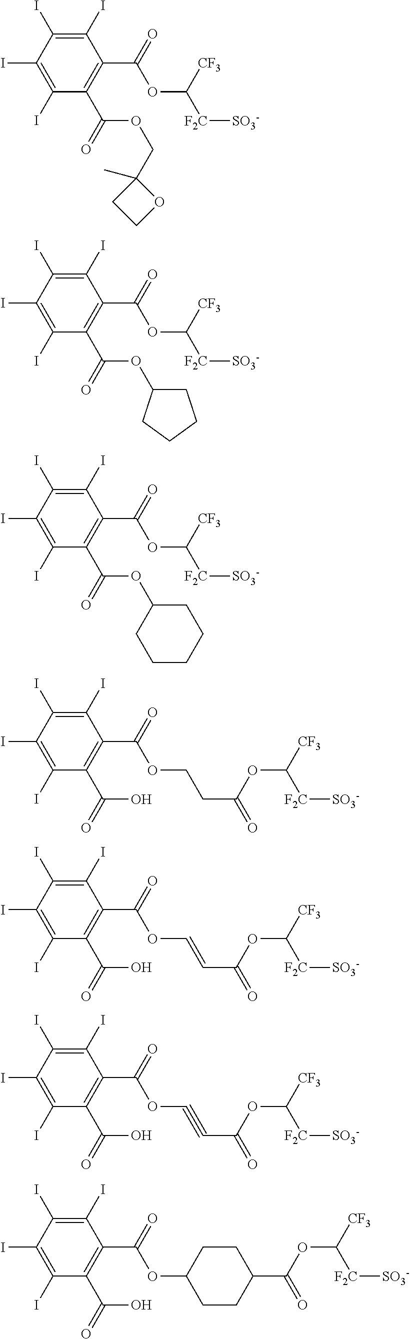

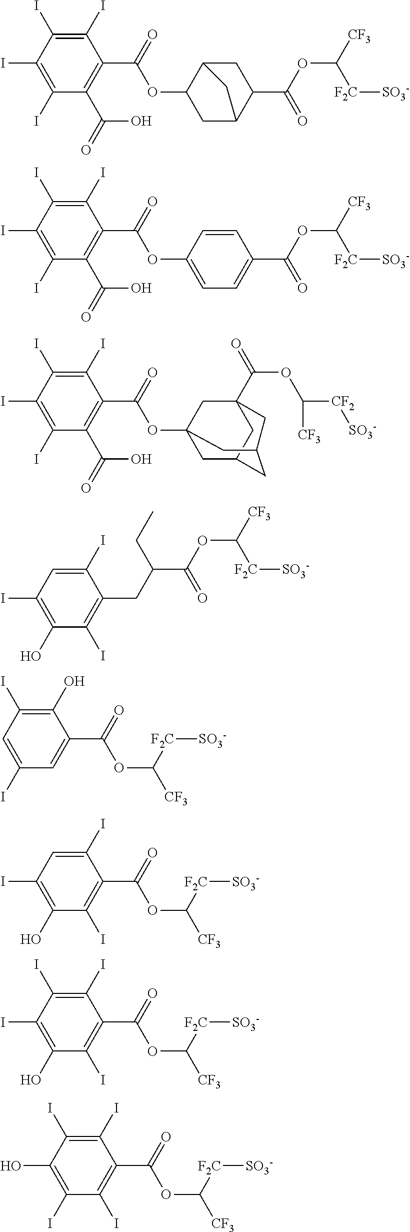

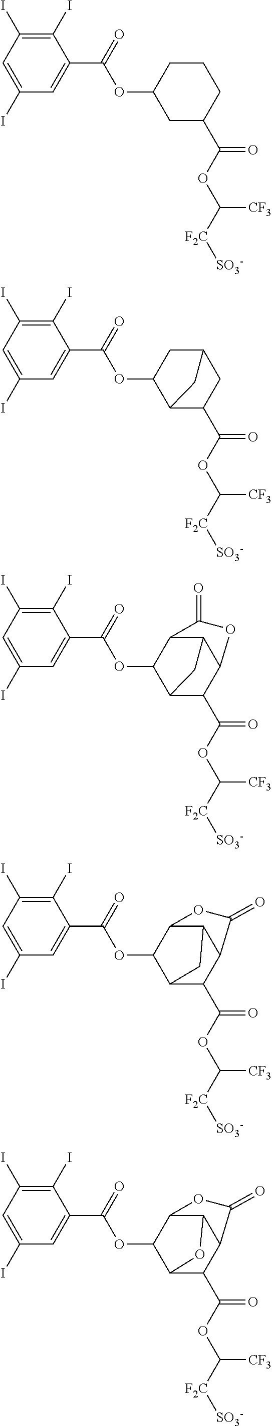

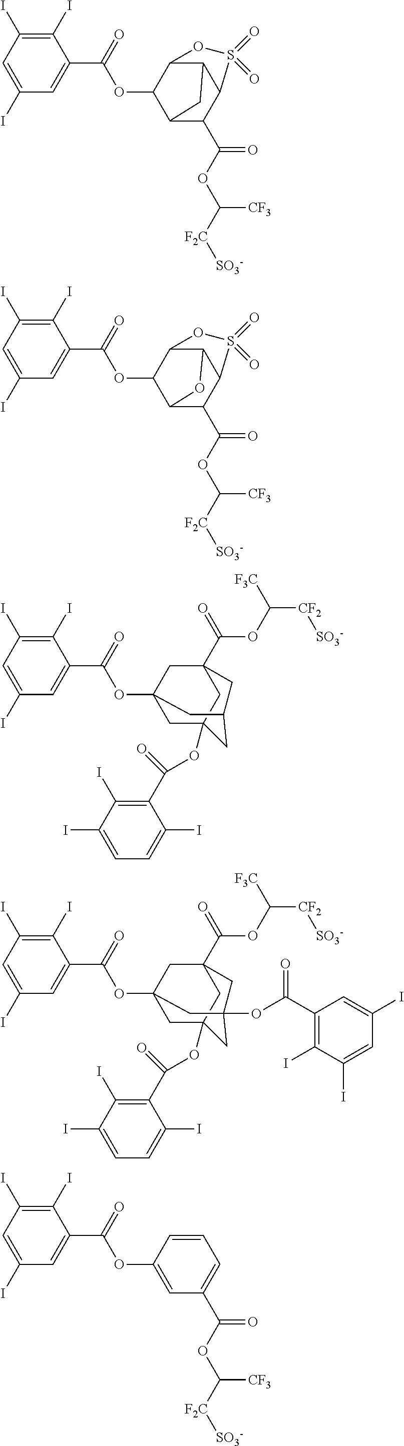

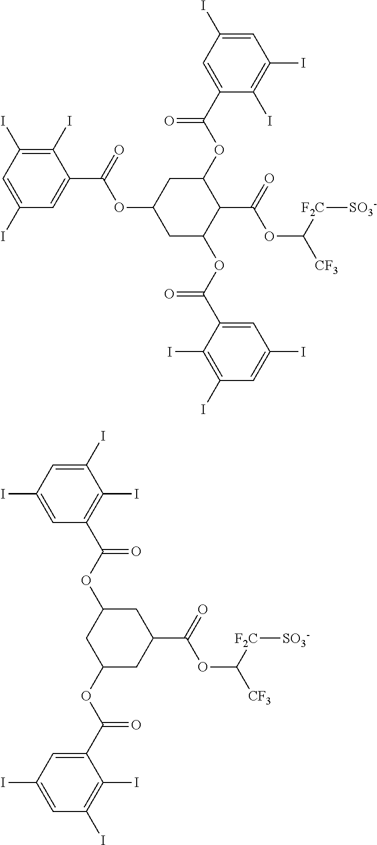

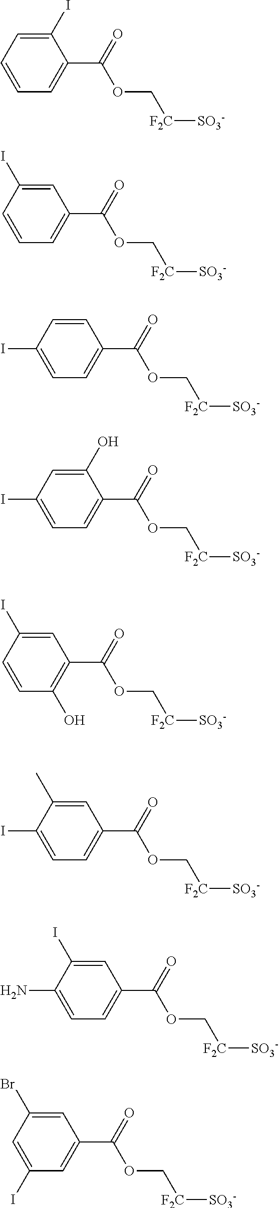

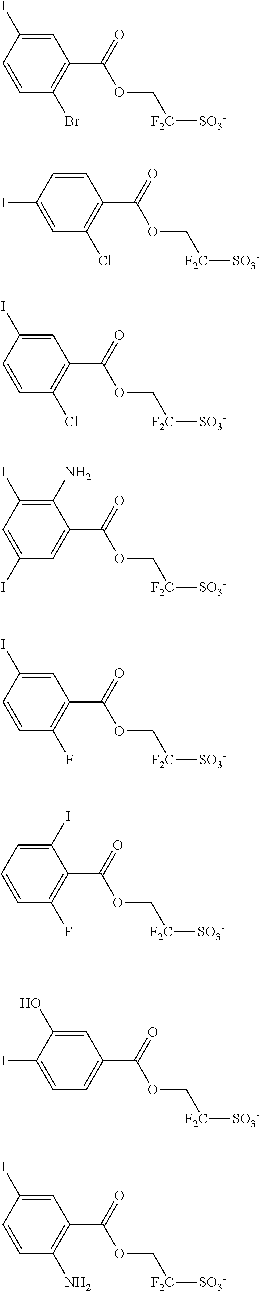

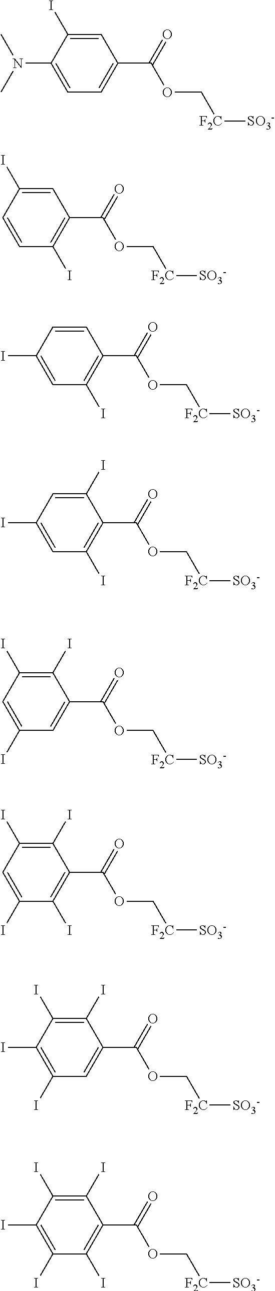

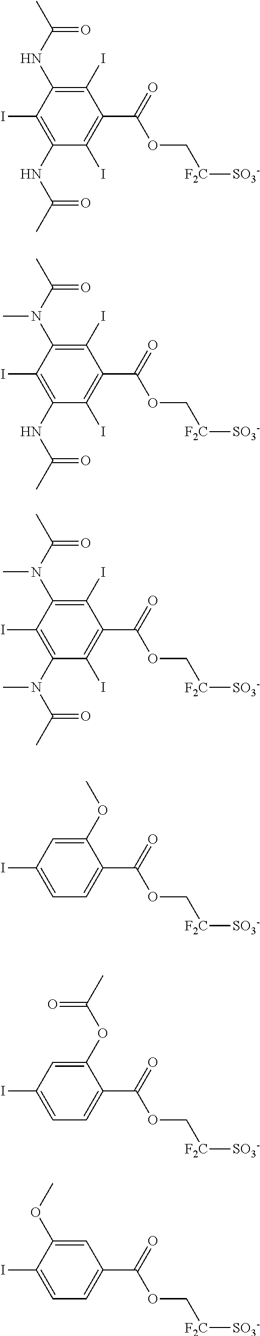

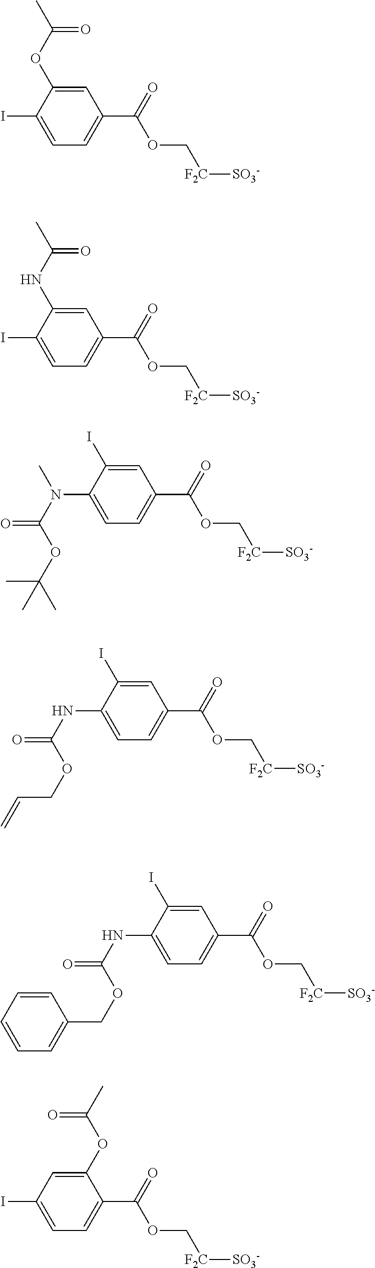

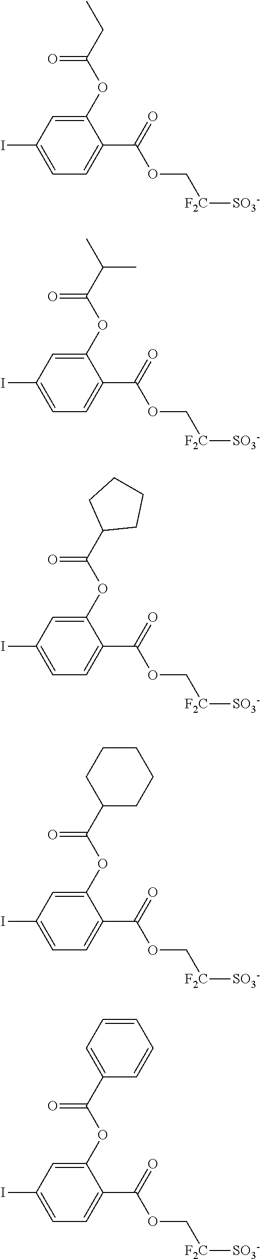

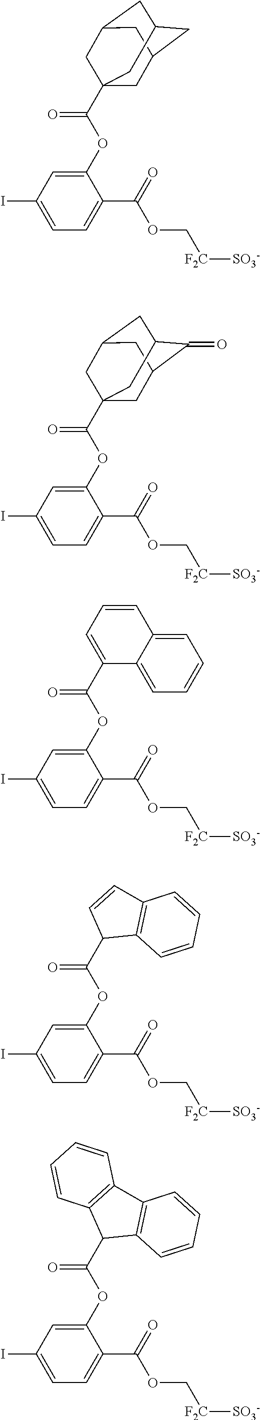

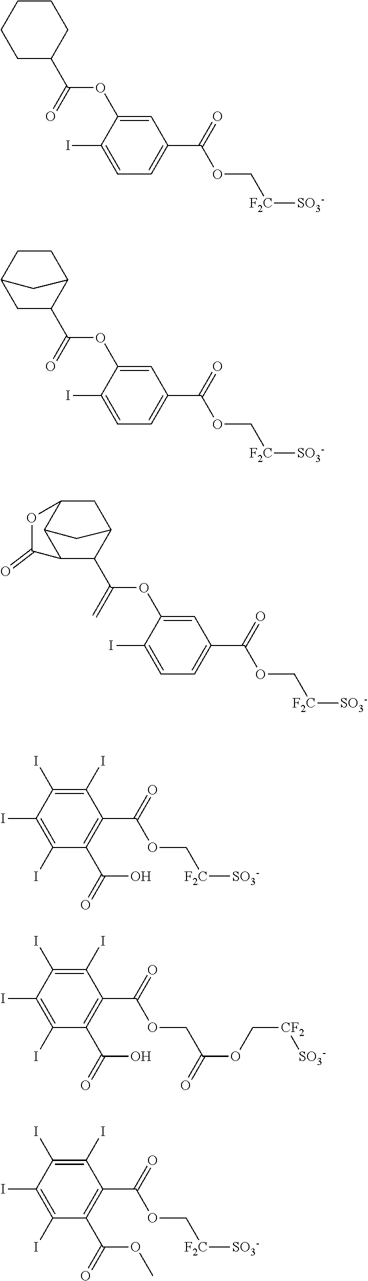

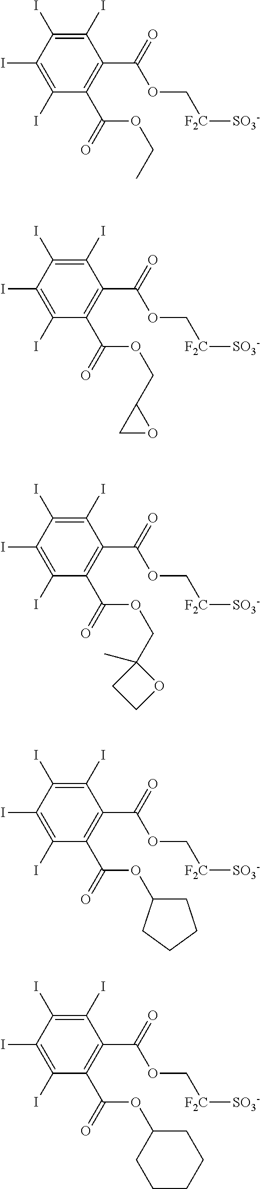

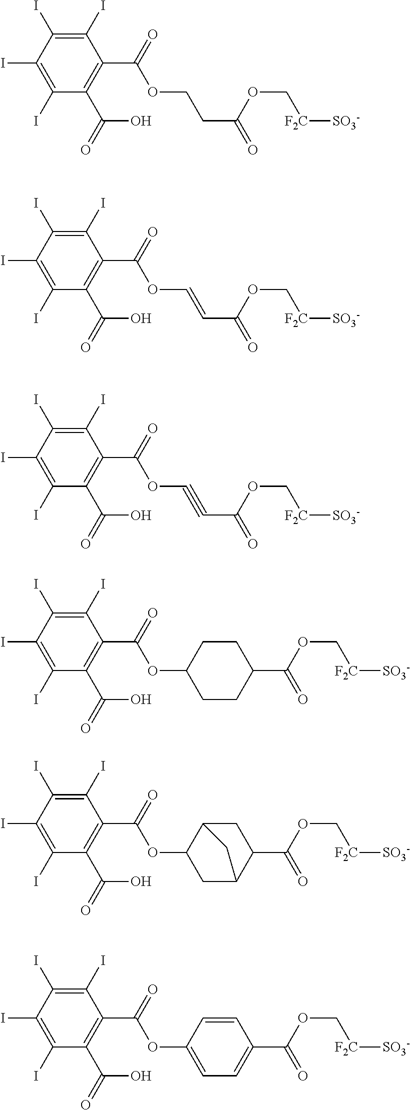

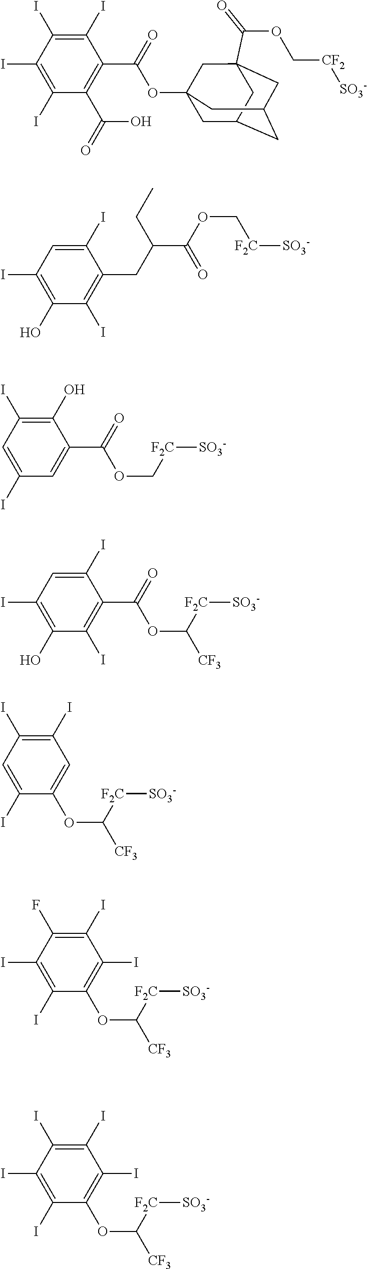

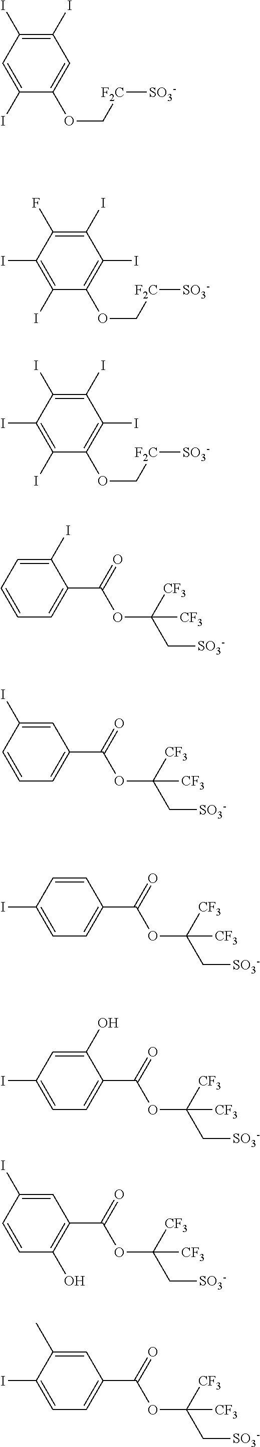

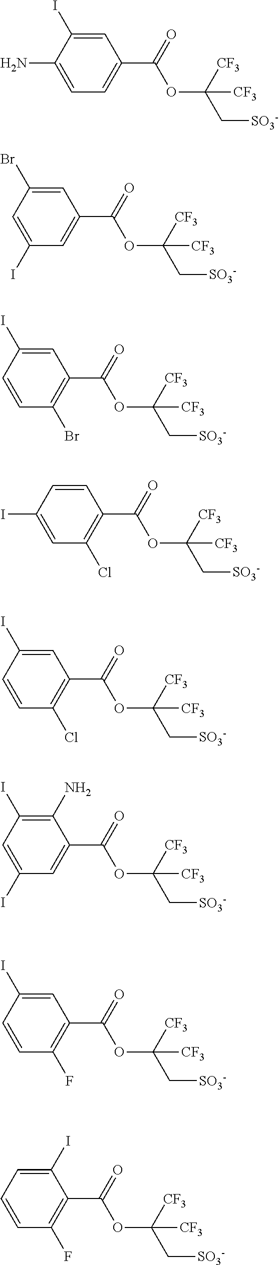

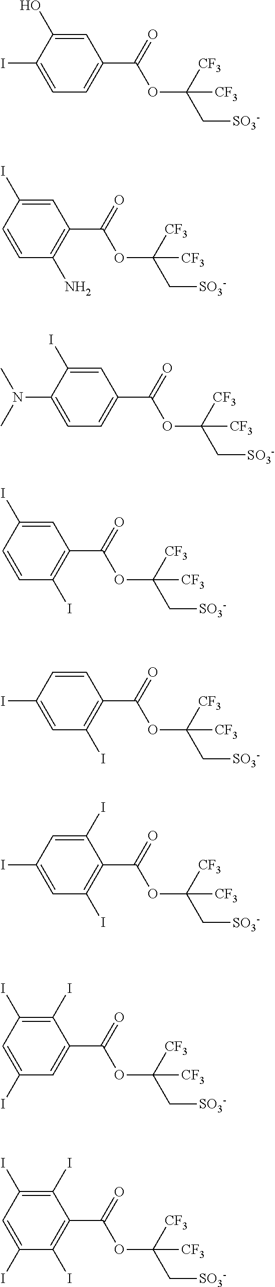

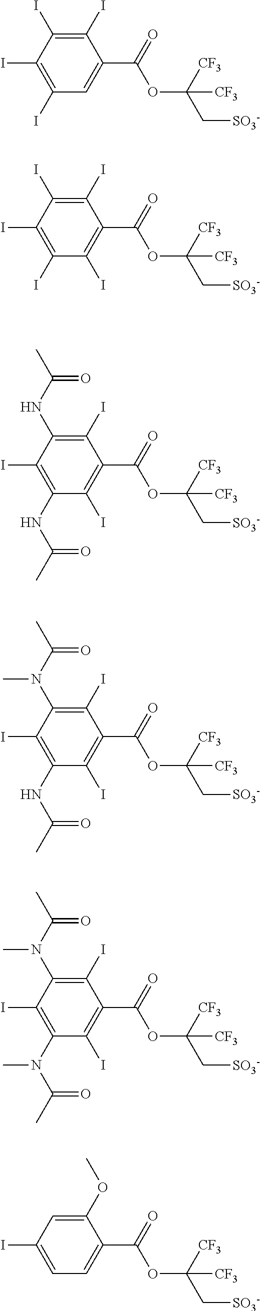

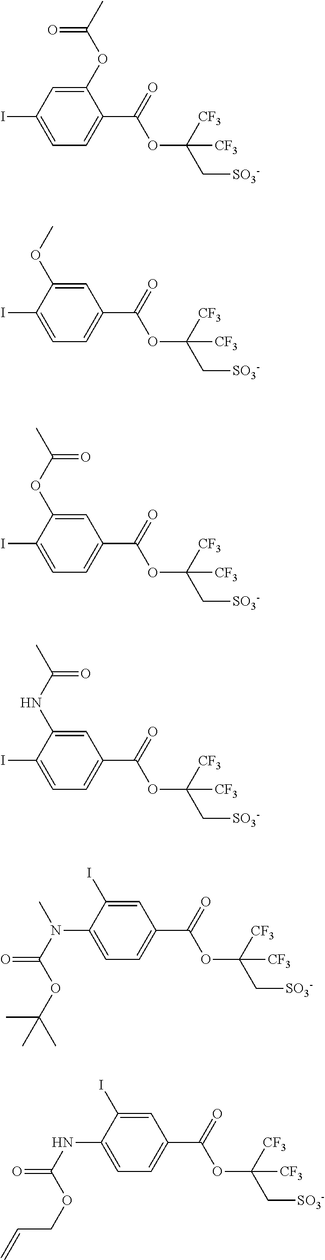

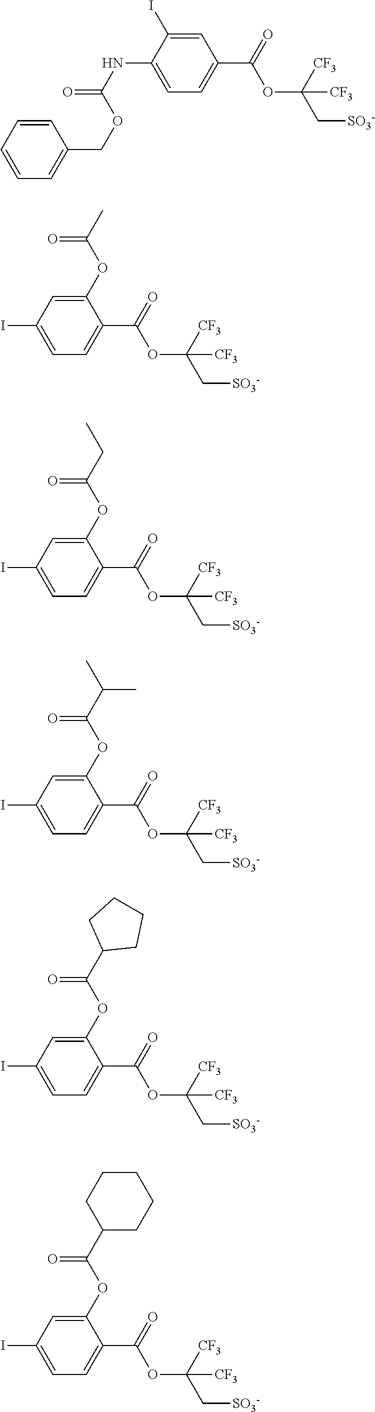

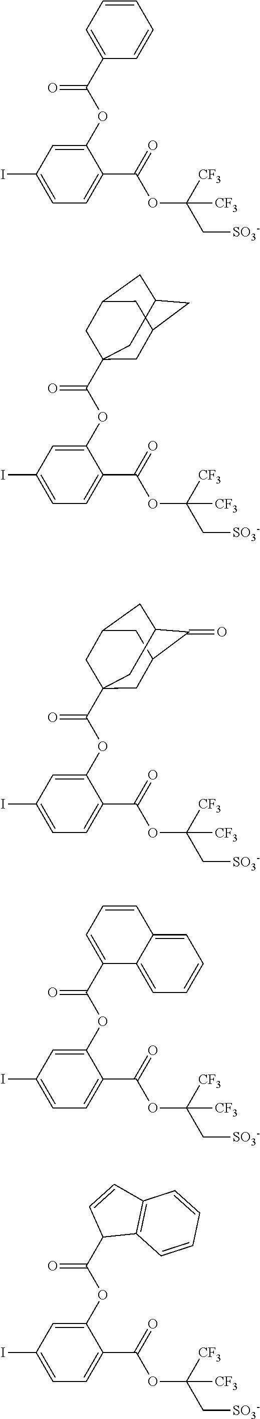

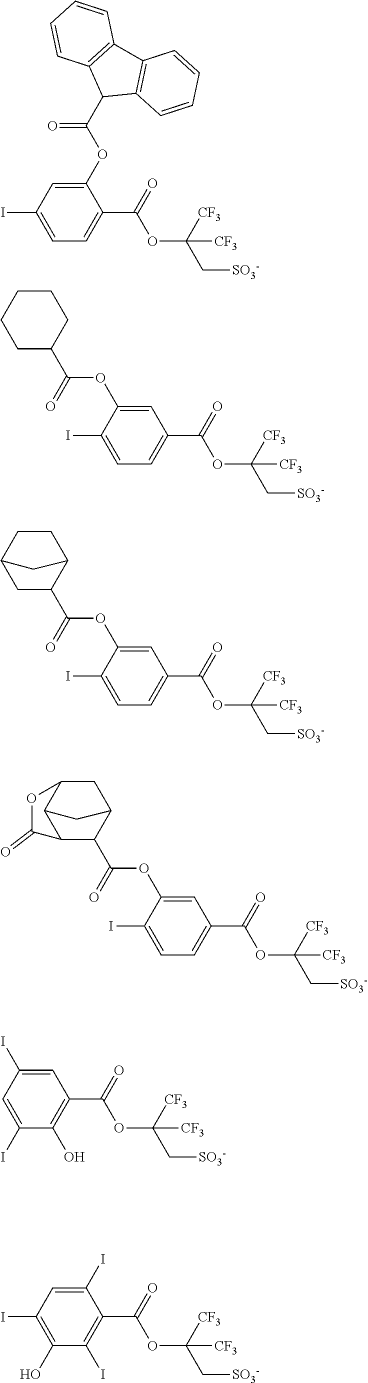

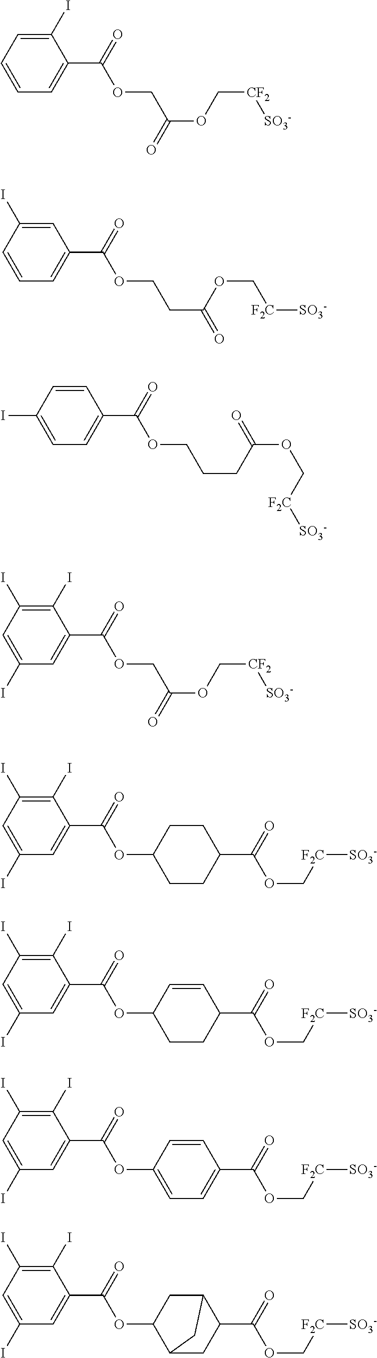

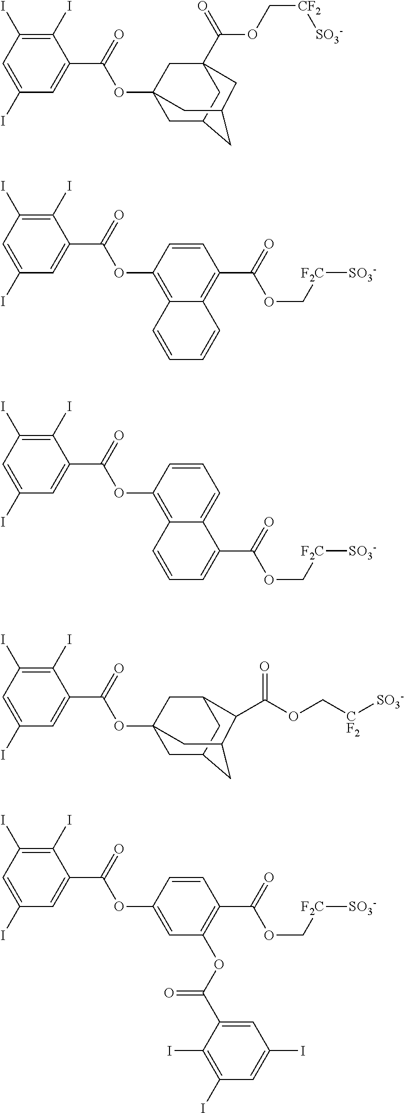

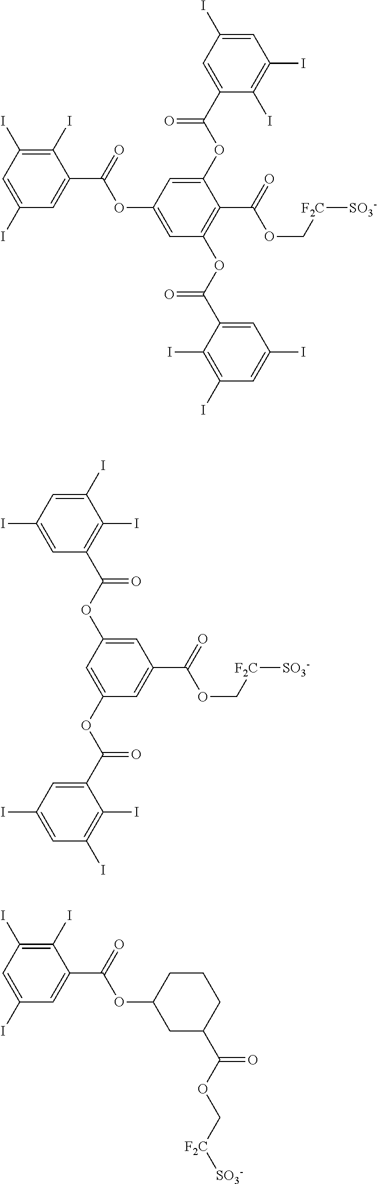

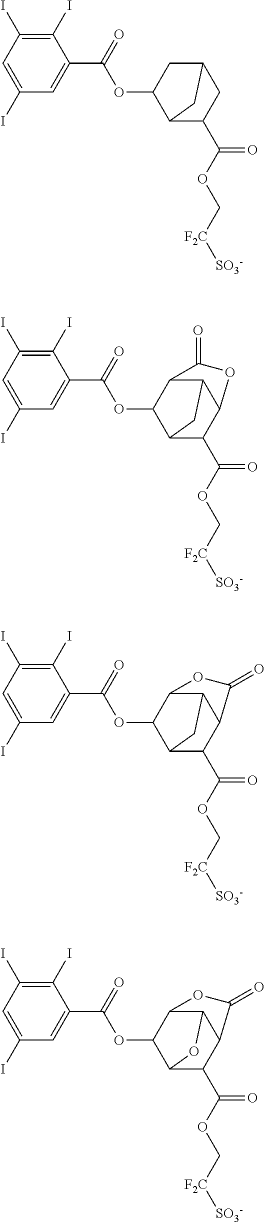

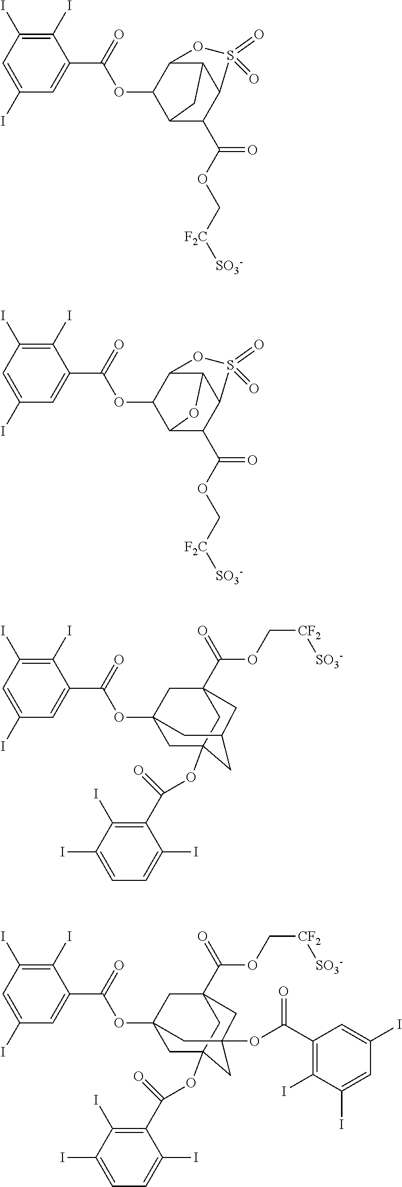

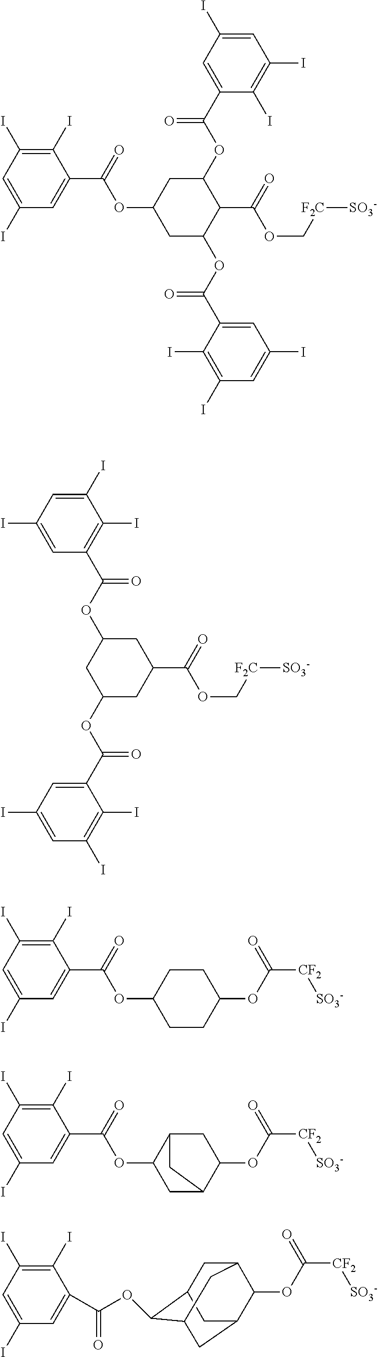

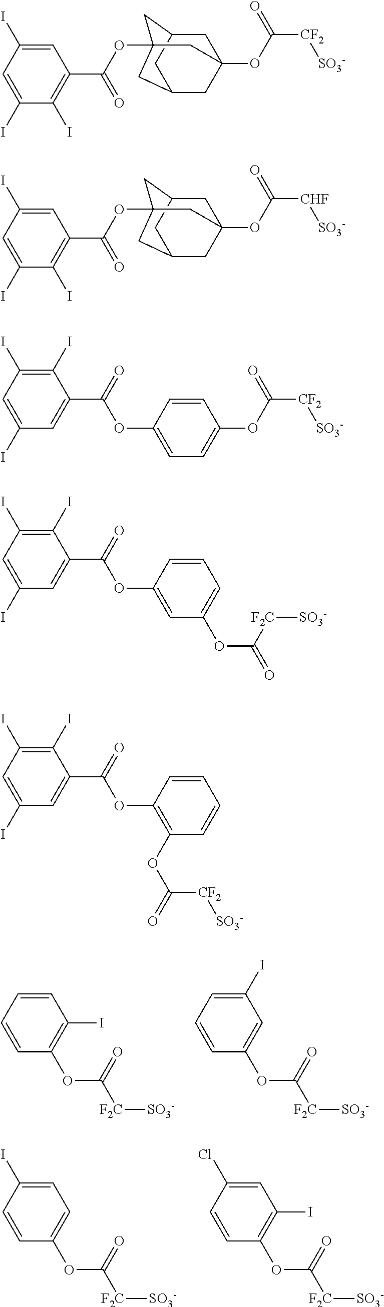

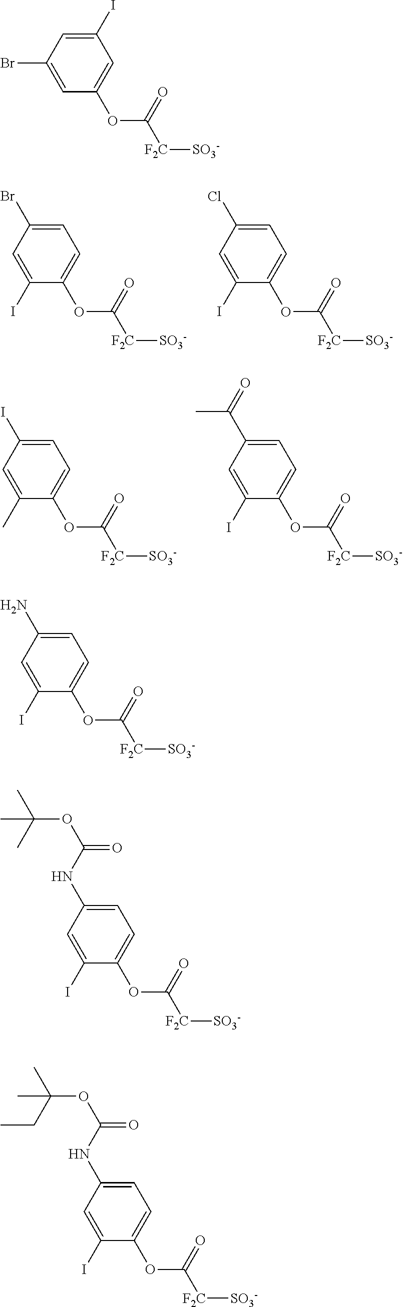

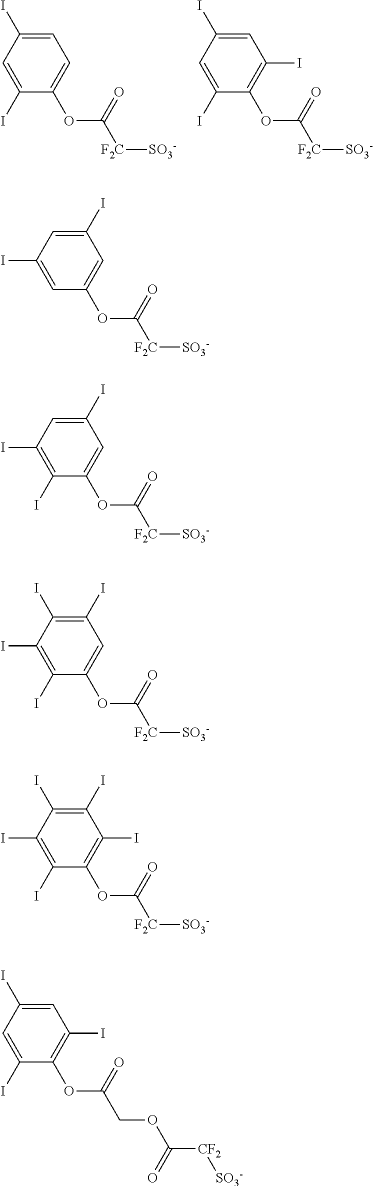

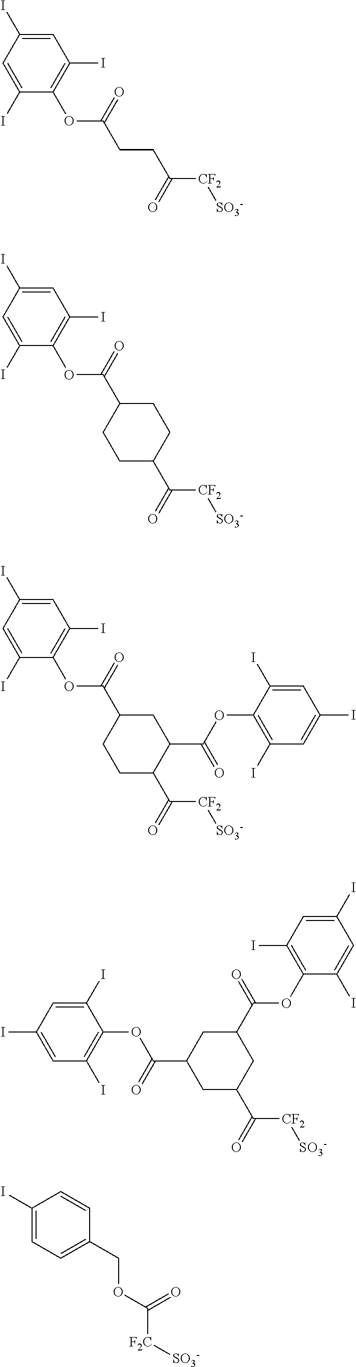

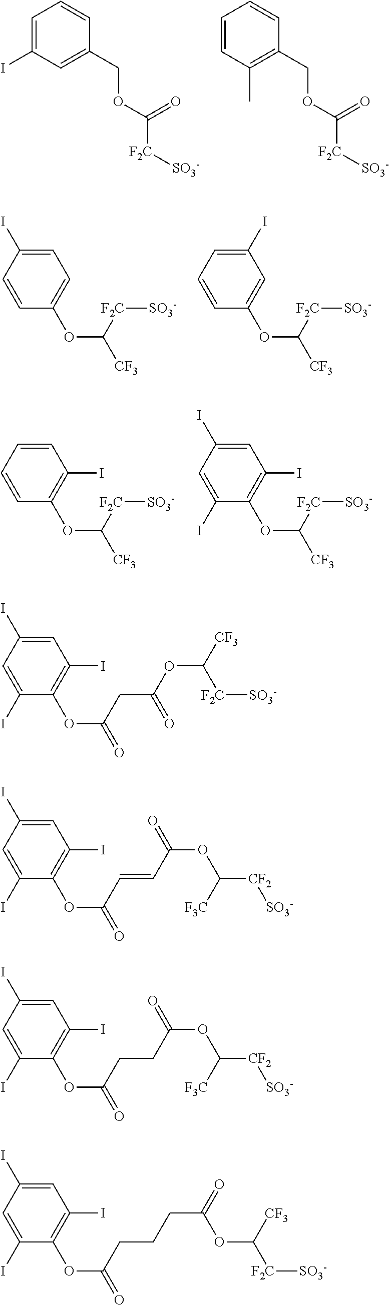

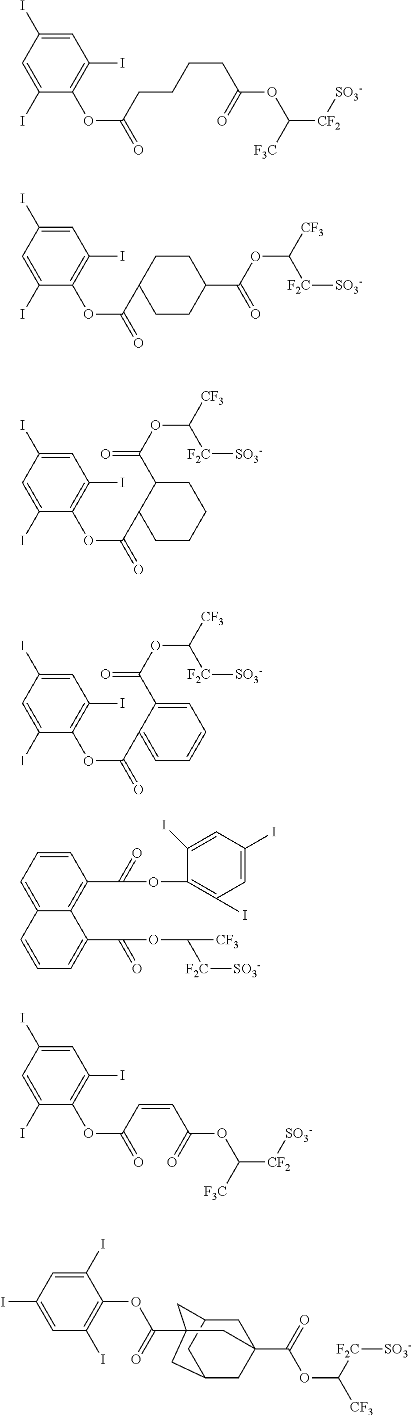

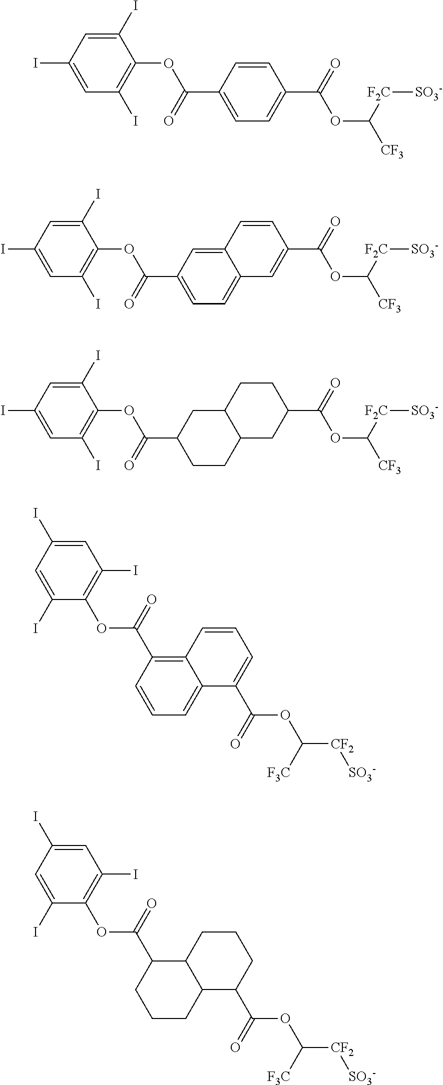

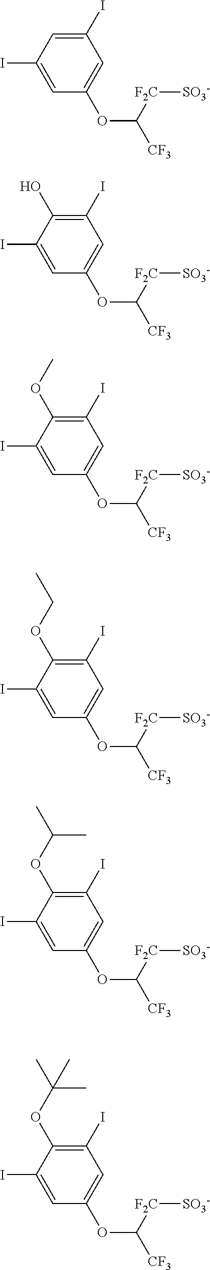

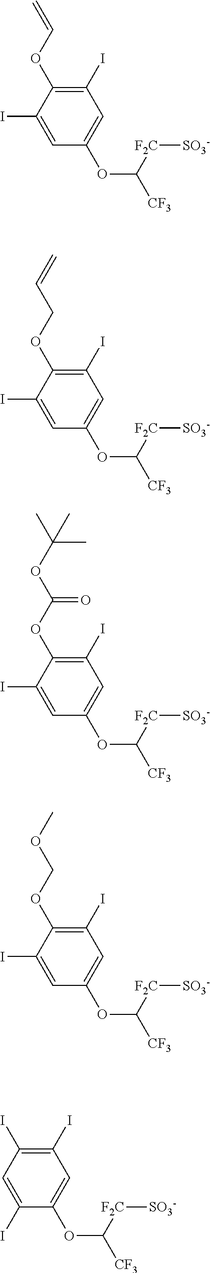

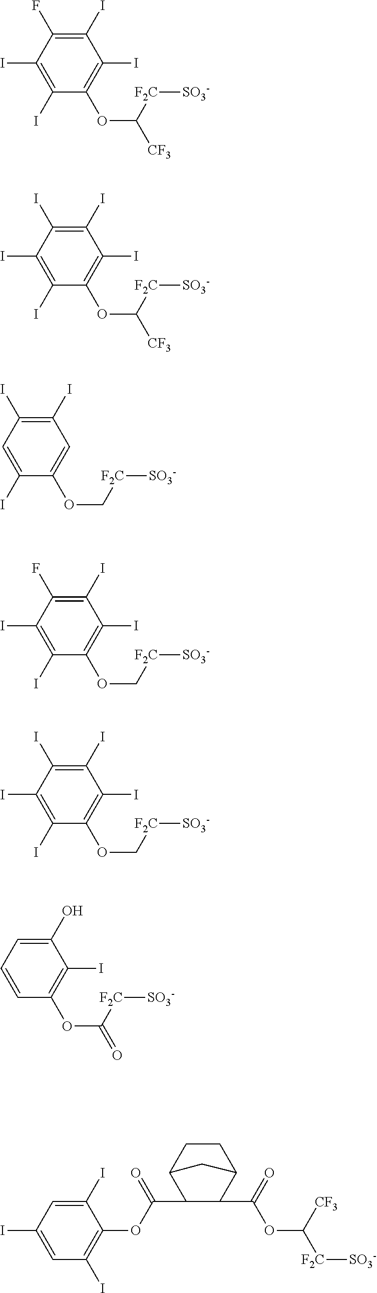

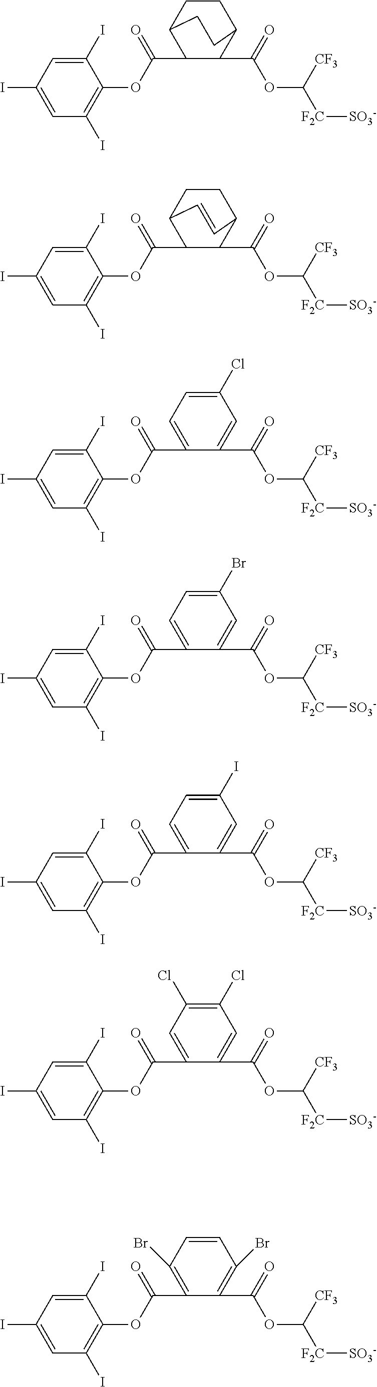

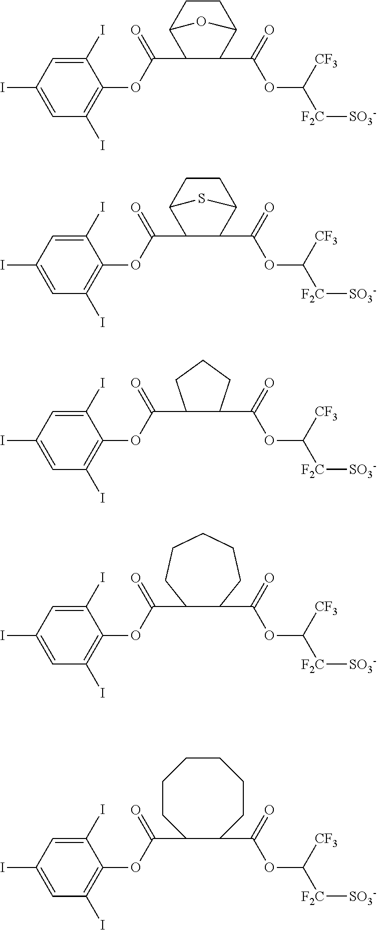

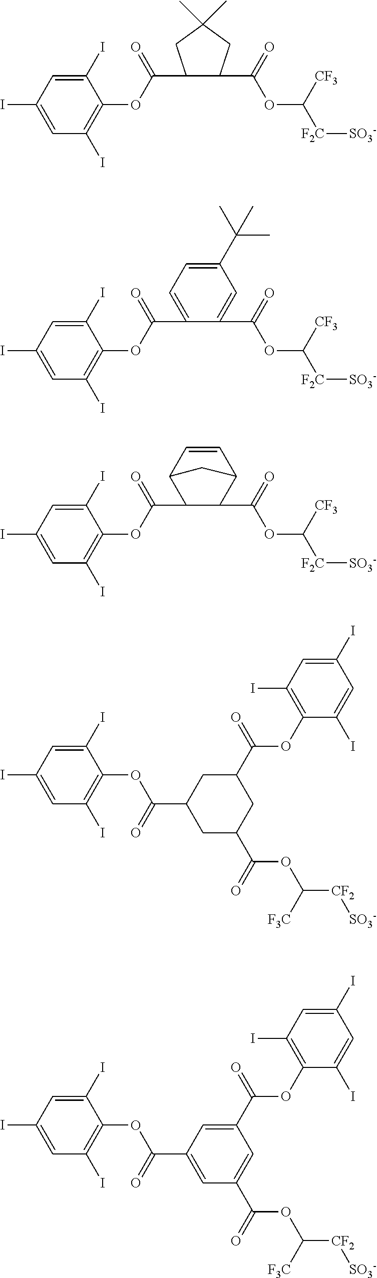

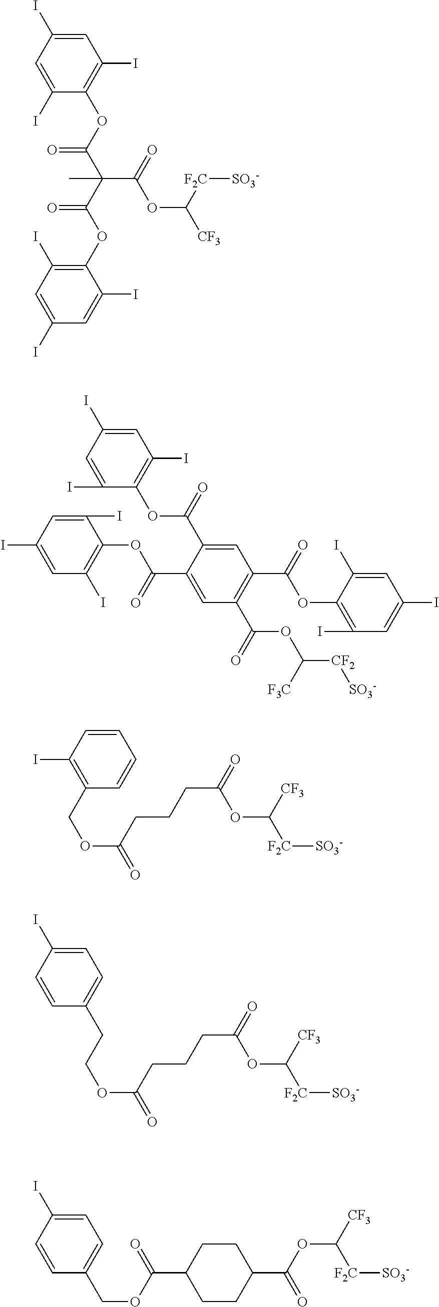

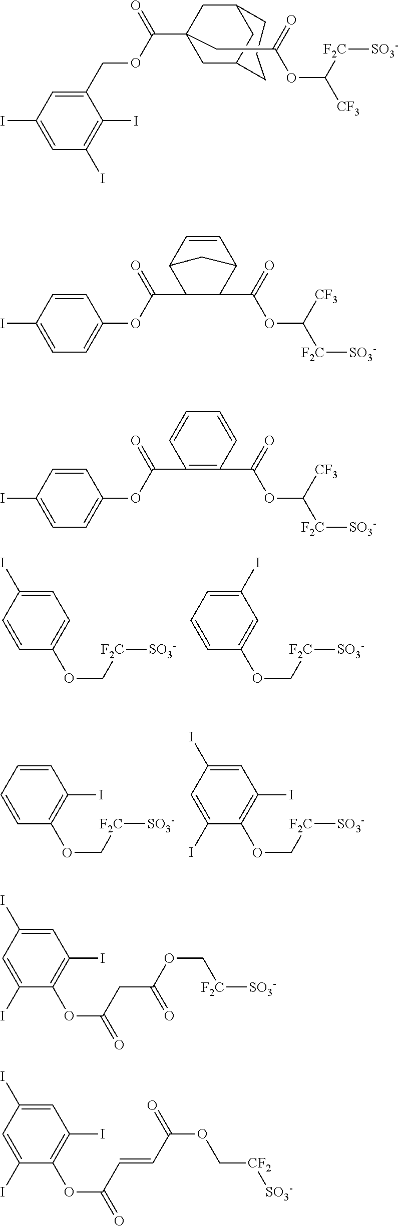

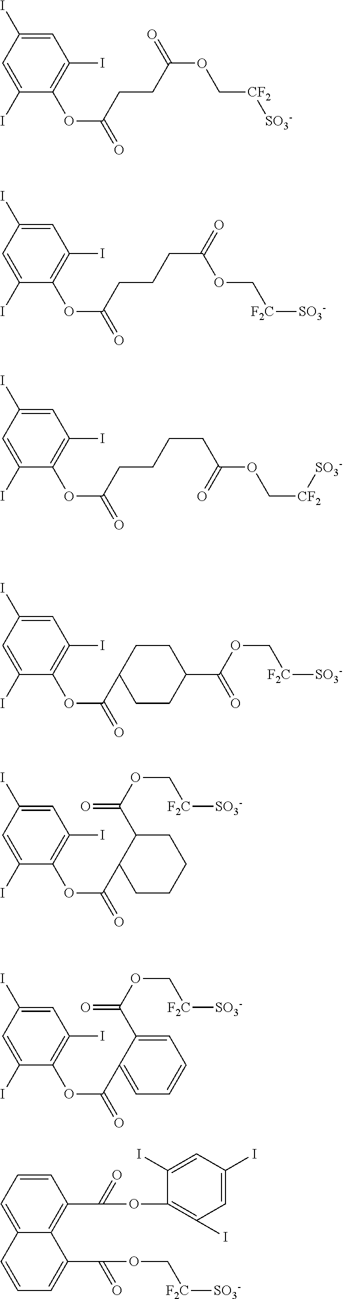

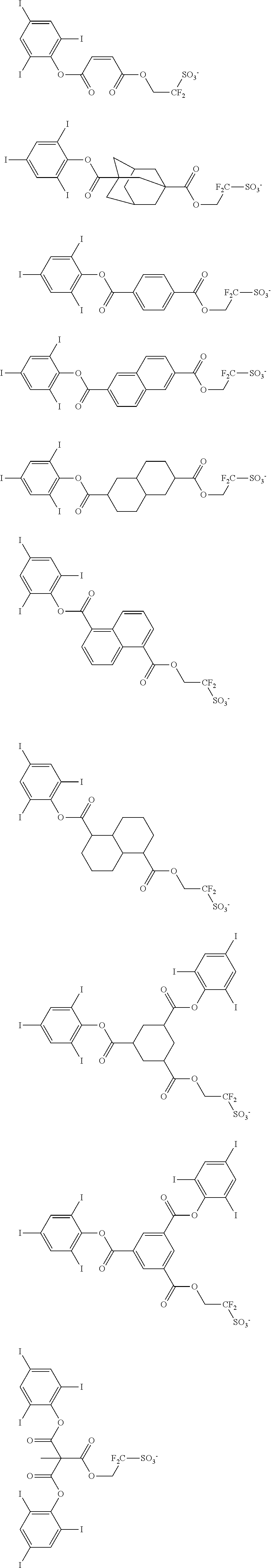

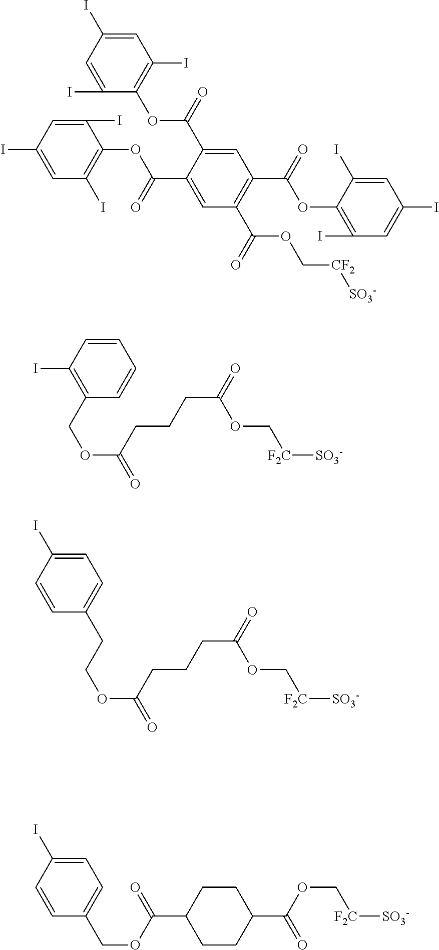

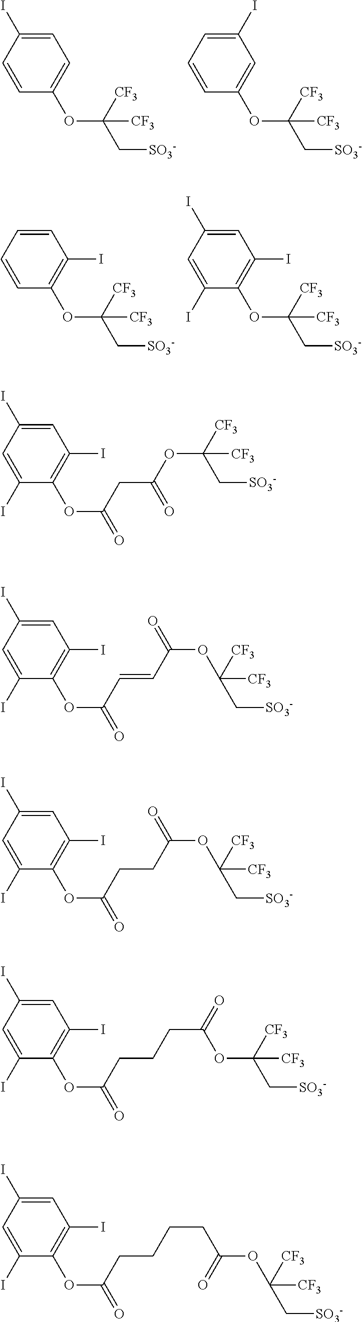

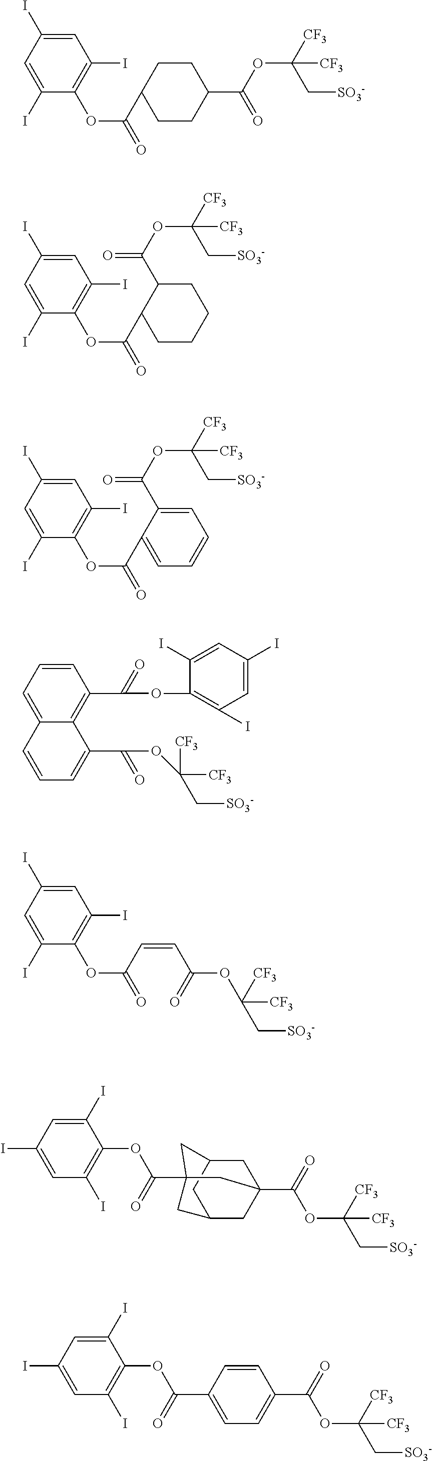

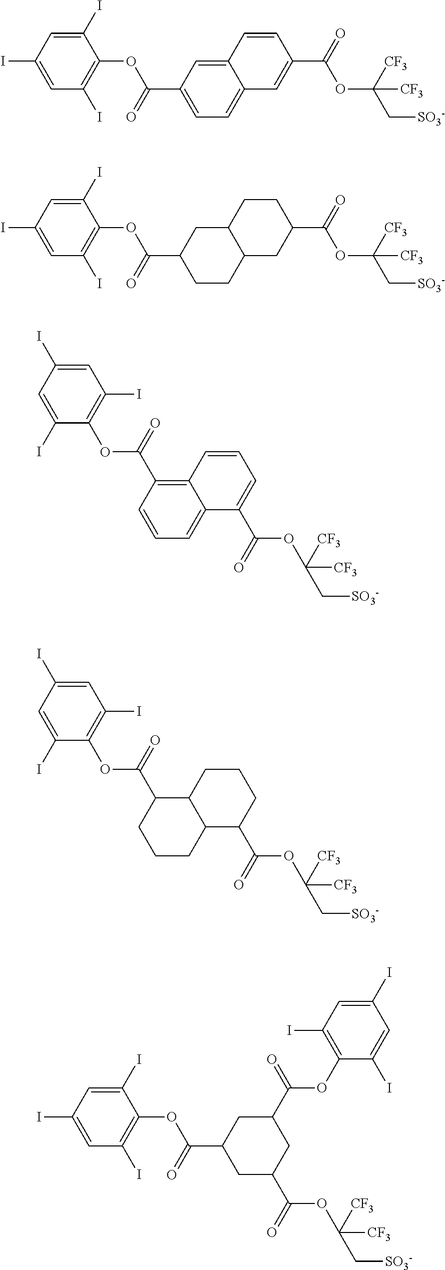

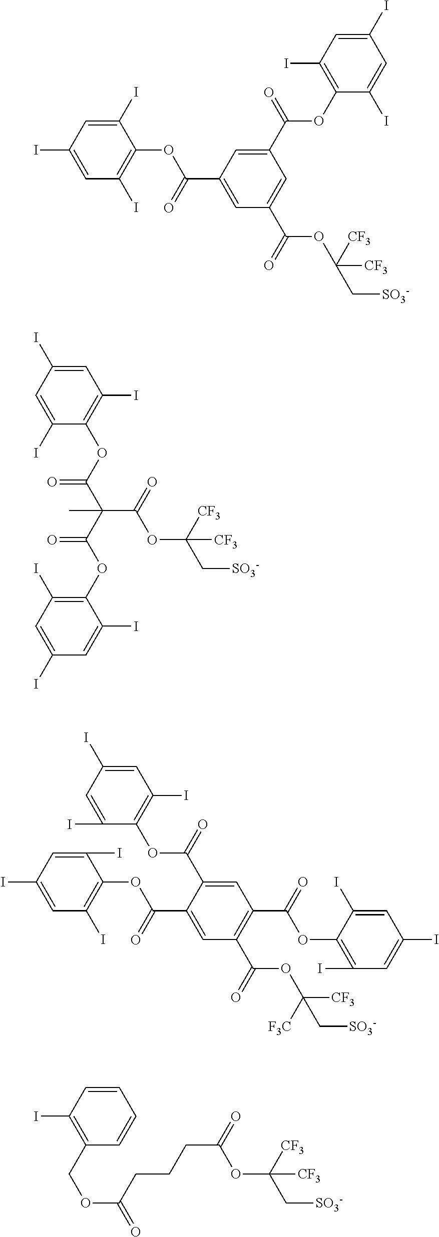

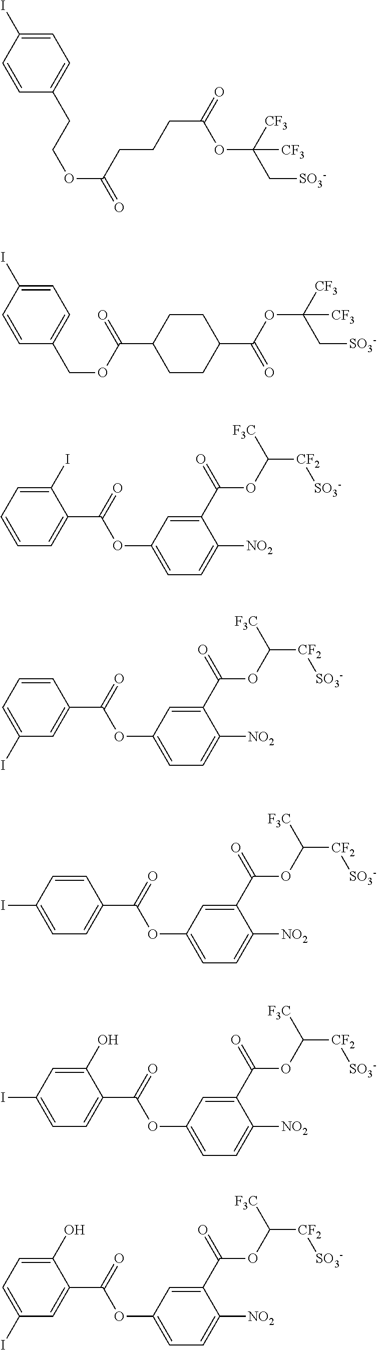

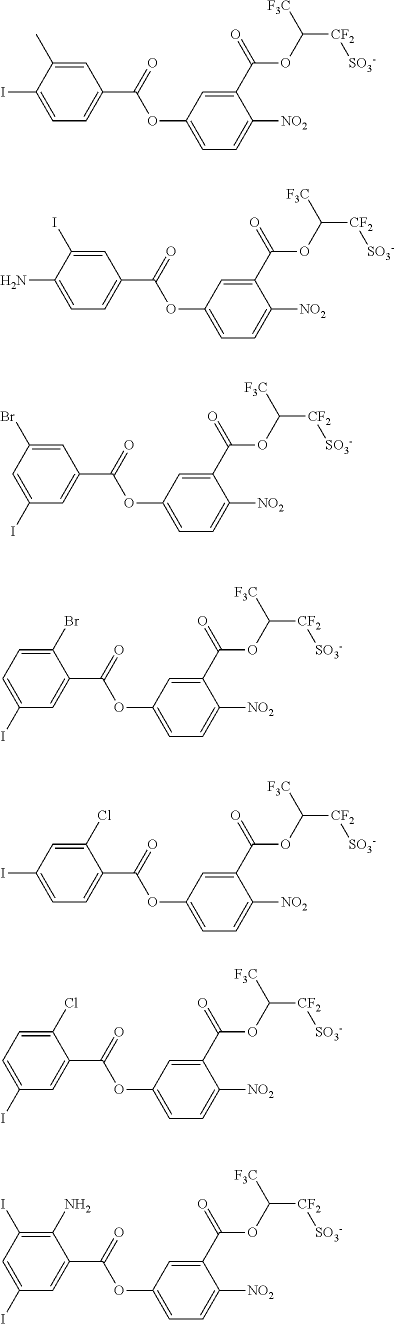

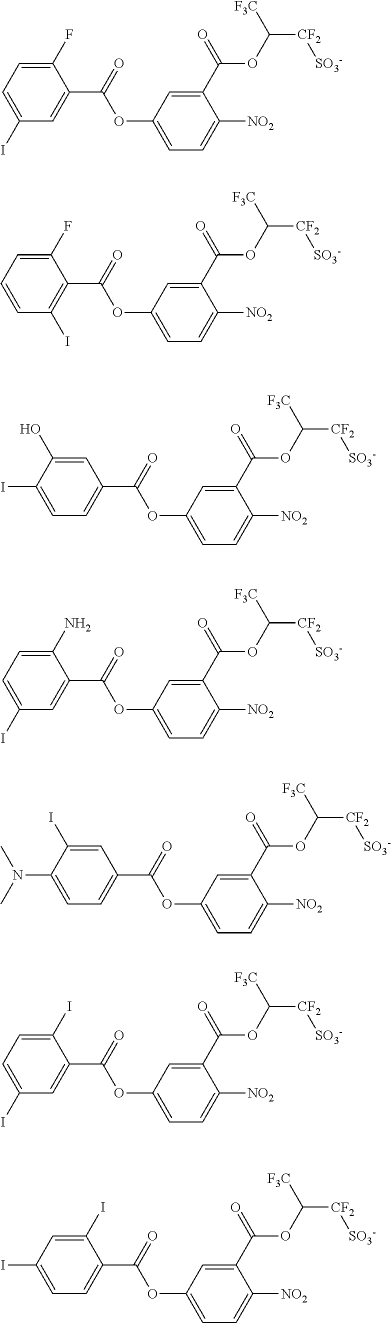

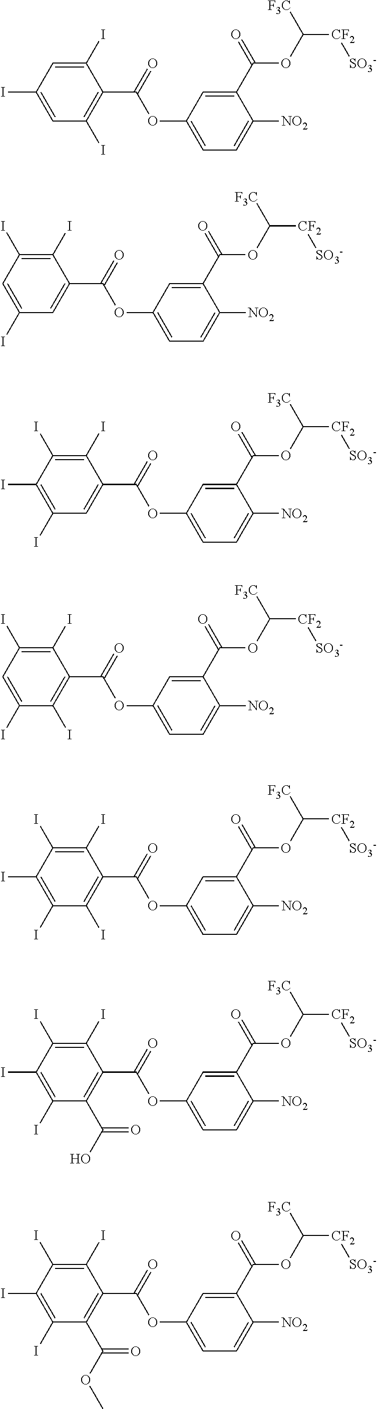

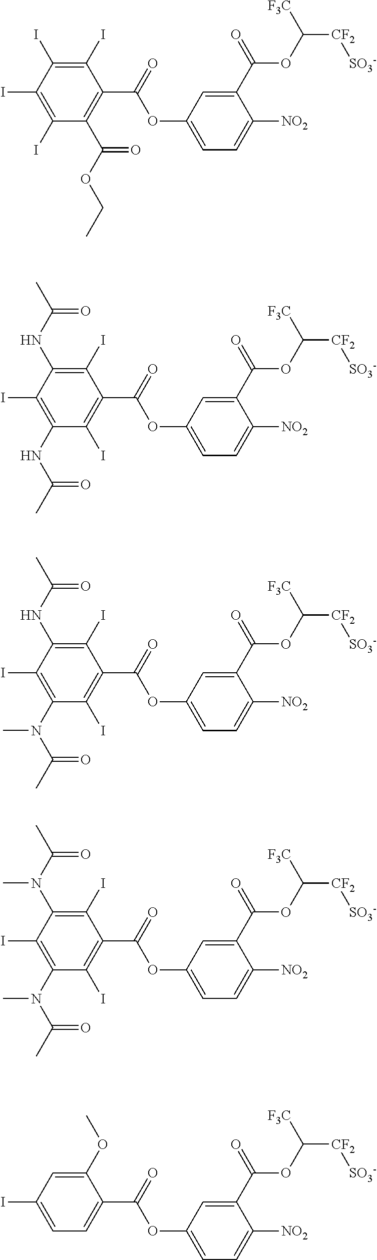

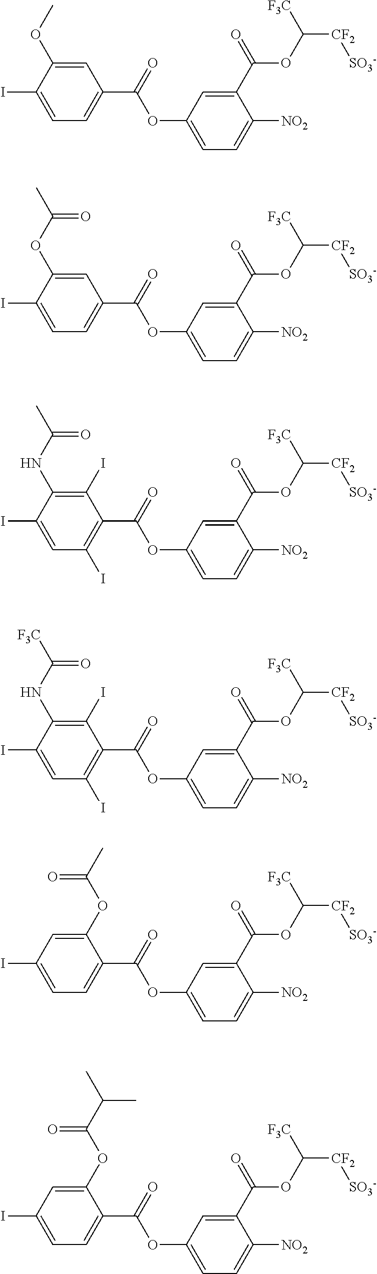

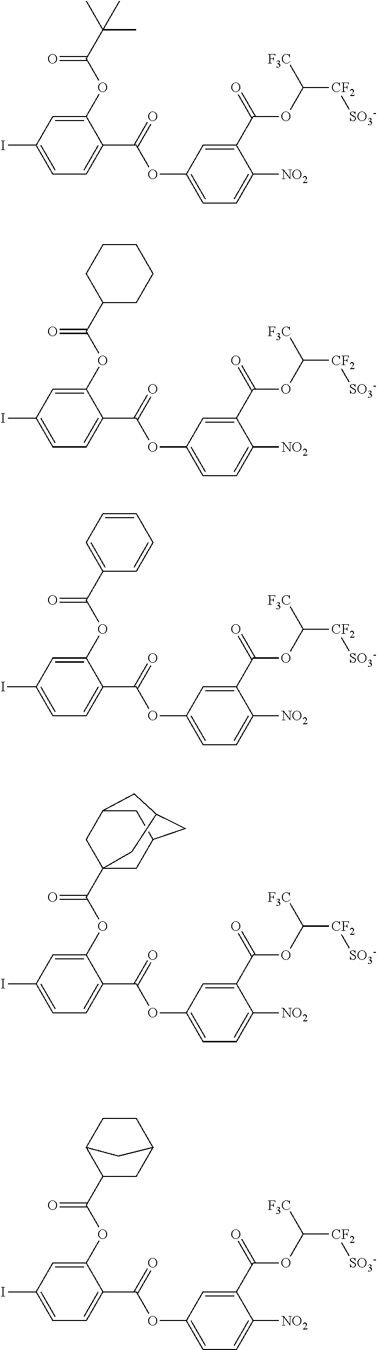

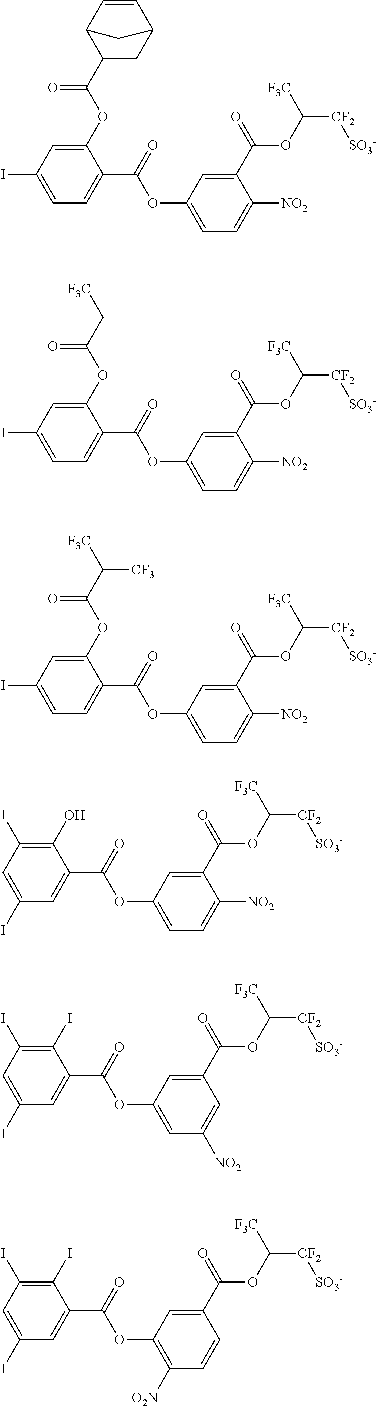

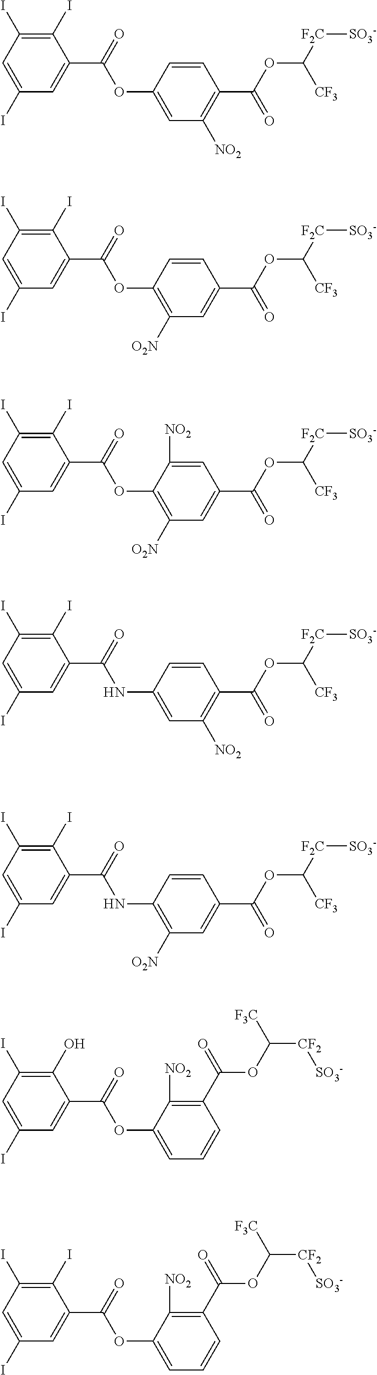

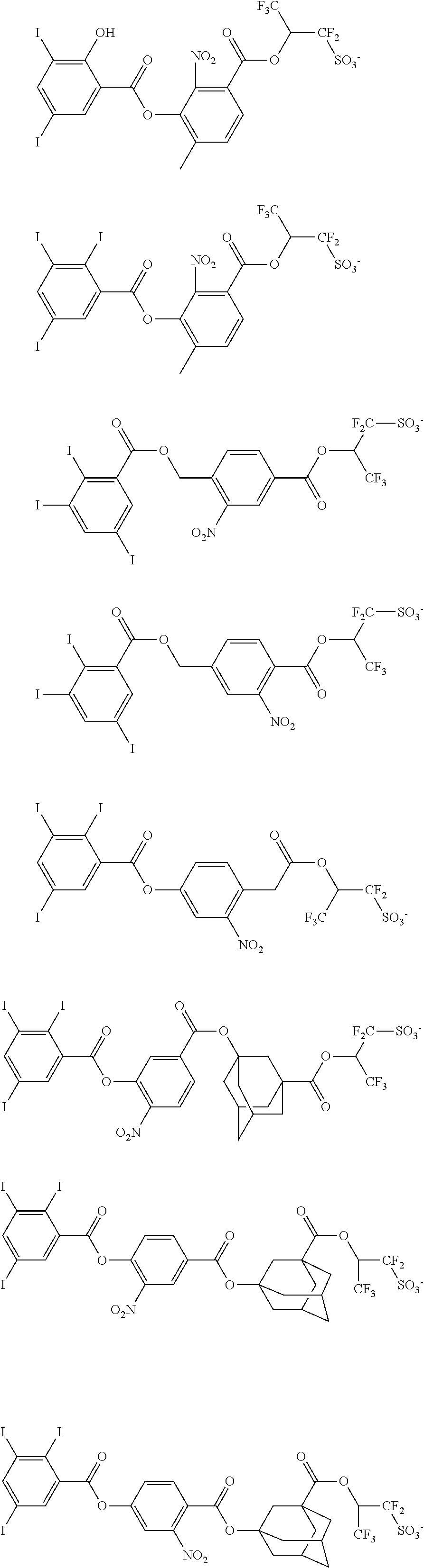

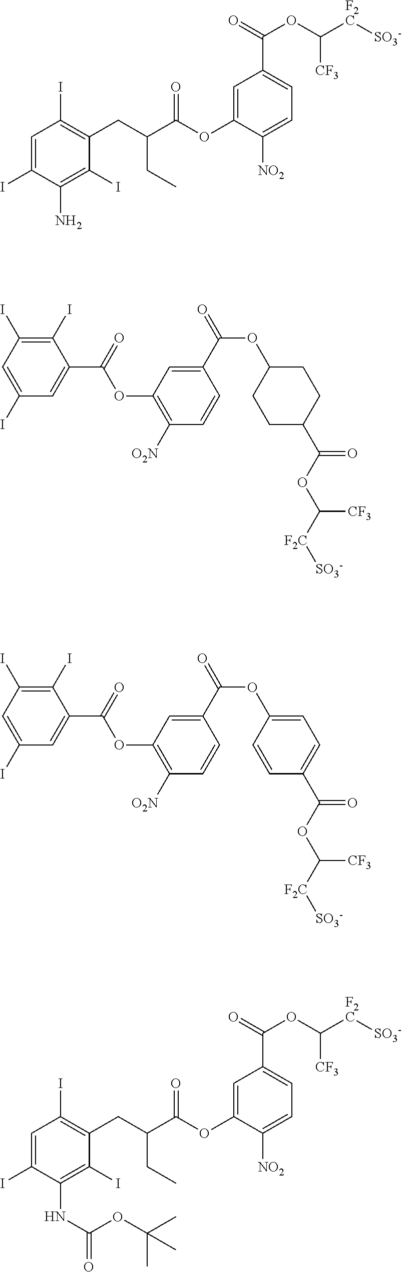

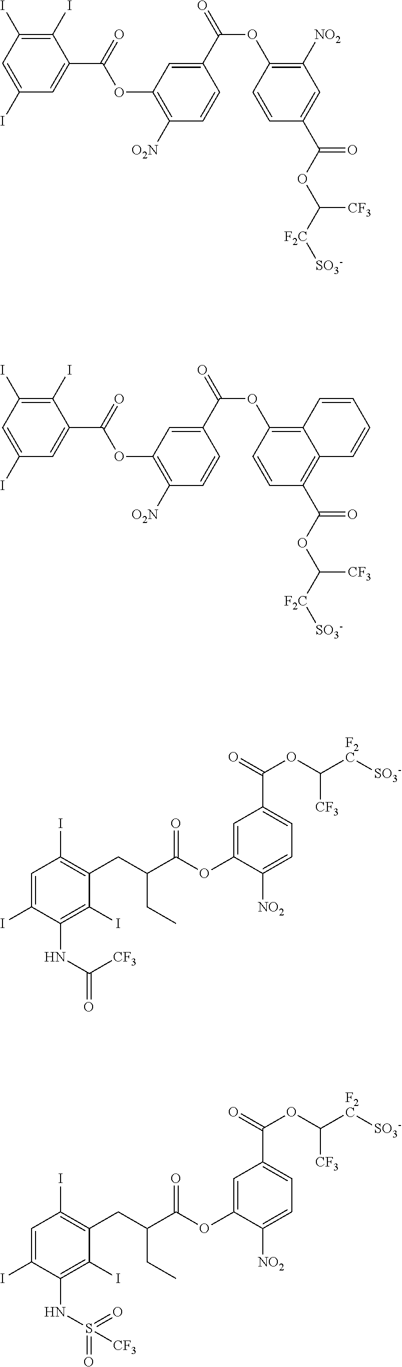

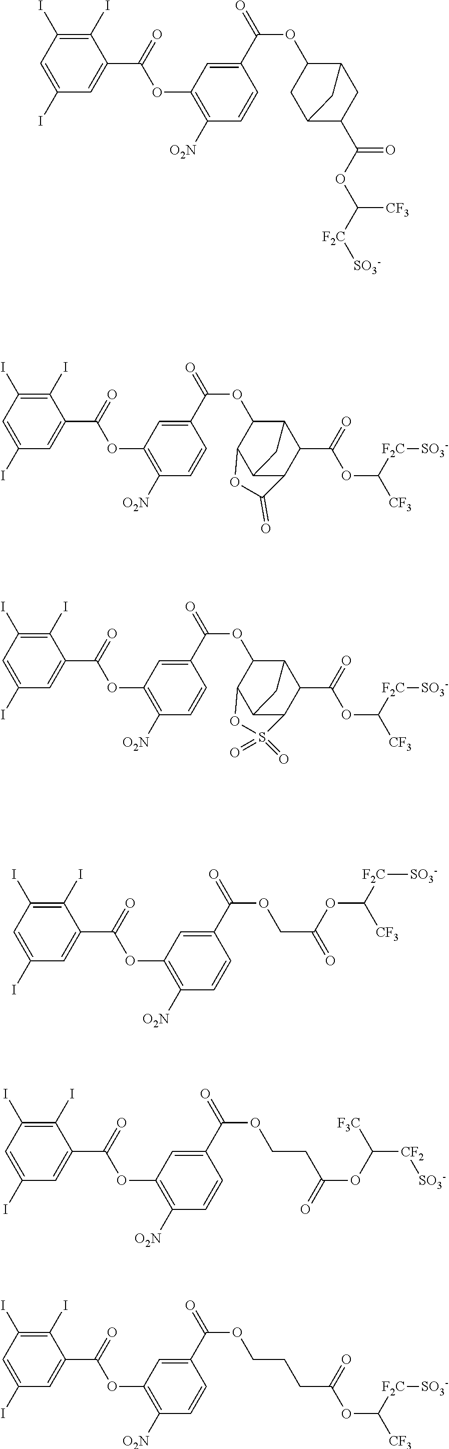

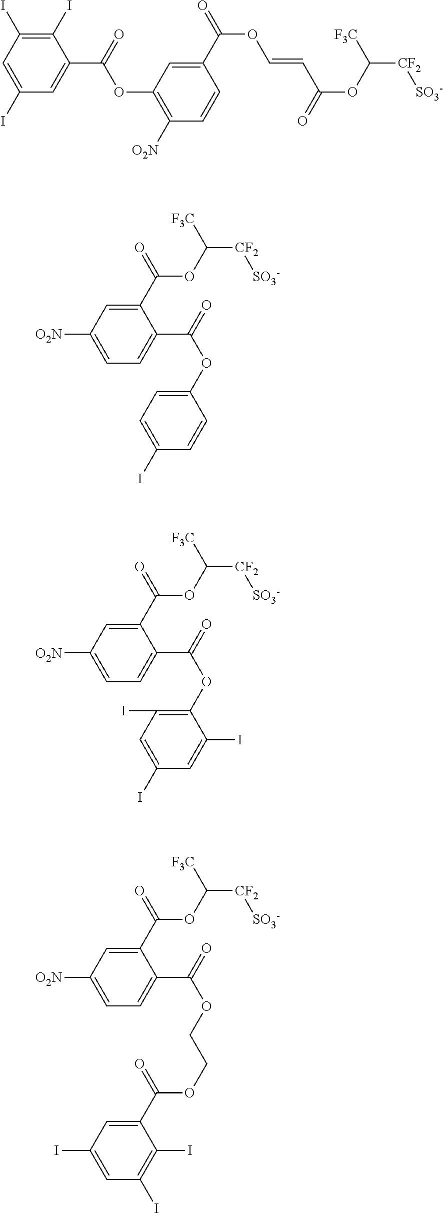

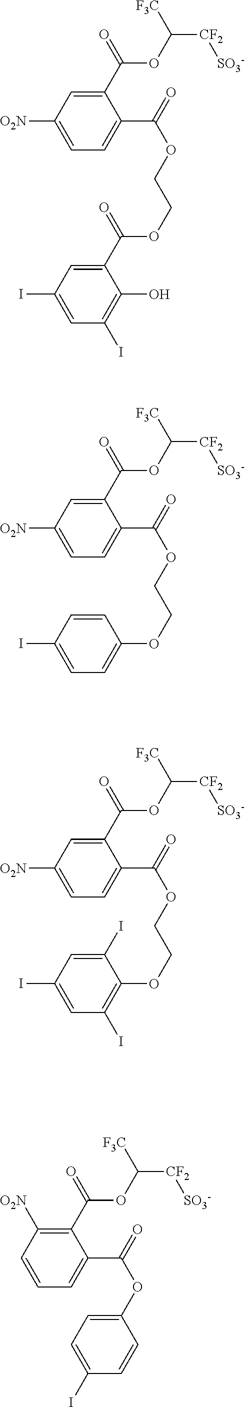

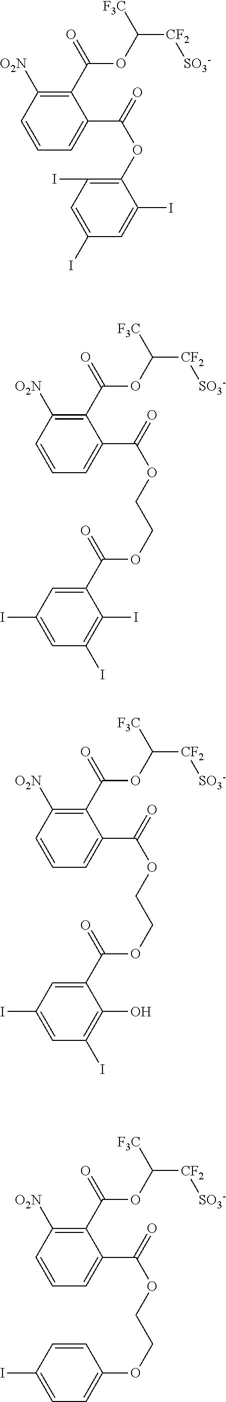

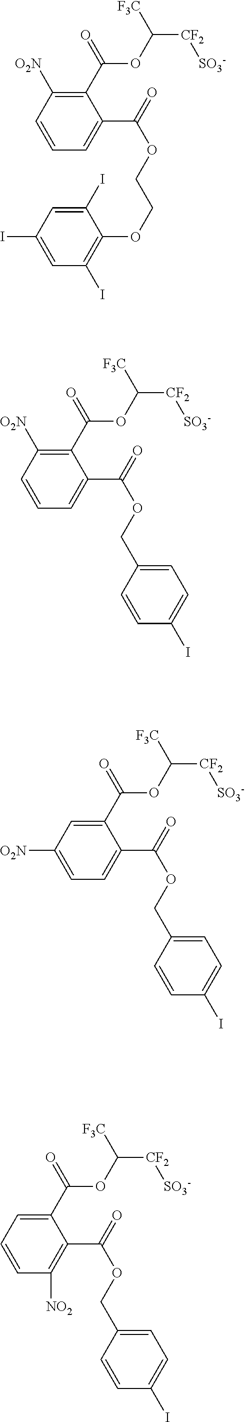

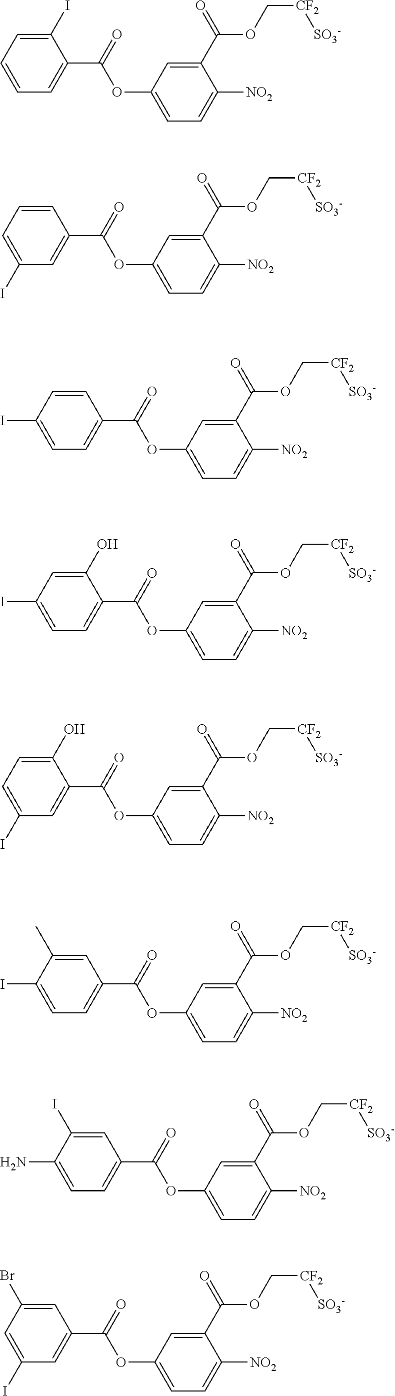

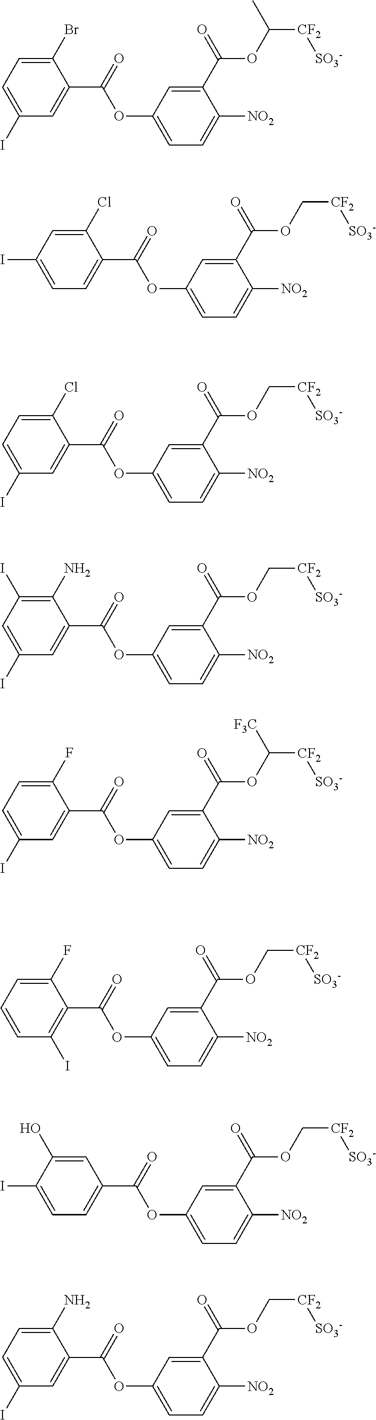

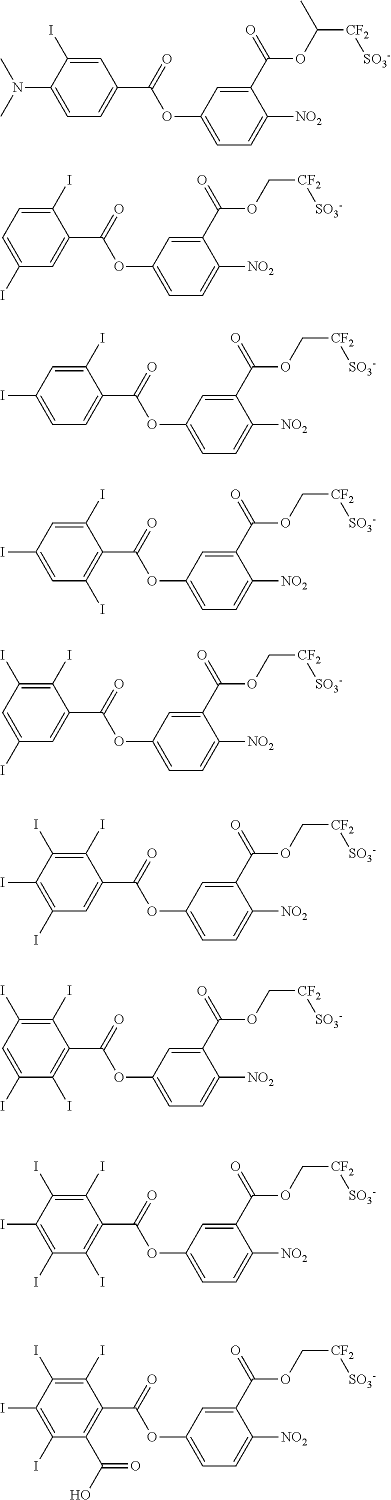

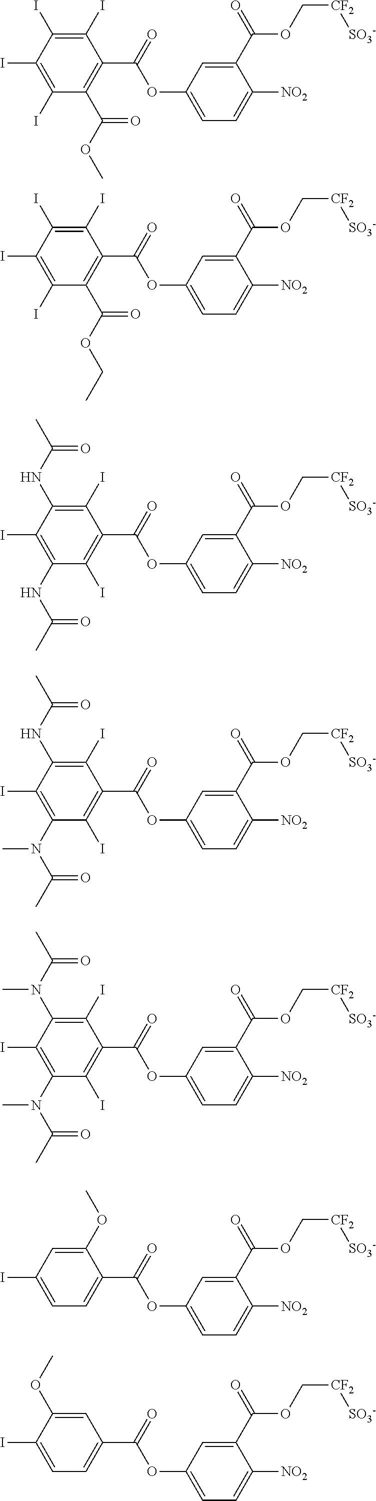

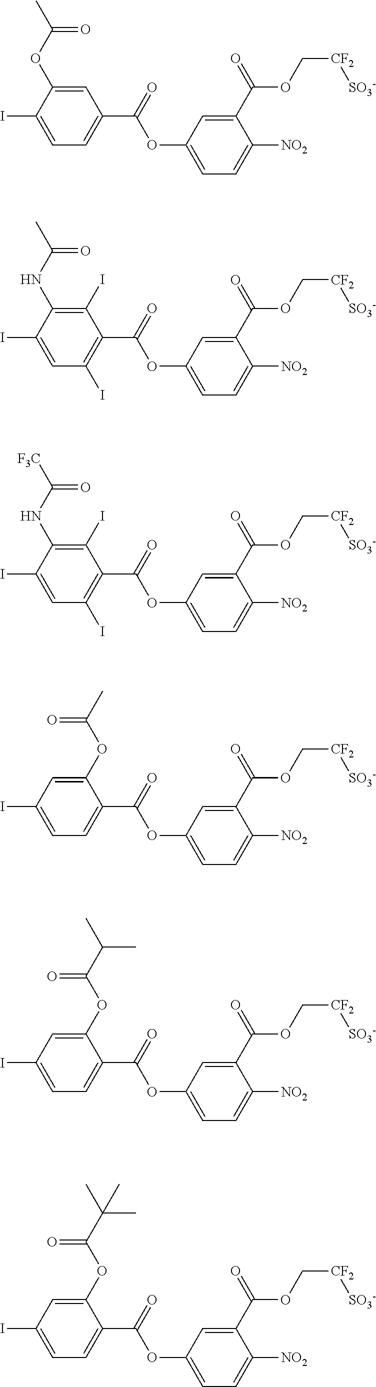

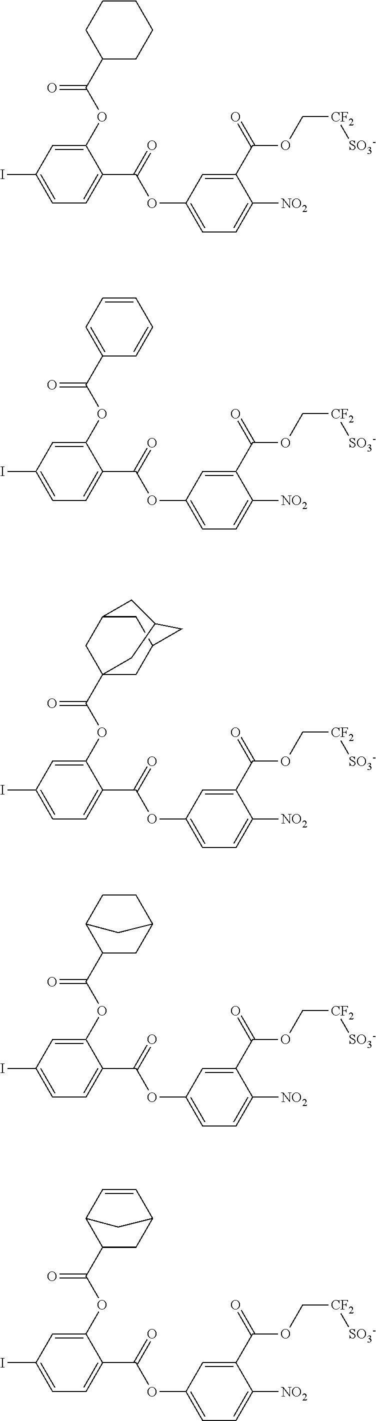

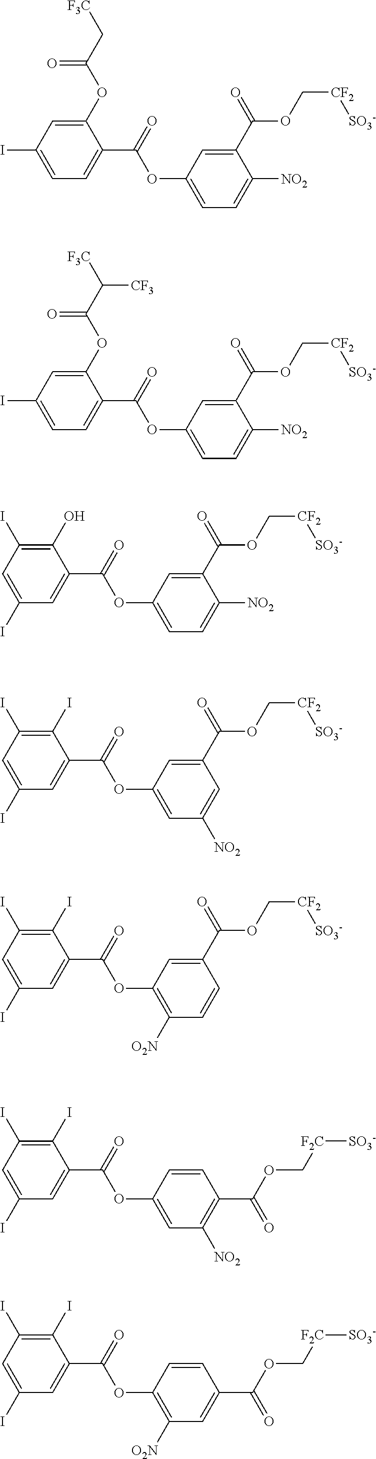

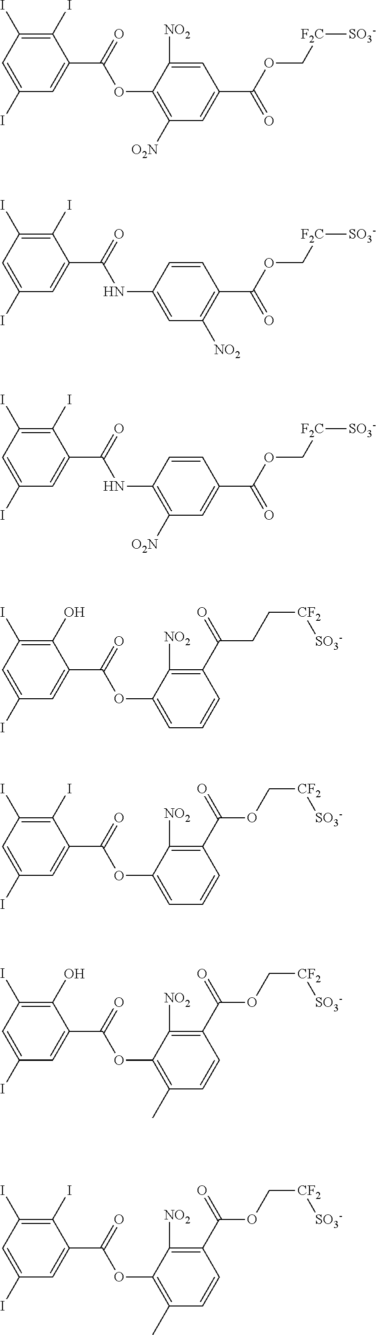

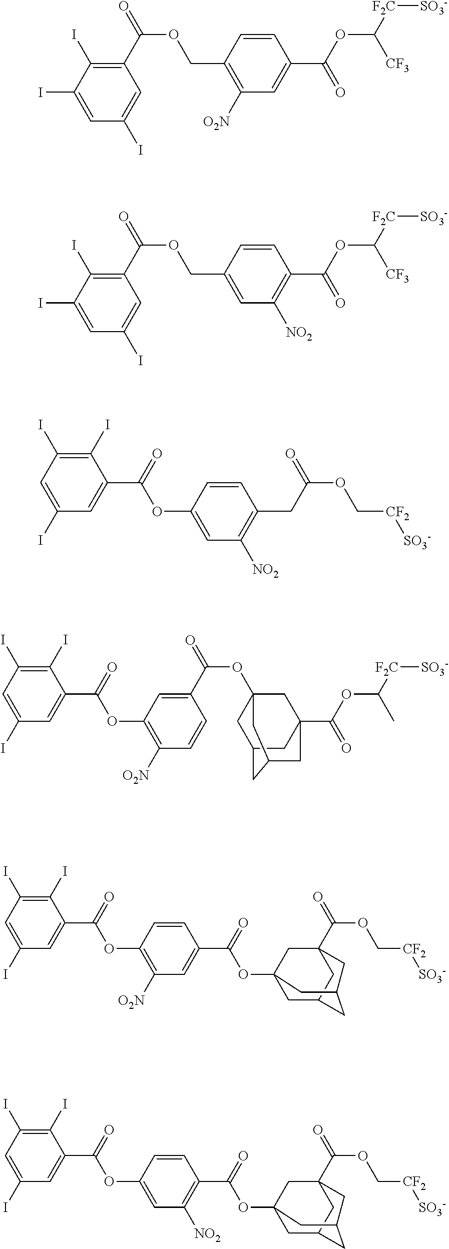

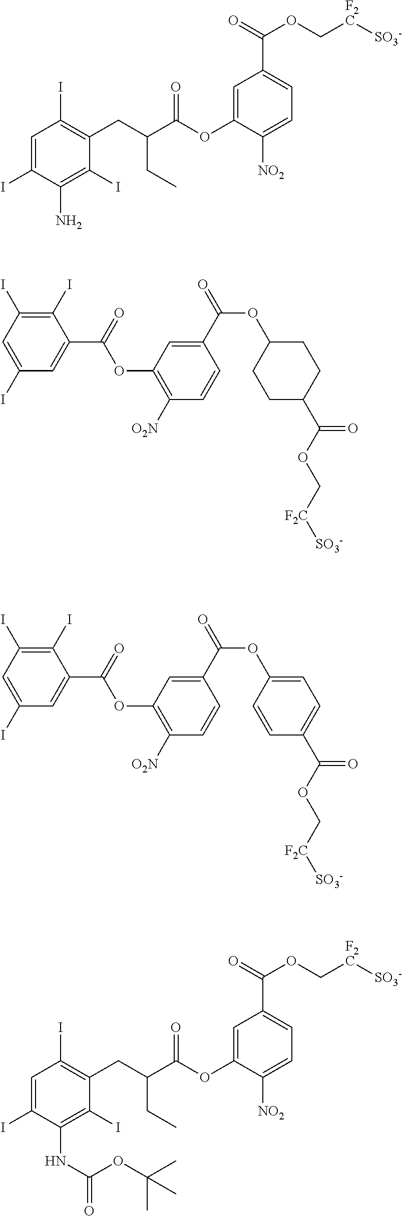

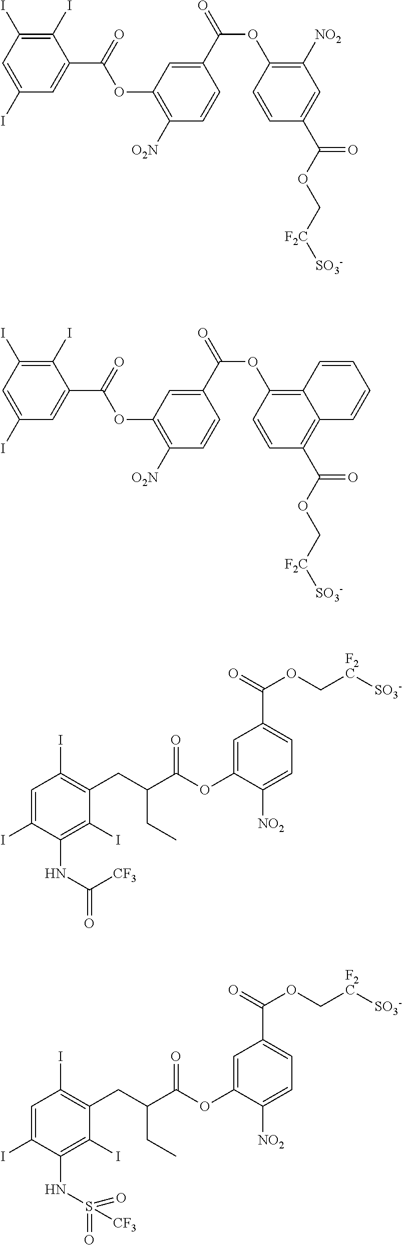

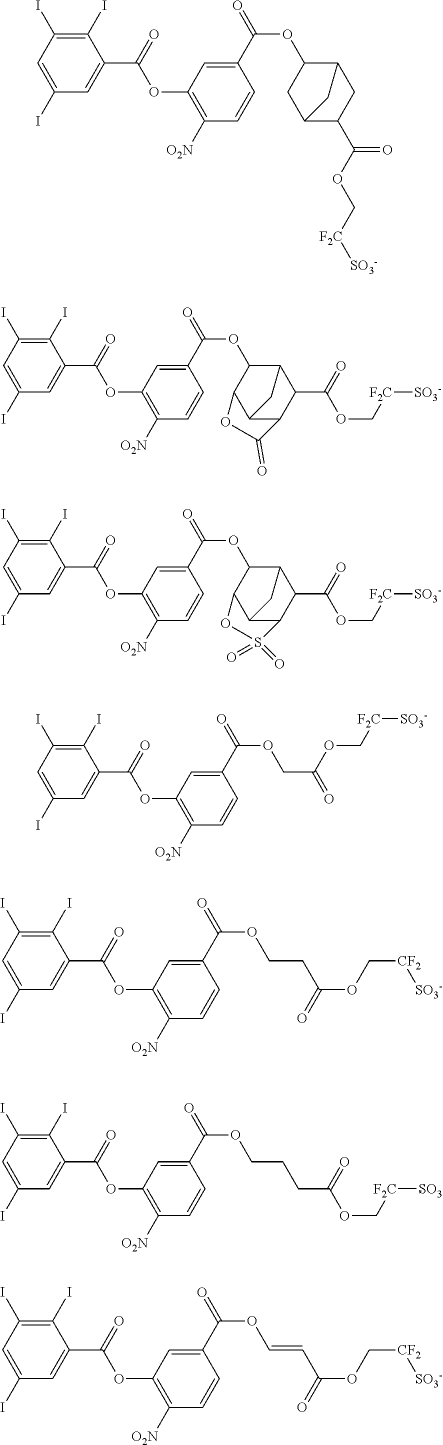

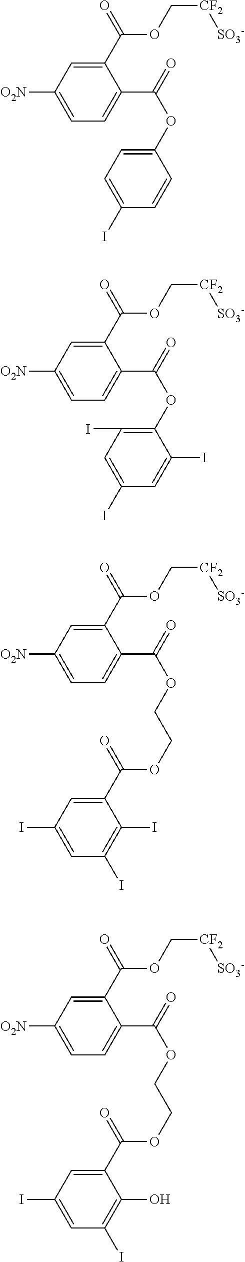

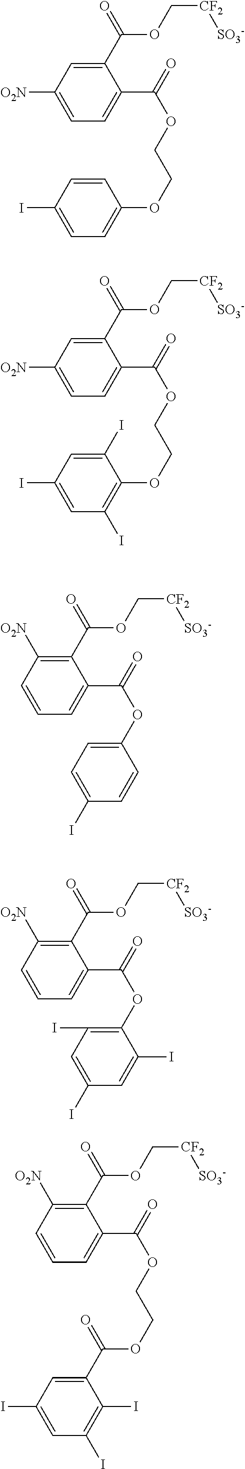

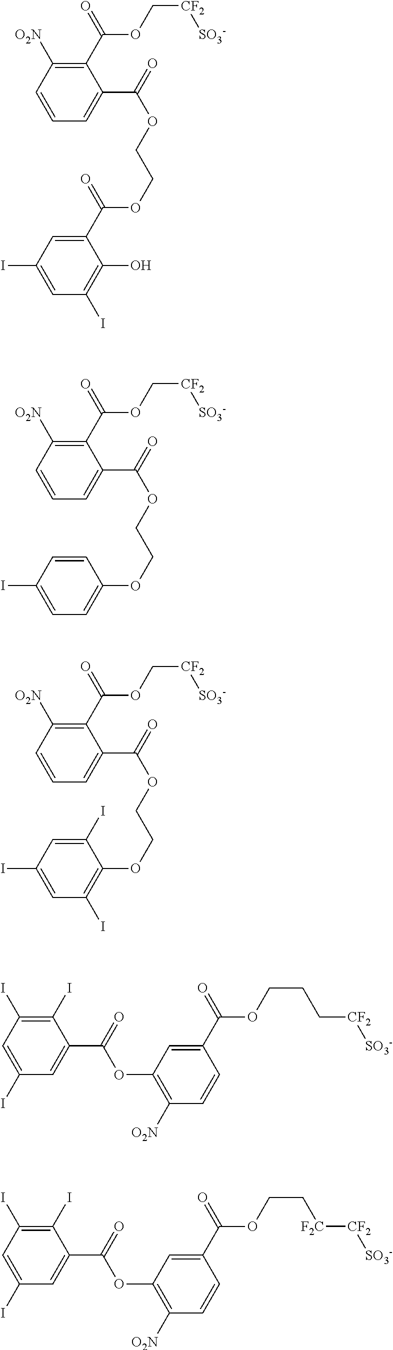

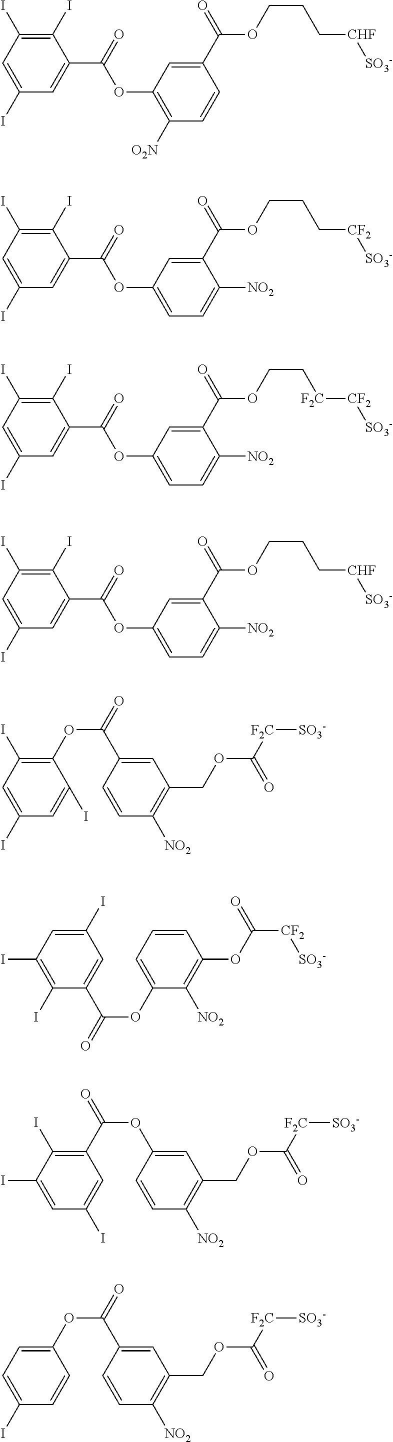

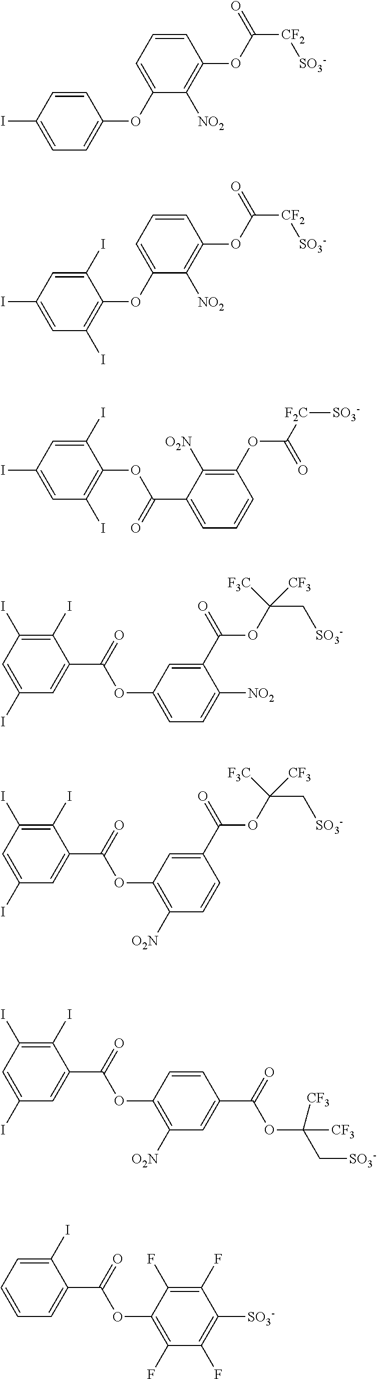

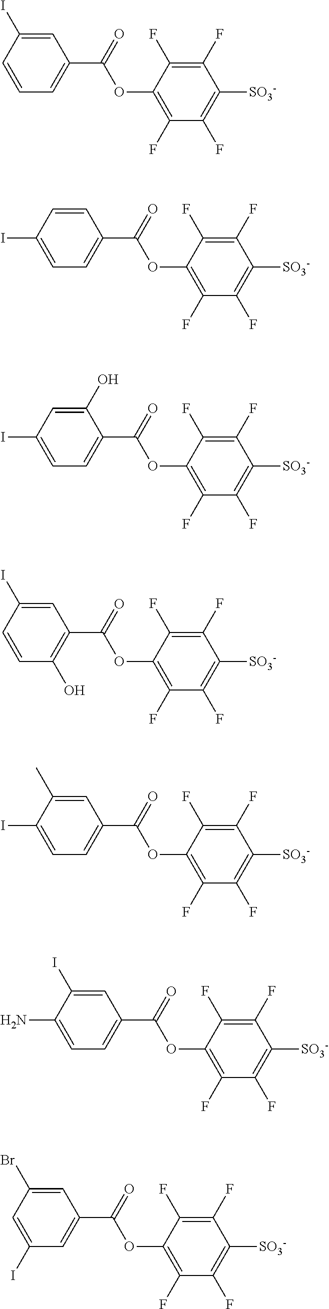

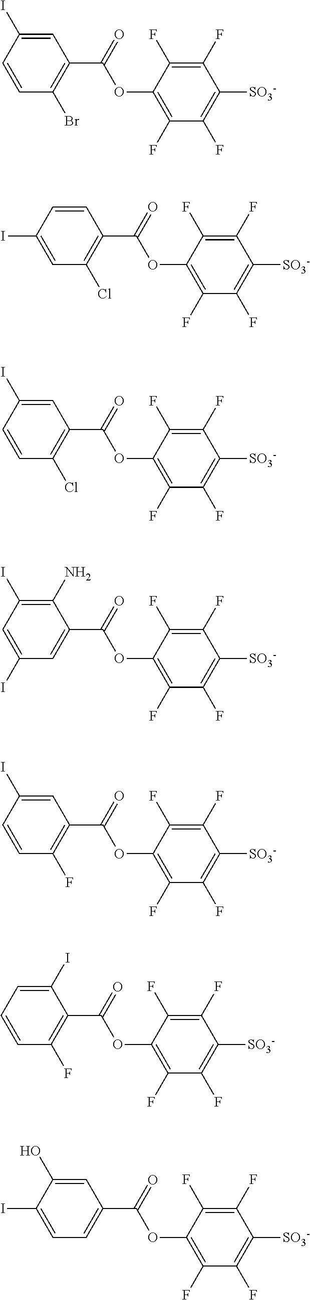

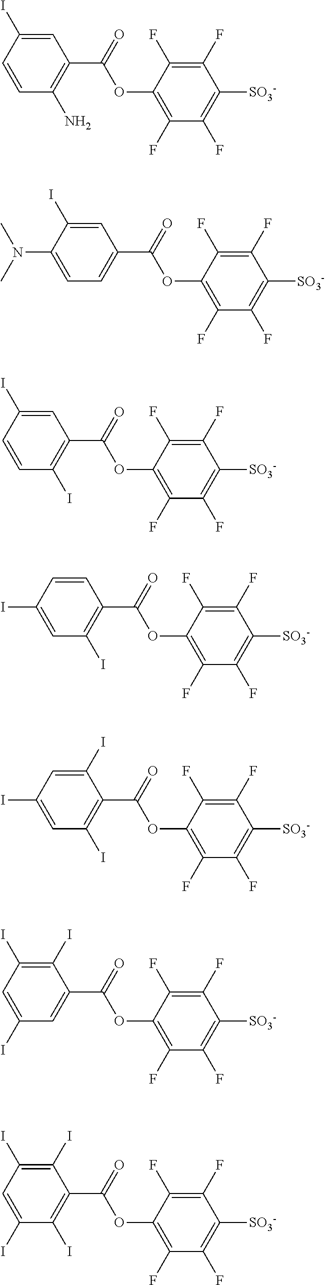

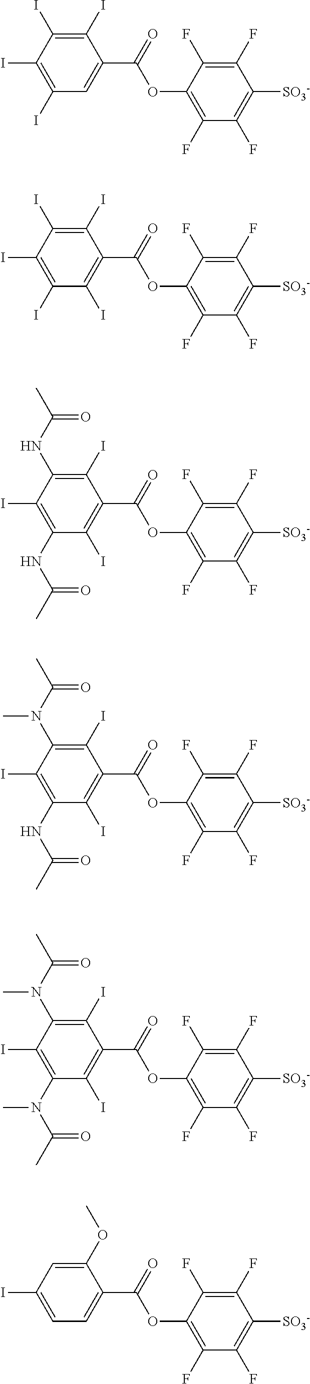

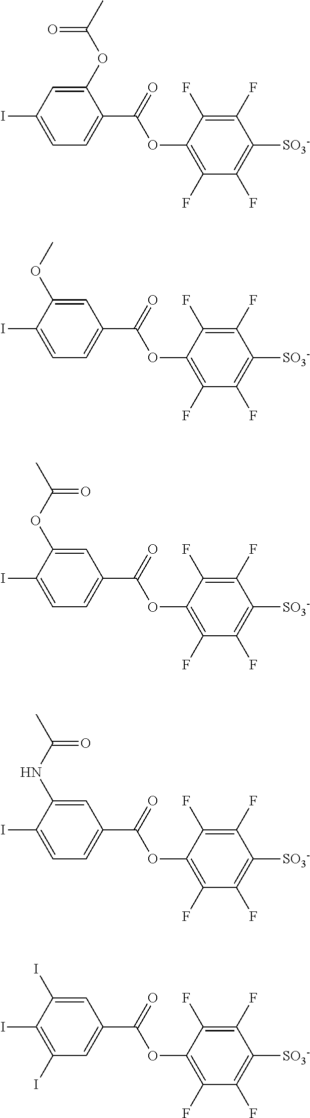

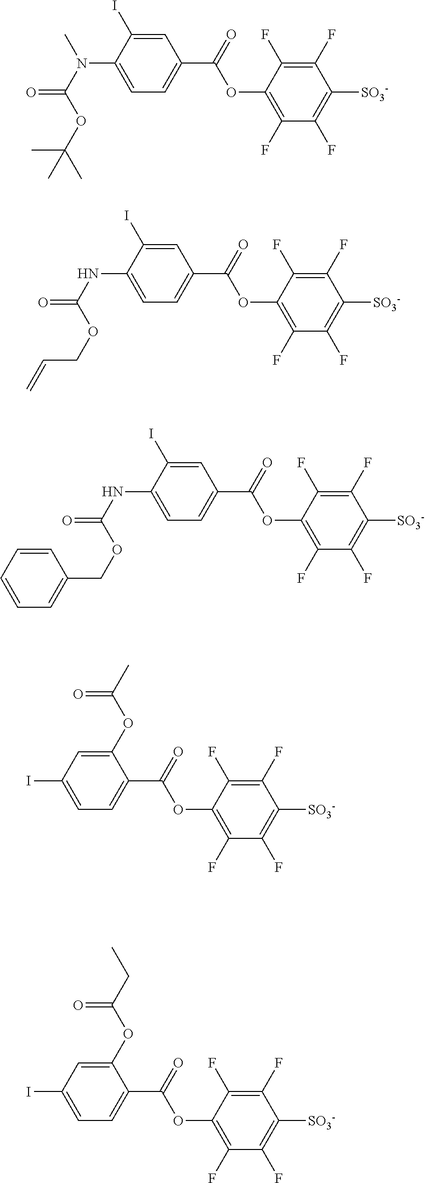

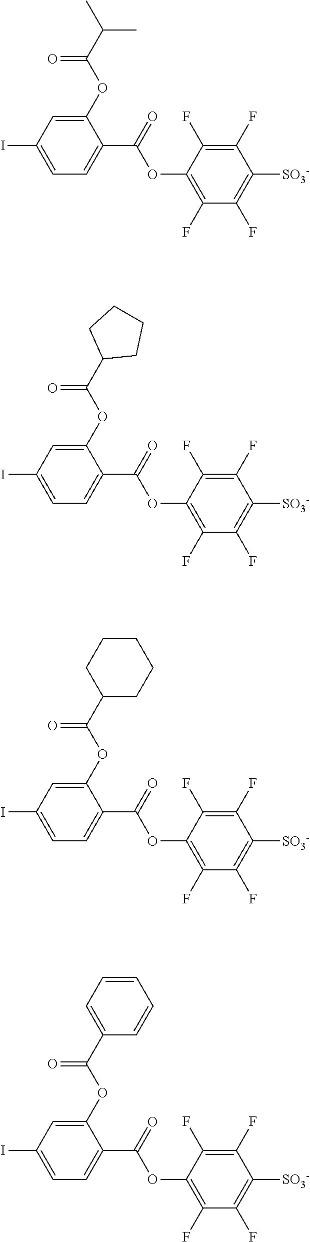

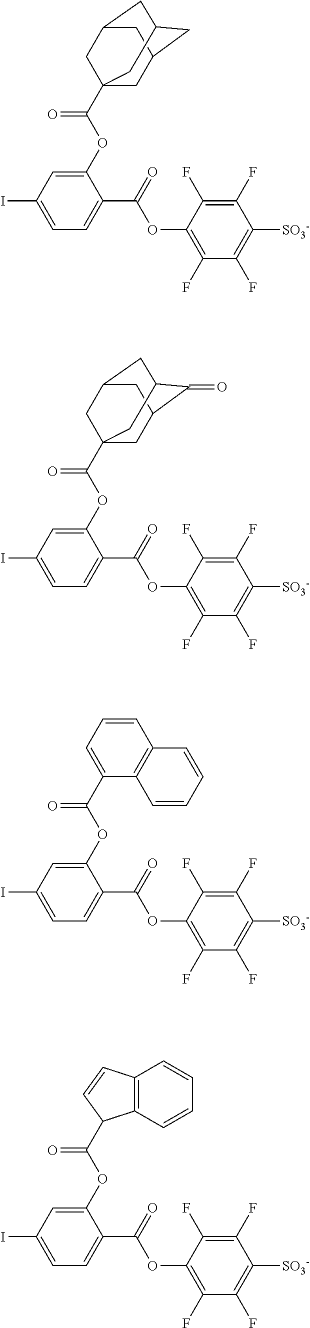

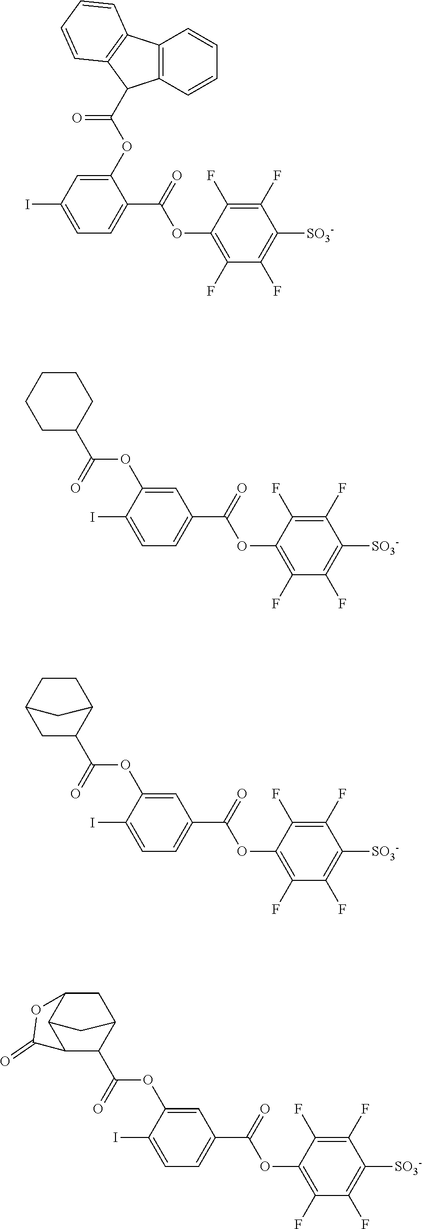

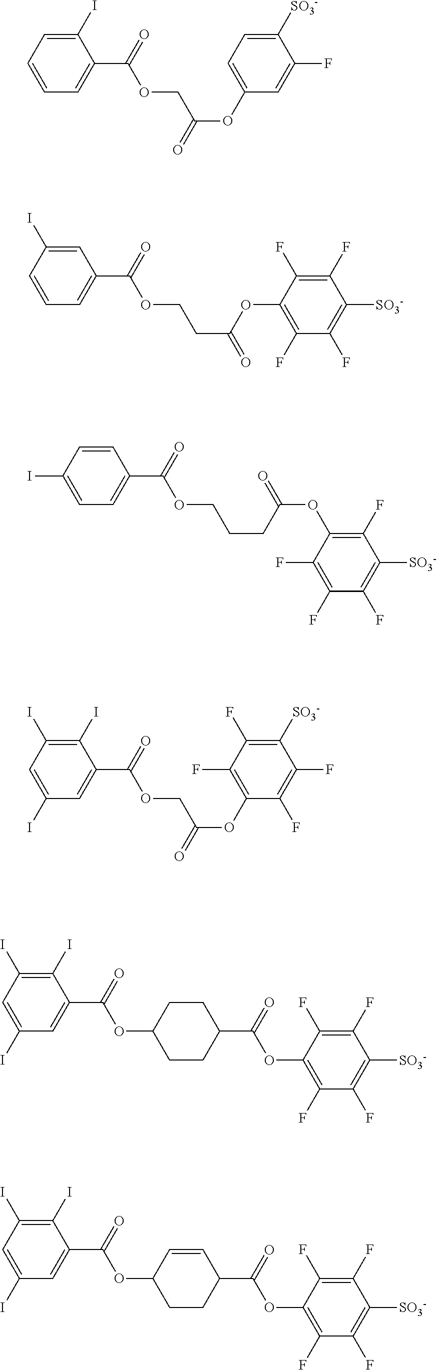

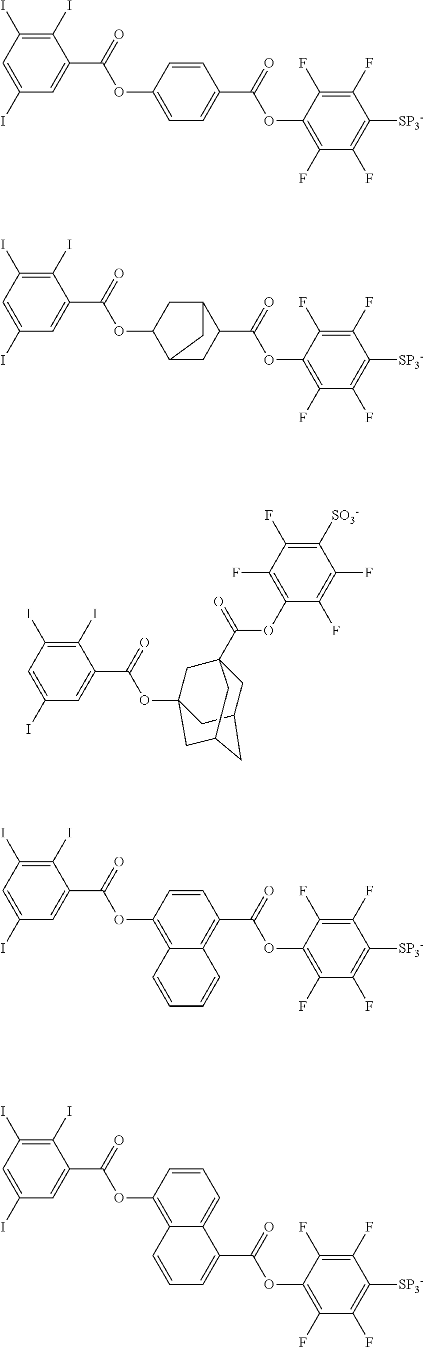

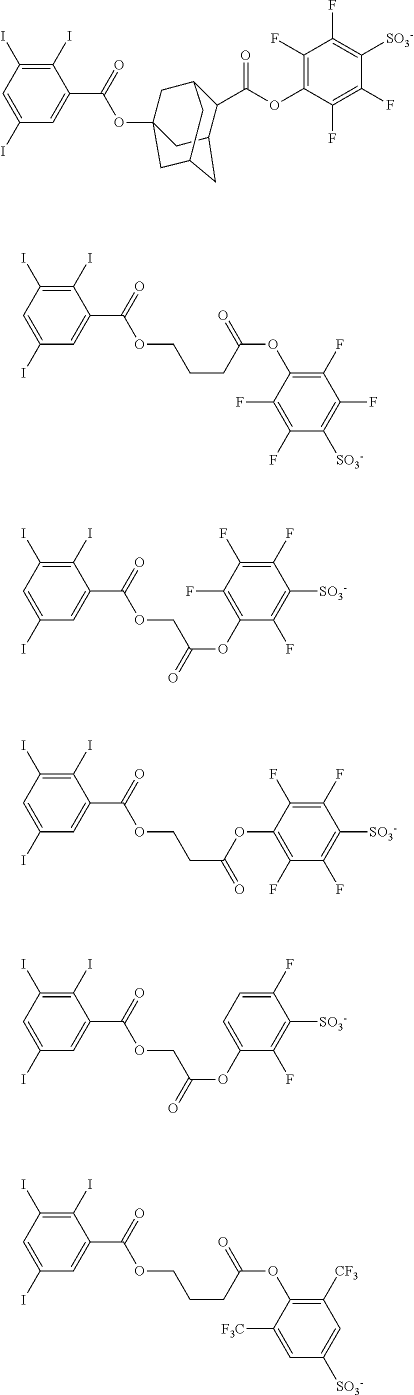

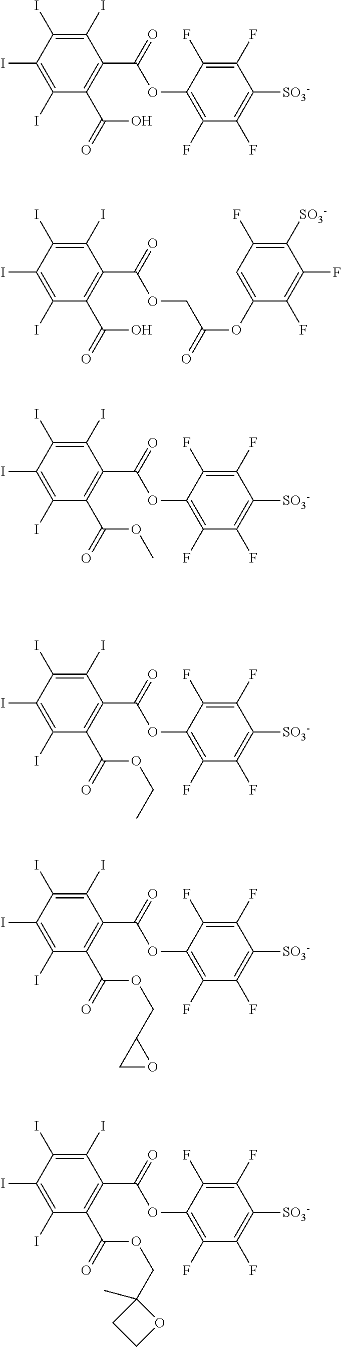

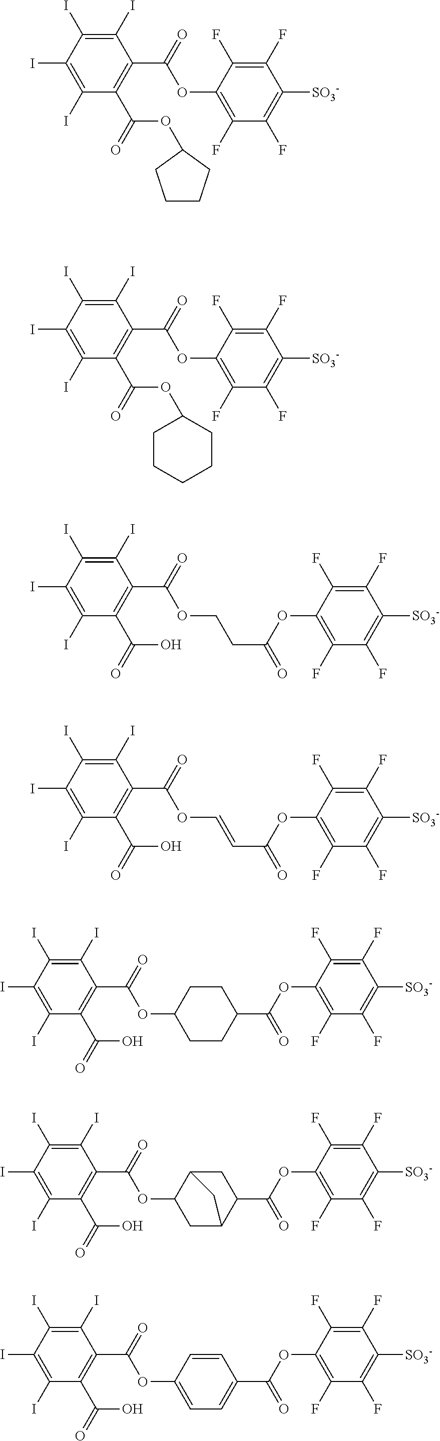

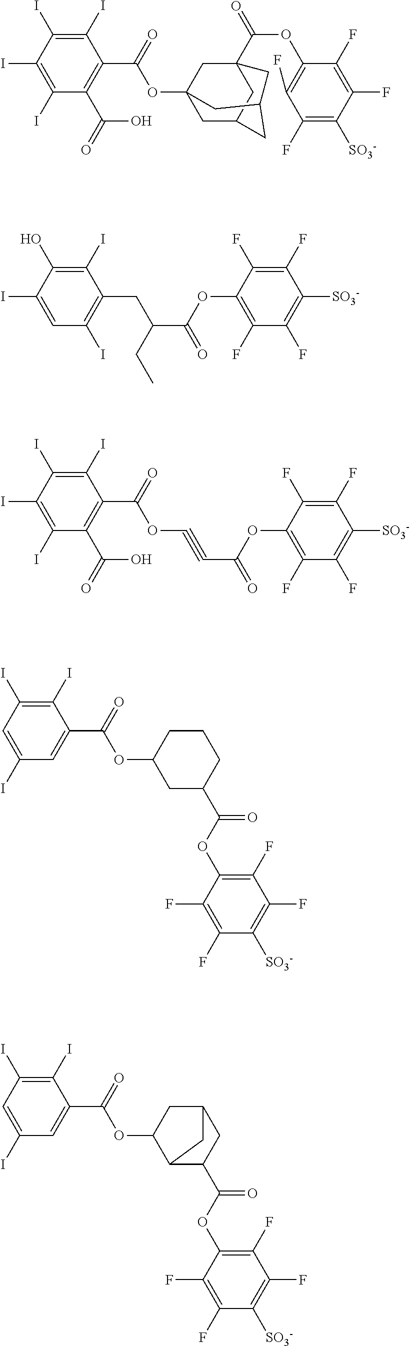

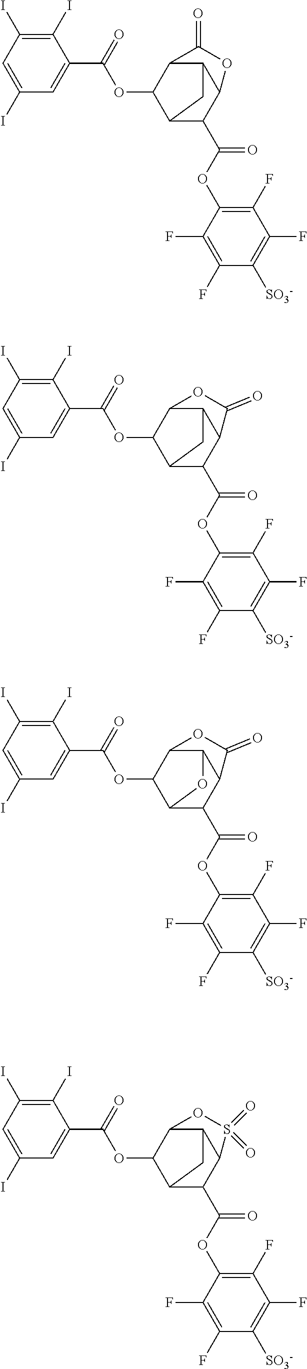

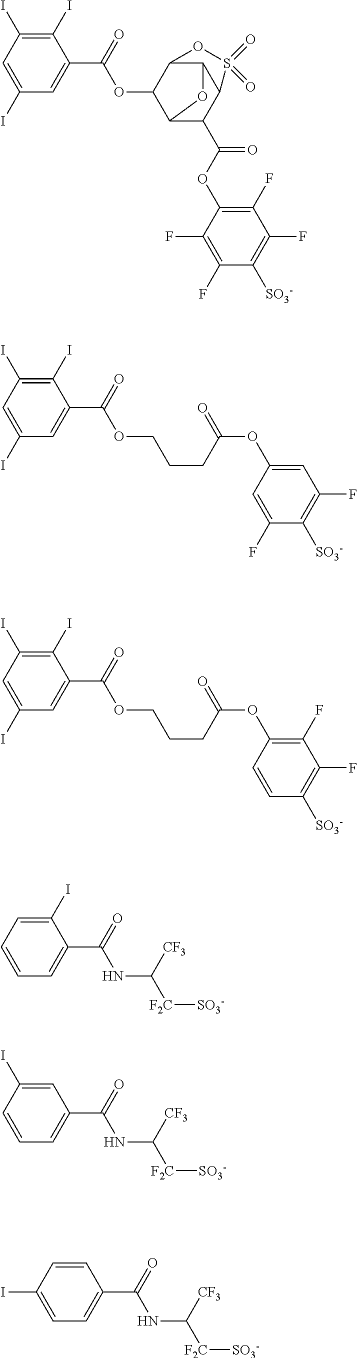

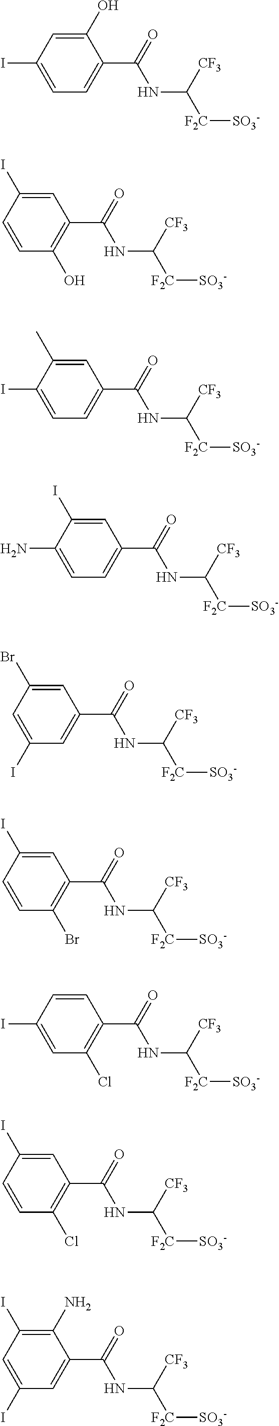

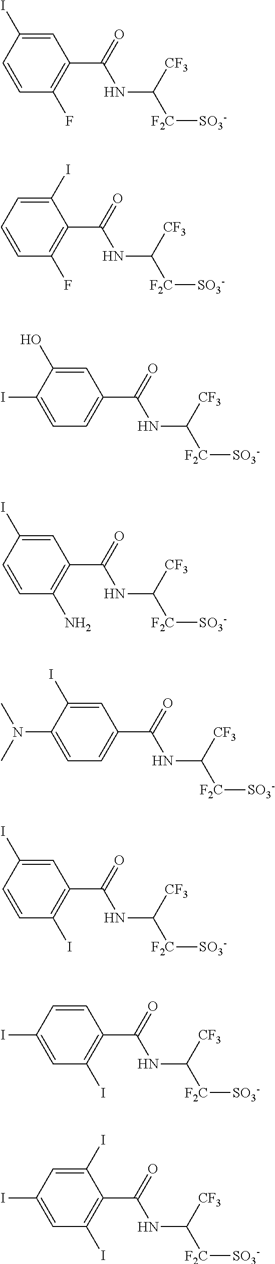

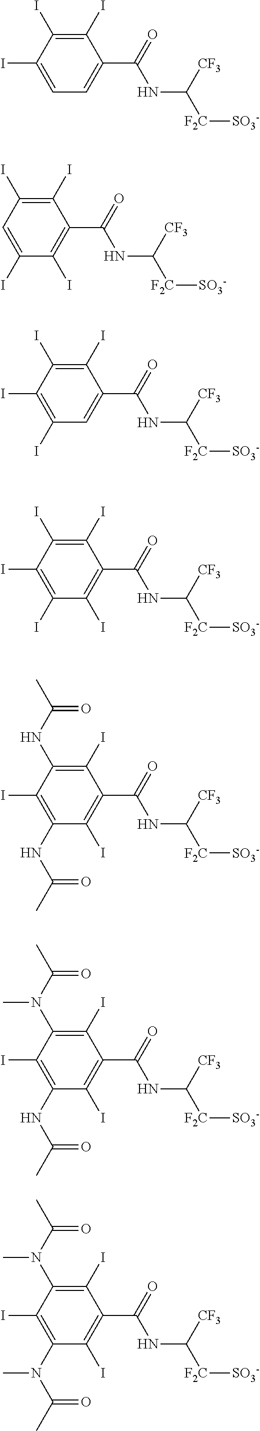

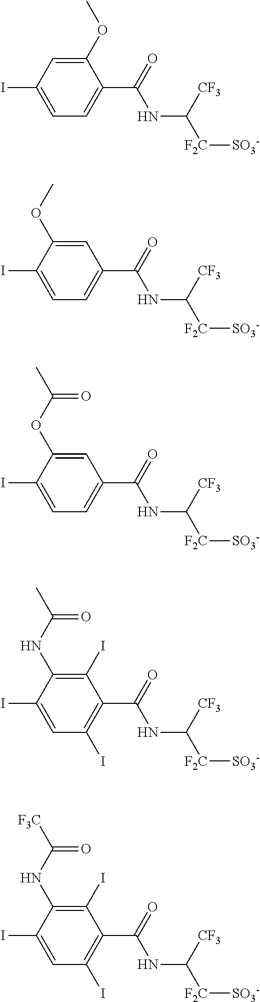

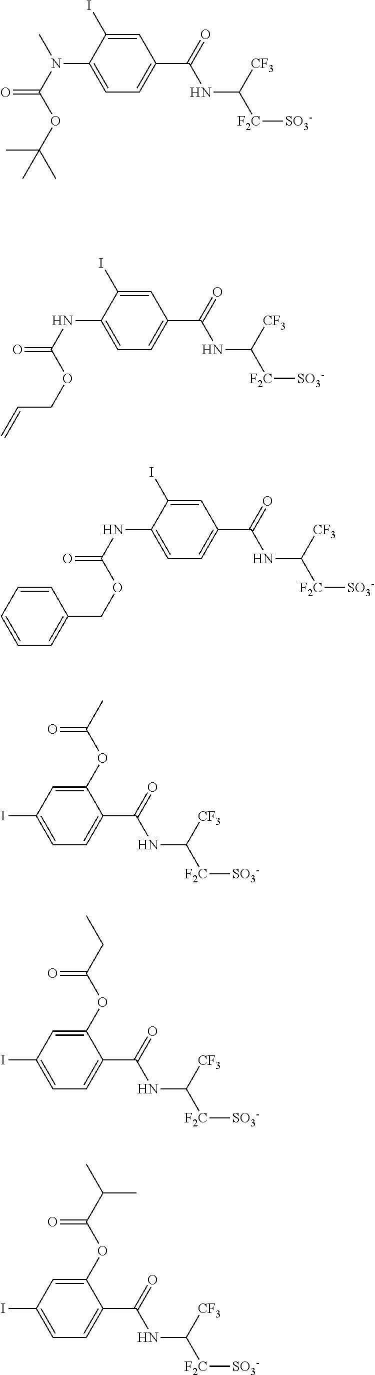

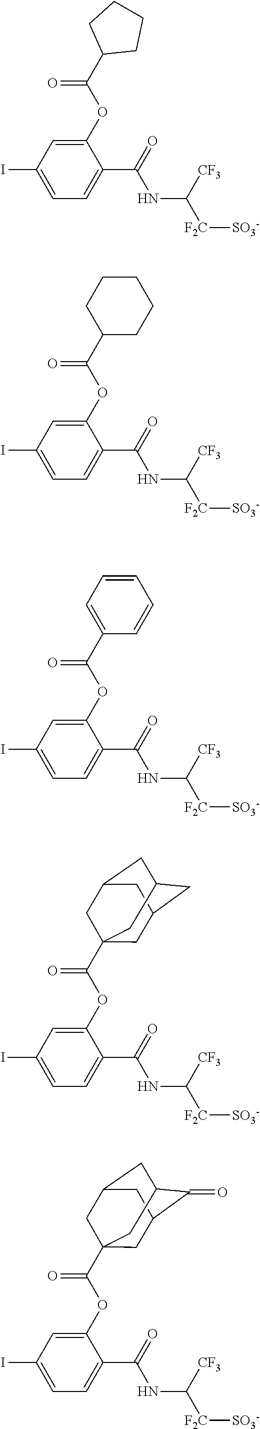

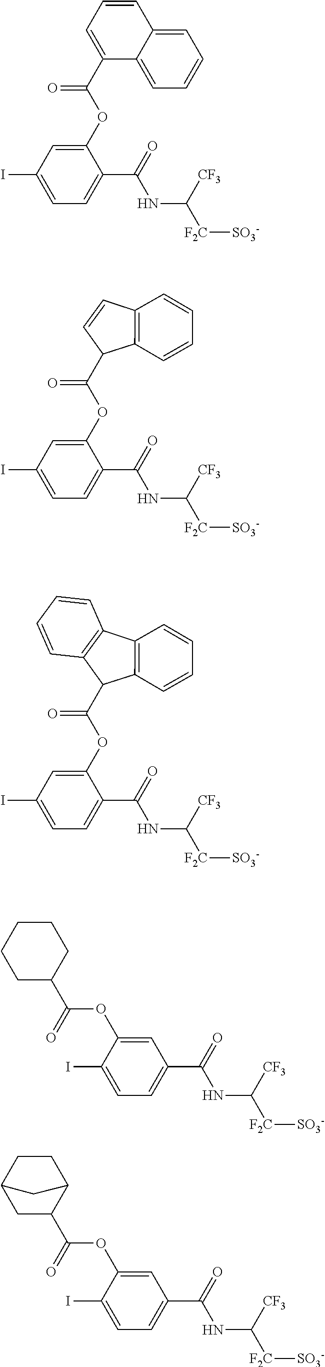

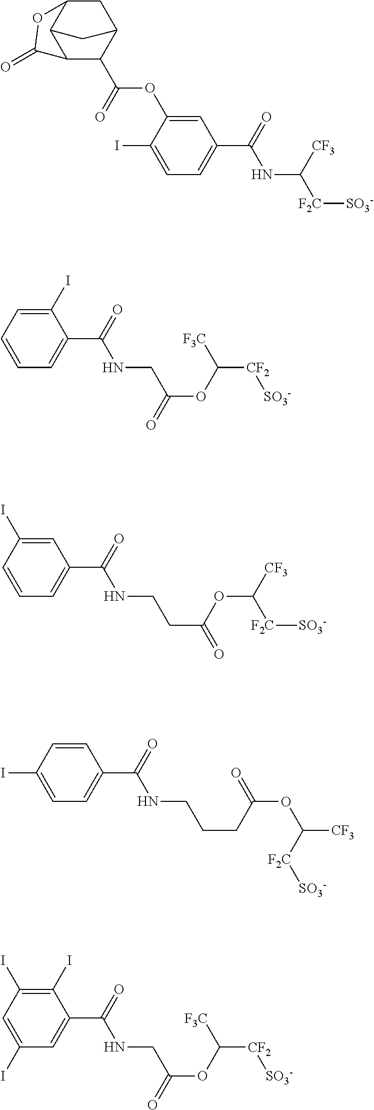

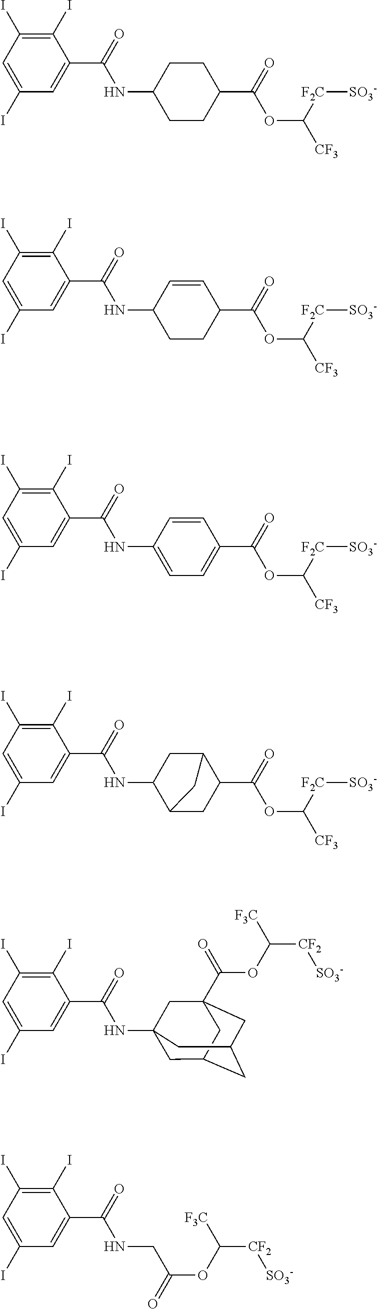

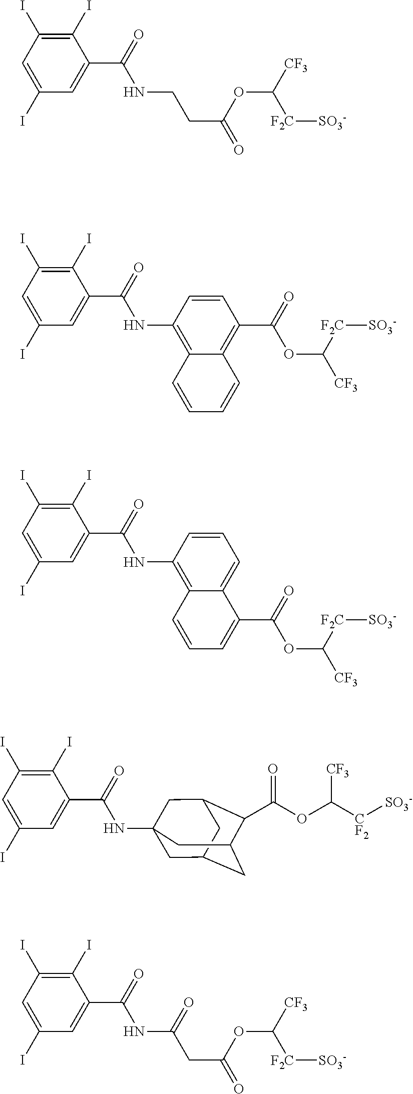

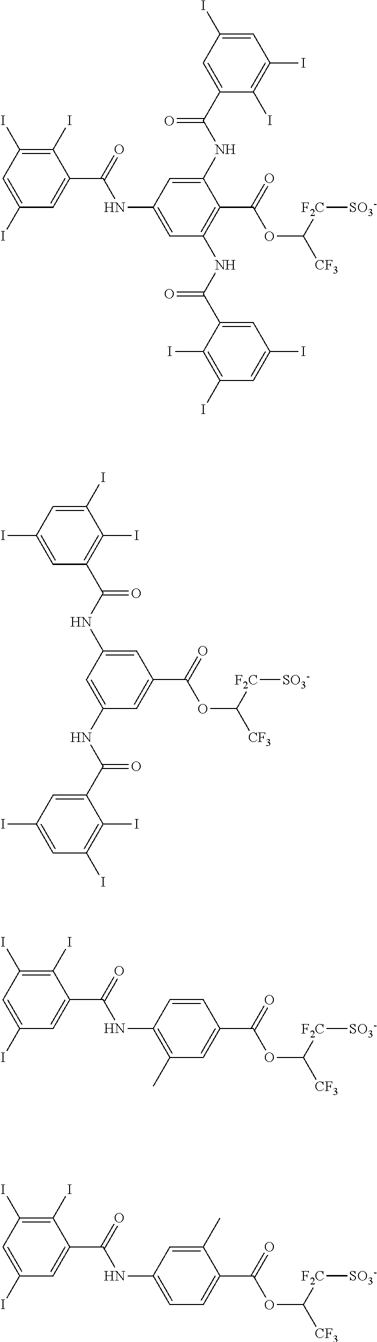

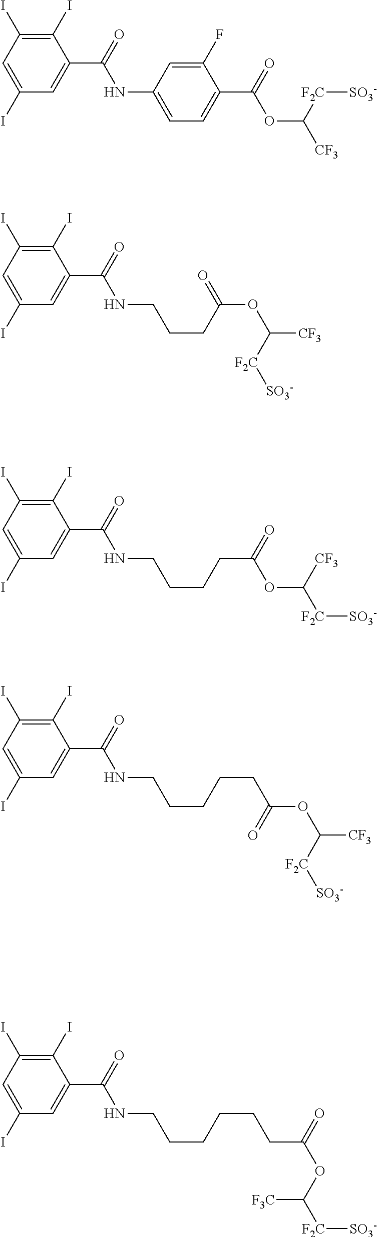

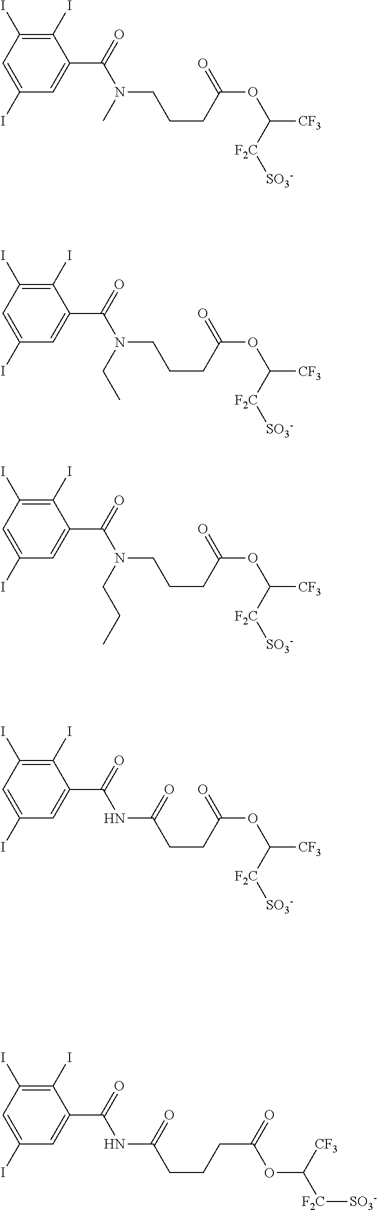

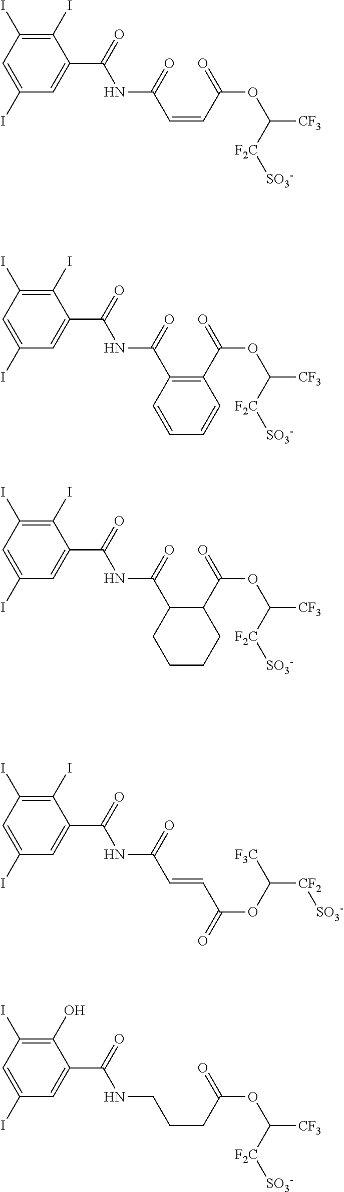

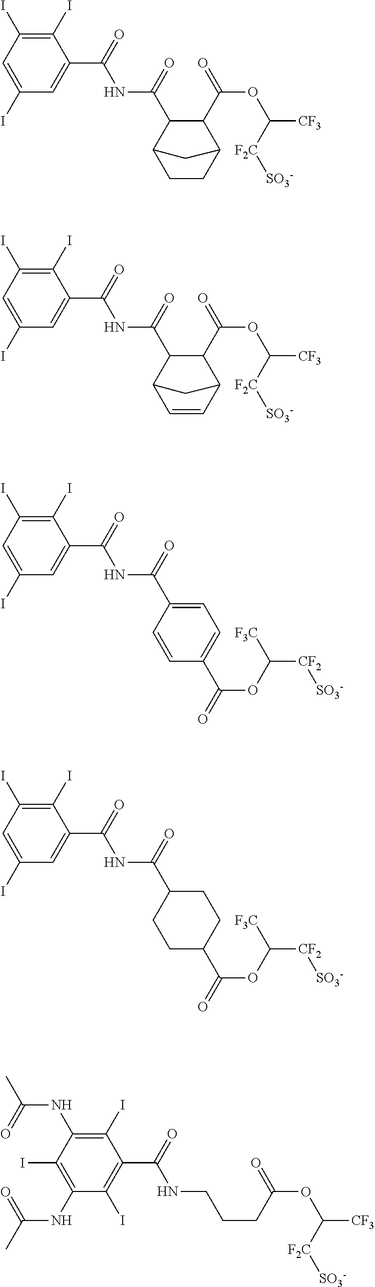

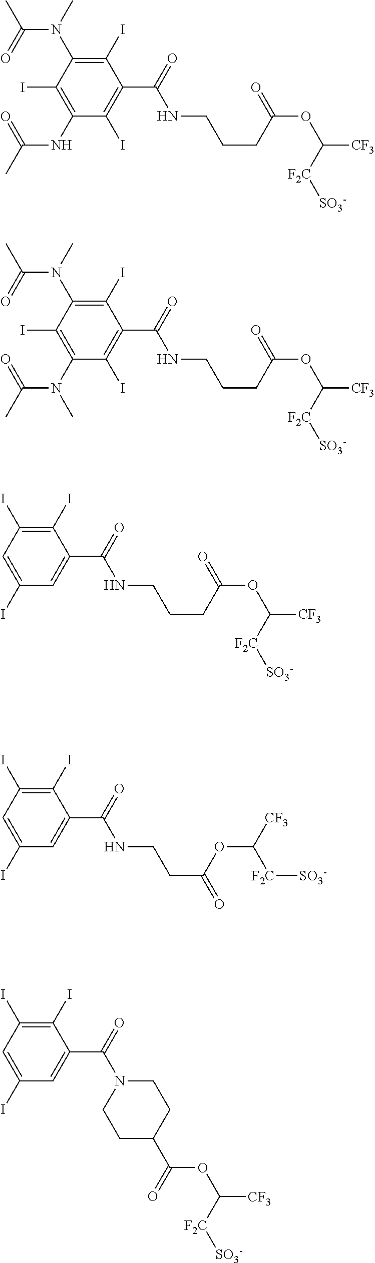

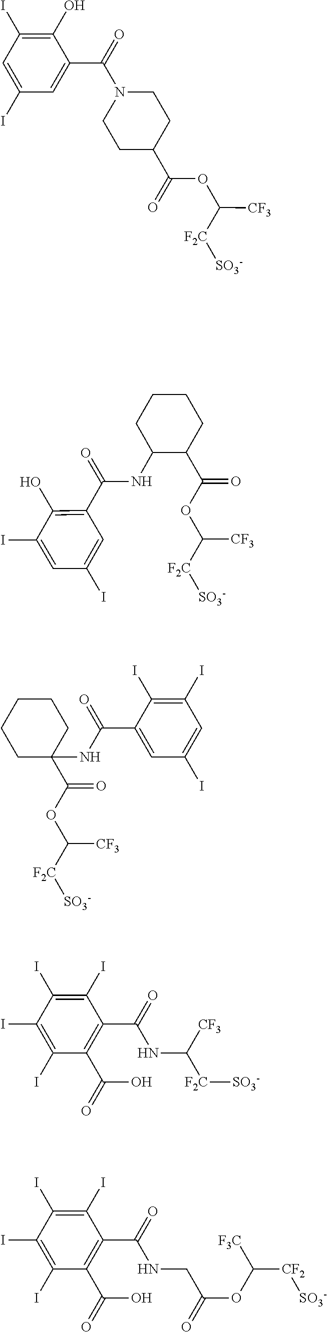

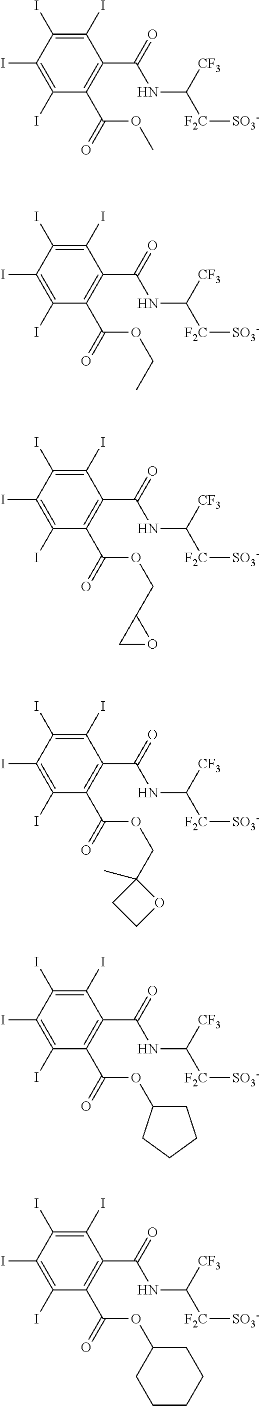

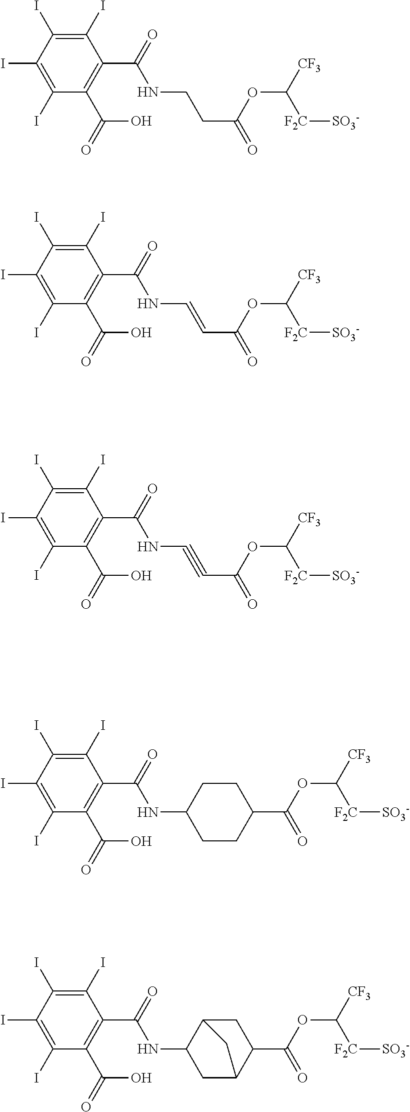

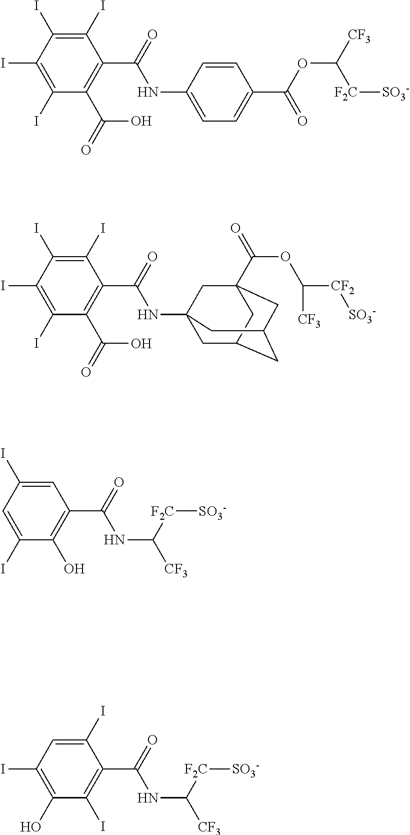

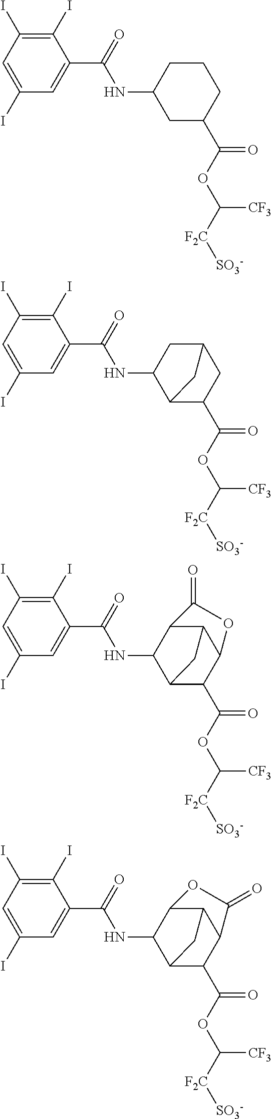

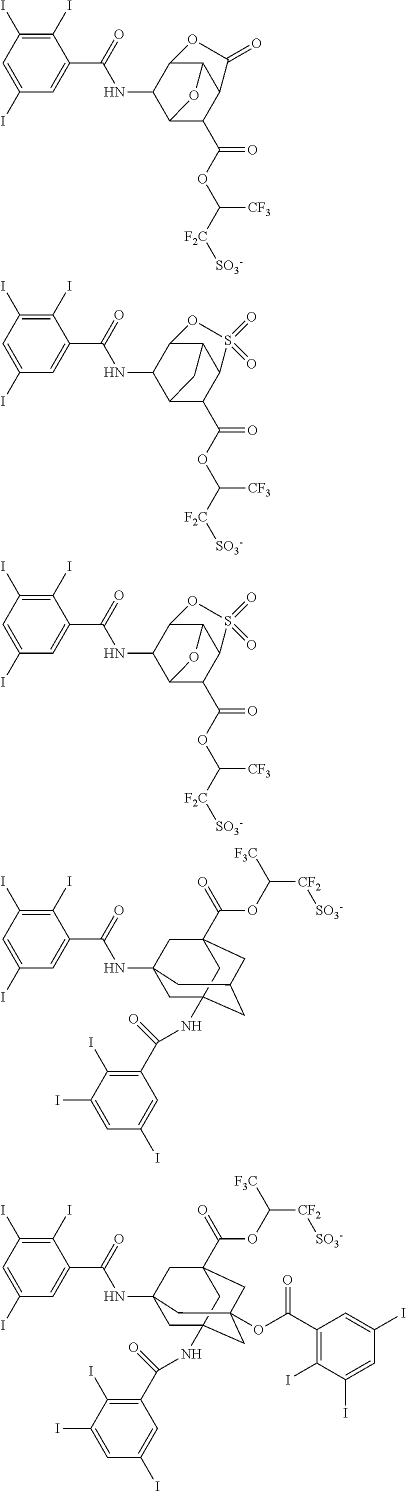

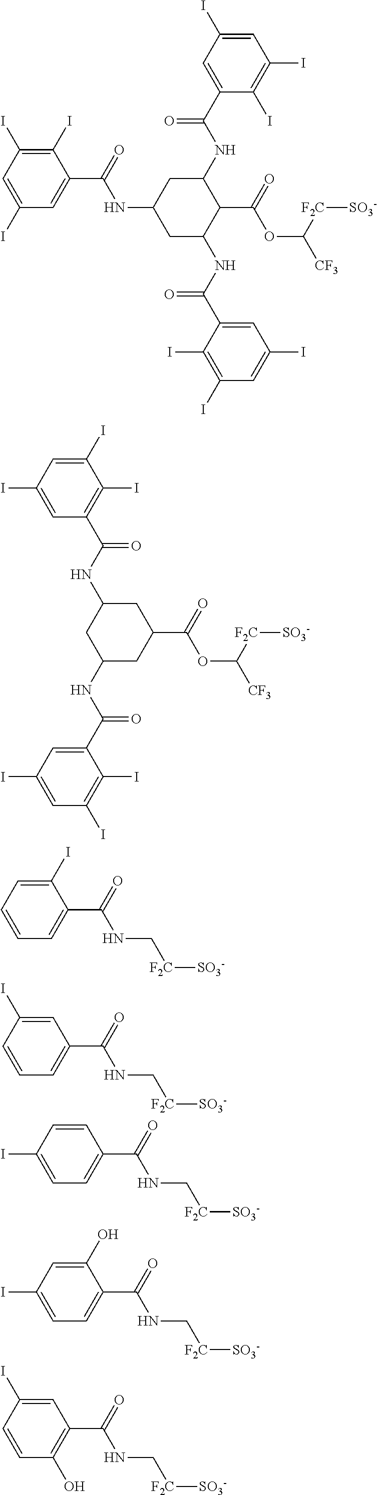

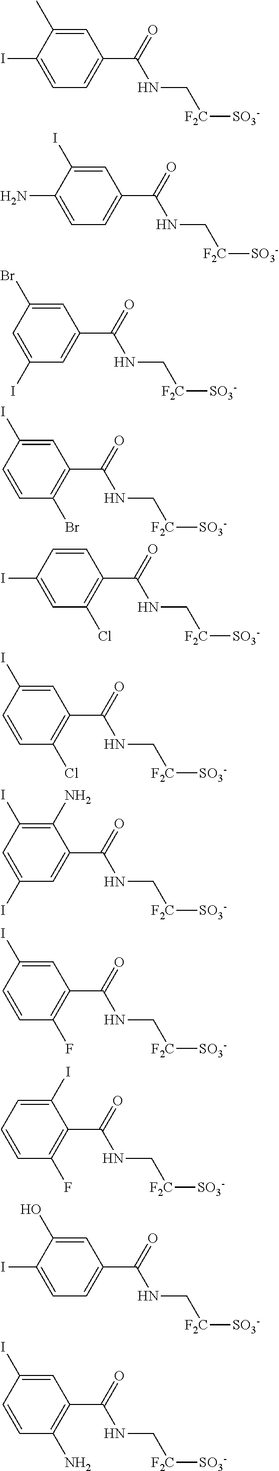

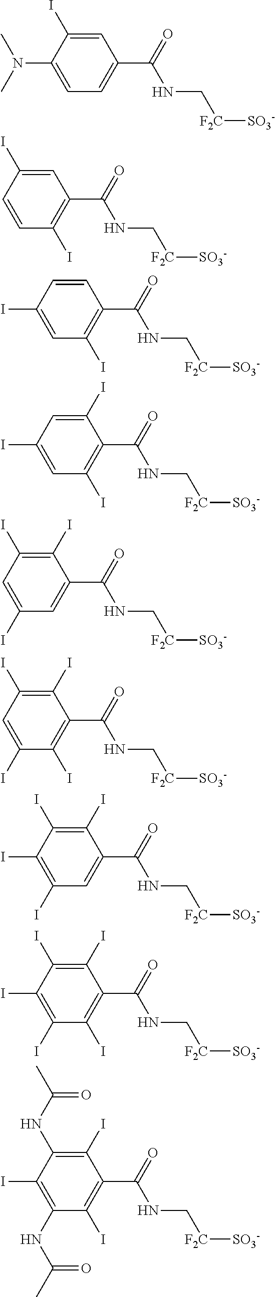

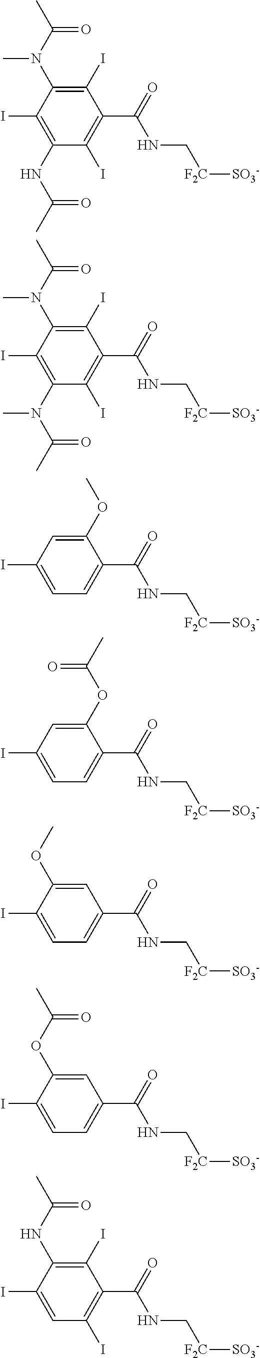

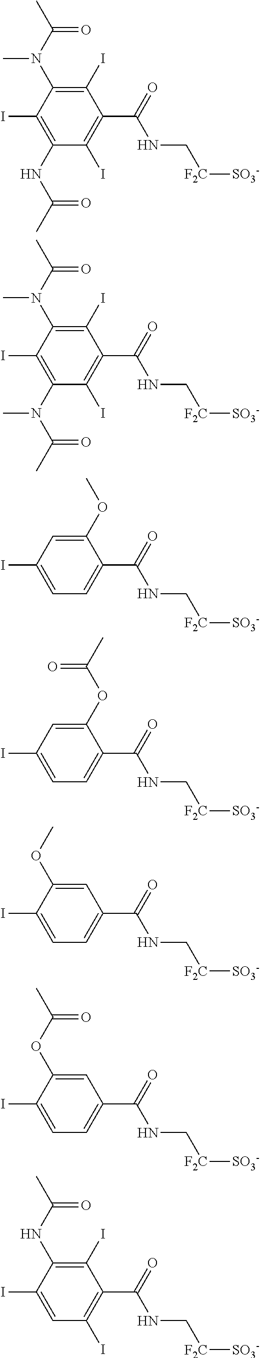

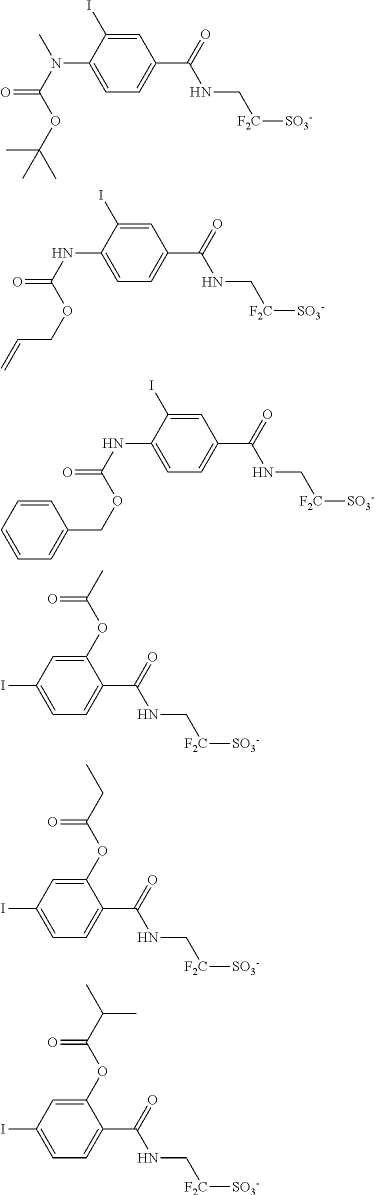

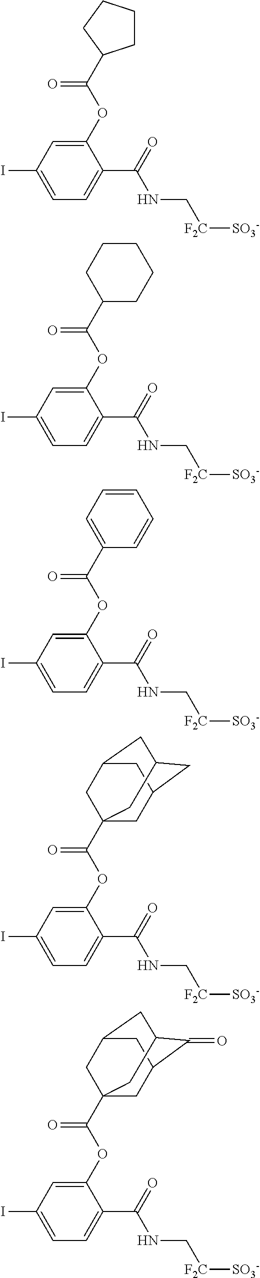

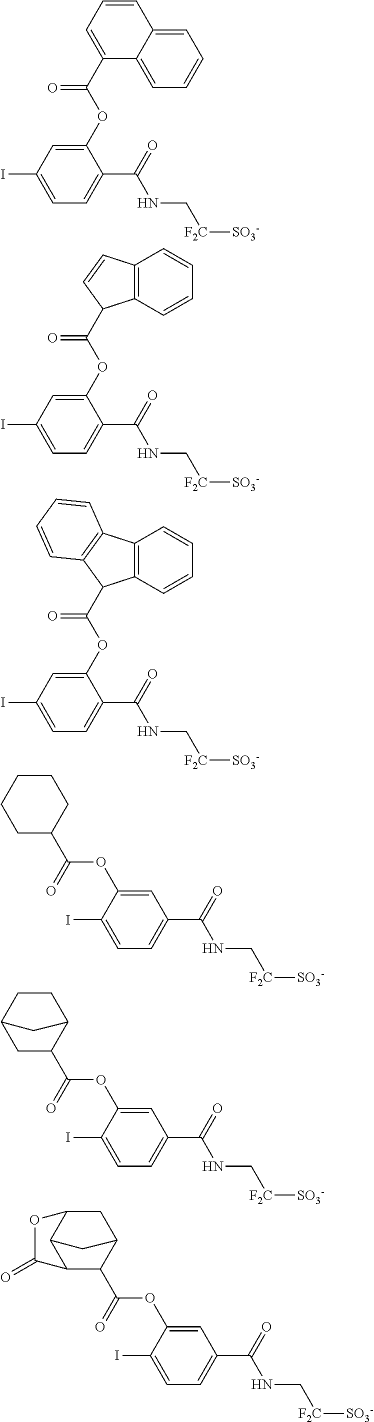

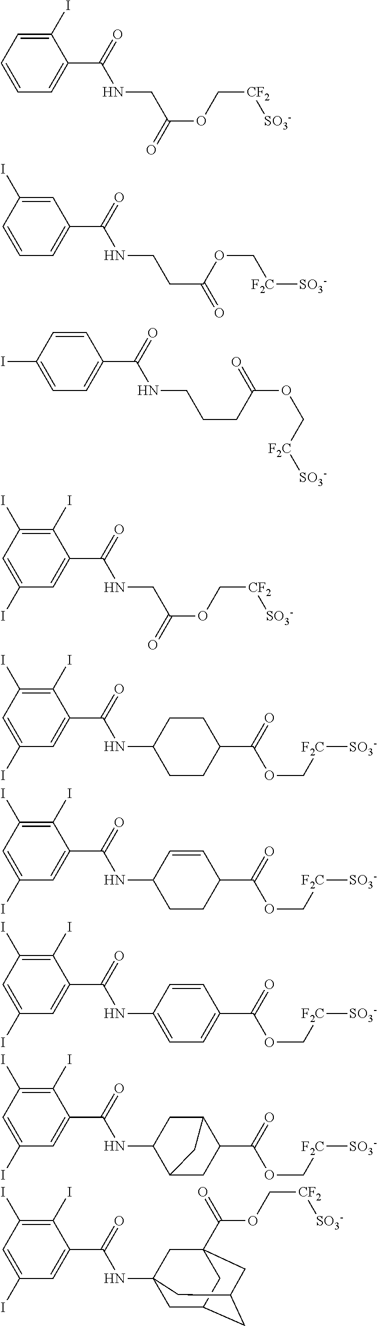

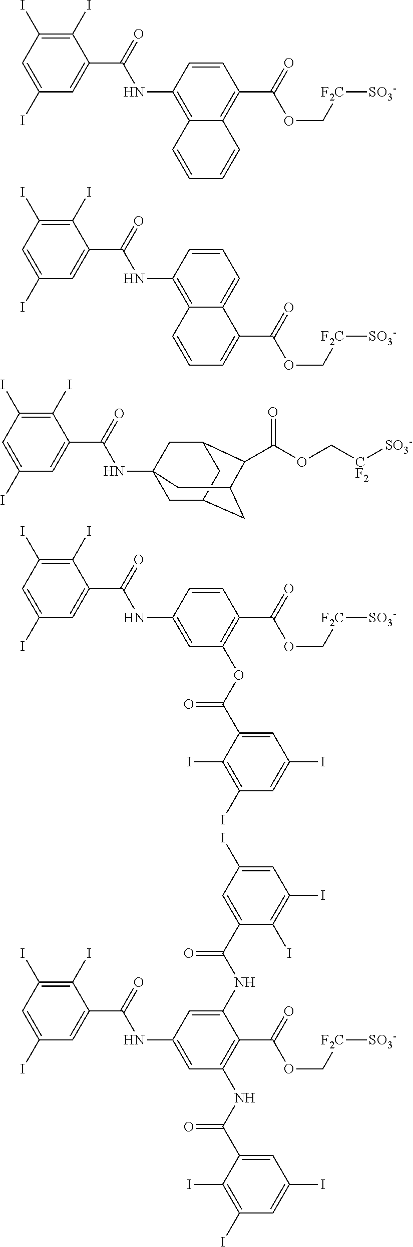

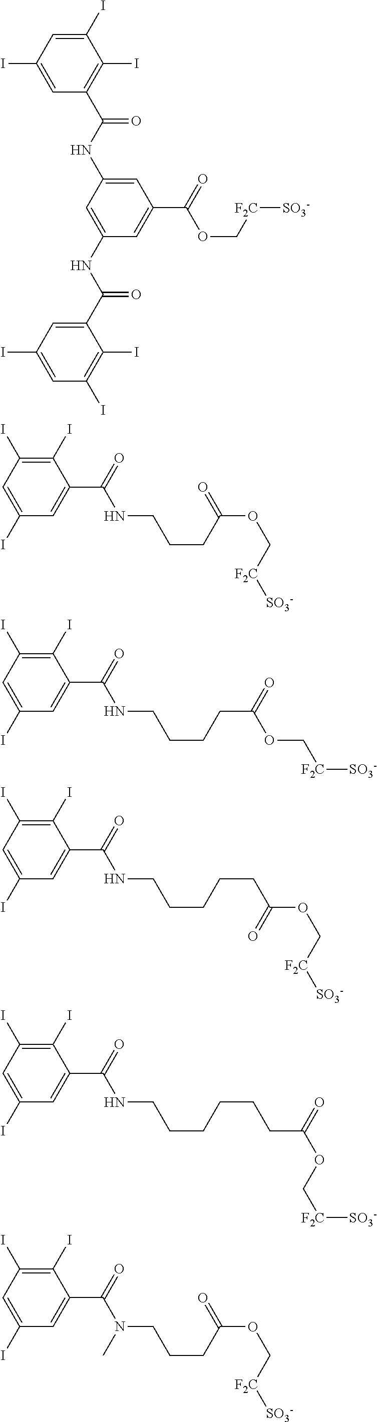

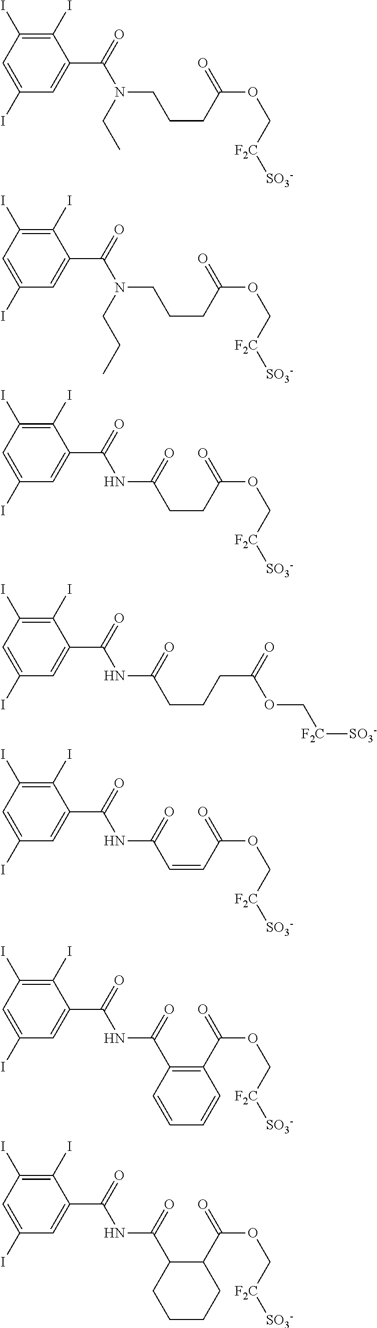

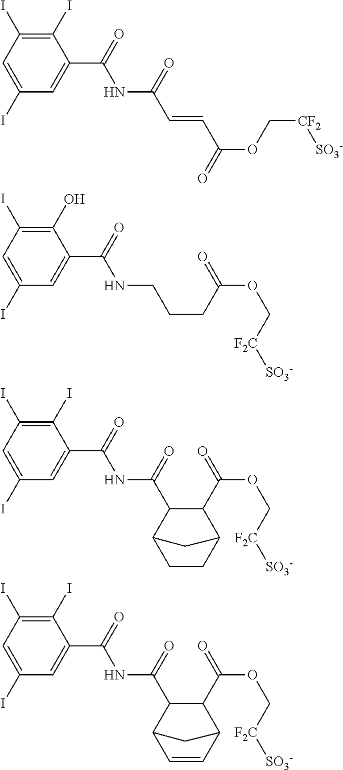

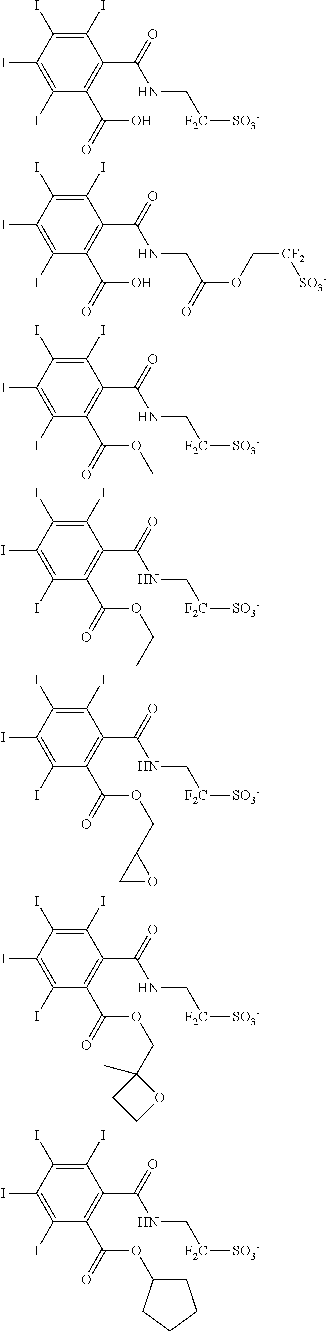

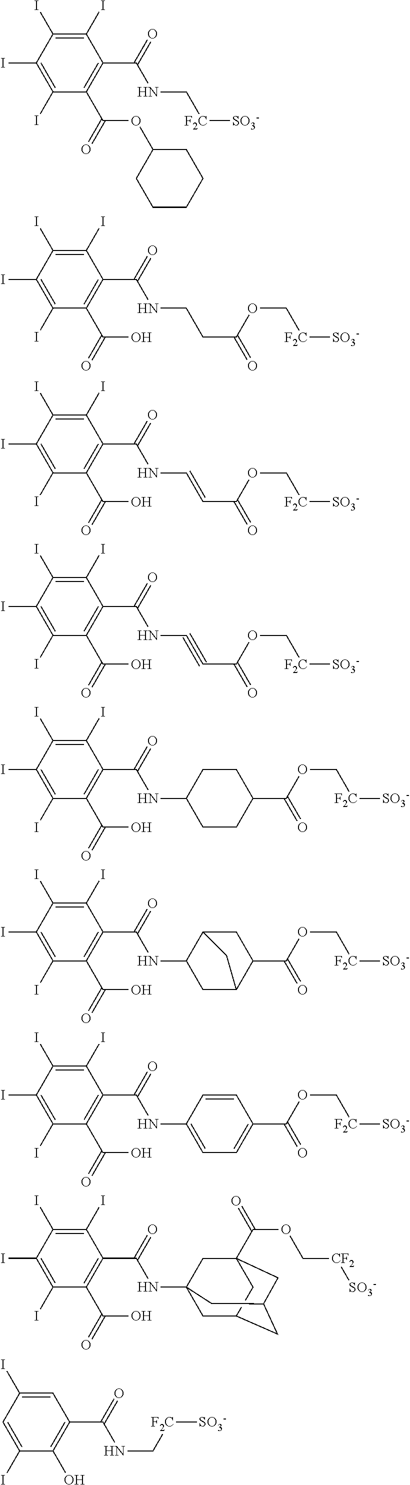

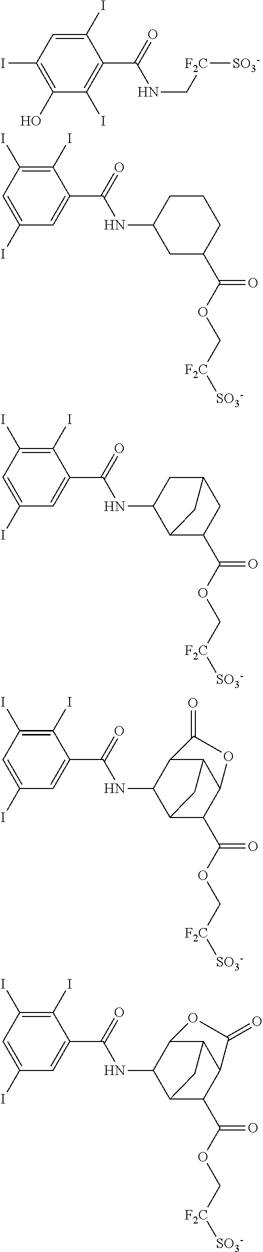

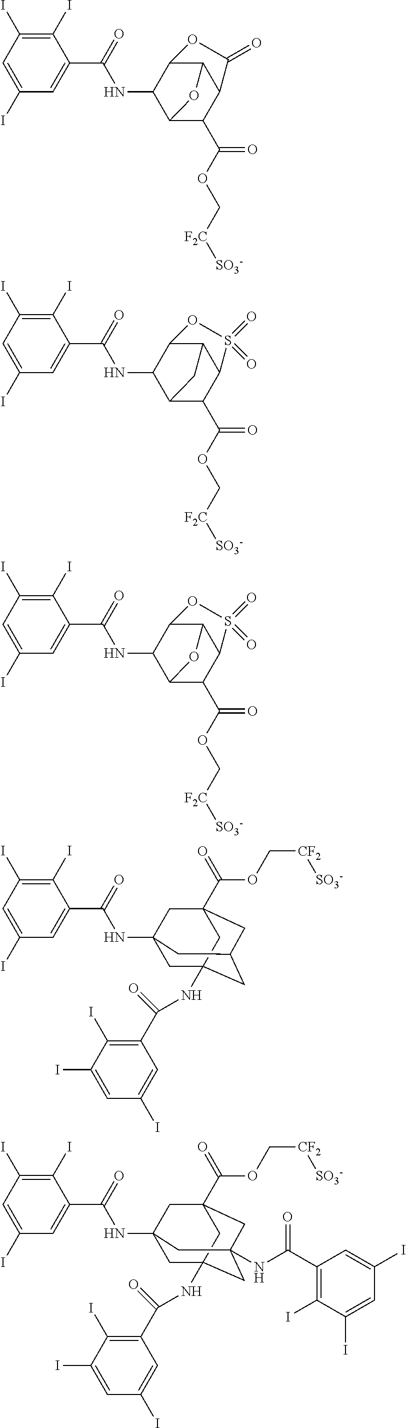

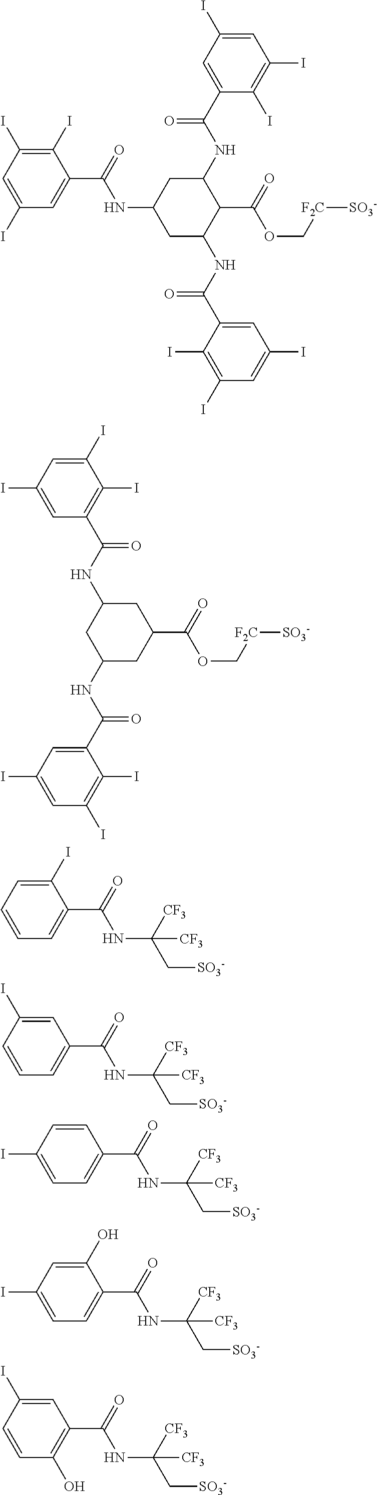

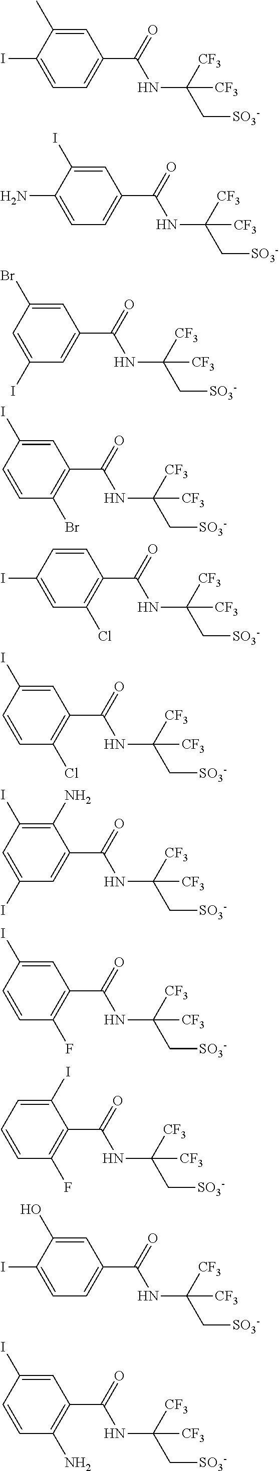

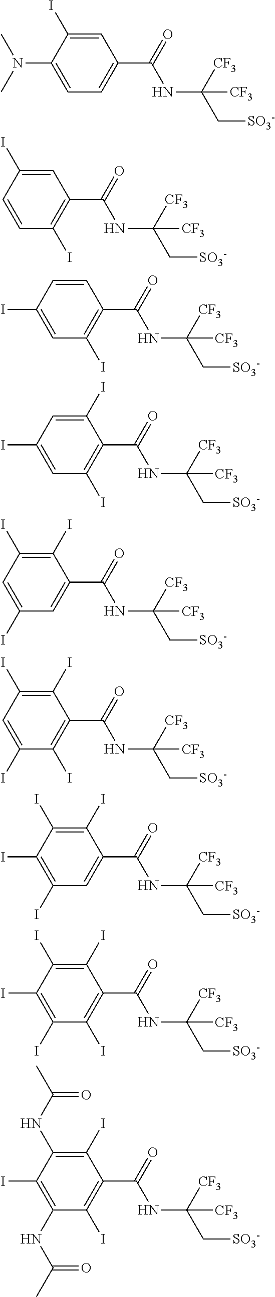

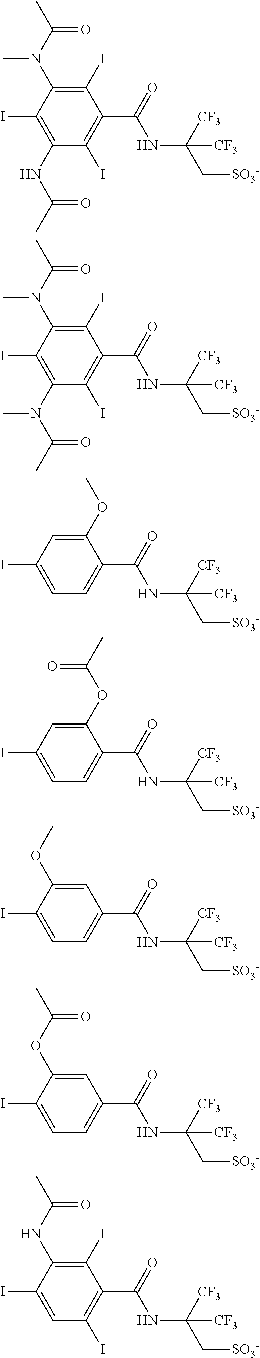

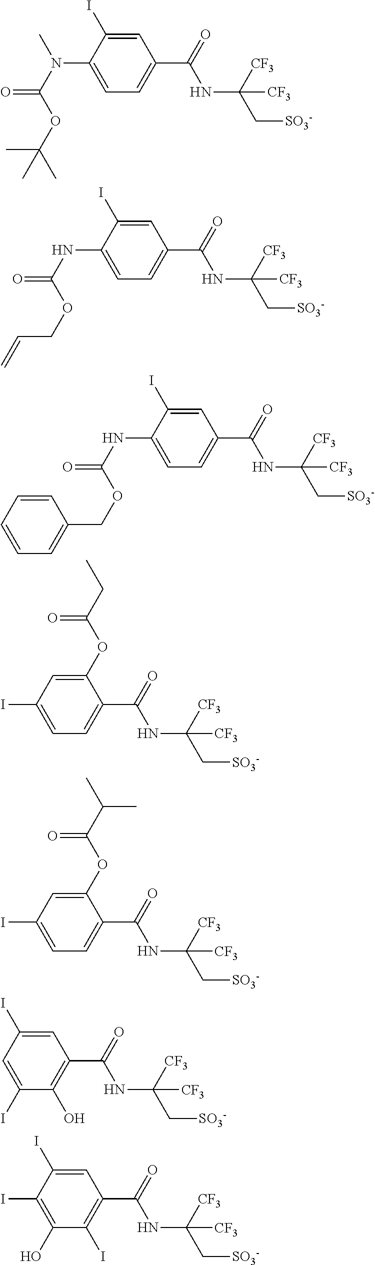

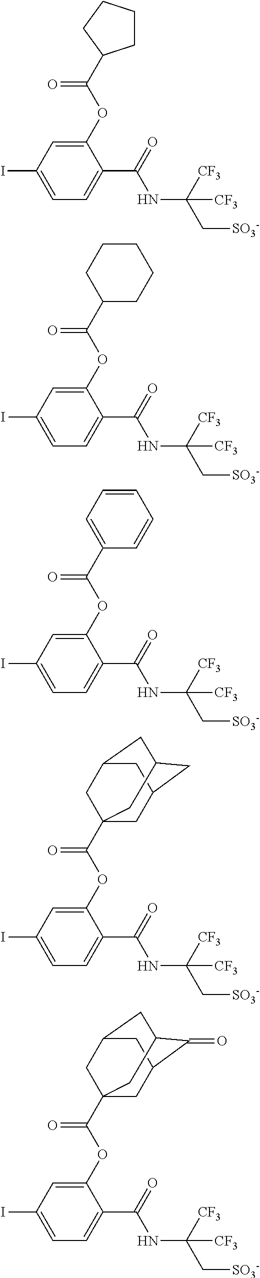

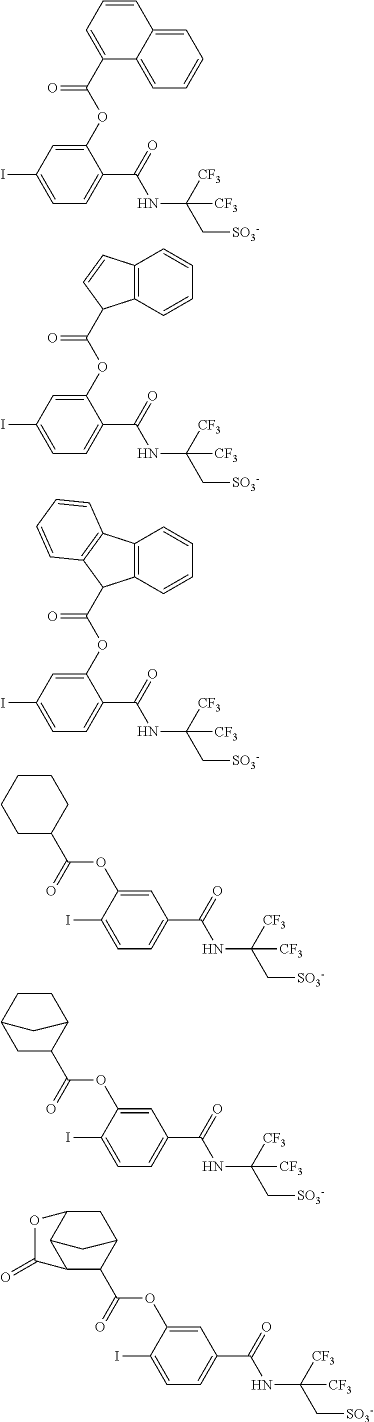

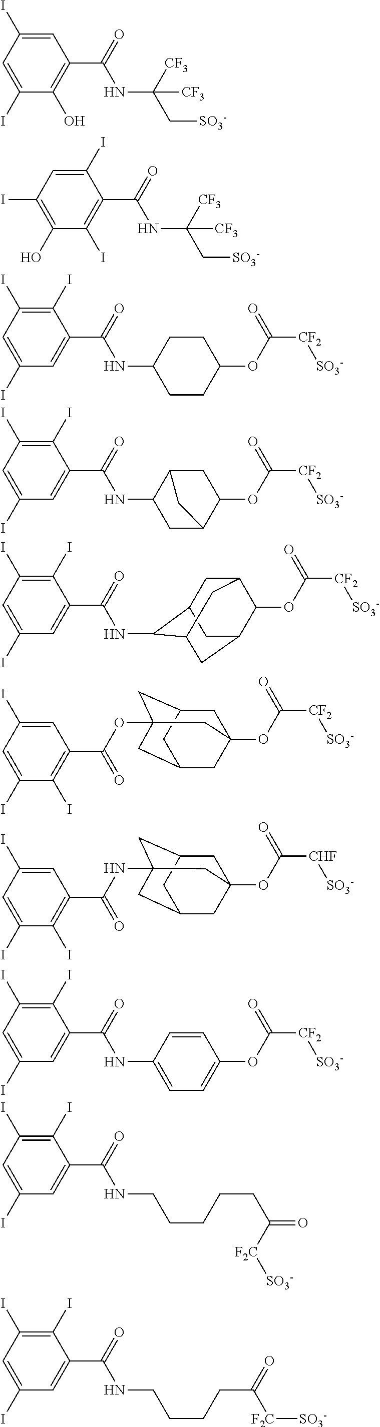

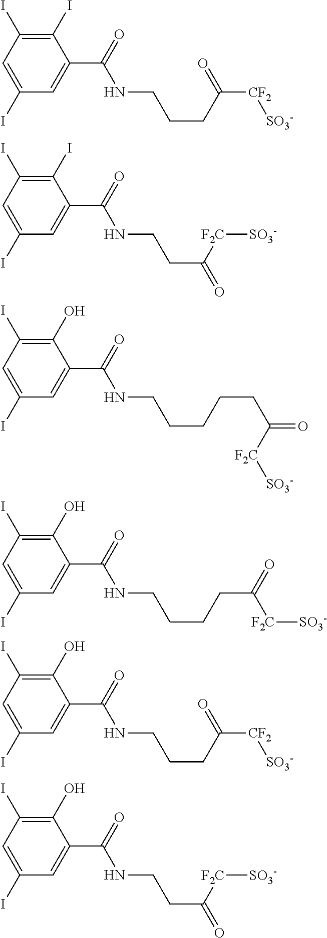

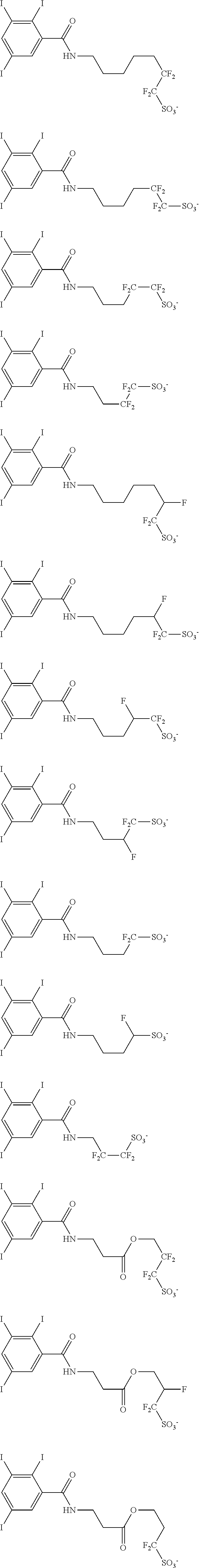

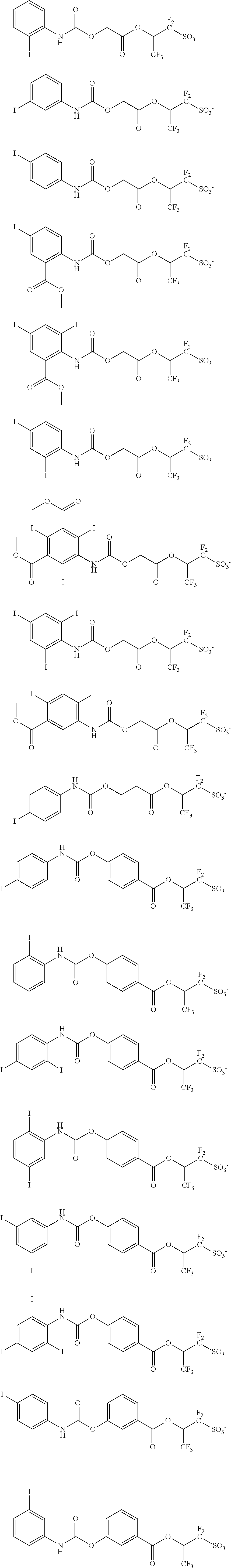

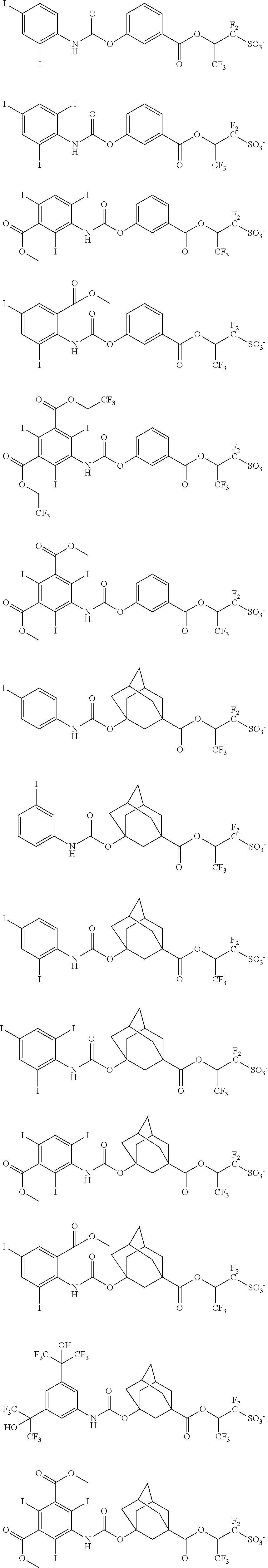

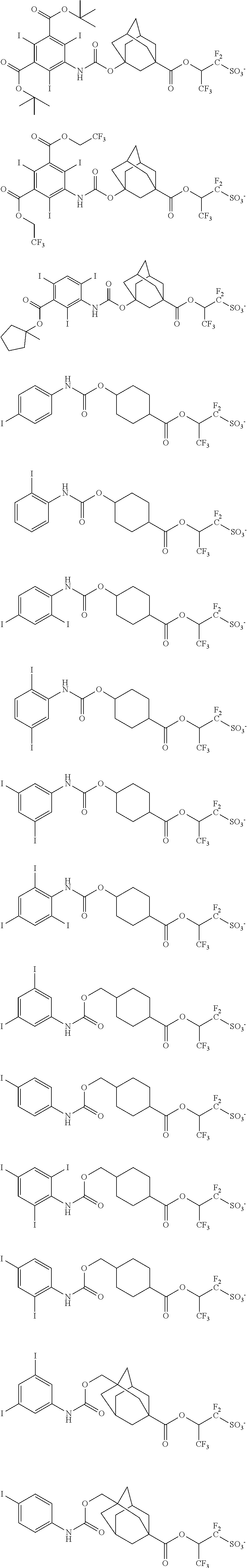

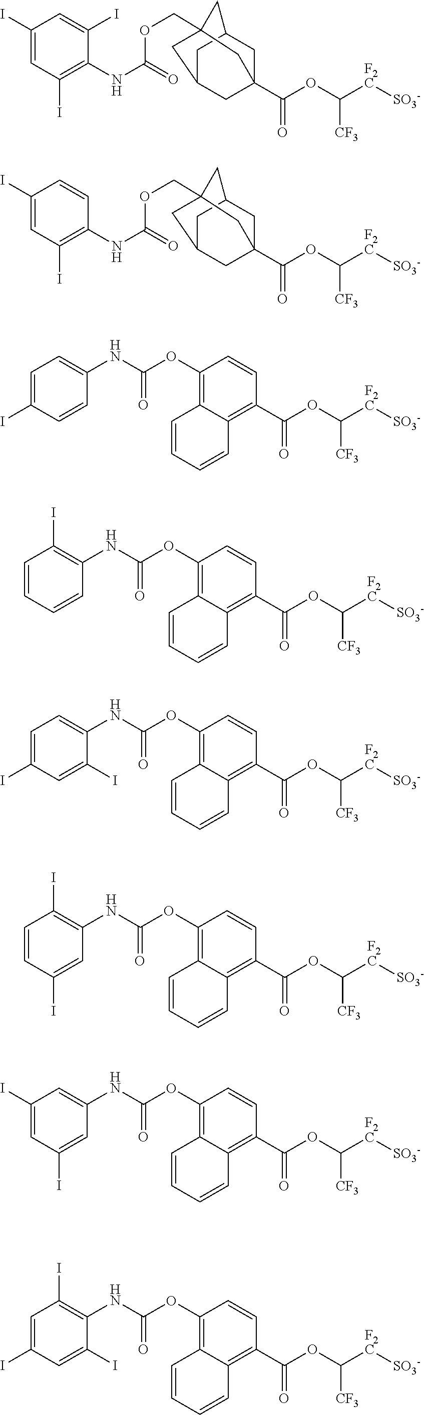

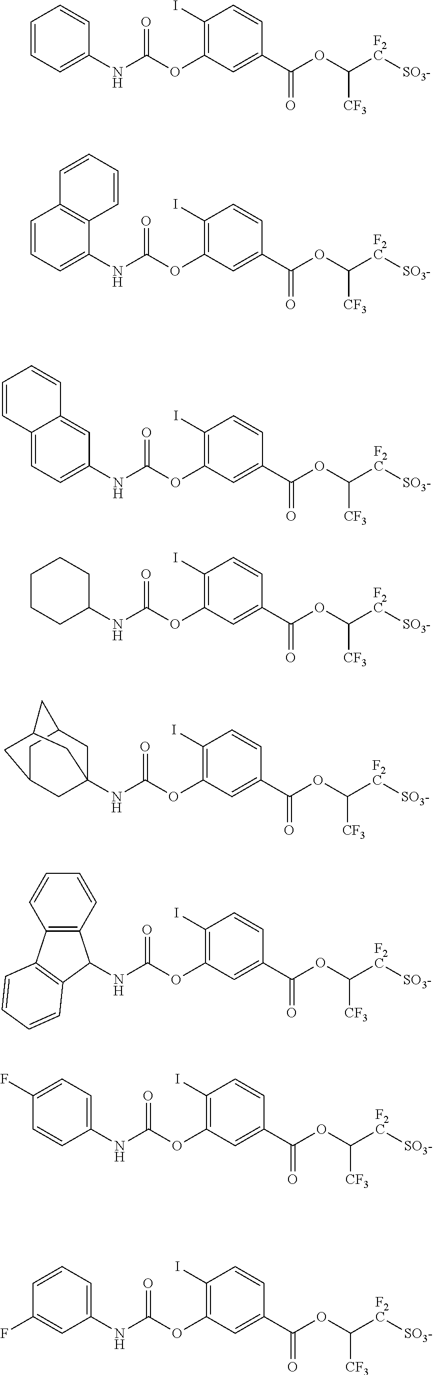

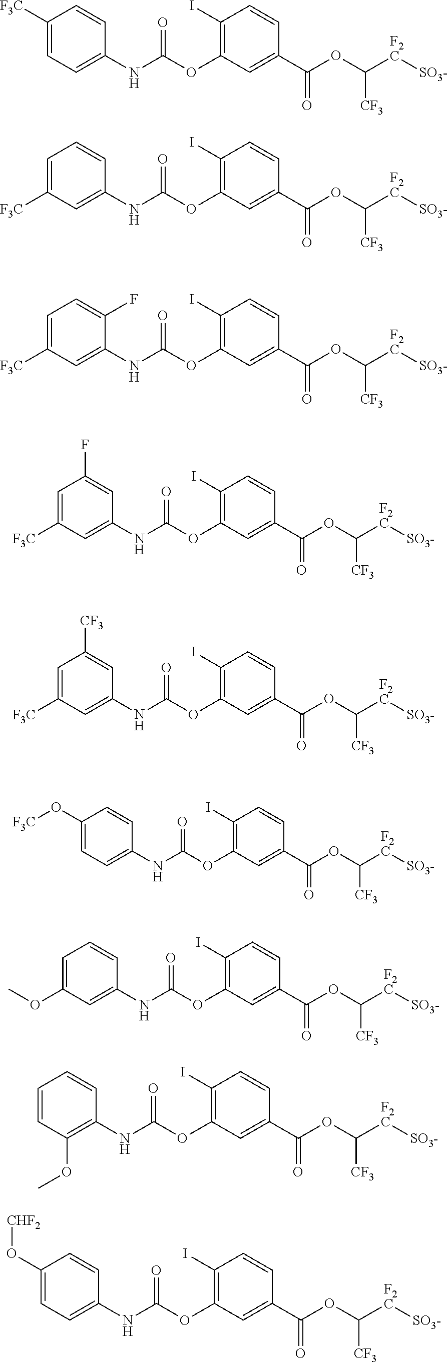

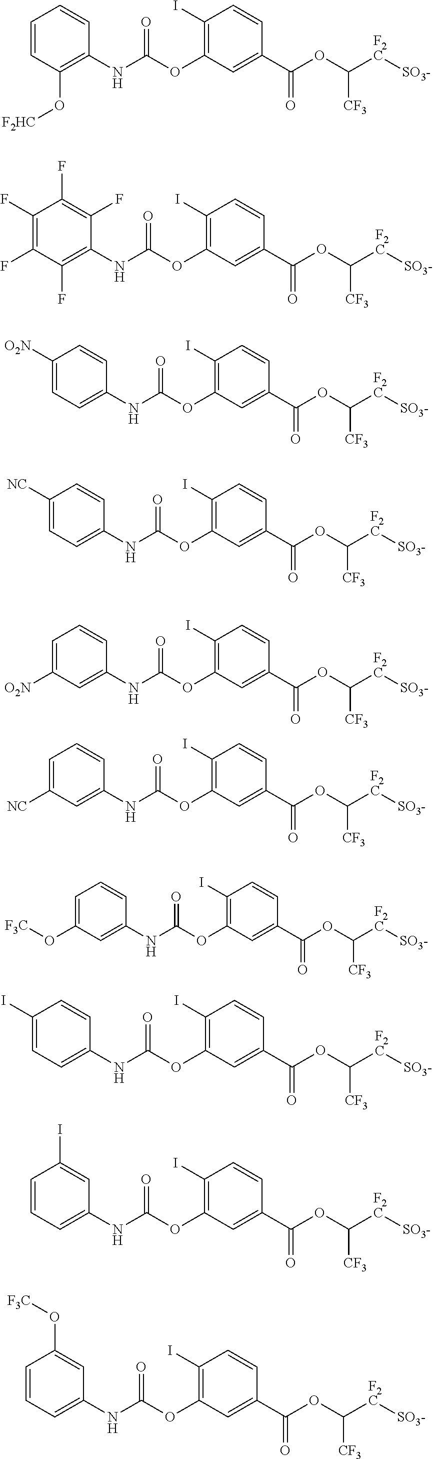

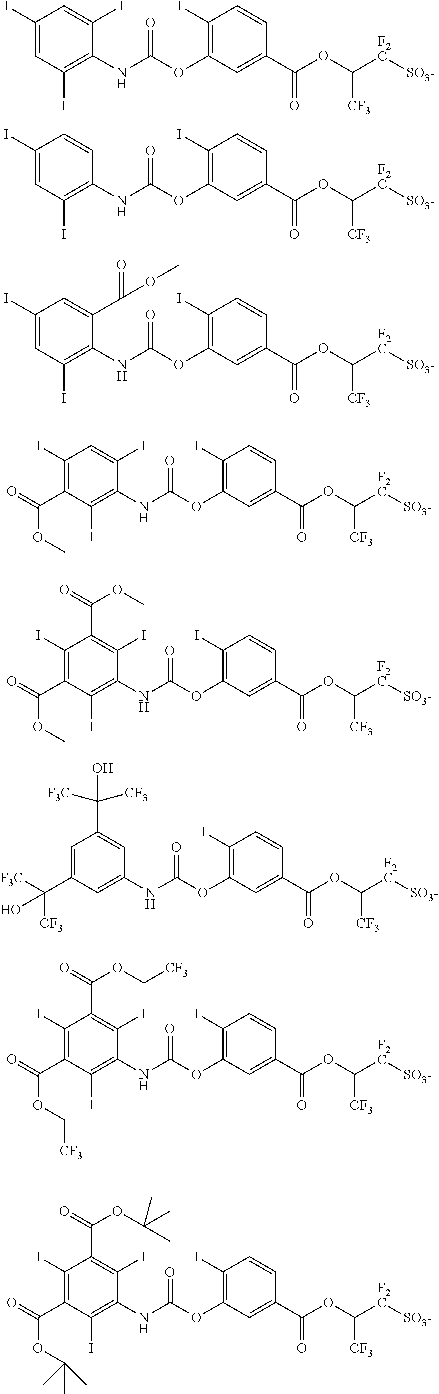

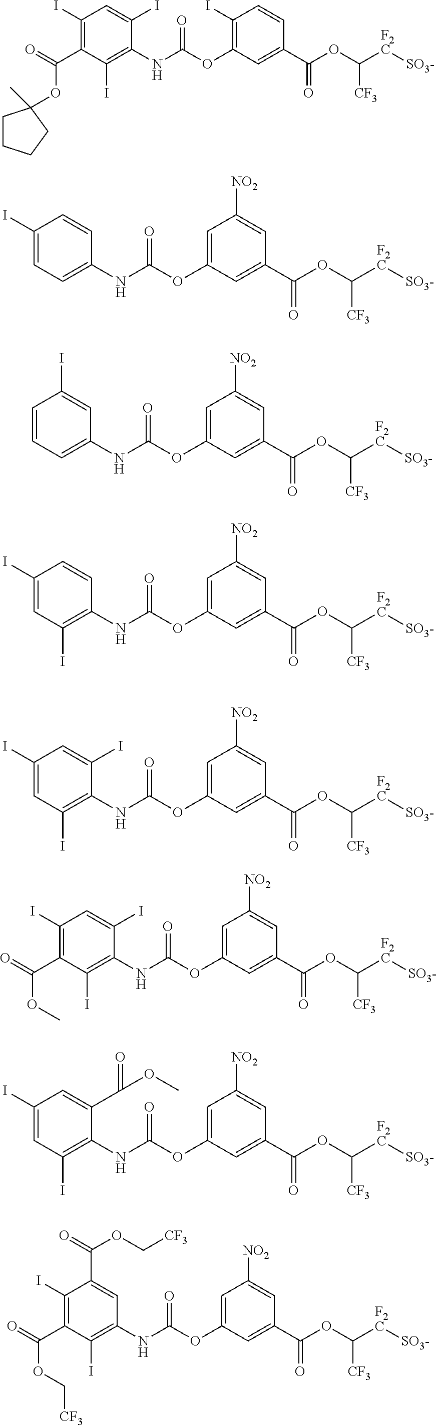

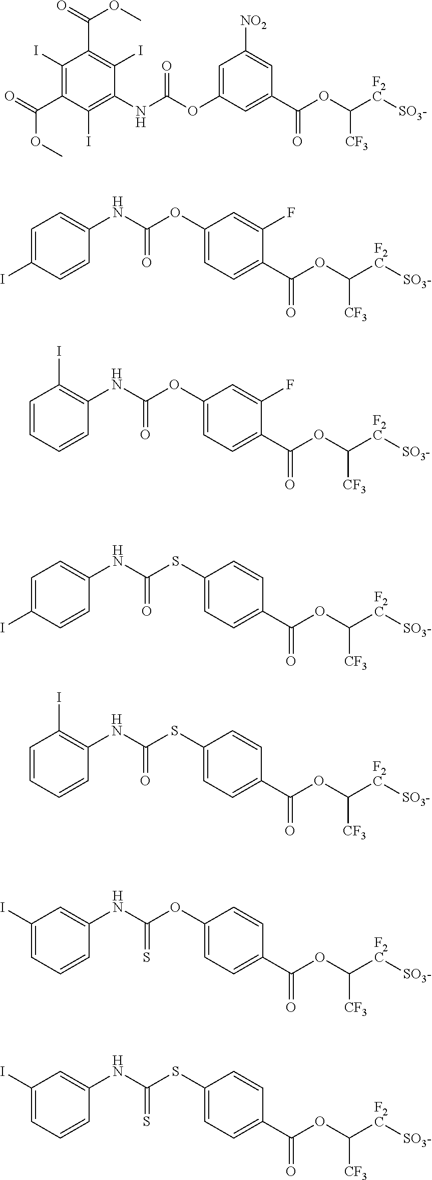

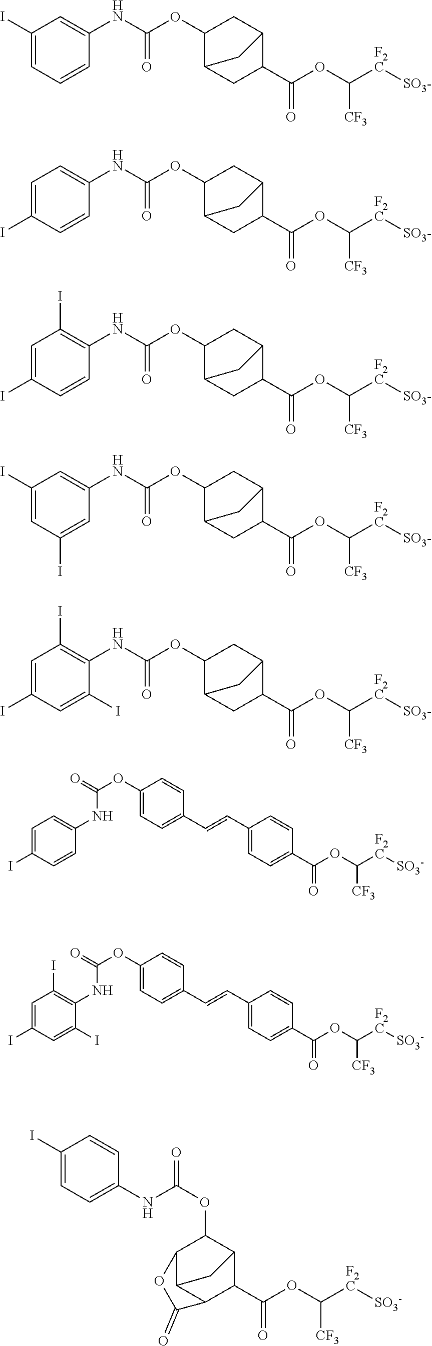

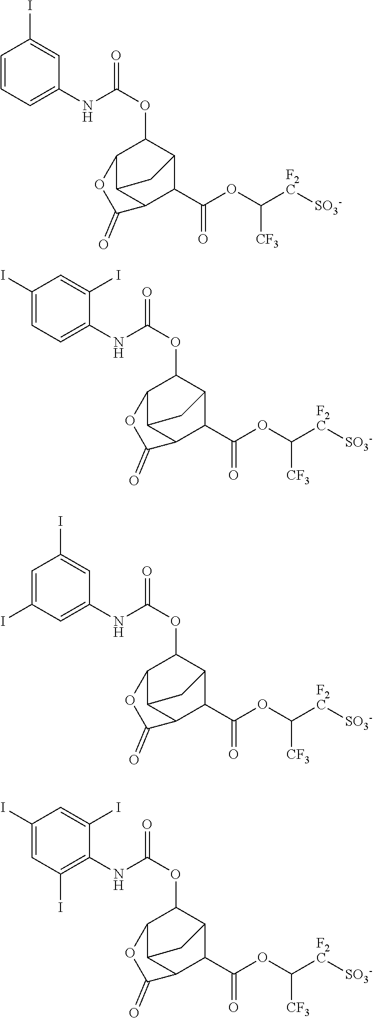

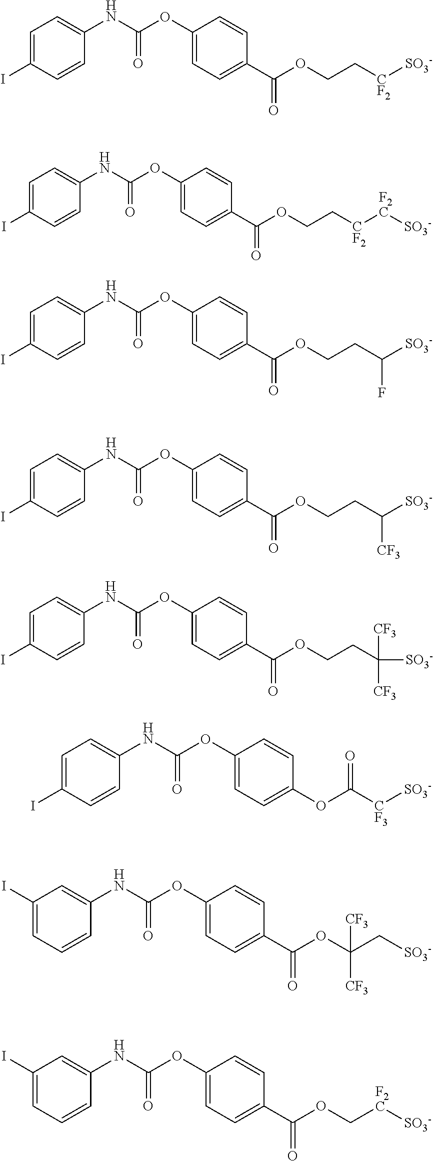

Also useful as the sulfonic acid anion having a carbon atom to which an iodine atom is bonded are the iodine atom-containing anions described in Patent Documents 11 to 16.

Examples of the method for synthesizing the sulfonium salt include a method of ion exchange between a salt containing the sulfonium cation and a weak acid anion and an ammonium salt having the above anion. The sulfonium cation can be obtained, for example, by the method described in paragraphs [0094] to [0097] of JP-A 2022-068394.

The sulfonium salt having formula (1) is preferably added to the resist composition of the present invention in an amount of 0.01 to 1,000 parts by weight, and more preferably 0.05 to 500 parts by weight per 100 parts by weight of the base polymer described later, from the viewpoint of sensitivity and an effect of reducing acid diffusion.

Base Polymer

When the resist composition of the present invention is of positive tone, the base polymer comprised in the resist composition contains repeat units containing an acid labile group. The repeat units containing an acid labile group are preferably repeat units having formula (a1) (hereinafter, the repeat units are also referred to as repeat units (a1)) or repeat units having formula (a2) (hereinafter, the repeat units are also referred to as repeat units (a2)).

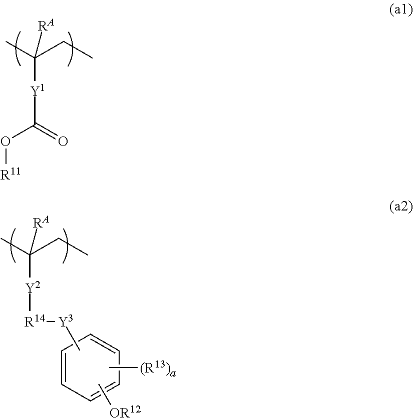

In formulae (a1) and (a2), R^{A} is each independently a hydrogen atom or a methyl group.

Y¹ is a single bond, a phenylene group, a naphthylene group, or a C₁-C₁₂ linking group containing at least one moiety selected from an ester bond, an ether bond, and a lactone ring.

Y² is a single bond or an ester bond. Y³ is a single bond, an ether bond, or an ester bond. R¹¹ and R¹² are each independently an acid labile group. R¹³ is a C₁-C₄ saturated hydrocarbyl group, a halogen atom, a C₂-C₅ saturated hydrocarbylcarbonyl group, a cyano group, or a C₂-C₅ saturated hydrocarbyloxycarbonyl group. R¹⁴ is a single bond or a C₁-C₆ alkanediyl group which may contain an ether bond or an ester bond. a is an integer of 0 to 4.

Examples of the monomer from which the repeat units (a1) are derived include those shown below, but are not limited thereto. In the formulae, R^{A} and R¹¹ are as defined above.

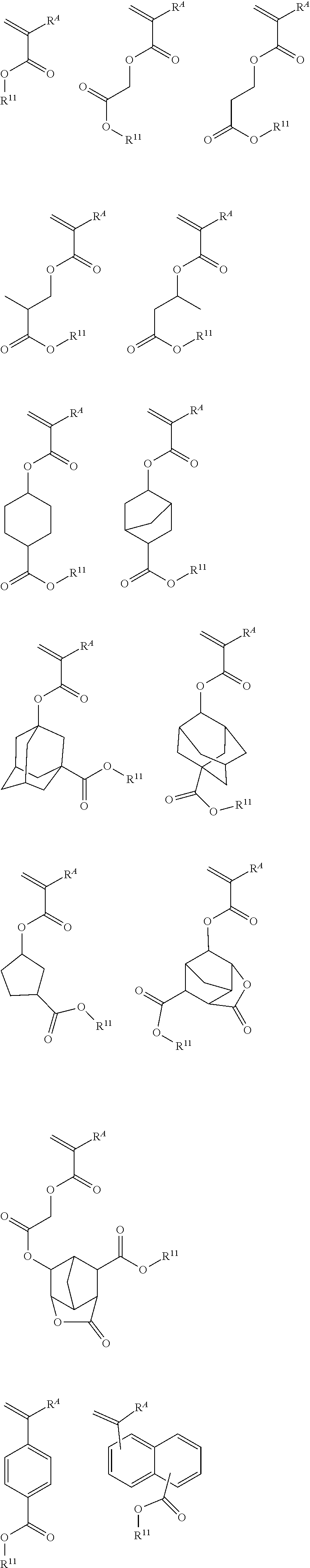

Examples of the monomer from which the repeat units (a2) are derived include those shown below, but are not limited thereto. In the formulae, R^{A} and R¹² are as defined above.

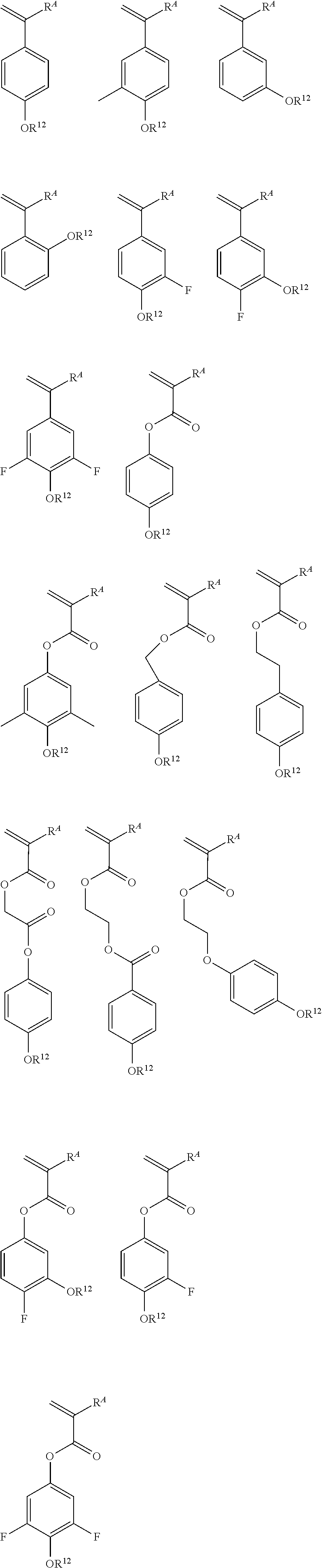

Examples of the acid labile groups represented by R¹¹ and R¹² in formulae (a1) and (a2) include those described in JP-A 2013-080033 and JP-A 2013-083821.

Typical examples of the acid labile groups include those represented by formulae (AL-1) to (AL-3).

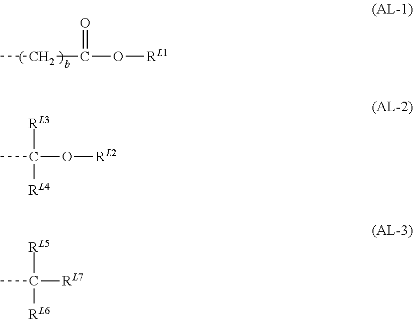

In the formulae, a broken line designates a bond.

In formulae (AL-1) and (AL-2), R^{L1} and R^{L2} are each independently a C₁-C₄₀ hydrocarbyl group which may contain a heteroatom such as an oxygen atom, a sulfur atom, a nitrogen atom, or a fluorine atom. The hydrocarbyl group may be saturated or unsaturated, and may be straight, branched, or cyclic. Preferred are C₁-C₄₀ saturated hydrocarbyl groups, especially C₁-C₂₀ saturated hydrocarbyl groups.

In formula (AL-1), b is an integer of 0 to 10, preferably an integer of 1 to 5.

In formula (AL-2), R^{L3} and R^{L4} are each independently a hydrogen atom or a C₁-C₂₀ hydrocarbyl group which may contain a heteroatom such as an oxygen atom, a sulfur atom, a nitrogen atom, or a fluorine atom. The hydrocarbyl group may be saturated or unsaturated, and may be straight, branched, or cyclic. Preferred are C₁-C₂₀ saturated hydrocarbyl groups. Any two of R^{L2}, R^{L3}, and R^{L4} may bond together to form a ring, typically an alicyclic ring, with the carbon atom or carbon and oxygen atoms to which they are bonded, the ring containing 3 to 20 carbon atoms, preferably 4 to 16 carbon atoms.

In formula (AL-3), R^{L5}, R^{L6}, and R^{L7} are each independently a C₁-C₂₀ hydrocarbyl group which may contain a heteroatom such as an oxygen atom, a sulfur atom, a nitrogen atom, or a fluorine atom. The hydrocarbyl group may be saturated or unsaturated, and may be straight, branched, or cyclic. Preferred are C₁-C₂₀ saturated hydrocarbyl groups. Any two of R^{L5}, R^{L6}, and R^{L7} may bond together to form a ring, typically an alicyclic ring, with the carbon atom to which they are bonded, the ring containing 3 to 20 carbon atoms, preferably 4 to 16 carbon atoms.

The base polymer may contain repeat units (b) having a phenolic hydroxy group as an adhesive group. Examples of the monomer from which the repeat units (b) are derived include those shown below, but are not limited thereto. In the formulae, R^{A} is as defined above.

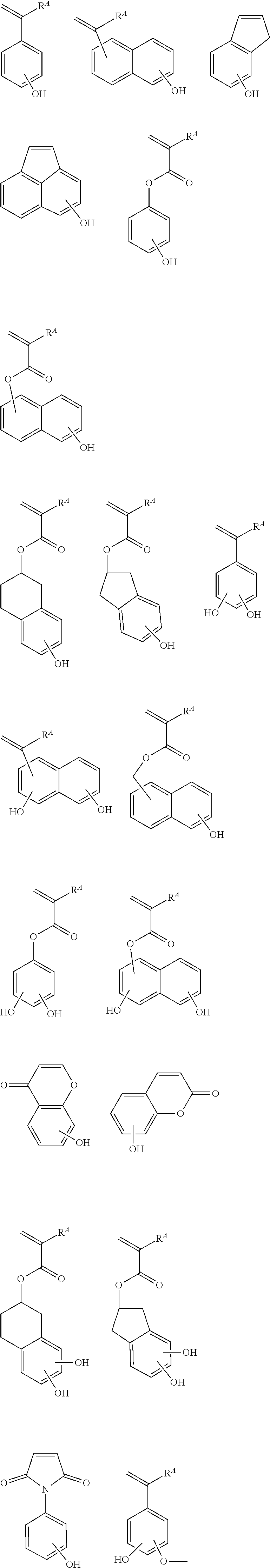

The base polymer may further contain repeat units (c) having another adhesive group selected from a hydroxy group other than the phenolic hydroxy group, a lactone ring, a sultone ring, an ether bond, an ester bond, a sulfonic ester bond, a carbonyl group, a sulfonyl group, a cyano group, and a carboxy group. Examples of the monomer from which the repeat units (c) are derived include those shown below, but are not limited thereto. In the formulae, R^{A} is as defined above.

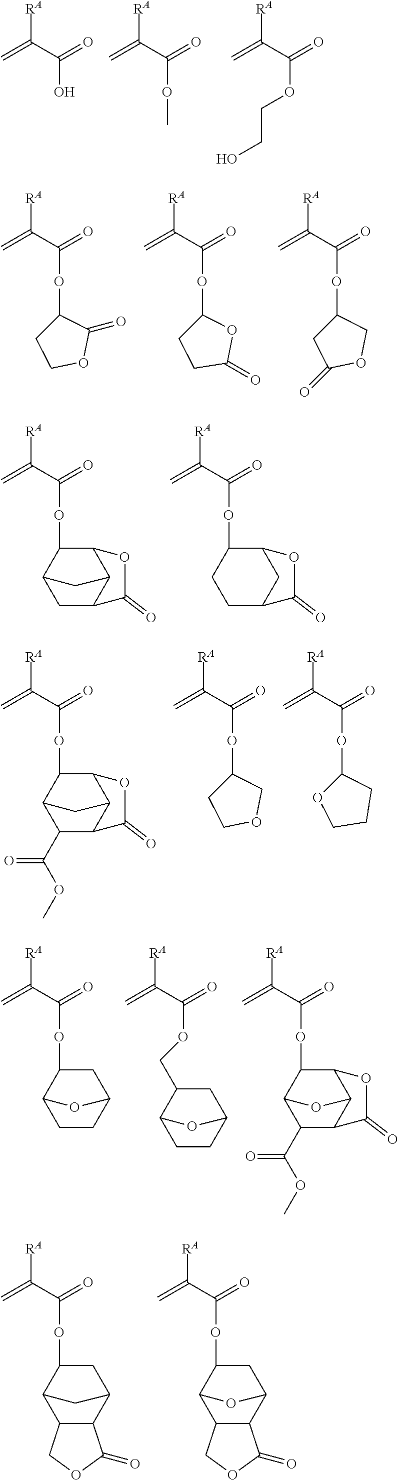

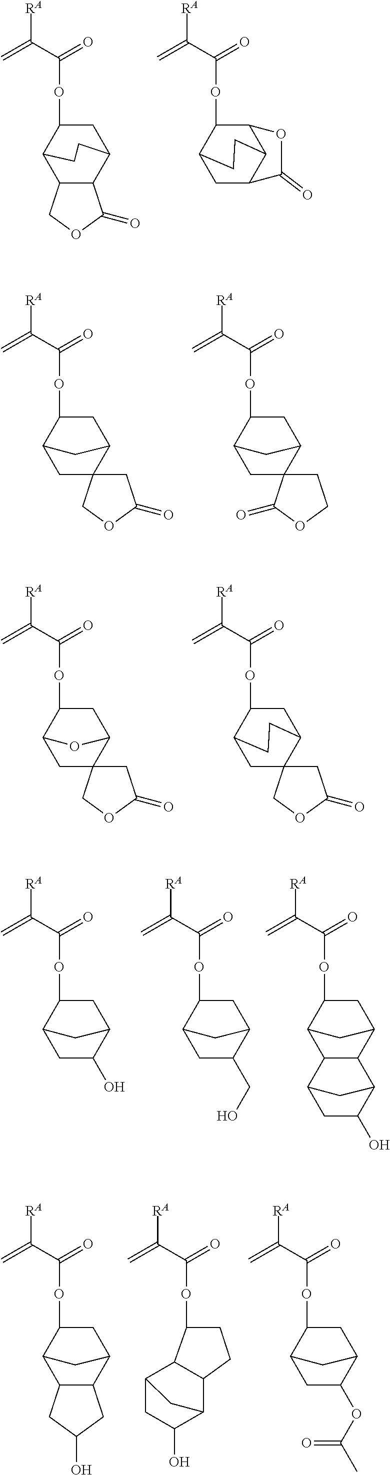

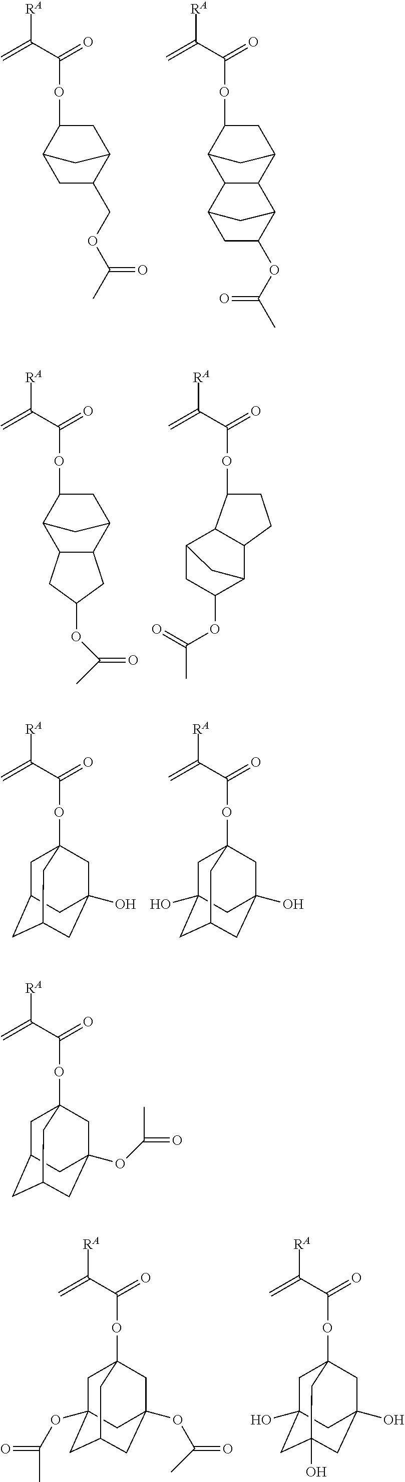

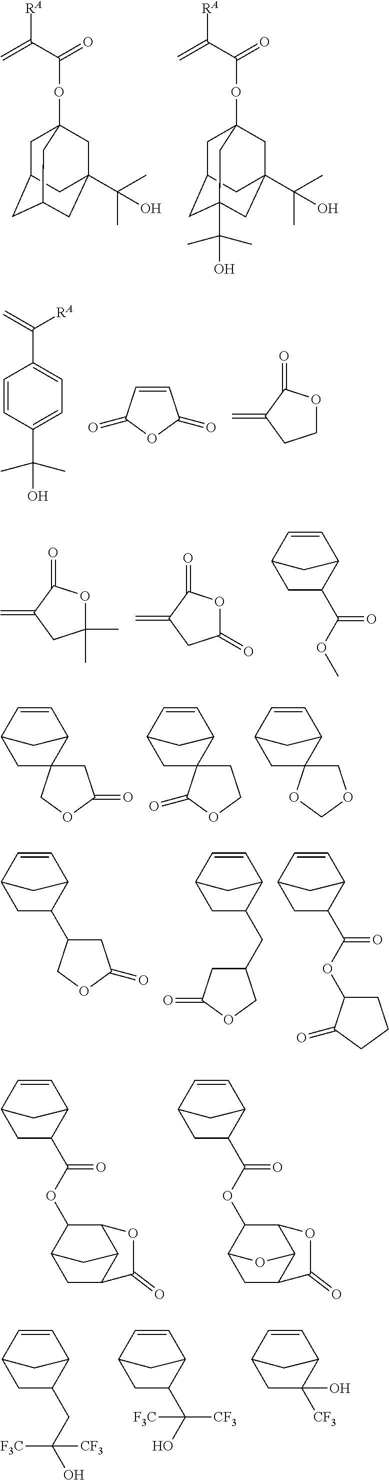

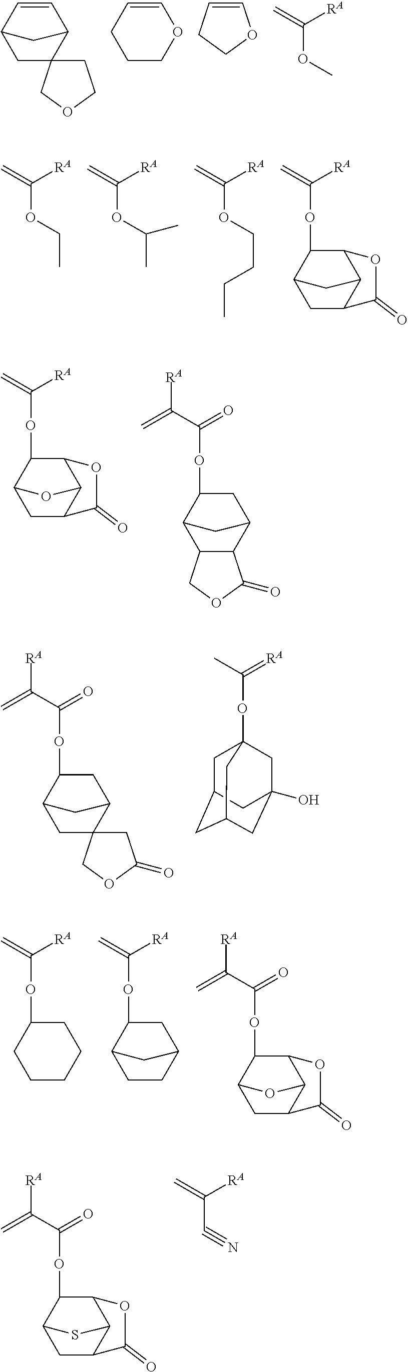

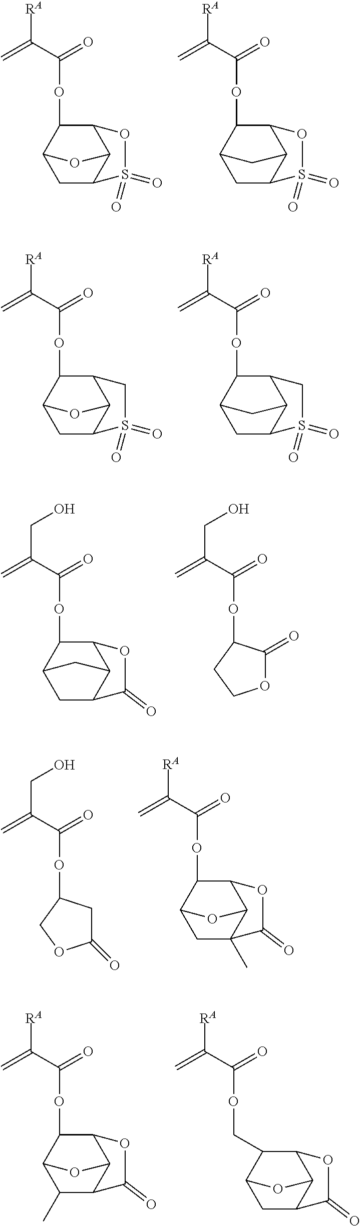

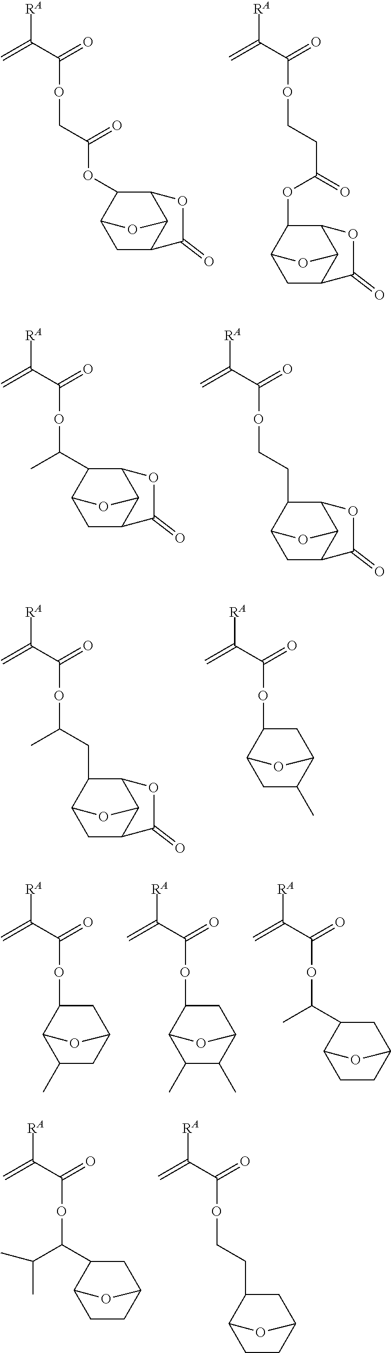

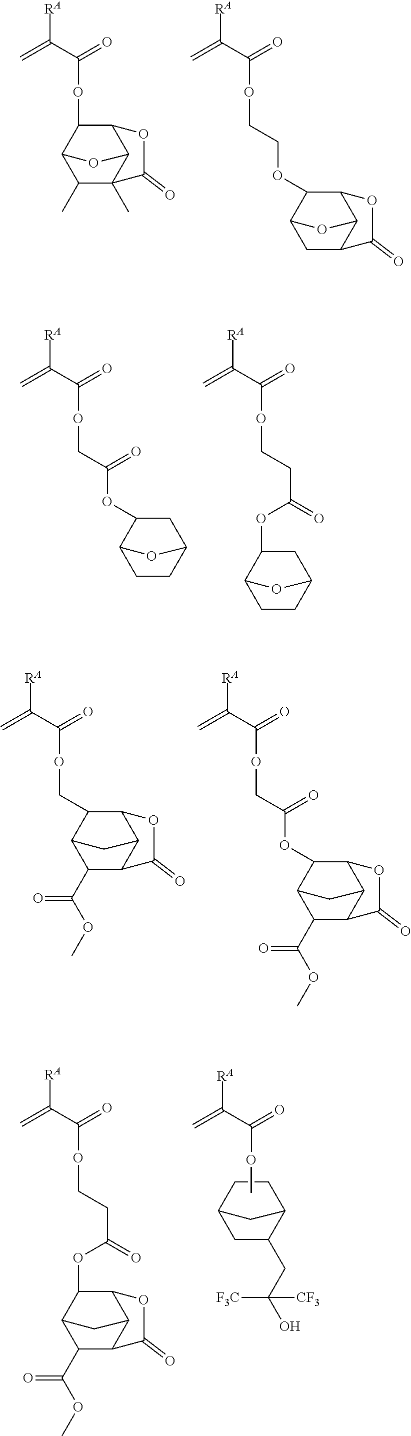

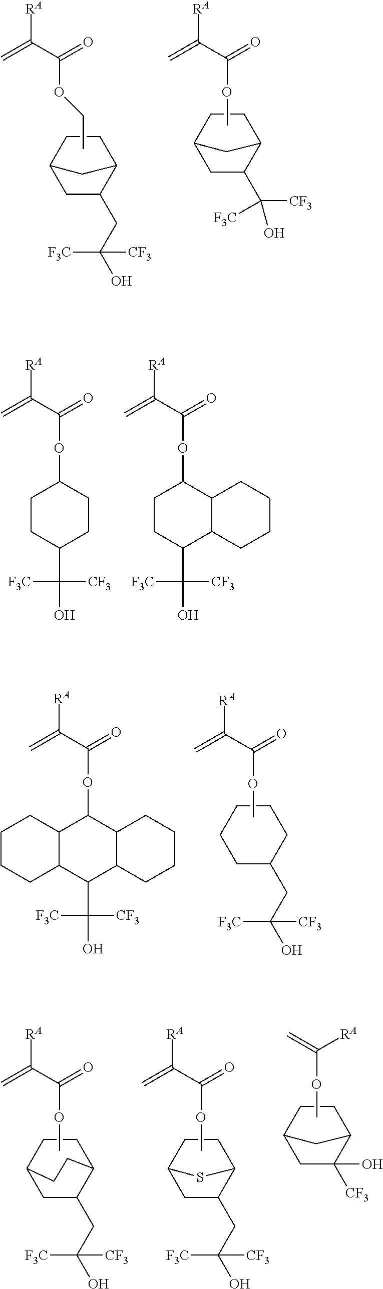

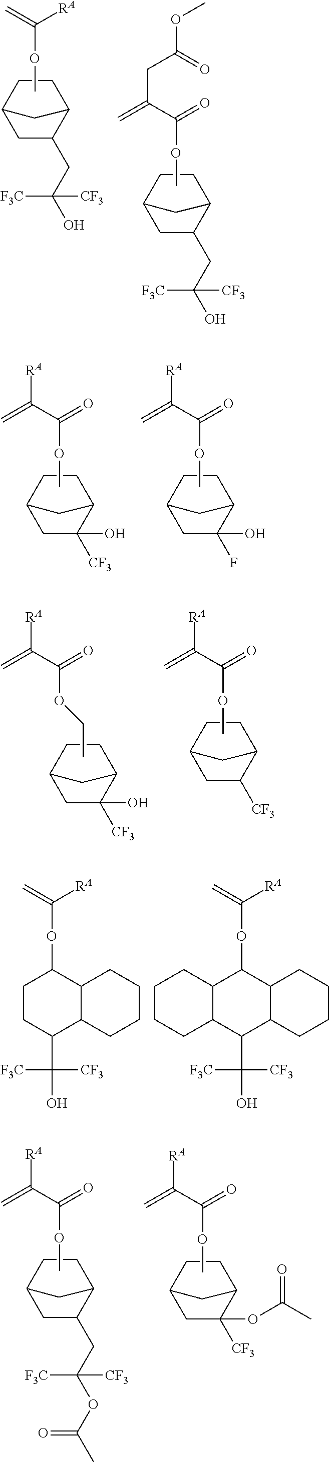

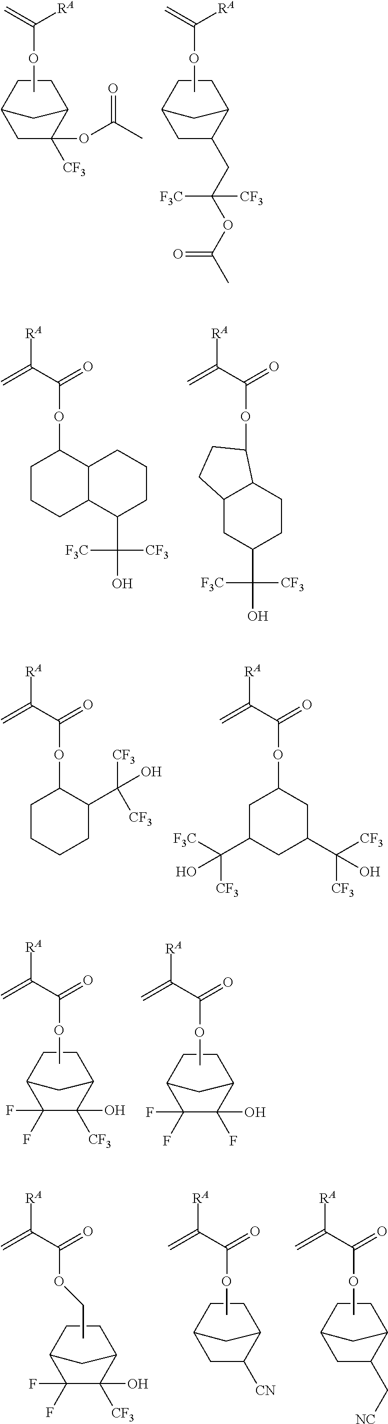

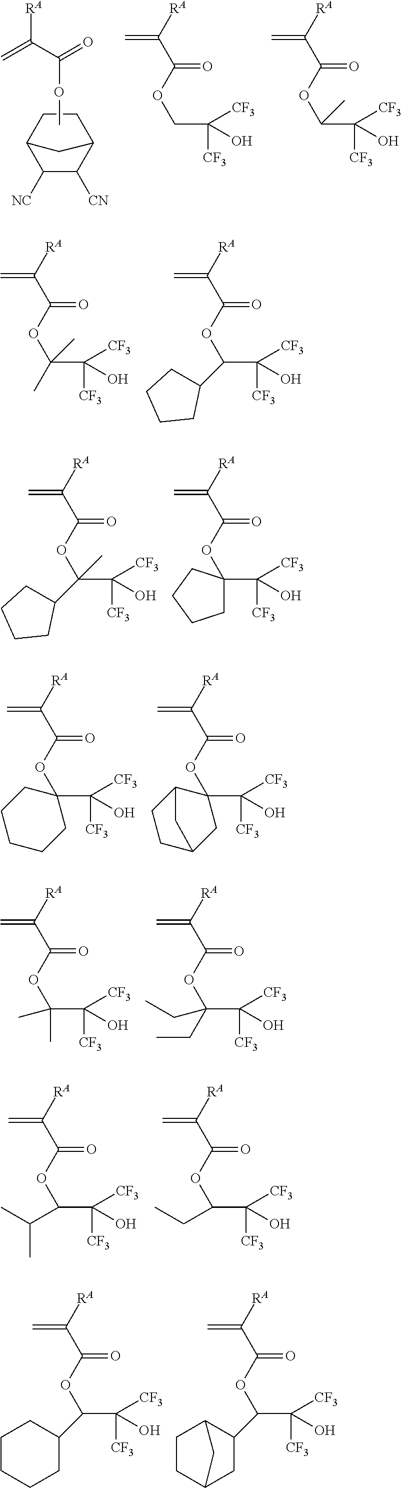

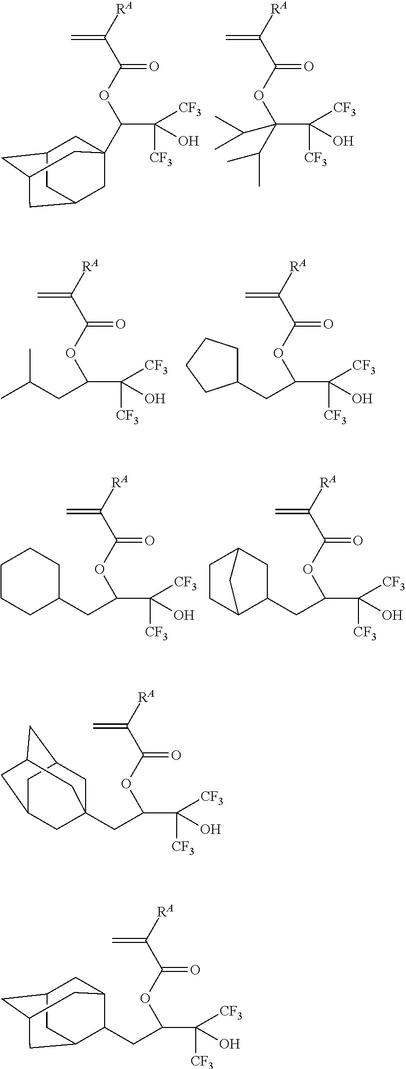

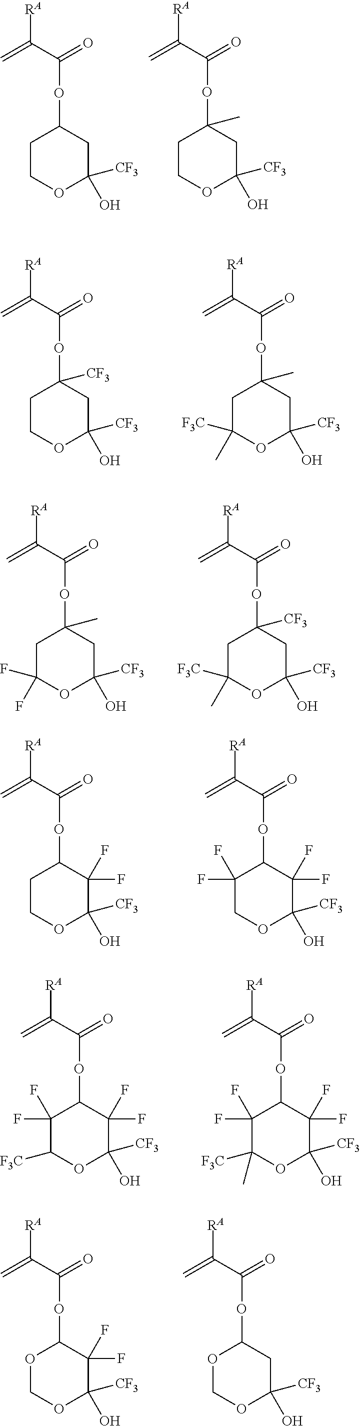

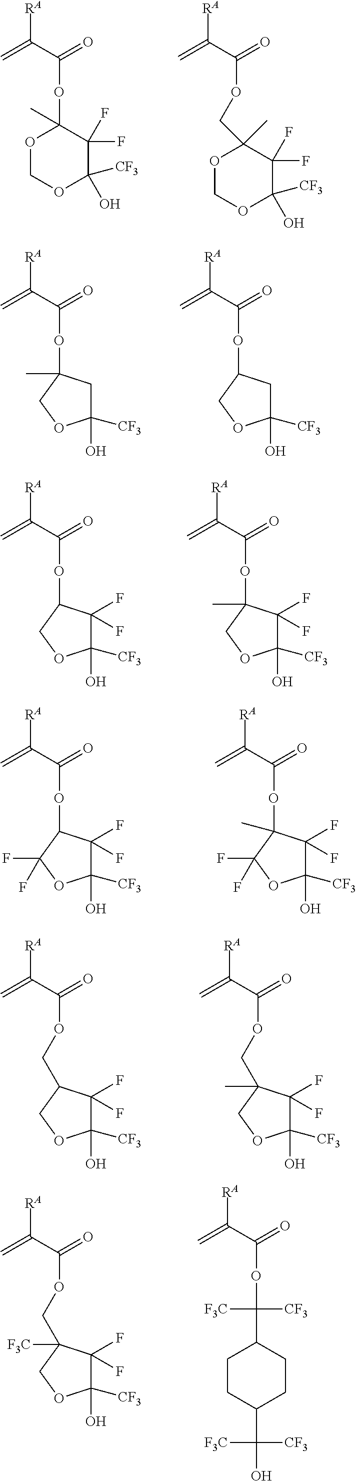

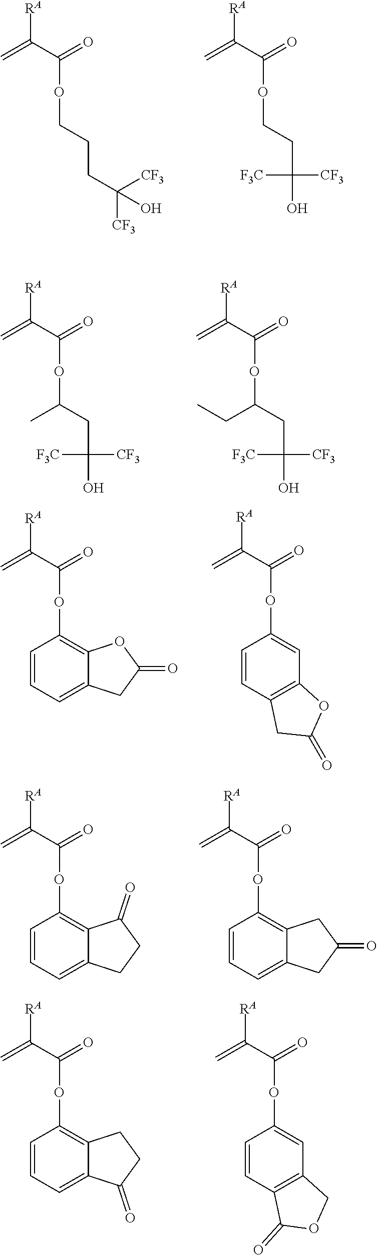

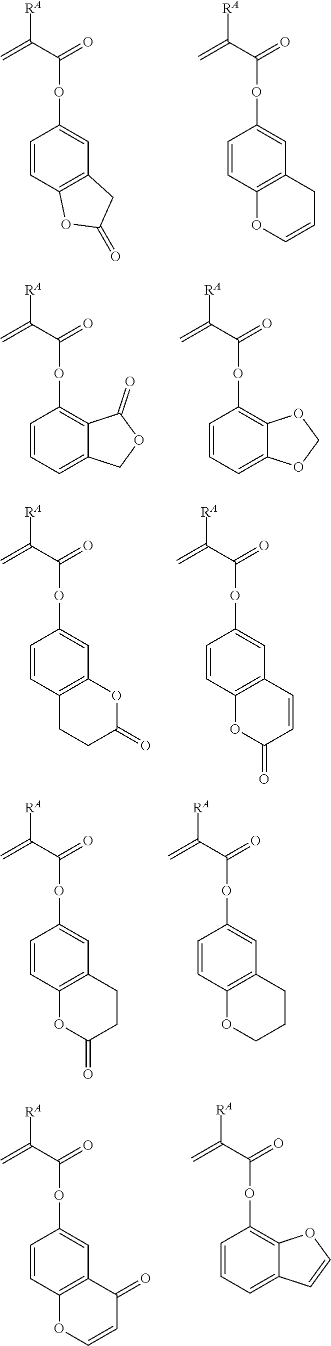

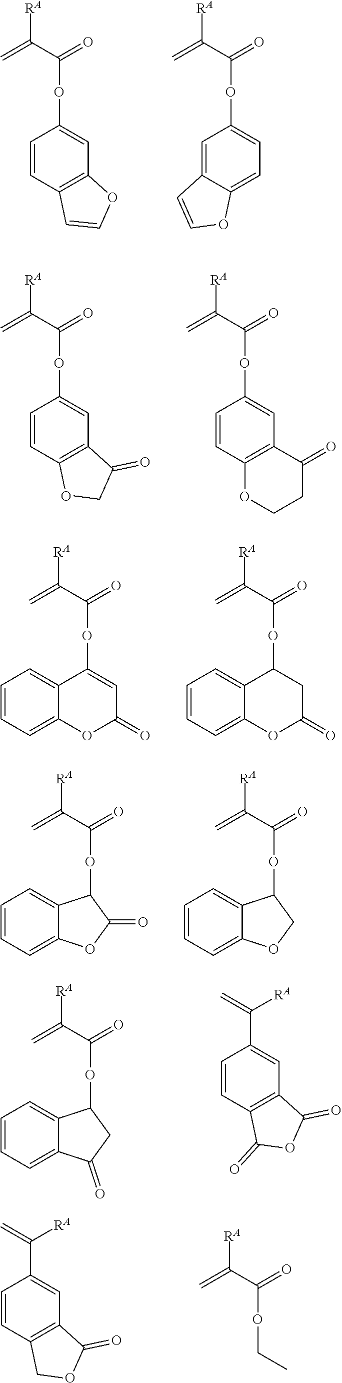

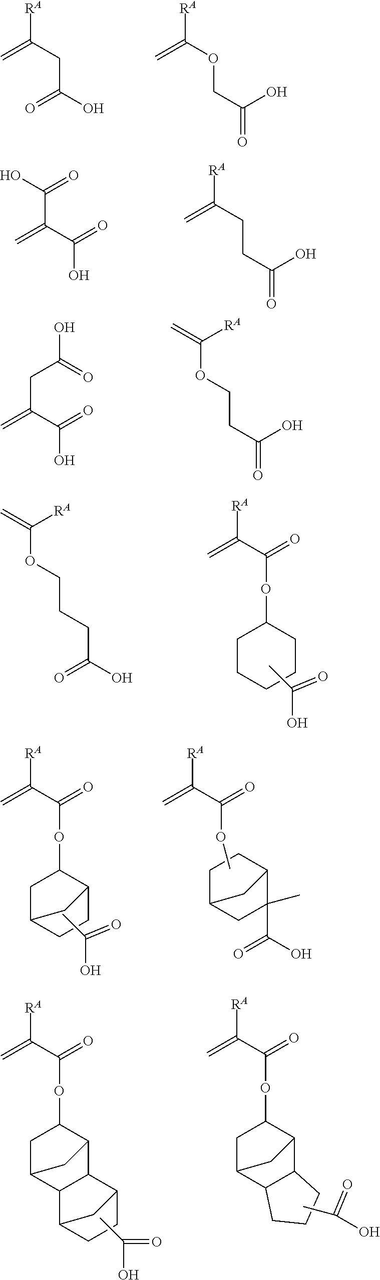

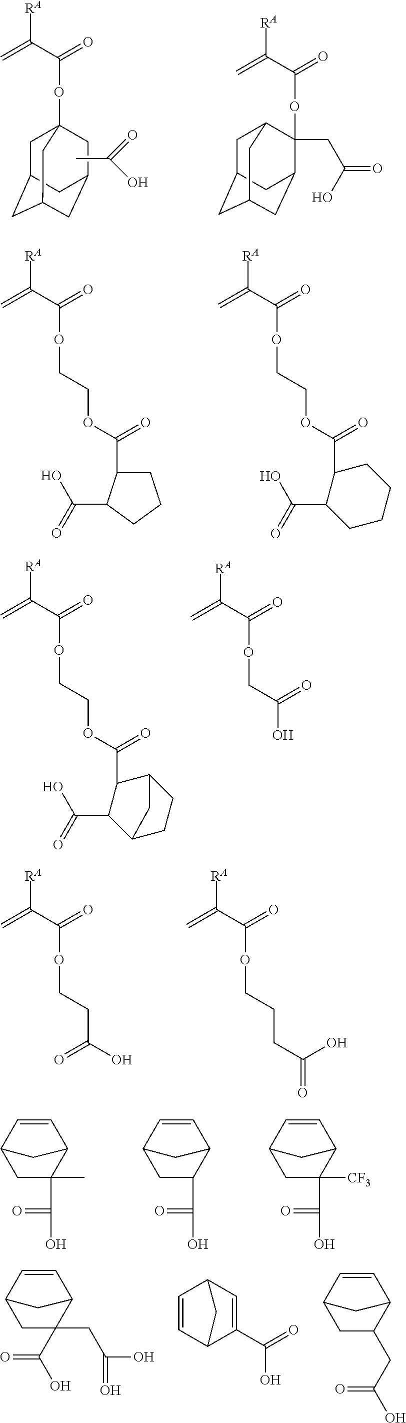

The base polymer may further contain repeat units (d) derived from styrene, indene, benzofuran, benzothiophene, acenaphthylene, chromone, coumarin, norbornadiene, or a derivative thereof. Examples of the monomer from which the repeat units (d) are derived include those shown below, but are not limited thereto. In the formulae, R^{A} is as defined above.

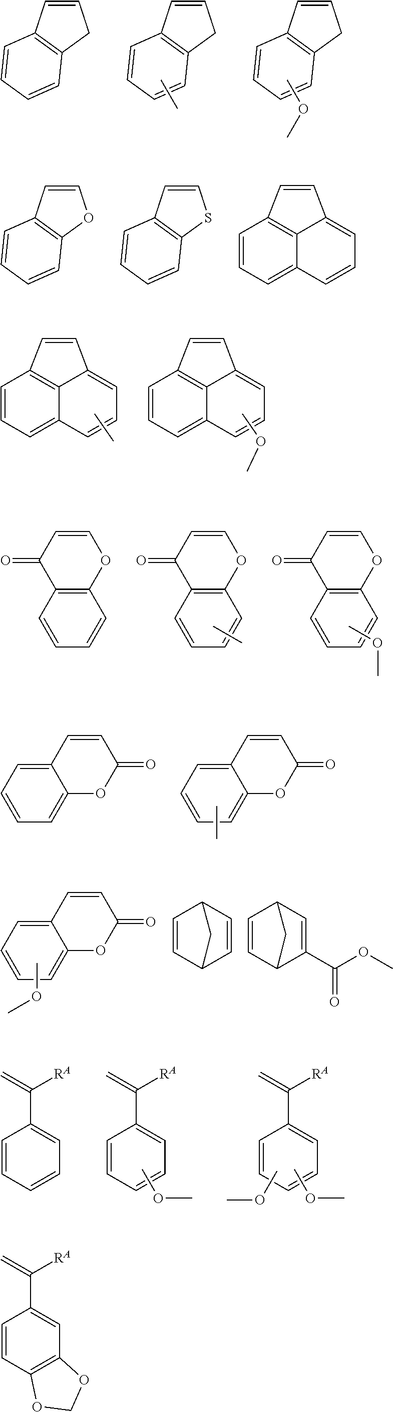

The base polymer may further contain repeat units (e) derived from vinylnaphthalene, vinylanthracene, vinylpyrene, methyleneindane, vinylpyridine, or vinylcarbazole.

The base polymer may further contain repeat units (f) derived from an onium salt containing a polymerizable olefin. Examples of the preferred repeat units (f) include repeat units having formula (f1) (hereinafter, the repeat units are also referred to as repeat units (f1)), repeat units having formula (f2) (hereinafter, the repeat units are also referred to as repeat units (f2)), and repeat units having formula (f3) (hereinafter, the repeat units are also referred to as repeat units (f3)). The repeat units (f1) to (f3) may each be used singly or in combination of two or more kinds thereof.

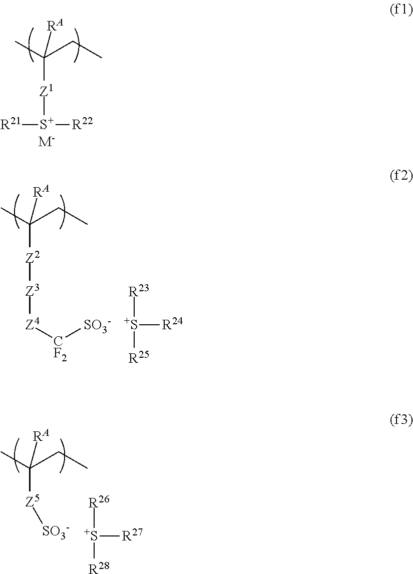

In formulae (f1) to (f3), R^{A} is each independently a hydrogen atom or a methyl group. Z¹ is a single bond, a C₁-C₆ aliphatic hydrocarbylene group, a phenylene group, a naphthylene group, a C₇-C₁₈ group obtained by combining the foregoing, —O—Z¹¹—, —C(═O)—O—Z¹¹, or —C(═O)—NH—Z¹¹—. Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group. Z² is a single bond or an ester bond. Z³ is a single bond, —Z³¹—C(═O)—O—, —Z³¹—O—, or —Z³¹—O—C(═O)—. Z³¹ is a C₁-C₁₂ aliphatic hydrocarbylene group, a phenylene group, or a C₇-C₁₈ group obtained by combining the foregoing, which may contain a carbonyl group, an ester bond, an ether bond, an iodine atom, or a bromine atom. Z⁴ is a methylene group, a 2,2,2-trifluoro-1,1-ethanediyl group, or a carbonyl group. Z⁵ is a single bond, a methylene group, an ethylene group, a phenylene group, a fluorinated phenylene group, a trifluoromethyl-substituted phenylene group, —O—Z⁵¹—, —C(═O)—O—Z⁵¹—, or —C(═O)—NH—Z⁵¹—. Z⁵¹ is a C₁-C₆ aliphatic hydrocarbylene group, a phenylene group, a fluorinated phenylene group, or a trifluoromethyl-substituted phenylene group, which may contain a carbonyl group, an ester bond, an ether bond, a hydroxy group, or a halogen atom.

In formulae (f1) to (f3), R²¹ to R²⁸ are each independently a halogen atom, or a C₁-C₂₀ hydrocarbyl group which may contain a heteroatom.

Examples of the halogen atom represented by R²¹ to R²⁸ include a fluorine atom, a chlorine atom, a bromine atom, and an iodine atom.

The hydrocarbyl group represented by R²¹ to R²⁸ may be saturated or unsaturated, and may be straight, branched, or cyclic. Examples thereof include C₁-C₂₀ alkyl groups such as a methyl group, an ethyl group, a n-propyl group, an isopropyl group, a n-butyl group, an isobutyl group, a sec-butyl group, a tert-butyl group, a n-pentyl group, a n-hexyl group, a n-octyl group, a n-nonyl group, a n-decyl group, an undecyl group, a dodecyl group, a tridecyl group, a tetradecyl group, a pentadecyl group, a heptadecyl group, an octadecyl group, a nonadecyl group, and an icosyl group; C₃-C₂₀ cyclic saturated hydrocarbyl groups such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; C₂-C₂₀ alkenyl groups such as a vinyl group, a propenyl group, a butenyl group, and a hexenyl group; C₂-C₂₀ alkynyl groups such as an ethynyl group, a propynyl group, and a butynyl group; C₃-C₂₀ cyclic unsaturated aliphatic hydrocarbyl groups such as a cyclohexenyl group and a norbornenyl group; C₆-C₂₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butylnaphthyl group, an isobutylnaphthyl group, a sec-butylnaphthyl group, and a tert-butylnaphthyl group; C₇-C₂₀ aralkyl groups such as a benzyl group and a phenethyl group; and groups obtained by combining the foregoing.

Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group.

R²³ and R²⁴ or R²⁶ and R²⁷ may bond together to form a ring together with the sulfur atom to which they are bonded. The ring preferably has the following structure.

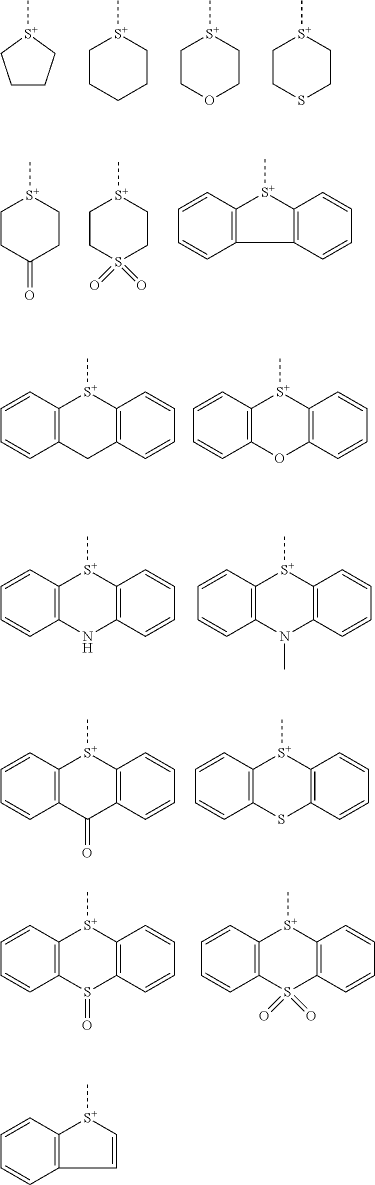

In the formulae, a broken line designates a bond with R²⁵ or R²⁸.

In formula (f1), M⁻ is a non-nucleophilic counter ion. Examples of the non-nucleophilic counter ion include halide ions such as a chloride ion and a bromide ion; fluoroalkylsulfonate ions such as a triflate ion, a 1,1,1-trifluoroethanesulfonate ion, and a nonafluorobutanesulfonate ion; arylsulfonate ions such as a tosylate ion, a benzenesulfonate ion, a 4-fluorobenzenesulfonate ion, and a 1,2,3,4,5-pentafluorobenzenesulfonate ion; alkylsulfonate ions such as a mesylate ion and a butanesulfonate ion; imide ions such as a bis(trifluoromethylsulfonyl)imide ion, a bis(perfluoroethylsulfonyl)imide ion, and a bis(perfluorobutylsulfonyl)imide ion; and methide ions such as a tris(trifluoromethylsulfonyl)methide ion and a tris(perfluoroethylsulfonyl)methide ion.

Examples of the non-nucleophilic counter ion further include sulfonate ions having a fluorine atom substituted at the α-position as represented by formula (f1-1) and sulfonate ions having a fluorine atom substituted at the α-position and a trifluoromethyl group substituted at the β-position as represented by formula (f1-2).

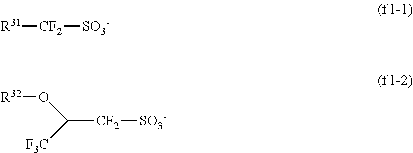

In formula (f1-1), R³¹ is a hydrogen atom, or a C₁-C₂₀ hydrocarbyl group which may contain an ether bond, an ester bond, a carbonyl group, a lactone ring, or a fluorine atom.

In formula (f1-2), R³² is a hydrogen atom, a C₁-C₃₀ hydrocarbyl group, or a C₂-C₃₀ hydrocarbylcarbonyl group, and the hydrocarbyl group and the hydrocarbylcarbonyl group may contain an ether bond, an ester bond, a carbonyl group, or a lactone ring.

In R³¹ and R³², the hydrocarbyl group and the hydrocarbyl moiety in the hydrocarbylcarbonyl group may be saturated or unsaturated, and may be straight, branched, or cyclic. Examples thereof include alkyl groups such as a methyl group, an ethyl group, a n-propyl group, an isopropyl group, a n-butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosyl group; cyclic saturated hydrocarbyl groups such as a cyclopentyl group, a cyclohexyl group, a 1-adamantyl group, a 2-adamantyl group, a 1-adamantylmethyl group, a norbornyl group, a norbornylmethyl group, a tricyclodecyl group, a tetracyclododecyl group, a tetracyclododecylmethyl group, and a dicyclohexylmethyl group; alkenyl groups such as an allyl group; cyclic unsaturated hydrocarbyl groups such as a 3-cyclohexenyl group; aryl groups such as a phenyl group, a 1-naphthyl group, and a 2-naphthyl group; aralkyl groups such as a benzyl group and a diphenylmethyl group; and groups obtained by combining the foregoing.

Some or all of hydrogen atoms of the hydrocarbyl group and the hydrocarbylcarbonyl group may be substituted with a group containing a heteroatom such as an oxygen atom, a sulfur atom, a nitrogen atom, or a halogen atom, and some of —CH₂— of the hydrocarbyl group and the hydrocarbylcarbonyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. Examples of the heteroatom-containing hydrocarbyl group include a tetrahydrofuryl group, a methoxymethyl group, an ethoxymethyl group, a methylthiomethyl group, an acetamidomethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group.

Examples of the cation in the monomer from which the repeat units (f1) are derived include those shown below, but are not limited thereto. In the formulae, R^{A} is as defined above.

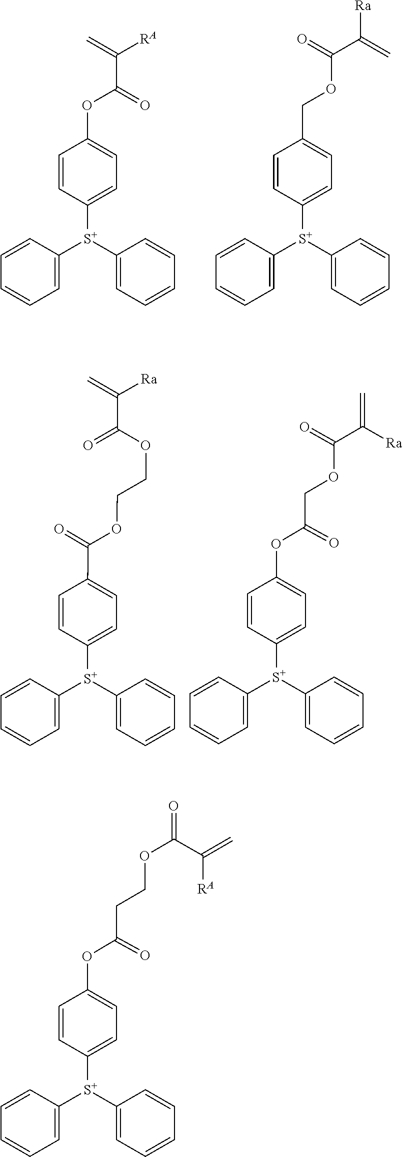

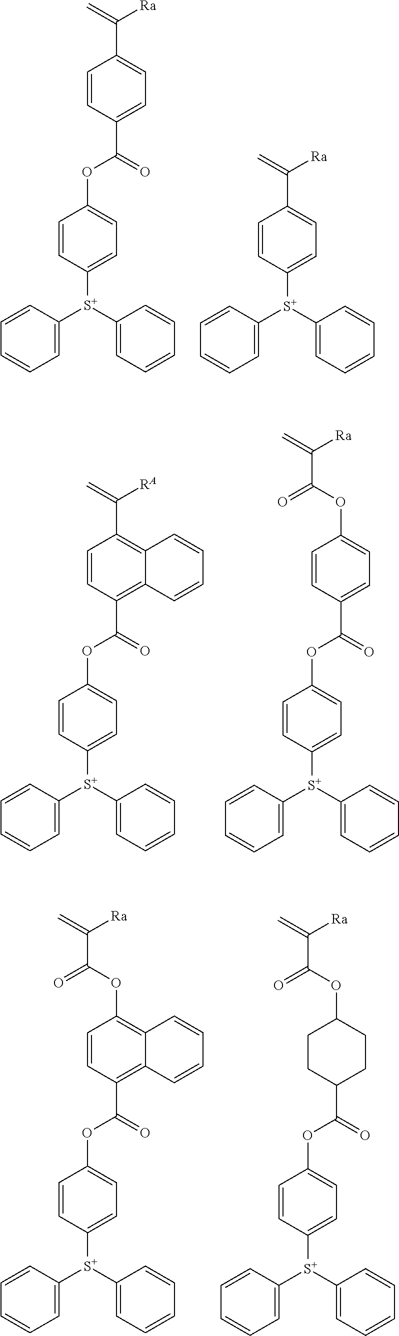

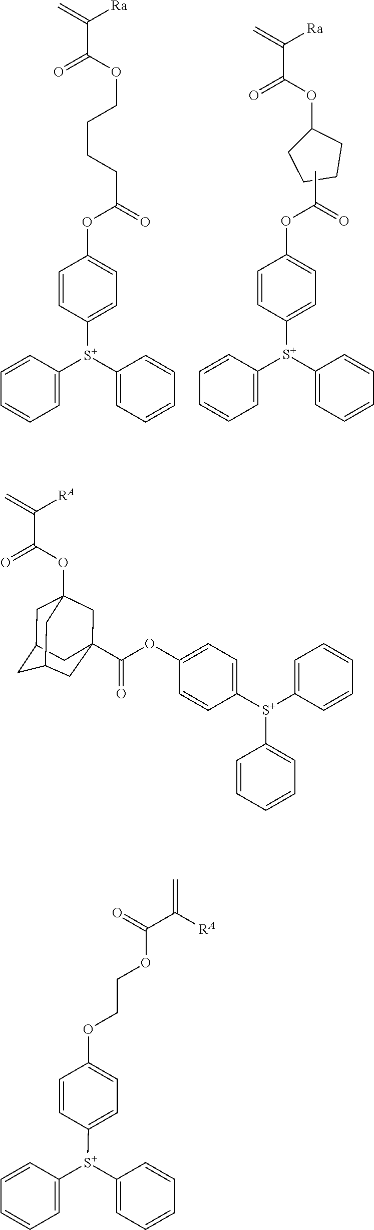

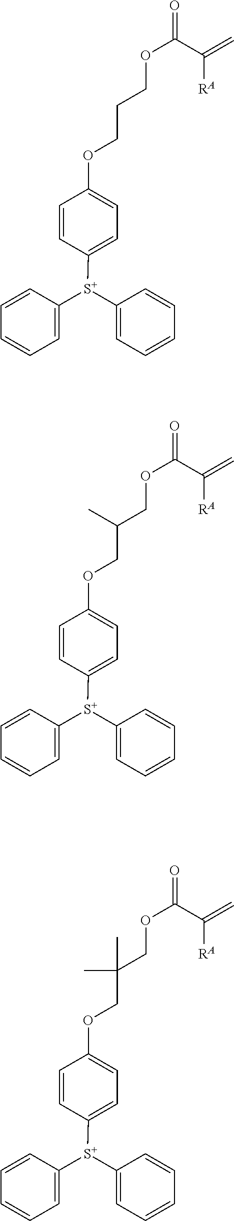

Examples of the cation in the monomer from which the repeat units (f2) or (f3) are derived include the sulfonium cation represented by formula (1) and those groups mentioned as the cation of the sulfonium salt represented by formula (1-1) as described in JP-A 2022-125970.

Examples of the anion in the monomer from which the repeat units (f2) are derived include those shown below, but are not limited thereto. In the formulae, R^{A} is as defined above.

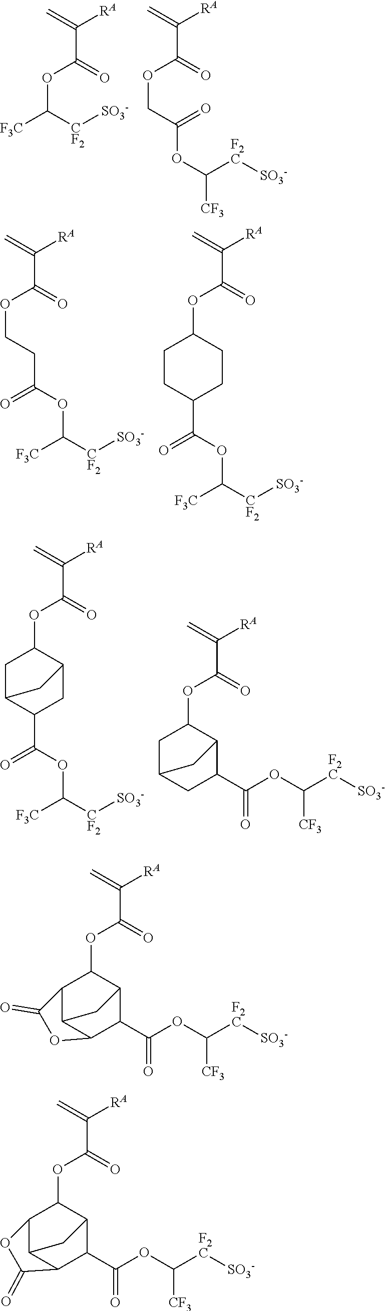

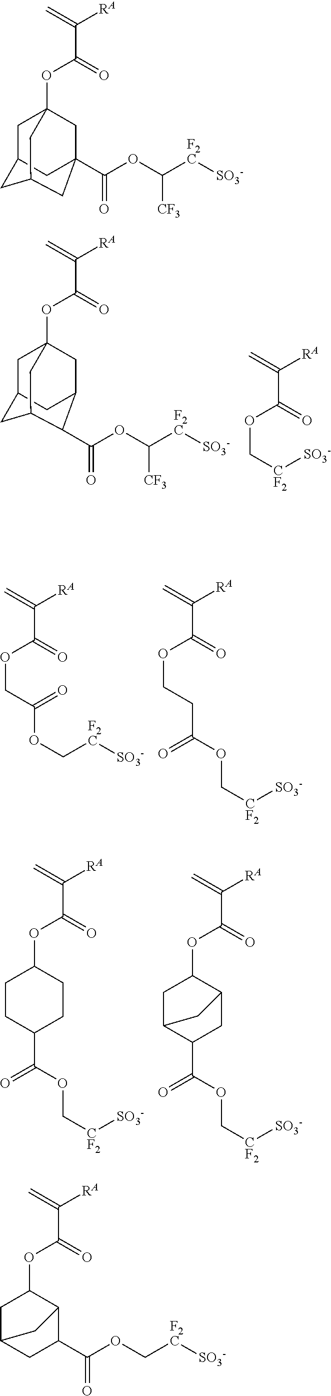

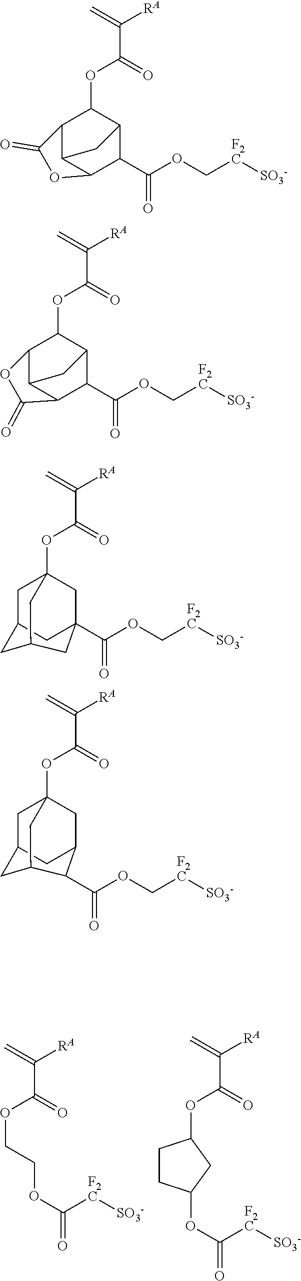

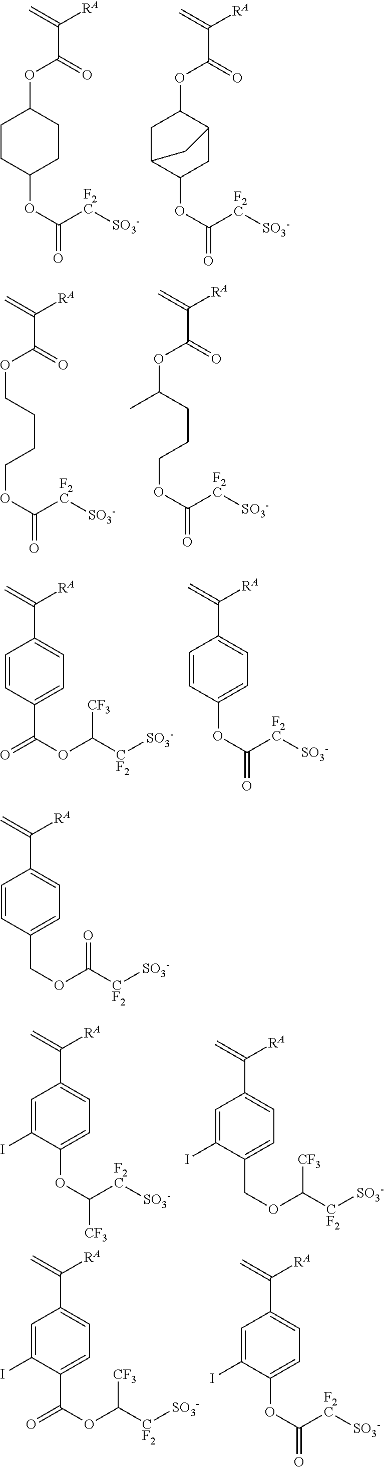

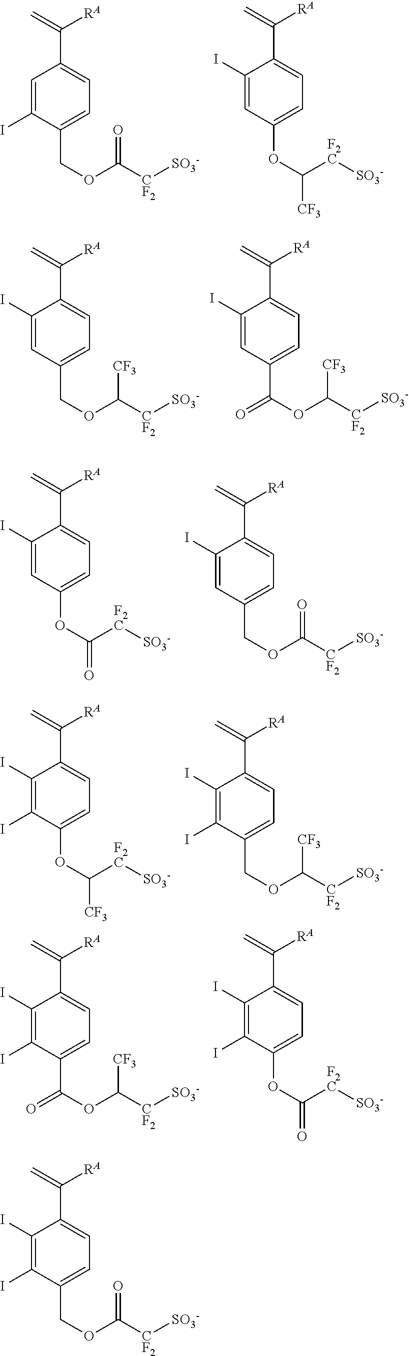

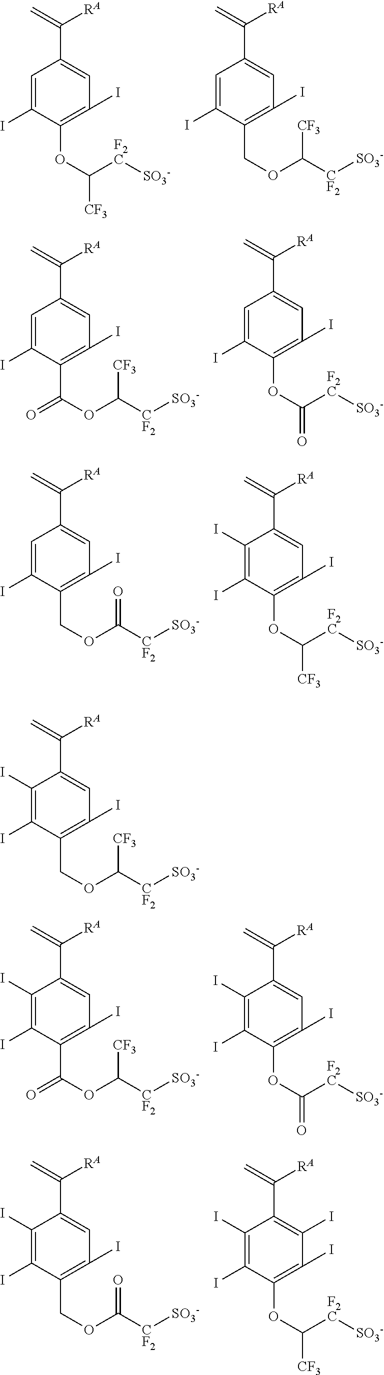

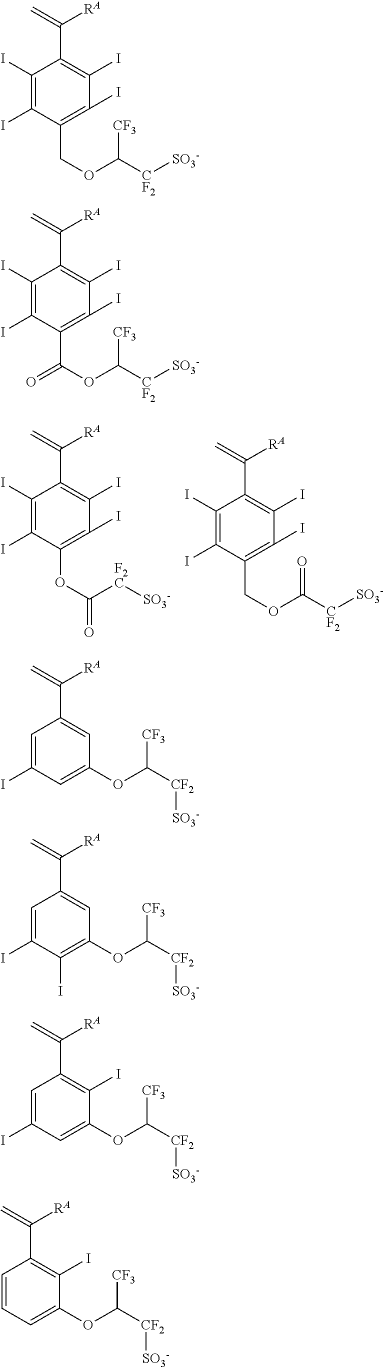

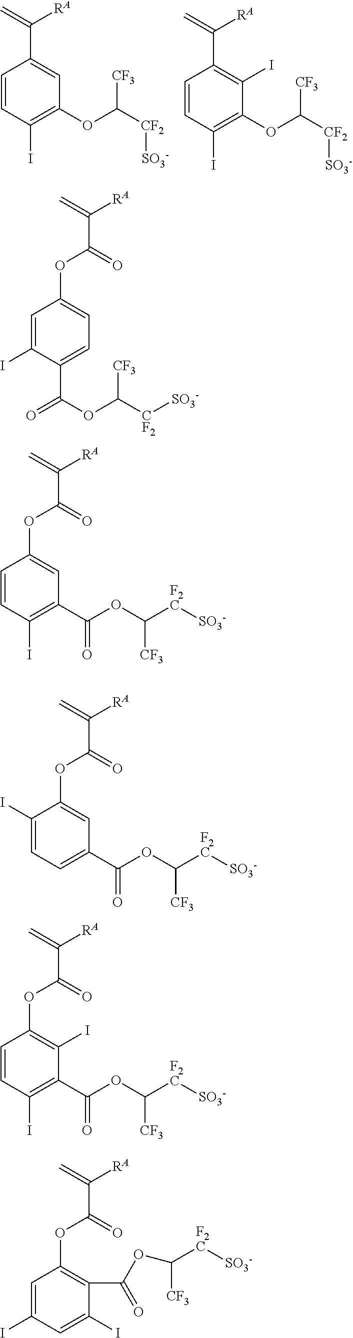

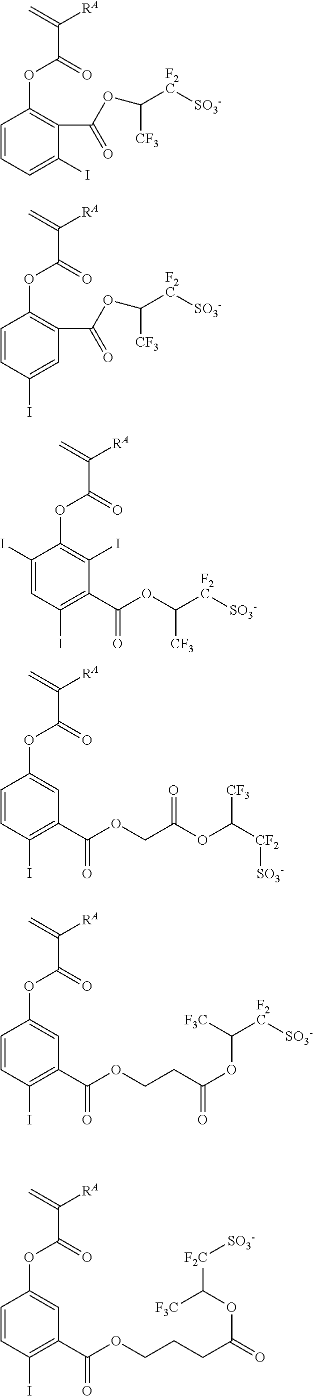

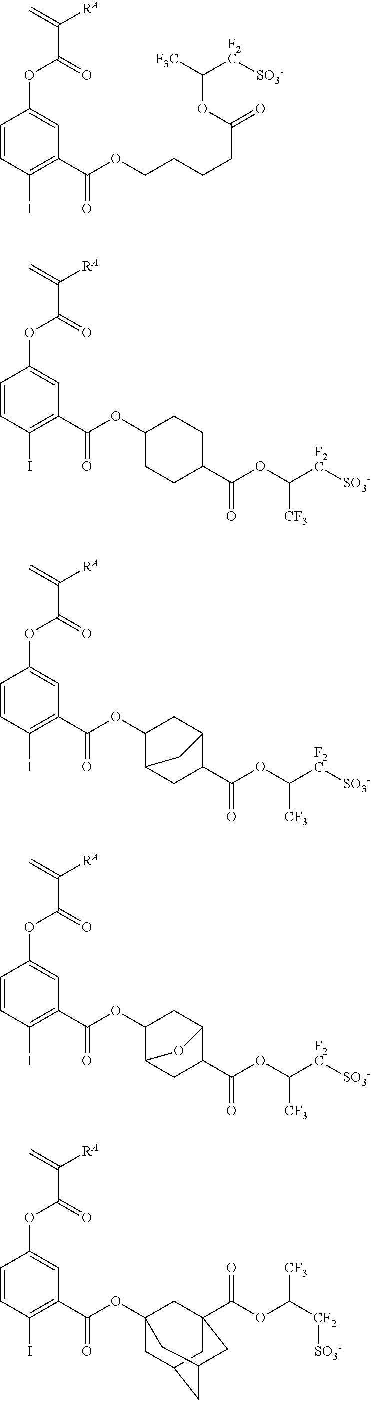

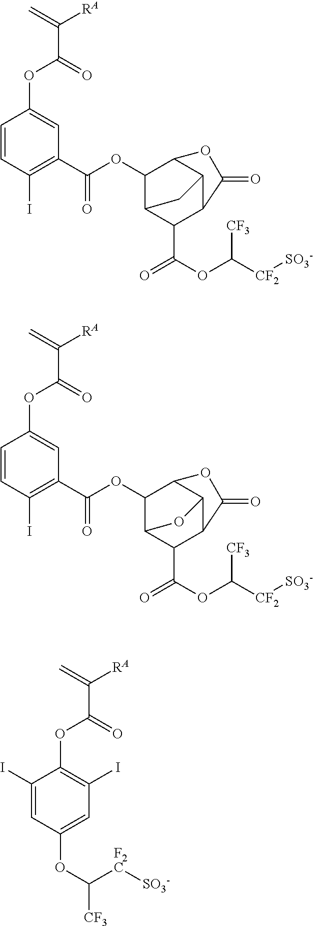

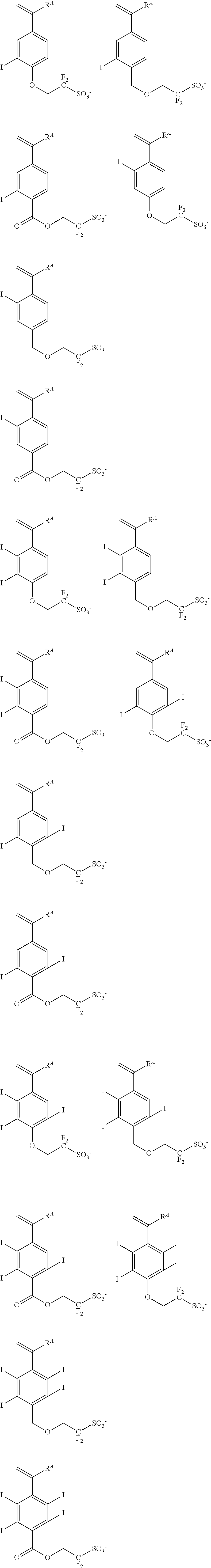

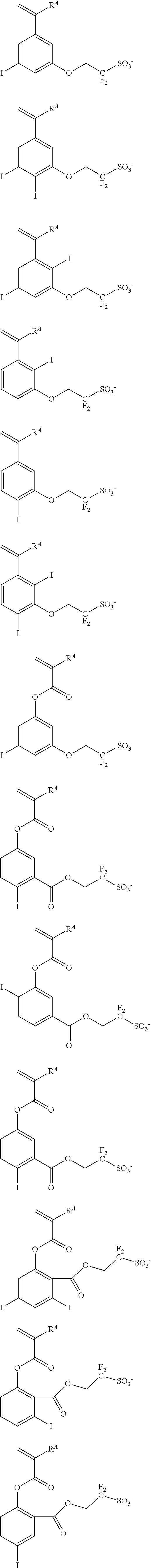

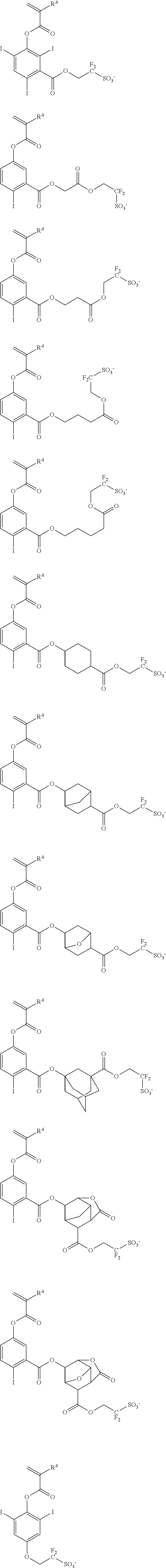

Examples of the anion in the monomer from which the repeat units (f3) are derived include those shown below, but are not limited thereto. In the formulae, R^{A} is as defined above.

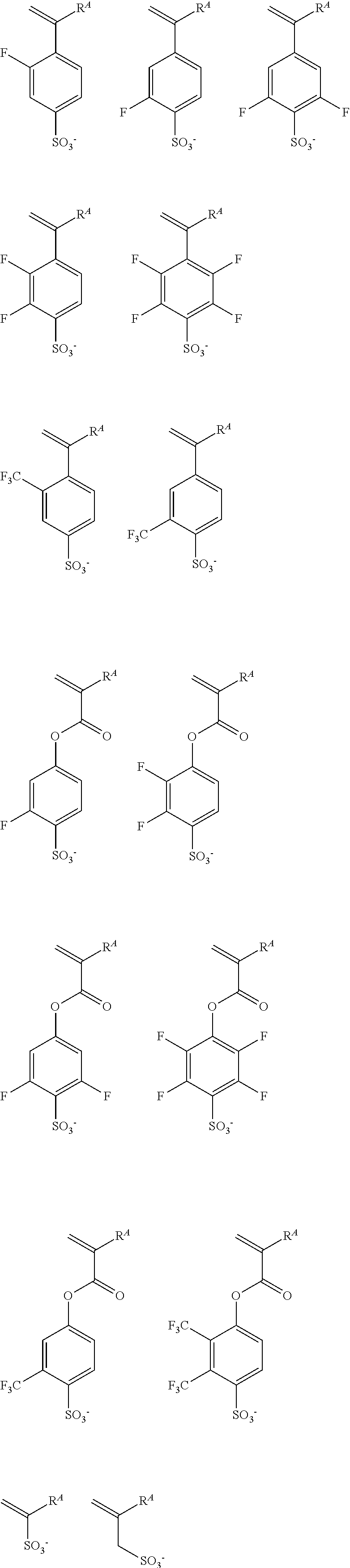

Bonding an acid generator to the polymer backbone is effective in restraining acid diffusion, thereby preventing a reduction of resolution due to blur by acid diffusion. In addition, the LWR and CDU are improved since the acid generator is uniformly distributed.

The base polymer for a positive resist composition essentially contains the repeat units (a1) or (a2) each containing an acid labile group. In this case, the fractions of the repeat units (a1), (a2), (b), (c), (d), (e), and (f) are preferably 0≤(a1)<1.0, 0≤(a2)<1.0, 0<(a1)+(a2)<1.0, 0≤(b)≤0.9, 0≤(c)≤0.9, 0≤(d)≤0.8, 0≤(e)≤0.8, and 0≤(f)≤0.5, more preferably 0≤(a1)≤0.9, 0≤(a2)≤0.9, 0.1≤(a1)+(a2)≤0.9, 0≤(b)≤0.8, 0≤(c)≤0.8, 0≤(d)≤0.7, 0≤(e)≤0.7, and 0≤(f)≤0.4, and even more preferably 0≤(a1)≤0.8, 0≤(a2)≤0.8, 0.1≤(a1)+(a2)≤0.8, 0≤(b)≤0.75, 0≤(c)≤0.75, 0≤(d)≤0.6, 0≤(e)≤0.6, and 0≤(f)≤0.3. The repeat units (f) satisfy (f)=(f1)+(f2)+(f3) when they are at least one selected from the repeat units (f1) to (f3). In addition, (a1)+(a2)+(b)+(c)+(d)+(e)+(f)=1.0.

Meanwhile, the base polymer for a negative resist composition does not necessarily contain an acid labile group. Examples of such a base polymer include those containing the repeat units (b) and further containing the repeat units (c), (d), (e), and/or (f) as necessary. The fractions of these repeat units are preferably 0<(b)≤1.0, 0≤(c)≤0.9, 0≤(d)≤0.8, 0≤(e)≤0.8, and 0≤(f)≤0.5, more preferably 0.2≤(b)≤1.0, 0≤(c)≤0.8, 0≤(d)≤0.7, 0≤(e)≤0.7, and 0≤(f)≤0.4, and even more preferably 0.3≤(b)≤1.0, 0≤(c)≤0.75, 0≤(d)≤0.6, 0≤(e)≤0.6, and 0≤(f)≤0.3. The repeat units (f) satisfy (f)=(f1)+(f2)+(f3) when they are at least one selected from the repeat units (f1) to (f3). In addition, (b)+(c)+(d)+(e)+(f)=1.0.

The base polymer may be synthesized, for example, by heating a monomer from which the repeat units are derived in an organic solvent with the addition of a radical polymerization initiator to perform polymerization.

Examples of the organic solvent used in the polymerization include toluene, benzene, tetrahydrofuran (THF), diethyl ether, and dioxane. Examples of the polymerization initiator include 2,2′-azobisisobutyronitrile (AIBN), 2,2′-azobis(2,4-dimethylvaleronitrile), dimethyl-2,2-azobis(2-methylpropionate), benzoyl peroxide, and lauroyl peroxide. The temperature during polymerization is preferably 50 to 80° C. The reaction time is preferably 2 to 100 hours, and more preferably 5 to 20 hours.

When a monomer having a hydroxy group is copolymerized, the hydroxy group may be substituted with an acetal group susceptible to deprotection with an acid such as an ethoxyethoxy group prior to polymerization, and the polymerization be followed by deprotection with a weak acid and water. Alternatively, the hydroxy group may be substituted with an acetyl group, a formyl group, a pivaloyl group or the like prior to polymerization, and the polymerization be followed by alkaline hydrolysis.

When hydroxystyrene or hydroxyvinylnaphthalene is copolymerized, acetoxystyrene or acetoxyvinylnaphthalene may be used instead of hydroxystyrene or hydroxyvinylnaphthalene, and after polymerization, the acetoxy group may be deprotected by alkaline hydrolysis for converting the polymer product to hydroxystyrene or hydroxyvinylnaphthalene.

For alkaline hydrolysis, a base such as aqueous ammonia or triethylamine may be used. The reaction temperature is preferably −20 to 100° C., and more preferably 0 to 60° C. The reaction time is preferably 0.2 to 100 hours, and more preferably 0.5 to 20 hours.

The base polymer preferably has a weight average molecular weight (Mw) in the range of 1,000 to 500,000, and more preferably 2,000 to 30,000, as measured by gel permeation chromatography (GPC) versus polystyrene standards using a THF solvent. A Mw in the range ensures that the resist film has heat resistance and high solubility in an alkaline developer.

If the base polymer has a wide molecular weight distribution (Mw/Mn), which indicates the presence of lower and higher molecular weight polymer fractions, there is a possibility that foreign matters are left on the pattern or the pattern profile is degraded after exposure. The influences of Mw and Mw/Mn tend to be stronger as the pattern rule becomes finer. Therefore, the base polymer should preferably have a narrow dispersity (Mw/Mn) of 1.0 to 2.0, especially 1.0 to 1.5, in order to provide a resist composition suitable for micropatterning to a small feature size.

The base polymer may contain two or more polymers having different compositional ratios, Mw, and Mw/Mn.

Organic Solvent

The resist composition of the present invention may contain an organic solvent. The organic solvent is not particularly limited as long as the components described above and below are soluble therein. Examples of the organic solvent are described in paragraphs [0144] to [0145] of JP-A 2008-111103, and include ketones such as cyclohexanone, cyclopentanone, methyl-2-n-pentyl ketone, and 2-heptanone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone.

The organic solvent is preferably added to the resist composition of the present invention in an amount of 100 to 10,000 parts by weight, and more preferably 200 to 8,000 parts by weight per 100 parts by weight of the base polymer. The organic solvent may be used singly or as a mixture of two or more kinds thereof.

Quencher

The resist composition of the present invention may contain a quencher. The quencher refers to a compound capable of trapping the acid generated from the acid generator in the resist composition to prevent the acid from diffusing to the unexposed region.

Examples of the quencher include conventional basic compounds. Examples of the conventional basic compounds include primary, secondary, and tertiary aliphatic amines, mixed amines, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amide derivatives, imide derivatives, and carbamate derivatives. In particular, primary, secondary, and tertiary amine compounds described in paragraphs [0146] to [0164] of JP-A 2008-111103, particularly amine compounds having a hydroxy group, an ether bond, an ester bond, a lactone ring, a cyano group, or a sulfonic ester bond, and compounds having a carbamate group described in JP 3790649 are preferred. Addition of a basic compound may be effective for further reducing the diffusion rate of the acid in the resist film or correcting the pattern profile.

Examples of the quencher also include onium salts such as sulfonium salts, iodonium salts, and ammonium salts of sulfonic acids which are not fluorinated at the α-position, or carboxylic acids, as described in JP-A 2008-158339. While a sulfonic acid which is fluorinated at the α-position, imide acid, or methide acid is necessary for deprotecting the acid labile group of a carboxylic acid ester, an α-non-fluorinated sulfonic acid or a carboxylic acid is released by salt exchange with an α-non-fluorinated onium salt. The α-non-fluorinated sulfonic acid and carboxylic acid function as a quencher because they do not induce deprotection reaction.

Examples of such a quencher include a compound having formula (3) (an onium salt of an α-non-fluorinated sulfonic acid) and a compound having formula (4) (an onium salt of a carboxylic acid).

R¹⁰¹—SO₃⁻Mq⁺ (3)

R¹⁰²—CO₂⁻Mq⁺ (4)

In formula (3), R¹⁰¹ is a hydrogen atom or a C₁-C₄₀ hydrocarbyl group which may contain a heteroatom, exclusive of a hydrocarbyl group in which a hydrogen atom bonded to the carbon atom at the α-position of the sulfo group is substituted with a fluorine atom or a fluoroalkyl group.

The C₁-C₄₀ hydrocarbyl group may be saturated or unsaturated, and may be straight, branched, or cyclic. Examples thereof include C₁-C₄₀ alkyl groups such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group, and a n-decyl group; C₃-C₄₀ cyclic saturated hydrocarbyl groups such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group, and an adamantylmethyl group; C₂-C₄₀ alkenyl groups such as a vinyl group, an allyl group, a propenyl group, a butenyl group, and a hexenyl group; C₃-C₄₀ cyclic unsaturated aliphatic hydrocarbyl groups such as a cyclohexenyl group; C₆-C₄₀ aryl groups such as a phenyl group, a naphthyl group, alkylphenyl groups (e.g., a 2-methylphenyl group, a 3-methylphenyl group, a 4-methylphenyl group, a 4-ethylphenyl group, a 4-tert-butylphenyl group, and a 4-n-butylphenyl group), dialkylphenyl groups (e.g., a 2,4-dimethylphenyl group and a 2,4,6-triisopropylphenyl group), alkylnaphthyl groups (e.g., a methylnaphthyl group and an ethylnaphthyl group), and dialkylnaphthyl groups (e.g., a dimethylnaphthyl group and a diethylnaphthyl group); and C₇-C₄₀ aralkyl groups such as a benzyl group, a 1-phenylethyl group, and a 2-phenylethyl group.

Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a cyano group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. Examples of the heteroatom-containing hydrocarbyl group include heteroaryl groups such as a thienyl group; alkoxyphenyl groups such as a 4-hydroxyphenyl group, a 4-methoxyphenyl group, a 3-methoxyphenyl group, a 2-methoxyphenyl group, a 4-ethoxyphenyl group, a 4-tert-butoxyphenyl group, and a 3-tert-butoxyphenyl group; alkoxynaphthyl groups such as a methoxynaphthyl group, an ethoxynaphthyl group, a n-propoxynaphthyl group, and a n-butoxynaphthyl group; dialkoxynaphthyl groups such as a dimethoxynaphthyl group and a diethoxynaphthyl group; and aryloxoalkyl groups, typically 2-aryl-2-oxoethyl groups such as a 2-phenyl-2-oxoethyl group, a 2-(1-naphthyl)-2-oxoethyl group, and a 2-(2-naphthyl)-2-oxoethyl group.

In formula (4), R¹⁰² is a C₁-C₄₀ hydrocarbyl group which may contain a heteroatom. Examples of the hydrocarbyl group represented by R¹⁰² include those groups mentioned as the hydrocarbyl group represented by R¹⁰¹. Also included are fluorinated alkyl groups such as a trifluoromethyl group, a trifluoroethyl group, a 2,2,2-trifluoro-1-methyl-1-hydroxyethyl group, and a 2,2,2-trifluoro-1-(trifluoromethyl)-1-hydroxyethyl group; and fluorinated aryl groups such as a pentafluorophenyl group and a 4-trifluoromethylphenyl group.

In formulae (3) and (4), Mq⁺ is an onium cation. The onium cation is preferably a sulfonium cation, an iodonium cation, or an ammonium cation, and more preferably a sulfonium cation or an iodonium cation.

A sulfonium salt of iodized benzene ring-containing carboxylic acid having formula (5) is also suitable for the quencher.

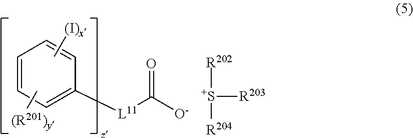

In formula (5), R²⁰¹ is a hydroxy group, a fluorine atom, a chlorine atom, a bromine atom, an amino group, a nitro group, a cyano group, or a C₁-C₆ saturated hydrocarbyl group, a C₁-C₆ saturated hydrocarbyloxy group, a C₂-C₆ saturated hydrocarbylcarbonyloxy group, or a C₁-C₄ saturated hydrocarbylsulfonyloxy group, in which some or all hydrogen atoms may be substituted with a halogen atom, —N(R^{201A})—C(═O)—R^{201B}, or —N(R^{201A})—C(═O)—O—R^{201B}, wherein R^{201A} is a hydrogen atom or a C₁-C₆ saturated hydrocarbyl group, and R^{201B} is a C₁-C₆ saturated hydrocarbyl group or a C₂-C₈ unsaturated aliphatic hydrocarbyl group.

In formula (5), x′ is an integer of 1 to 5. y′ is an integer of 0 to 3. z′ is an integer of 1 to 3. L¹¹ is a single bond, or a C₁-C₂₀ (z′+1)-valent linking group which may contain at least one moiety selected from an ether bond, a carbonyl group, an ester bond, an amide bond, a sultone ring, a lactam ring, a carbonate bond, a halogen atom, a hydroxy group, and a carboxy group. The saturated hydrocarbyl group, the saturated hydrocarbyloxy group, the saturated hydrocarbylcarbonyloxy group, and the saturated hydrocarbylsulfonyloxy group may be straight, branched, or cyclic. Groups R²⁰¹ may be identical or different when y′ and/or z′ is 2 or more.

In formula (5), R²⁰², R²⁰³, and R²⁰⁴ are each independently a halogen atom, or a C₁-C₂₀ hydrocarbyl group which may contain a heteroatom. The hydrocarbyl group may be saturated or unsaturated, and may be straight, branched, or cyclic. Examples thereof include those groups mentioned as the hydrocarbyl group represented by R²¹ to R²⁸ in the description of formulae (f1) to (f3). In these hydrocarbyl groups, some or all of hydrogen atoms may be substituted with a hydroxy group, a carboxy group, a halogen atom, an oxo group, a cyano group, a nitro group, a sultone ring, a sulfo group, or a sulfonium salt-containing group, and some constituent —CH₂— may be substituted with an ether bond, an ester bond, a carbonyl group, an amide bond, a carbonate bond, or a sulfonic ester bond. R²⁰² and R²⁰³ may bond together to form a ring together with the sulfur atom to which they are bonded.

Examples of the compound having formula (5) include compounds described in JP-A 2017-219836.

Examples of the quencher further include a polymeric quencher described in JP-A 2008-239918. The polymeric quencher segregates at the resist film surface and thus enhances the rectangularity of the resist pattern. When a protective film is applied as is often the case in immersion lithography, the polymeric quencher is also effective for preventing a film thickness loss of the resist pattern or rounding of the pattern top.

The quencher is preferably added to the resist composition of the present invention in an amount of 0 to 5 parts by weight, and more preferably 0 to 4 parts by weight per 100 parts by weight of the base polymer.

Other Components

In addition to the foregoing components, the resist composition of the present invention may contain other components such as an acid generator other than the sulfonium salt containing a sulfonic acid anion having a carbon atom to which an iodine atom is bonded and a sulfonium cation having formula (1) (hereinafter, the acid generator is referred to as another acid generator), a surfactant, a dissolution inhibitor, a crosslinker, a water repellency improver, and an acetylene alcohol.

Examples of the other acid generator include a compound that generates an acid in response to actinic rays or radiation (the compound is referred to as photoacid generator, PAG). Although the PAG may be any compound capable of generating an acid upon exposure to high-energy radiation, those compounds capable of generating a sulfonic acid, imide acid (imidic acid), or methide acid are preferred. Suitable PAGs include sulfonium salts, iodonium salts, sulfonyldiazomethane, N-sulfonyloxyimide, and oxime-O-sulfonate acid generators. Examples of the acid generator include those described in paragraphs [0122] to [0142] of JP-A 2008-111103, JP-A 2018-005224, and JP-A 2018-025789. The other acid generator is preferably added to the resist composition of the present invention in an amount of 0 to 200 parts by weight, and more preferably 0.1 to 100 parts by weight per 100 parts by weight of the base polymer. The other acid generator may be used singly or in combination of two or more kinds thereof.

Examples of the surfactant include those described in paragraphs [0165] to [0166] of JP-A 2008-111103. Addition of a surfactant may improve or control the coating characteristics of the resist composition. The surfactant is preferably added to the resist composition of the present invention in an amount of 0.0001 to 10 parts by weight per 100 parts by weight of the base polymer. The surfactant may be used singly or in combination of two or more kinds thereof.

In the embodiment wherein the resist composition of the present invention is of positive tone, the addition of a dissolution inhibitor may lead to an increased difference in dissolution rate between the exposed region and the unexposed region and a further improvement in resolution. Examples of the dissolution inhibitor include a compound having at least two phenolic hydroxy groups in the molecule, in which 0 to 100 mol % of all the hydrogen atoms in the phenolic hydroxy groups are substituted with acid labile groups or a compound having at least one carboxy group in the molecule, in which an average of 50 to 100 mol % of all the hydrogen atoms in the carboxy group are substituted with acid labile groups, both the compounds preferably having a molecular weight of 100 to 1,000, and more preferably 150 to 800. Examples thereof include bisphenol A, trisphenol, phenolphthalein, cresol novolac, naphthalenecarboxylic acid, adamantanecarboxylic acid, and cholic acid derivatives, in which the hydrogen atom in the hydroxy or carboxy group is substituted with an acid labile group, as described in paragraphs [0155] to [0178] of JP-A 2008-122932.

The dissolution inhibitor is preferably added to the resist composition of positive tone of the present invention in an amount of 0 to 50 parts by weight, and more preferably 5 to 40 parts by weight per 100 parts by weight of the base polymer. The dissolution inhibitor may be used singly or in combination of two or more kinds thereof.

When the resist composition of the present invention is of negative tone, a negative pattern can be obtained by adding a crosslinker to reduce the dissolution rate of a resist film in the exposed region. Examples of the crosslinker include epoxy compounds, melamine compounds, guanamine compounds, glycoluril compounds, and urea compounds having substituted thereon at least one group selected from a methylol group, an alkoxymethyl group, and an acyloxymethyl group, isocyanate compounds, azide compounds, and compounds having a double bond such as an alkenyloxy group. These compounds may be used as an additive or introduced into a polymer side chain as a pendant group. In addition, a compound containing a hydroxy group can also be used as a crosslinker.

Examples of the epoxy compound include tris(2,3-epoxypropyl) isocyanurate, trimethylolmethane triglycidyl ether, trimethylolpropane triglycidyl ether, and triethylolethane triglycidyl ether.

Examples of the melamine compound include hexamethylol melamine, hexamethoxymethyl melamine, hexamethylol melamine compounds having 1 to 6 methylol groups methoxymethylated and mixtures thereof, hexamethoxyethyl melamine, hexaacyloxymethyl melamine, and hexamethylol melamine compounds having 1 to 6 methylol groups acyloxymethylated and mixtures thereof.

Examples of the guanamine compound include tetramethylol guanamine, tetramethoxymethyl guanamine, tetramethylol guanamine compounds having 1 to 4 methylol groups methoxymethylated and mixtures thereof, tetramethoxyethyl guanamine, tetraacyloxyguanamine, and tetramethylol guanamine compounds having 1 to 4 methylol groups acyloxymethylated and mixtures thereof.

Examples of the glycoluril compound include tetramethylol glycoluril, tetramethoxy glycoluril, tetramethoxymethyl glycoluril, tetramethylol glycoluril compounds having 1 to 4 methylol groups methoxymethylated and mixtures thereof, and tetramethylol glycoluril compounds having 1 to 4 methylol groups acyloxymethylated and mixtures thereof. Examples of the urea compound include tetramethylol urea, tetramethoxymethyl urea, tetramethylol urea compounds having 1 to 4 methylol groups methoxymethylated and mixtures thereof, and tetramethoxyethyl urea.

Examples of the isocyanate compound include tolylene diisocyanate, diphenylmethane diisocyanate, hexamethylene diisocyanate, and cyclohexane diisocyanate.

Examples of the azide compound include 1,1′-biphenyl-4,4′-bisazide, 4,4′-methylidenebisazide, and 4,4′-oxybisazide.

Examples of the alkenyloxy group-containing compound include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylol propane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, and trimethylol propane trivinyl ether.

The crosslinker is preferably added to the resist composition of negative tone of the present invention in an amount of 0.1 to 50 parts by weight, and more preferably 1 to 40 parts by weight per 100 parts by weight of the base polymer. The crosslinker may be used singly or in combination of two or more kinds thereof.

The water repellency improver improves the water repellency of the surface of the resist film after spin coating, and can be used in the topcoatless immersion lithography. Examples of preferred water repellency improvers include polymers having a fluoroalkyl group and polymers having a specific structure with a 1,1,1,3,3,3-hexafluoro-2-propanol residue, and those described in JP-A 2007-297590 and JP-A 2008-111103, for example, are more preferred. The water repellency improver should be soluble in alkaline developers and organic solvent developers. The water repellency improver having a specific structure with a 1,1,1,3,3,3-hexafluoro-2-propanol residue is well soluble in the developer. A polymer having an amino group or amine salt copolymerized as repeat units may serve as the water repellency improver and is effective for preventing evaporation of the acid during PEB, thus preventing any hole pattern opening failure after development. The water repellency improver is preferably added to the resist composition of the present invention in an amount of 0 to 20 parts by weight, and more preferably 0.5 to 10 parts by weight per 100 parts by weight of the base polymer. The water repellency improver may be used singly or in combination of two or more kinds thereof.

Examples of the acetylene alcohol include those described in paragraphs [0179] to [0182] of JP-A 2008-122932. The acetylene alcohol is preferably added to the resist composition of the present invention in an amount of 0 to 5 parts by weight per 100 parts by weight of the base polymer. The acetylene alcohol may be used singly or in combination of two or more kinds thereof.

Pattern Forming Process

The resist composition of the present invention is used in the fabrication of various integrated circuits by a well-known lithography technique. Examples of the pattern forming process include a process comprising the steps of: applying the resist composition onto a substrate to form a resist film thereon, exposing the resist film to high-energy radiation, and developing the exposed resist film in a developer.

The resist composition of the present invention is first applied onto a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, MoSi₂, or SiO₂) by a suitable coating technique such as spin coating, roll coating, flow coating, dipping, spraying, or doctor coating so that the coating may have a thickness of 0.01 to 2 μm. The coating is prebaked on a hotplate preferably at a temperature of 60 to 150° C. for 10 seconds to 30 minutes, and more preferably at 80 to 120° C. for 30 seconds to 20 minutes to form a resist film.

The resist film is then exposed to high-energy radiation such as UV, deep-UV, EB, EUV having a wavelength of 3 to 15 nm, X-rays, soft X-rays, excimer laser, γ-rays, or synchrotron radiation. When UV, deep-UV, EUV, X-rays, soft X-rays, excimer laser, γ-rays, or synchrotron radiation is used as the high-energy radiation, the resist film is exposed thereto directly or through a mask having a desired pattern preferably at a dose of about 1 to 200 mJ/cm², and more preferably about 10 to 100 mJ/cm². When EB is used as the high-energy radiation, the resist film is exposed thereto directly or through a mask having a desired pattern preferably at a dose of about 0.1 to 300 μC/cm², and more preferably about 0.5 to 200 μC/cm². It is appreciated that the resist composition of the present invention is suitable for micropatterning using high-energy radiation such as KrF excimer laser, ArF excimer laser, EB, EUV, X-rays, soft X-rays, γ-rays, or synchrotron radiation, especially for micropatterning using EB or EUV.

After the exposure, the resist film may be baked (PEB) on a hotplate or in an oven preferably at 30 to 150° C. for 10 seconds to 30 minutes, and more preferably at 50 to 120° C. for 30 seconds to 20 minutes.

After the exposure or PEB, the resist film is developed in a developer in the form of an alkaline aqueous solution for 3 seconds to 3 minutes, preferably 5 seconds to 2 minutes by conventional techniques such as dip, puddle, and spray techniques, so that the resist film in the exposed region is dissolved in the developer whereas the resist film in the unexposed region is not dissolved, and a desired pattern is formed on the substrate. A preferred developer is a 0.1 to 10 wt %, more preferably 2 to 5 wt % aqueous solution of tetramethylammonium hydroxide (TMAH), tetraethylammonium hydroxide (TEAH), tetrapropylammonium hydroxide (TPAH), or tetrabutylammonium hydroxide (TBAH). In the case of a positive resist composition, the resist film in the exposed region is dissolved in the developer whereas the resist film in the unexposed region is not dissolved. In this way, the desired positive pattern is formed. In the case of a negative resist composition, inversely the resist film in the exposed region is insolubilized in the developer whereas the resist film in the unexposed region is dissolved.

A negative pattern can be obtained from the positive resist composition comprising a base polymer containing an acid labile group by effecting organic solvent development. Examples of the developer used herein include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. The organic solvent may be used singly or as a mixture of two or more kinds thereof.

At the end of development, the resist film is rinsed. The rinsing liquid is preferably a solvent which is miscible with the developer and does not dissolve the resist film. Examples of preferred solvents include alcohols having 3 to 10 carbon atoms, ether compounds having 8 to 12 carbon atoms, alkanes, alkenes, and alkynes each having 6 to 12 carbon atoms, and aromatic solvents.

Examples of the alcohols having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Examples of the ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Examples of the alkanes having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Examples of the alkenes having 6 to 12 carbon atoms include hexene, heptene, octene, cyclohexene, methylcyclohexene, dimethylcyclohexene, cycloheptene, and cyclooctene. Examples of the alkynes having 6 to 12 carbon atoms include hexyne, heptyne, and octyne.

Examples of the aromatic solvents include toluene, xylene, ethylbenzene, isopropylbenzene, tert-butylbenzene, and mesitylene.

Rinsing is effective for reducing the resist pattern collapse and defect formation. However, rinsing is not essential. If rinsing is omitted, the amount of solvent used may be reduced.

A hole or trench pattern after development may be shrunk by the thermal flow, RELACS®, or DSA process. A hole pattern is shrunk by applying a shrink agent thereto, and baking the resist composition such that the shrink agent may undergo crosslinking at the resist film surface due to diffusion of the acid catalyst from the resist film during baking, and the shrink agent may attach to the sidewall of the hole pattern. The baking temperature is preferably 70 to 180° C., more preferably 80 to 170° C., and the baking time is preferably 10 to 300 seconds to remove the excess shrink agent and shrink the hole pattern.

### EXAMPLES

Hereinafter, the present invention is specifically described with reference to Synthesis Examples, Examples, and Comparative Examples, but the present invention is not limited to the following Examples.

Structures of the acid generators PAG-1 to PAG-27 used in the resist compositions are shown below. PAG-1 to PAG-27 were each synthesized by ion exchange between a sulfonium salt containing a sulfonium cation having formula (1) and a trifluoromethylsulfonic acid anion, and an ammonium cation and a sulfonic acid anion having a carbon atom to which an iodine atom is bonded.

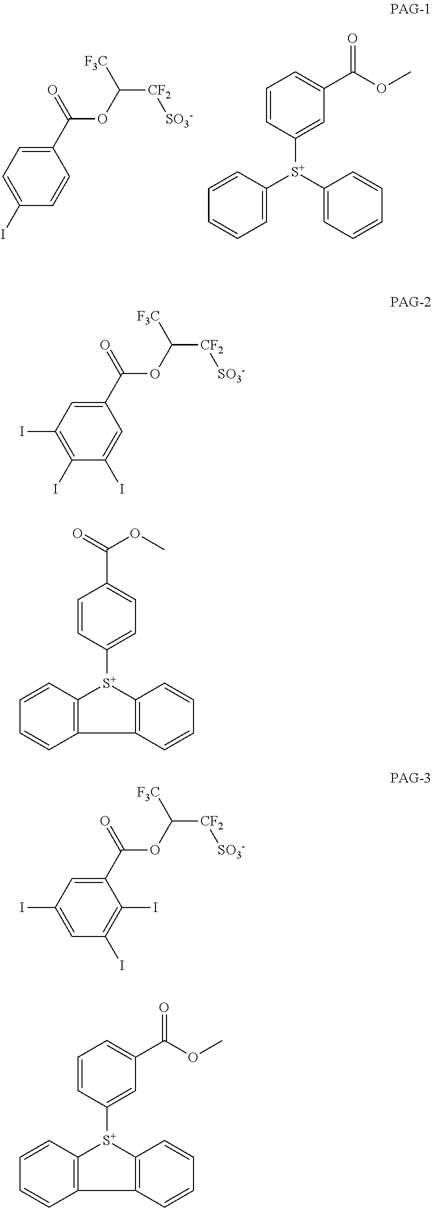

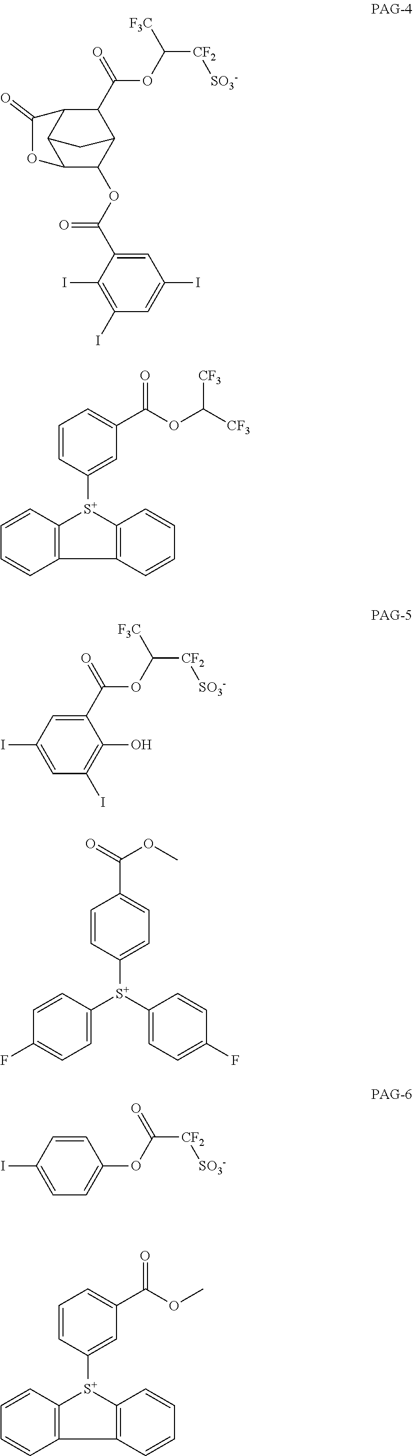

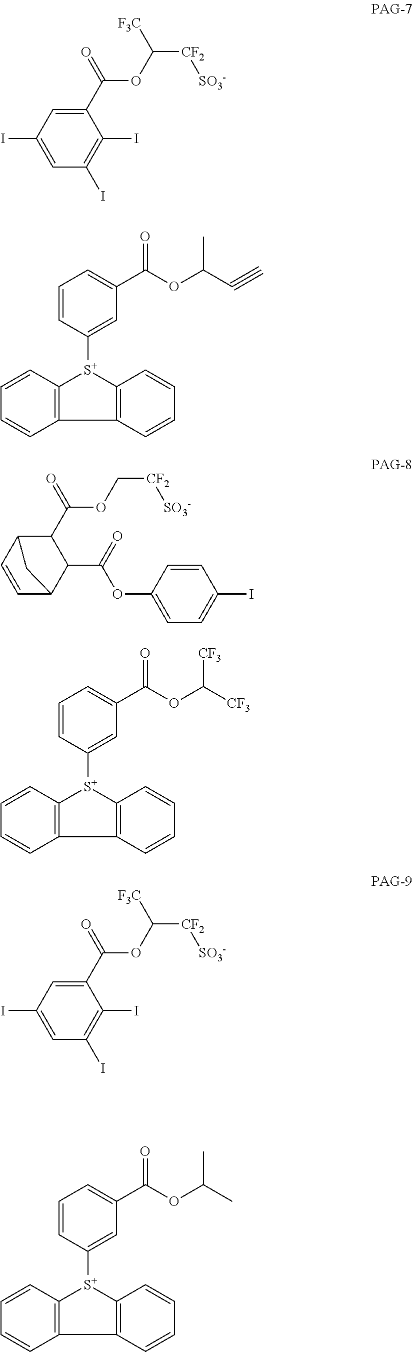

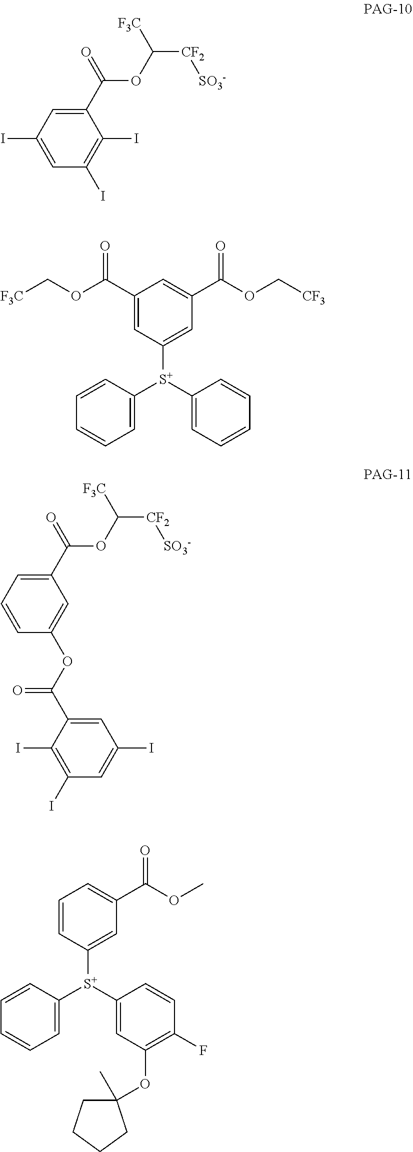

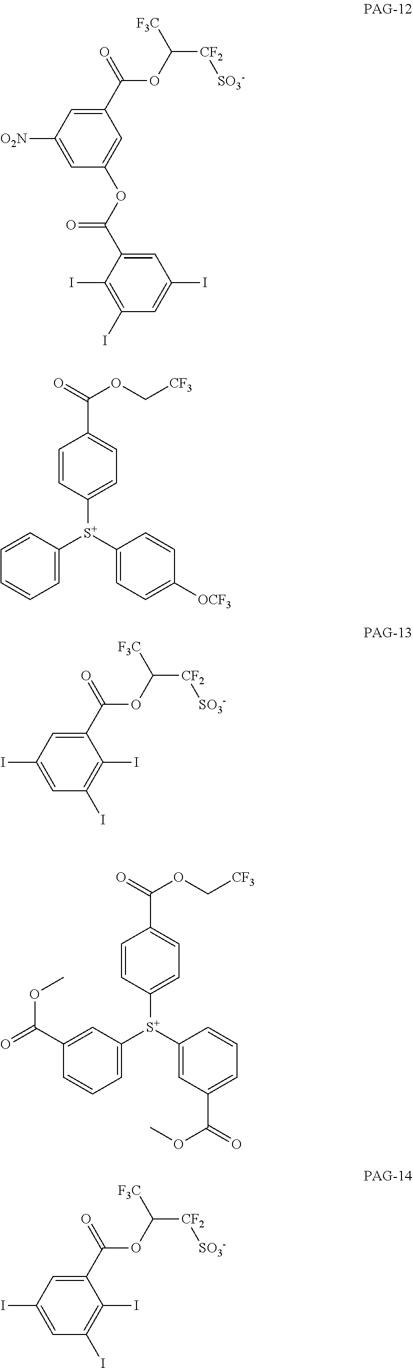

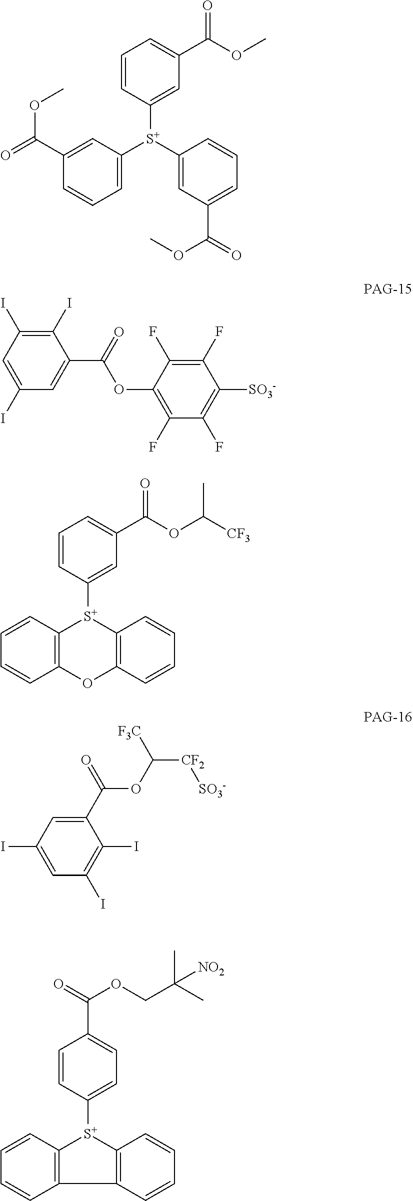

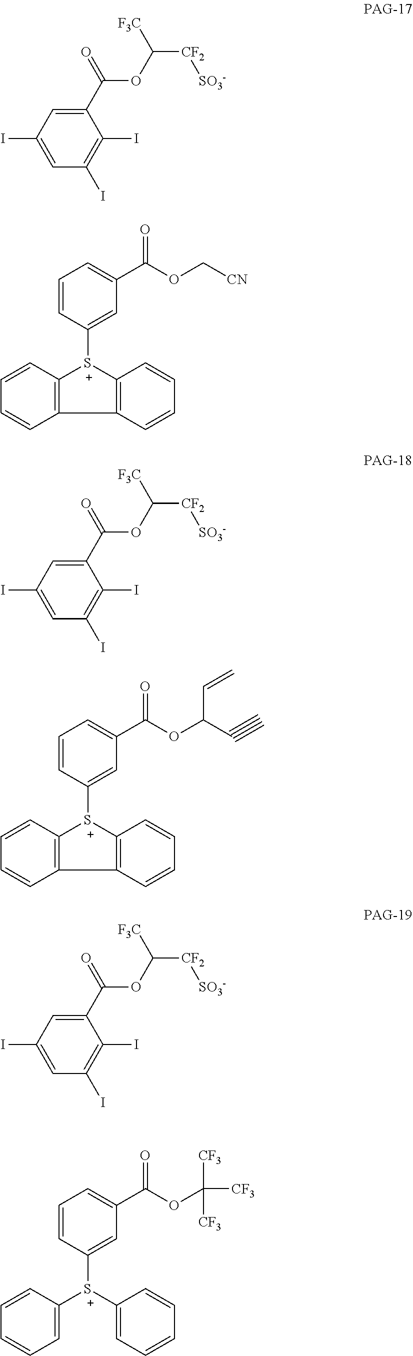

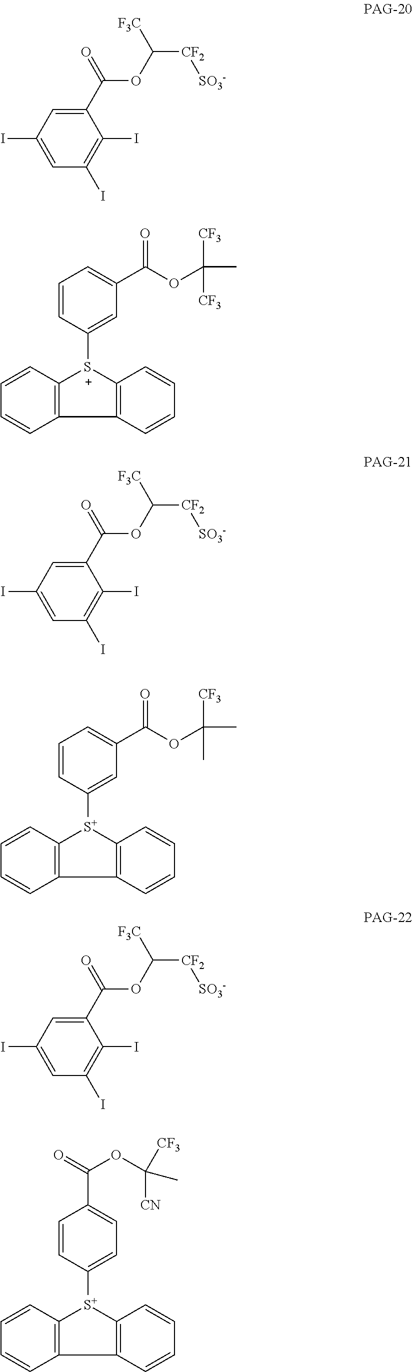

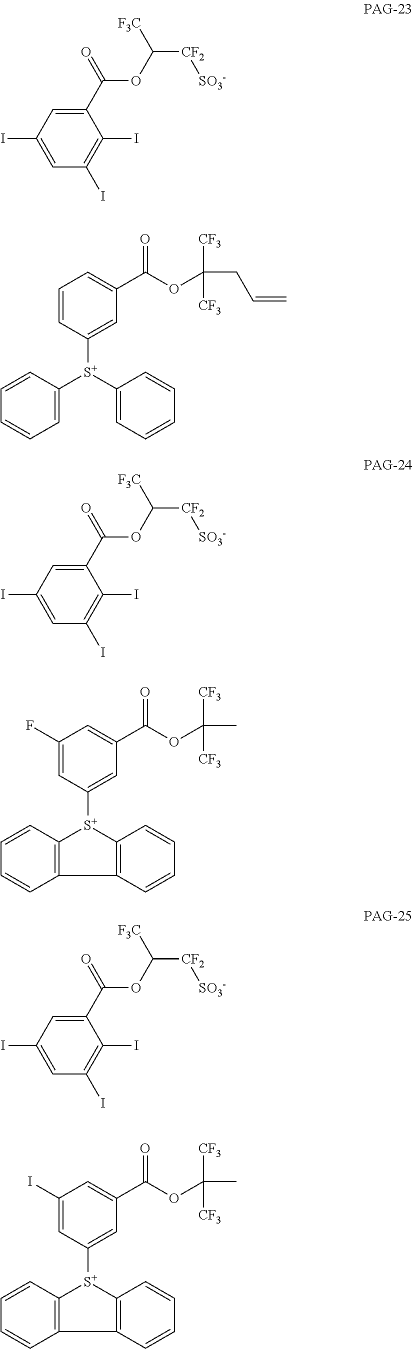

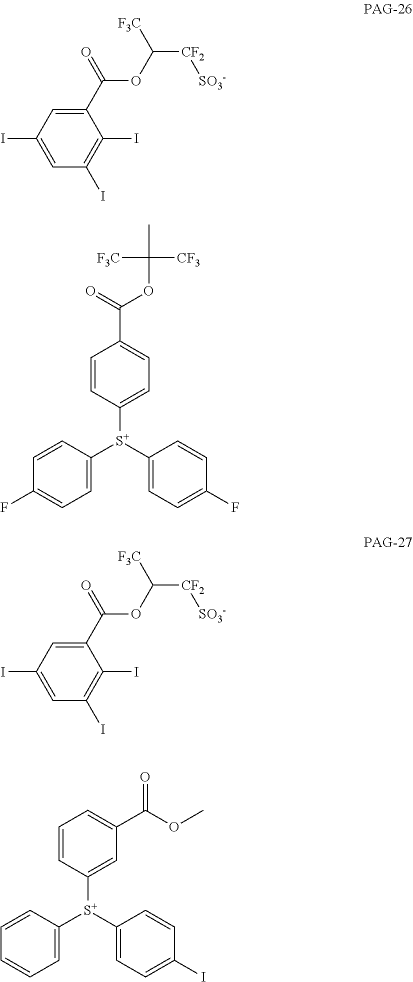

### Synthesis Example Synthesis of Base Polymers P-1 to P-5

Base polymers P-1 to P-5 each having the composition shown below were synthesized by combining monomers, effecting copolymerization reaction in a THF solvent, pouring the reaction solution into methanol, washing the solid precipitate with hexane, isolation, and drying. The base polymers were analyzed for composition by ¹H-NMR spectroscopy and for Mw and Mw/Mn by GPC versus polystyrene standards using a THF solvent.

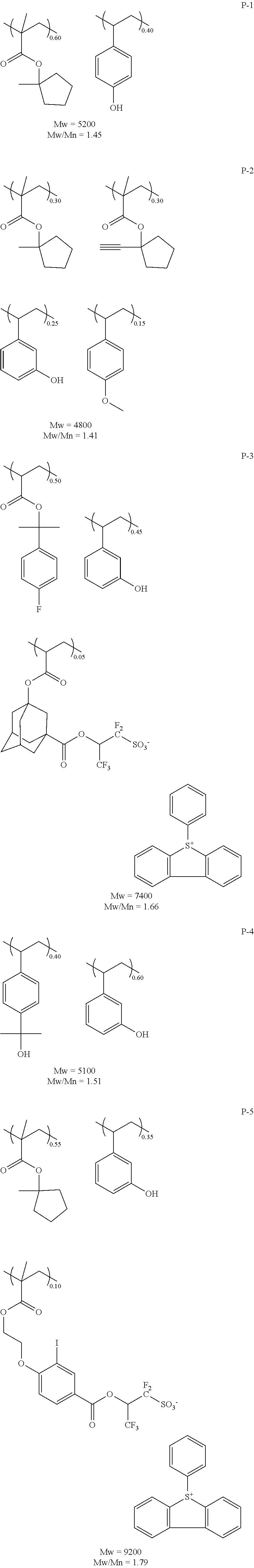

### Examples 1 to 31 and Comparative Examples 1 to 3 Preparation and Evaluation of Resist Compositions

(1) Preparation of Resist Compositions

In a solvent in which 40 ppm of Polyfox PF-636 manufactured by Omnova Solutions, Inc. was dissolved as a surfactant, the components having the composition shown in Tables 1 to 3 were dissolved. The resulting solution was filtered through a filter having a pore size of 0.2 μm to prepare a resist composition.

The components in Tables 1 to 3 are as follows.

Organic Solvents:
PGMEA (propylene glycol monomethyl ether acetate)
EL (ethyl lactate)
DAA (diacetone alcohol)

Comparative Acid Generators: cPAG-1 and cPAG-2

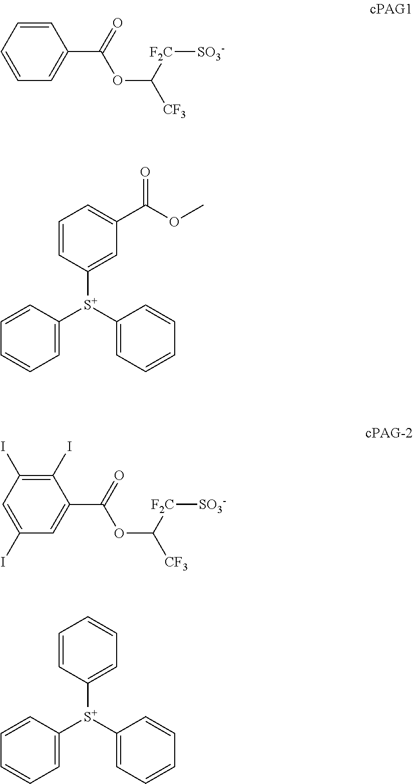

Quenchers: Q-1 and Q-2

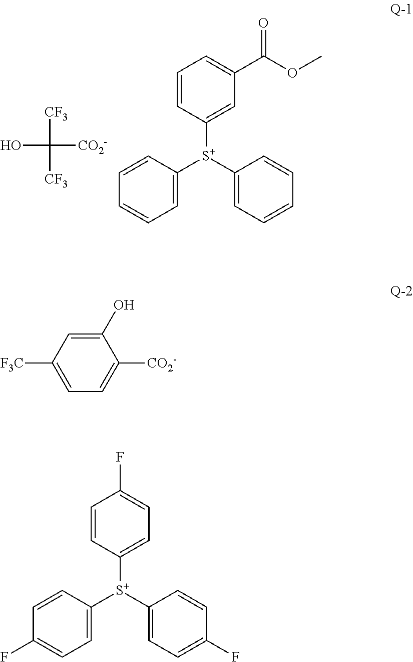

(2) EUV Lithography Evaluation

Each of the resist compositions shown in Tables 1 to 3 was applied by spin coating to a silicon substrate having a 20-nm coating of silicon-containing spin-on hard mask SHB-A940 (Shin-Etsu Chemical Co., Ltd., Si content 43 wt %) and prebaked on a hotplate at 105° C. for 60 seconds to form a 50 nn-thick resist film. Using an EUV scanner NXE3400 (ASML, NA 0.33, σ 0.9/0.6, quadrupole illumination), the resist film was exposed to EUV through a mask bearing a hole pattern at a pitch of 40 nm (on-wafer size) and +20% bias. The resist film was baked (PEB) on a hotplate at the temperature shown in Tables 1 to 3 for 60 seconds and developed in a 2.38 wt % TMAH aqueous solution for 30 seconds to form a hole pattern having a size of 20 nm in Examples 1 to 25 and 27 to 31 and Comparative Examples 1 and 2, and a dot pattern having a size of 20 nm in Example 26 and Comparative Example 3. The resist pattern was observed under CD-SEM (CG6300, Hitachi High-Technologies Corp.). The exposure dose that provides a hole pattern or a dot pattern was reported as sensitivity. The size of 50 holes or dots printed at that dose was measured, from which a 3-fold value (3σ) of the standard deviation (σ) was computed and reported as dimensional variation (CDU). The results are collectively shown in Tables 1 to 3.

TABLE 1

| | | Base polymer | Acid generator | Quencher | Organic solvent | PEB | Sensitivity | CDU |
|---|---|---|---|---|---|---|---|---|
| | | (pbw) | (pbw) | (pbw) | (pbw) | (° C.) | (mJ/cm²) | (nm) |
| Example | 1 | P-1 | PAG-1 | Q-1 | PGMEA (500) | 90 | 29 | 2.9 |
| | | (100) | (19.5) | (5.32) | EL (2000) | | | |
| | 2 | P-1 | PAG-2 | Q-1 | PGMEA (500) | 90 | 26 | 2.7 |
| | | (100) | (25.7) | (5.32) | EL (2000) | | | |
| | 3 | P-1 | PAG-3 | Q-1 | PGMEA (500) | 90 | 25 | 2.8 |
| | | (100) | (25.8) | (5.32) | EL (2000) | | | |
| | 4 | P-1 | PAG-4 | Q-1 | PGMEA (2000) | 90 | 24 | 2.7 |
| | | (100) | (33.7) | (5.32) | DAA (500) | | | |
| | 5 | P-1 | PAG-5 | Q-1 | PGMEA (2000) | 90 | 25 | 2.6 |
| | | (100) | (24.0) | (5.32) | DAA (500) | | | |
| | 6 | P-1 | PAG-6 | Q-1 | PGMEA (2000) | 90 | 28 | 2.9 |
| | | (100) | (17.4) | (5.32) | DAA (500) | | | |
| | 7 | P-1 | PAG-7 | Q-1 | PGMEA (2000) | 90 | 26 | 2.6 |
| | | (100) | (26.7) | (5.32) | DAA (500) | | | |
| | 8 | P-1 | PAG-8 | Q-1 | PGMEA (2000) | 90 | 28 | 2.8 |
| | | (100) | (24.6) | (5.32) | DAA (500) | | | |
| | 9 | P-1 | PAG-9 | Q-1 | PGMEA (2000) | 90 | 27 | 2.7 |
| | | (100) | (26.5) | (5.32) | DAA (500) | | | |
| | 10 | P-1 | PAG-10 | Q-1 | PGMEA (2000) | 90 | 25 | 2.7 |
| | | (100) | (30.7) | (5.32) | DAA (500) | | | |
| | 11 | P-1 | PAG-11 | Q-1 | PGMEA (2000) | 90 | 27 | 2.7 |
| | | (100) | (31.7) | (5.32) | DAA (500) | | | |
| | 12 | P-1 | PAG-12 | Q-1 | PGMEA (2000) | 90 | 26 | 2.6 |
| | | (100) | (33.7) | (5.32) | DAA (500) | | | |
| | 13 | P-1 | PAG-13 | Q-1 | PGMEA (2000) | 90 | 28 | 2.6 |
| | | (100) | (30.4) | (5.32) | DAA (500) | | | |
| | 14 | P-1 | PAG-14 | Q-1 | PGMEA (2000) | 90 | 26 | 2.7 |
| | | (100) | (28.7) | (5.32) | DAA (500) | | | |
| | 15 | P-1 | PAG-15 | Q-2 | PGMEA (2000) | 90 | 26 | 2.5 |
| | | (100) | (28.6) | (5.22) | DAA (500) | | | |
| | 16 | P-1 | PAG-16 | Q-2 | PGMEA (2000) | 90 | 28 | 2.5 |
| | | (100) | (28.0) | (5.22) | DAA (500) | | | |
| | 17 | P-1 | PAG-17 | Q-2 | PGMEA (2000) | 90 | 27 | 2.7 |
| | | (100) | (26.4) | (5.22) | DAA (500) | | | |
| | 18 | P-1 | PAG-18 | Q-2 | PGMEA (2000) | 90 | 27 | 2.5 |
| | | (100) | (27.0) | (5.22) | DAA (500) | | | |
| | 19 | P-1 | PAG-19 | Q-2 | PGMEA (2000) | 90 | 26 | 2.5 |
| | | (100) | (30.9) | (5.22) | DAA (500) | | | |
| | 20 | P-1 | PAG-20 | Q-2 | PGMEA (2000) | 90 | 26 | 2.6 |
| | | (100) | (28.2) | (5.22) | DAA (500) | | | |
| | 21 | P-1 | PAG-21 | Q-2 | PGMEA (2000) | 90 | 27 | 2.6 |
| | | (100) | (28.4) | (5.22) | DAA (500) | | | |
| | 22 | P-1 | PAG-22 | Q-2 | PGMEA (2000) | 90 | 27 | 2.7 |
| | | (100) | (30.2) | (5.22) | DAA (500) | | | |
| | 23 | P-1 | PAG-23 | Q-2 | PGMEA (2000) | 90 | 28 | 2.8 |
| | | (100) | (26.7) | (5.22) | DAA (500) | | | |
| | 24 | P-2 | PAG-7 | Q-2 | PGMEA (2000) | 90 | 26 | 2.5 |
| | | (100) | (26.7) | (5.22) | DAA (500) | | | |
| | 25 | P-3 | PAG-7 | Q-2 | PGMEA (2000) | 90 | 28 | 2.5 |
| | | (100) | (13.4) | (5.22) | DAA (500) | | | |
| | 26 | P-4 | PAG-5 | Q-2 | PGMEA (2000) | 130 | 32 | 3.0 |
| | | (100) | (19.1) | (3.22) | DAA (500) | | | |

TABLE 2

| | | Base polymer | Acid generator | Quencher | Organic solvent | PEB | Sensitivity | CDU |
|---|---|---|---|---|---|---|---|---|
| | | (pbw) | (pbw) | (pbw) | (pbw) | (° C.) | (mJ/cm²) | (nm) |
| Example | 27 | P-1 | PAG-24 | Q-2 | PGMEA (2000) | 90 | 26 | 2.6 |
| | | (100) | (29.9) | (5.22) | DAA (500) | | | |
| | 28 | P-1 | PAG-25 | Q-2 | PGMEA (2000) | 90 | 26 | 2.7 |
| | | (100) | (32.6) | (5.22) | DAA (500) | | | |
| | 29 | P-1 | PAG-26 | Q-2 | PGMEA (2000) | 90 | 26 | 2.8 |
| | | (100) | (30.4) | (5.22) | DAA (500) | | | |
| | 30 | P-1 | PAG-27 | Q-2 | PGMEA (2000) | 90 | 27 | 2.8 |
| | | (100) | (29.0) | (5.22) | DAA (500) | | | |
| | 31 | P-5 | PAG-3 | Q-2 | PGMEA (2000) | 90 | 23 | 2.7 |
| | | (100) | (10.3) | (5.22) | DAA (500) | | | |

TABLE 3

| | | Base polymer | Acid generator | Quencher | Organic solvent | PEB | Sensitivity | CDU |
|---|---|---|---|---|---|---|---|---|
| | | (pbw) | (pbw) | (pbw) | (pbw) | (° C.) | (mJ/cm²) | (nm) |
| Comparative | 1 | P-1 | cPAG-1 | Q-1 | PGMEA (2000) | 90 | 34 | 3.7 |
| Example | | (100) | (16.1) | (5.32) | DAA (500) | | | |
| | 2 | P-1 | cPAG-2 | Q-1 | PGMEA (2000) | 90 | 28 | 3.0 |
| | | (100) | (24.4) | (5.32) | DAA (500) | | | |
| | 3 | P-4 | cPAG-1 | Q-1 | PGMEA (2000) | 130 | 41 | 4.0 |
| | | (100) | (13.1) | (3.32) | DAA (500) | | | |

From the results shown in Tables 1 to 3, it was found that the resist composition of the present invention, which comprises, as an acid generator, a sulfonium salt containing a sulfonic acid anion having a carbon atom to which an iodine atom is bonded and a sulfonium cation having formula (1), has high sensitivity and good CDU.

Japanese Patent Application No. 2022-169784 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising an acid generator containing a sulfonium salt containing a sulfonic acid anion having a carbon atom to which an iodine atom is bonded and a sulfonium cation having formula (1): 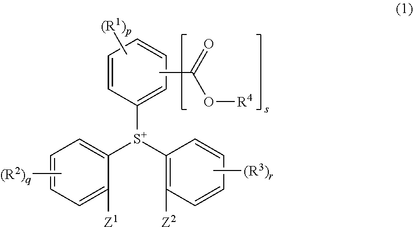
wherein p, q, and r are each independently an integer of 0 to 3, and s is 1 or 2, provided that 1≤r+s≤3,
R¹ is a halogen atom, a trifluoromethyl group, a trifluoromethoxy group, a trifluoromethylthio group, a nitro group, a cyano group, —C(═O)—R⁵, —O—C(═O)—R⁵, or —O—R⁵,
R² and R³ are each independently a halogen atom, a trifluoromethyl group, a trifluoromethoxy group, a trifluoromethylthio group, a nitro group, a cyano group, —C(═O)—O—R⁴, —C(═O)—R⁵, —O—C(═O)—R⁵, —O—C(═O)—O—R⁵, or —O—R⁵,
R⁴ is a C₁-C₁₀ aliphatic hydrocarbyl group, a C₆-C₁₂ aryl group, or a C₄-C₁₂ heteroaryl group, some or all of hydrogen atoms of these groups may be substituted with a halogen atom other than an iodine atom, a hydroxy group, a cyano group, a nitro group, a halogenated alkyl group, a halogenated alkoxy group, or a halogenated alkylthio group, and some of —CH₂— of these groups may be substituted with an ether bond, an ester bond, a carbonyl group, or a sulfonic ester bond, provided that R⁴ is not an acid labile group,
R⁵ is a C₁-C₁₀ hydrocarbyl group, and
Z¹ and Z² are each independently a hydrogen atom, a halogen atom, a trifluoromethyl group, a trifluoromethoxy group, a trifluoromethylthio group, a nitro group, a cyano group, —C(═O)—O—R⁴, —C(═O)—R⁵, —O—C(═O)—R⁵, —O—C(═O)—O—R⁵, or —O—R⁵, and Z¹ and Z² may together form a single bond, an ether bond, a carbonyl group, —N(R^{N})—, a sulfide bond, or a sulfonyl group, wherein R^{N} is a hydrogen atom or a C₁-C₆ saturated hydrocarbyl group.

2. The resist composition of claim 1, wherein the sulfonic acid anion having a carbon atom to which an iodine atom is bonded has formula (2)-1: 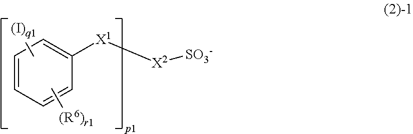
wherein p1 is an integer of 1 to 3, q1 is an integer of 1 to 5, and r1 is an integer of 0 to 4, provided that 1≤q1+r1≤5,
R⁶ is a hydroxy group, a carboxy group, a halogen atom other than an iodine atom, an amino group, or a C₁-C₂₀ hydrocarbyl group, a C₁-C₂₀ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a halogen atom, a hydroxy group, an amino group, or an ether bond, —N(R^{6A})(R^{6B}), —N(R^{6C})—C(═O)—R^{6D}, or —N(R^{6C})—C(═O)—O—R^{6D}, wherein R^{6A} and R^{6B} are each independently a hydrogen atom or a C₁-C₆ saturated hydrocarbyl group, R^{6C} is a hydrogen atom or a C₁-C₆ saturated hydrocarbyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group, R^{6D} is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group,
X¹ is a single bond, an ether bond, an amide bond, a urethane bond, an ester bond, or a C₁-C₆ saturated hydrocarbylene group which may contain an ether bond or an ester bond, and
X² is a single bond or a C₁-C₂₂ divalent linking group when p1 is 1, and a C₁-C₂₂ (p1+1)-valent linking group which may contain an oxygen atom, a sulfur atom, a nitrogen atom, or a halogen atom when p1 is 2 or 3.

3. The resist composition of claim 1, wherein the sulfonic acid anion having a carbon atom to which an iodine atom is bonded has formula (2)-2: 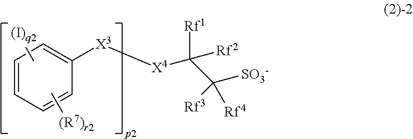
wherein p2 is an integer of 1 to 3, q2 is an integer of 1 to 5, and r2 is an integer of 0 to 4, provided that 1≤q2+r2≤5,
R⁷ is a hydroxy group, a carboxy group, a halogen atom other than an iodine atom, an amino group, or a C₁-C₂₀ hydrocarbyl group, a C₁-C₂₀ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a halogen atom, a hydroxy group, an amino group, or an ether bond, —N(R^{7A})(R^{7B}), —N(R^{7C})—C(═O)—R^{7D}, or —N(R^{7C})—C(═O)—O—R^{7D}, wherein R^{7A} and R^{7B} are each independently a hydrogen atom or a C₁-C₆ saturated hydrocarbyl group, R^{7C} is a hydrogen atom or a C₁-C₆ saturated hydrocarbyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group, R^{7D} is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group,
X³ is a single bond, an ether bond, an amide bond, a urethane bond, an ester bond, or a C₁-C₆ saturated hydrocarbylene group which may contain an ether bond or an ester bond,
X⁴ is a single bond or a C₁-C₂₀ divalent linking group when p2 is 1, and a C₁-C₂₀ (p2+1)-valent linking group which may contain an oxygen atom, a sulfur atom, or a nitrogen atom when p2 is 2 or 3, and
Rf¹ to Rf⁴ are each independently a hydrogen atom, a fluorine atom, or a trifluoromethyl group, provided that at least one of Rf¹ to Rf⁴ is a fluorine atom or a trifluoromethyl group, and Rf¹ and Rf² may together form a carbonyl group.

4. The resist composition of claim 1, further comprising a base polymer.

5. The resist composition of claim 4, wherein the base polymer further contains repeat units having formula (a1) or (a2): 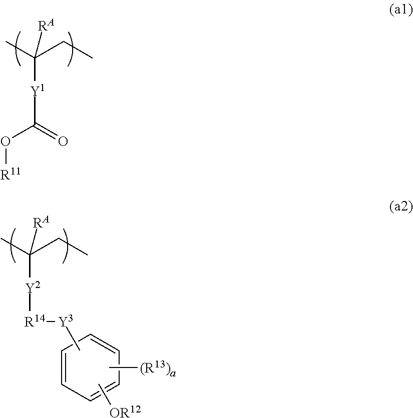
wherein R^{A} is each independently a hydrogen atom or a methyl group,
Y¹ is a single bond, a phenylene group, a naphthylene group, or a C₁-C₁₂ linking group containing at least one moiety selected from an ester bond, an ether bond, and a lactone ring,
Y² is a single bond or an ester bond,
Y³ is a single bond, an ether bond, or an ester bond,
R¹¹ and R¹² are each independently an acid labile group,
R¹³ is a C₁-C₄ saturated hydrocarbyl group, a halogen atom, a C₂-C₅ saturated hydrocarbylcarbonyl group, a cyano group, or a C₂-C₅ saturated hydrocarbyloxycarbonyl group,
R¹⁴ is a single bond or a C₁-C₆ alkanediyl group which may contain an ether bond or an ester bond, and
a is an integer of 0 to 4.

6. The resist composition of claim 5, which is a chemically amplified positive resist composition.

7. The resist composition of claim 4, wherein the base polymer is free of an acid labile group.

8. The resist composition of claim 7, which is a chemically amplified negative resist composition.

9. The resist composition of claim 1, further comprising an organic solvent.

10. The resist composition of claim 1, further comprising a quencher.

11. The resist composition of claim 1, further comprising a surfactant.

12. A pattern forming process comprising the steps of:
applying the resist composition of claim 1 onto a substrate to form a resist film thereon,
exposing the resist film to high-energy radiation, and
developing the exposed resist film in a developer.

13. The pattern forming process of claim 12, wherein the high-energy radiation is ArF excimer laser having a wavelength of 193 nm, KrF excimer laser having a wavelength of 248 nm, electron beam, or extreme ultraviolet having a wavelength of 3 to 15 nm.
